(19) United States
(12) Patent Application Publication
(10) Pub. No.: US 2024/0036254 A1
(43) Pub. Date: Feb. 1, 2024

(54) HIGH-CAPACITY OPTICAL INPUT/OUTPUT FOR DATA PROCESSORS

(71) Applicant: Nubis Communications, Inc., Aberdeen, NJ (US)

(72) Inventors: Peter Johannes Winzer, Aberdeen, NJ (US); Peter James Pupalaikis, Ramsey, NJ (US); Brett Michael Dunn Sawyer, Pasadena, CA (US); Karen Liu, Montclair, NJ (US)

(21) Appl. No.: 18/127,494

(22) Filed: Mar. 28, 2023

Related U.S. Application Data
(60) Provisional application No. 63/324,429, filed on Mar. 28, 2022.

(51) Int. Cl. G02B 6/12

(52) U.S. Cl. CPC G02B 6/12014; G02B 6/12004; G02B 2006/12085

(57) ABSTRACT

A system includes a wafer-scale processing module that has an array of data processors. Optical input/output modules are provided near edges of the wafer-scale processing module. Each optical input/output module includes an array of photonic integrated circuits that convert optical signals received from optical links to electrical signals that are transmitted to the data processors, and convert electrical signals received from the data processors to optical signals that are output to the optical links.

### CROSS-REFERENCE TO RELATED APPLICATION

This application claims priority to U.S. Provisional Application 63/324,429, filed on Mar. 28, 2022. The entire disclosure of the above application is hereby incorporated by reference.

### TECHNICAL FIELD

This document describes high-capacity optical input/output for data processors.

### BACKGROUND

This section introduces aspects that can help facilitate a better understanding of the disclosure. Accordingly, the statements of this section are to be read in this light and are not to be understood as admissions about what is in the prior art or what is not in the prior art.

As the input/output (I/O) capacities of electronic processing chips increase, electrical signals may not provide sufficient input/output capacity across the limited size of a practically viable electronic chip package. For example, some data centers include racks of data processing servers (e.g., switch servers) and use optical fibers to transmit optical signals between the data processing servers. Each data processing server receives first optical signals from optical fiber cables, converts the first optical signals to first electrical signals, perform operations (e.g., switching operations) on the first electrical signals to generate second electrical signals, convert the second electrical signals to second optical signals, and outputs the second optical signals through the optical fiber cables.

### SUMMARY OF THE INVENTION

In a general aspect, a system includes: a first optical input/output module including a plurality of photonic integrated circuits arranged in a two-dimensional pattern including at least three photonic integrated circuits, and at least one data processor that is configured to receive, directly or through an interface circuit, the first electrical signals generated by at least some of the photonic integrated circuits, and to transmit, directly or through the interface circuit, the second electrical signals to at least some of the photonic integrated circuits. Each of at least some of the photonic integrated circuits is configured to receive first optical signals and generate first electrical signals based on the first optical signals, each of at least some of the photonic integrated circuits is configured to receive second electrical signals and generate second optical signals based on the second electrical signals.

Implementations can include one or more of the following features. The first optical input/output module can include a plurality of photonic integrated circuits arranged in a two-dimensional array including at least two rows and at least two columns of photonic integrated circuits.

The first optical input/output module can include a plurality of optical connectors, in which each optical connector is associated with a photonic integrated circuit, and the optical connector is coupled to a first surface of the photonic integrated circuit. The first optical input/output module can include a plurality of sets of first electronic integrated circuits, in which each set of the first electronic integrated circuit is associated with one of the photonic integrated circuits, and each set of the first electronic integrated circuits includes at least two electronic integrated circuits that are coupled to the first surface of the associated photonic integrated circuit.

Each set of first electronic integrated circuits can include two electronic integrated circuits that are positioned on opposite sides of the optical connector along a plane parallel to the first surface of the associated photonic integrated circuit.

Each set of first electronic integrated circuits can include three electronic integrated circuits that surround three sides of the optical connector along a plane parallel to the first surface of the photonic integrated circuit.

Each set of first electronic integrated circuits can include four electronic integrated circuits that surround four sides of the optical connector along a plane parallel to the first surface of the photonic integrated circuit.

Each set of first electronic integrated circuits can include at least one of an electrical drive amplifier or a transimpedance amplifier.

The first optical input/output module can include a substrate, in which the plurality of photonic integrated circuits are mounted on the substrate. The first optical input/output module can include a plurality of sets of second electronic integrated circuits mounted on the substrate, in which each set of second electronic integrated circuits is associated with a photonic integrated circuit and electrically coupled to the photonic integrated circuit through one or more signal conductors and/or traces.

Each set of second electronic integrated circuits can include three electronic integrated circuits that surround three sides of the photonic integrated circuit along a plane parallel to a first surface of the substrate.

Each set of second electronic integrated circuits can include four electronic integrated circuits that surround four sides of the photonic integrated circuit along a plane parallel to a first surface of the substrate.

Each set of second electronic integrated circuits can include a serializers/deserializers module.

Each of at least some of the photonic integrated circuits can include an array of grating couplers, a plurality of optical waveguides coupled to the array of grating couplers, and a plurality of photodetectors coupled to the plurality of optical waveguides.

Each of the at least one data processor can include at least one of a network switch, a central processor unit, a graphics processor unit, a tensor processing unit, a neural network processor, an artificial intelligence accelerator, a digital signal processor, a microcontroller, an application specific integrated circuit (ASIC), or a data storage device.

The system can include a wafer-scale processing module including a plurality of data processors, in which the first optical input/output module is configured to receive a plurality of first optical signals through at least some of a plurality of optical links, generate a plurality of first electrical signals based on the plurality of first optical signals, and transmit the plurality of first electrical signals to the data processors.

The plurality of data processors can be configured to generate a plurality of second electrical signals that are transmitted to the first optical input/output module, the first optical input/output module can be configured to generate a plurality of second optical signals based on the plurality of second electrical signals, and output the plurality of optical signals through at least some of the plurality of optical links.

The wafer-scale processing module can include a wafer and a two-dimensional arrangement of at least three data processors formed on the wafer.

The two-dimensional arrangement of at least three data processors can include an array of at least two rows and at least two columns of data processors.

The array of data processors can include at least three rows and at least three columns of data processors.

The array of data processors can include at least four rows and at least four columns of data processors.

The first optical input/output module can include at least four photonic integrated circuits that are configured to transmit electrical signals to and receive electrical signals from the wafer-scale processing module.

The first optical input/output module can include at least eight photonic integrated circuits that are configured to transmit electrical signals to and receive electrical signals from the wafer-scale processing module.

The first optical input/output module can include at least sixteen photonic integrated circuits that are configured to transmit electrical signals to and receive electrical signals from the wafer-scale processing module.

The first optical input/output module can include at least thirty-two photonic integrated circuits that are configured to transmit electrical signals to and receive electrical signals from the wafer-scale processing module.

The first optical input/output module can include at least sixty-four photonic integrated circuits that are configured to transmit electrical signals to and receive electrical signals from the wafer-scale processing module.

Each of more than half of the photonic integrated circuits in the first optical input/output module can have electronic integrated circuits arranged at four sides of the photonic integrated circuit.

Each of more than 80% of the photonic integrated circuits in the first optical input/output module can have electronic integrated circuits arranged at four sides of the photonic integrated circuit.

The plurality of photonic integrated circuits can be arranged in a staggered array configuration.

The plurality of photonic integrated circuits can include a staggered array of photonic integrated circuits. The staggered array can include a first row, a second row, and a third row. In the first row, the photonic integrated circuits can be positioned at (x, y) coordinates (1, 1), (3, 1), (5, 1), . . . , (n1, 1), n1 being an odd number. In the second row, the photonic integrated circuits can be positioned at (x, y) coordinates (2, 2), (4, 2), (6, 2), . . . , (n2, 2), n2 being an even number. In the third row, the photonic integrated circuits can be positioned at (x, y) coordinates (1, 3), (3, 3), (5, 3), . . . , (n3, 3), n3 being an odd number.

The wafer-scale processing module can have a first edge and a second edge, and the first optical input/output module can be positioned in a vicinity of the first edge. The system can include a second optical input/output module that is positioned in a vicinity of the second edge of the wafer-scale processing module. The second optical input/output module can include a plurality of photonic integrated circuits arranged in a two-dimensional pattern including at least three photonic integrated circuits. Each of at least some of the photonic integrated circuits can be configured to receive third optical signals and generate third electrical signals based on the third optical signals, and each of at least some of the photonic integrated circuits can be configured to receive fourth electrical signals and generate fourth optical signals based on the fourth electrical signals. At least some of the data processors in the wafer-scale processing module can be configured to receive the third electrical signals generated by the second optical input/output module, and to transmit the fourth electrical signals to the second optical input/output module.

The wafer-scale processing module can have a third edge. The system can include a third optical input/output module that is positioned in a vicinity of the third edge of the wafer-scale processing module. The third optical input/output module can include a plurality of photonic integrated circuits arranged in a two-dimensional pattern including at least three photonic integrated circuits, in which each of at least some of the photonic integrated circuits can be configured to receive 5^{th} optical signals and generate 5^{th} electrical signals based on the 5^{th} optical signals, and each of at least some of the photonic integrated circuits can be configured to receive 6^{th} electrical signals and generate 6^{th} optical signals based on the 6^{th} electrical signals. At least some of the data processors in the wafer-scale processing module can be configured to receive the 5^{th} electrical signals generated by the third optical input/output module, and to transmit the 5^{th} electrical signals to the third optical input/output module.

The wafer-scale processing module can have a fourth edge. The system can include a fourth optical input/output module that is positioned in a vicinity of the fourth edge of the wafer-scale processing module. The fourth optical input/output module can include a plurality of photonic integrated circuits arranged in a two-dimensional pattern including at least three photonic integrated circuits, in which each of at least some of the photonic integrated circuits can be configured to receive 7^{th} optical signals and generate 7^{th} electrical signals based on the 7^{th} optical signals, and each of at least some of the photonic integrated circuits can be configured to receive 8^{th} electrical signals and generate 8^{th} optical signals based on the 8^{th} electrical signals. At least some of the data processors in the wafer-scale processing module can be configured to receive the 7^{th} electrical signals generated by the fourth optical input/output module, and to transmit the 8^{th} electrical signals to the fourth optical input/output module.

The first optical input/output module can be configured to support at least 50 Tbps data throughput to the first edge of the wafer-scale processing module.

The second optical input/output module can be configured to support at least 50 Tbps data throughput to the second edge of the wafer-scale processing module.

The third optical input/output module can be configured to support at least 50 Tbps data throughput to the third edge of the wafer-scale processing module.

The fourth optical input/output module can be configured to support at least 50 Tbps data throughput to the fourth edge of the wafer-scale processing module.

The first, second, third, and fourth optical input/output modules can be configured to support an aggregate data throughput of at least 200 Tbps to the wafer-scale processing module.

Each of some of the second electronic integrated circuits can be electrically interconnected to two or more photonic integrated circuits.

Each of some of the second electronic integrated circuits can include a serializers/deserializers module that is configured to condition the electrical signals transmitted to or from two or more photonic integrated circuits.

The first optical input/output module can include two rows of photonic integrated circuits that support an aggregate data throughput of approximately 59.1 Tbps.

The wafer-scale processing module can have a first edge, the first optical input/output module can be positioned in a vicinity of the first edge, and the first optical input/output module can be configured to support an aggregate data throughput per unit edge length of approximately 288 Gbps/mm.

The first optical input/output module can include three rows of photonic integrated circuits that support an aggregate data throughput of approximately 89.6 Tbps.

The wafer-scale processing module can have a first edge, the first optical input/output module can be positioned in a vicinity of the first edge, and the first optical input/output module can be configured to support an aggregate data throughput per unit edge length of approximately 437 Gbps/mm.

The first optical input/output module can include four rows of photonic integrated circuits that support an aggregate data throughput of approximately 118.3 Tbps.

The wafer-scale processing module can have a first edge, the first optical input/output module can be positioned in a vicinity of the first edge, and the first optical input/output module can be configured to support an aggregate data throughput per unit edge length of approximately 576 Gbps/mm.

The first optical input/output module can include five rows of photonic integrated circuits that support an aggregate data throughput of approximately 148.7 Tbps.

The wafer-scale processing module can have a first edge, the first optical input/output module can be positioned in a vicinity of the first edge, and the first optical input/output module can be configured to support an aggregate data throughput per unit edge length of approximately 725 Gbps/mm.

The at least one data processor can include an integrated circuit or a system on a chip (SoC) that includes at least one million transistors.

The wafer-scale processing module can include at least one billion transistors.

The first optical input/output module can include a plurality of co-packaged optical modules, and each co-packaged optical module can include at least one of the photonic integrated circuits.

Each co-packaged optical module can include a first optical connector part that is configured to be removably coupled to a second optical connector part that is attached to a first fiber cable that includes an array of optical fibers.

The fiber cable can include at least 10 cores of optical fibers, and the first optical connector part can be configured to couple at least 10 channels of optical signals to the photonic integrated circuit.

The fiber cable can include at least 100 cores of optical fibers, and the first optical connector part can be configured to couple at least 100 channels of optical signals to the photonic integrated circuit.

The fiber cable can include at least 500 cores of optical fibers, and the first optical connector part can be configured to couple at least 500 channels of optical signals to the photonic integrated circuit.

The fiber cable can include at least 1000 cores of optical fibers, and the first optical connector part can be configured to couple at least 1000 channels of optical signals to the photonic integrated circuit.

The photonic integrated circuit can be configured to generate a plurality of first serial electrical signals based on the received optical signals, in which each first serial electrical signal can be generated based on one of the channels of first optical signals. The co-packaged optical module can include a first serializers/deserializers module including multiple serializer units and deserializer units. The first serializers/deserializers module can be configured to generate a plurality of sets of first parallel electrical signals based on the plurality of first serial electrical signals, and condition the electrical signals, and each set of first parallel electrical signals can be generated based on a corresponding first serial electrical signal. The co-packaged optical module can include a second serializers/deserializers module including multiple serializer units and deserializer units. The second serializers/deserializers module can be configured to generate a plurality of second serial electrical signals based on the plurality of sets of first parallel electrical signals, and each second serial electrical signal can be generated based on a corresponding set of first parallel electrical signals.

The co-packaged optical module can be electrically coupled to a circuit board or a substrate using electrical contacts that include at least one of spring-loaded elements, compression interposers, or land-grid arrays.

The system can include a rackmount server, the housing can include an enclosure for the rackmount server, the rackmount server can have an n rack unit form factor, and n can be an integer in a range from 1 to 8.

In another general aspect, a supercomputer that includes any of the systems described above.

The wafer-scale processing module can include an artificial intelligence processor.

The system can be configured to simulate weather.

The system can be configured to construct and/or support a metaverse that includes one or more virtual environments and enable users to interact with one another in the one or more virtual environments, or interact with objects in the one or more virtual environments.

The system can be configured to construct and/or support a simulated environment for training autonomous vehicles.

In another general aspect, an autonomous vehicle that includes any of the systems or the supercomputer described above.

The autonomous vehicle can include at least one of a car, a truck, a train, a boat, a ship, a submarine, a helicopter, a drone, an airplane, a space rover, or a space ship.

In another general aspect, a robot that includes any of the systems or the supercomputer described above.

The robot can include at least one of an industrial robot, a helper robot, a medical surgery robot, a merchandise delivery robot, a teaching robot, a cleaning robot, a cooking robot, a construction robot, or an entertainment robot.

In another general aspect, a system include a wafer-scale processing module including an array of data processors, and a first optical input/output module including a plurality of photonic integrated circuits arranged in a two-dimensional pattern including at least three photonic integrated circuits. Each of at least some of the photonic integrated circuits can be configured to receive first optical signals and generate first electrical signals based on the first optical signals. Each of at least some of the photonic integrated circuits can be configured to receive second electrical signals and generate second optical signals based on the second electrical signals. At least some of the data processors can be configured to receive the first electrical signals generated by at least some of the photonic integrated circuits, and at least some of the data processors can be configured to transmit the second electrical signals to at least some of the photonic integrated circuits.

Implementations can include one or more of the following features. The first optical input/output module can include an edge interface module that is disposed near an edge of the wafer-scale processor, and can be configured to transmit electrical signals to and receive electrical signals from data processors positioned near the edge of the wafer-scale processing module.

The first optical input/output module can be configured to support at least 50 Tbps data throughput to an edge of the wafer-scale processing module.

The first optical input/output module can be configured to support at least 100 Tbps data throughput to an edge of the wafer-scale processing module.

The wafer-scale processing module can include a semiconductor wafer, and the data processors can be formed on the semiconductor wafer or mounted on the semiconductor wafer. The photonic integrated circuits can be mounted on a substrate. Electrical contacts on the substrate can be electrically coupled to electrical contacts on the semiconductor wafer.

The photonic integrated circuits can be electrically coupled to the data processors through a first set of signal lines on the substrate and a second set of signal lines on the semiconductor wafer. Signal propagation loss for the second set of signal lines on the semiconductor wafer can be higher than the signal propagation loss for the first set of signal lines on the substrate for a given propagation length. A longer signal line in the first set can be coupled to a shorter signal line in the second set, and a shorter signal line in the first set can be coupled to a longer signal line in the second set, to reduce the maximum signal propagation loss for the signals transmitted between the photonic integrated circuits and the data processors.

The first optical input/output module can include a plurality of co-packaged optical (CPO) modules, and each CPO module can include a photonic integrated circuit and an electronic integrated circuit. The electronic integrated circuit can include at least one of (i) an XSR chip, (ii) a driver amplifier, or (iii) a transimpedance amplifier (TIA).

The first optical input/output module can include a substrate and a plurality of co-packaged optical (CPO) modules can be mounted on the substrate. Each CPO module can include a photonic integrated circuit and an electronic integrated circuit. The electronic integrated circuit can include at least one of (i) a driver amplifier, or (ii) a transimpedance amplifier (TIA). The first optical input/output module can include a plurality of XSR-to-XSR converters that are disposed near a first edge of the substrate. The first edge can be positioned near the data processors, and the XSR-to-XSR converters can be configured to regenerate signals transmitted between the CPO modules to the data processors.

The first optical input/output module can include a substrate and a plurality of co-packaged optical (CPO) modules mounted on the substrate. Each CPO module can include a photonic integrated circuit and an electronic integrated circuit. The electronic integrated circuit can include at least one of (i) a driver amplifier, or (ii) a transimpedance amplifier (TIA). The first optical input/output module can include a plurality of XSR-to-LR converters that are disposed near a first edge of the substrate. The first edge can be positioned near the data processors, and the XSR-to-LR converters can be configured to regenerate signals transmitted between the CPO modules and the data processors.

Each of at least a subset of the co-packaged optical (CPO) modules can be surrounded by other CPO modules and does not have any XSR chip between the CPO module and other CPO modules.

The first optical input/output module can include a substrate, in which the photonic integrated circuits are mounted on the substrate. The first optical input/output module can include a plurality of XSR-to-LR converters that are disposed near a first edge of the substrate, in which the first edge can be positioned near the data processors, and the XSR-to-LR converters can be configured to regenerate signals transmitted between the photonic integrated circuits and the data processors.

Each photonic integrated circuit can be driven directly by a corresponding XSR-to-LR converter without a separate driver amplifier or transimpedance amplifier.

In another general aspect, a method includes using a first optical input/output module as a high throughput input to a wafer-scale processing module including an array of data processors, including using the first optical input/output module to support at least 50 Tbps data throughput to a first edge the wafer-scale processing module. The first optical input/output module can include a plurality of photonic integrated circuits arranged in a two-dimensional pattern including at least three photonic integrated circuits. Each of at least some of the photonic integrated circuits can receive first optical signals, generate first electrical signals based on the first optical signals, and transmit the first electrical signals to the wafer-scale processing module. Each of at least some of the photonic integrated circuits can receive second electrical signals from the wafer-scale processing module, generate second optical signals based on the second electrical signals, and output the second optical signals through one or more optical links.

Implementations can include one or more of the following features. The method can include using the first optical input/output module to support at least 100 Tbps data throughput to the first edge of the wafer-scale processing module.

The method can include using a second optical input/output module to support at least 50 Tbps data throughput to a second edge of the wafer-scale processing module.

The method can include using a third optical input/output module to support at least 50 Tbps data throughput to a third edge of the wafer-scale processing module.

The method can include using a fourth optical input/output module to support at least 50 Tbps data throughput to a fourth edge of the wafer-scale processing module. The first, second, third, and fourth optical input/output modules can be configured to support an aggregate data throughput of at least 200 Tbps to the wafer-scale processing module.

In another general aspect, a system includes: a multi-wafer processing module including: a first wafer-scale processing module, and a second wafer-scale processing module. The first wafer-scale processing module includes a first array of data processors and a first optical input/output module, in which the first optical input/output module includes at least three photonic integrated circuits arranged in a two-dimensional pattern. The second wafer-scale processing module includes a second array of data processors and a second optical input/output module, in which the second optical input/output module includes at least three photonic integrated circuits arranged in a two-dimensional pattern. The multi-wafer processing module includes one or more optical fibers that optically connect the first optical input/output module to the second input/output module. The first optical input/output module, the second optical input/output module, and the one or more optical fibers provide one or more optical communication links between the first array of data processors and the second array of data processors.

Implementations can include one or more of the following features. The first wafer-scale processing module and the second wafer-scale processing module can be positioned side-by-side, the first array of data processors and the second array of data processors can face a same direction.

The first wafer-scale processing module can include a first substrate, the first array of data processors can be coupled to the first substrate, the second wafer-scale processing module can include a second substrate, the second array of data processors can be coupled to the second substrate. The first and second wafer-scale processing modules can be vertically stacked such that the first array of data processors face toward the second array of data processors, wherein the first and second arrays of data processors are positioned between the first and second substrates.

The first substrate can include a first semiconductor wafer, and the second substrate can include a second semiconductor wafer.

The system can include a first shared power supply positioned between the first wafer-scale processing module and the second wafer-scale processing module, in which the first shared power supply is configured to provide power to the first array of data processors and the second array of data processors.

The system can include a first shared cooling device positioned between the first wafer-scale processing module and the second wafer-scale processing module, in which the first shared cooling device is configured to remove heat from the first array of data processors and the second array of data processors.

The system can include a third wafer-scale processing module including a third array of data processors and a third optical input/output module, in which the third optical input/output module includes at least three photonic integrated circuits arranged in a two-dimensional pattern. The first, second, and third wafer-scale processing modules can be vertically stacked together.

The system can include a second shared power supply positioned between the second wafer-scale processing module and the third wafer-scale processing module, in which the second shared power supply is configured to provide power to the second array of data processors and the third array of data processors.

The system can include a second shared cooling device positioned between the second wafer-scale processing module and the third wafer-scale processing module, in which the second shared cooling device is configured to remove heat from the second array of data processors and the third array of data processors.

The system can include a fourth wafer-scale processing module including a fourth array of data processors and a fourth optical input/output module, in which the fourth optical input/output module includes at least three photonic integrated circuits arranged in a two-dimensional pattern. The first, second, third, and fourth wafer-scale processing modules can be vertically stacked together.

The system can include a third shared power supply positioned between the third wafer-scale processing module and the fourth wafer-scale processing module, in which the third shared power supply is configured to provide power to the third array of data processors and the fourth array of data processors.

The system can include a third shared cooling device positioned between the third wafer-scale processing module and the fourth wafer-scale processing module, in which the third shared cooling device is configured to remove heat from the third array of data processors and the fourth array of data processors.

The second wafer-scale processing module can include a second substrate, the second array of data processors can be coupled to the second substrate, the third wafer-scale processing module can include a third substrate, the third array of data processors can be coupled to the third substrate, and a back side of the second substrate can face a back side of the third substrate.

The second shared power supply can provide power to the second array of data processors through conductive lines that pass through the second substrate, and the second shared power supply can provide power to the third array of data processors through conductive lines that pass through the third substrate.

The second shared cooling device can remove heat from the second array of data processors through thermally conductive paths that pass through the second substrate, and the second shared cooling device can remove heat from the third array of data processors through thermally conductive paths that pass through the third substrate.

In another general aspect, a system includes: a large scale multi-wafer processing module including: two or more multi-wafer processing modules arranged in a two-dimensional array, in which each multi-wafer processing module includes two or more wafer-scale processing modules vertically stacked together. At least one wafer-scale processing module communicates with another wafer-scale processing modules through optical communication links.

Implementations can include one or more of the following features. Each wafer-scale processing module can include an array of data processors and an optical input/output module, in which a first wafer-scale processing module is optically linked to a second wafer-scale processing module through a first optical input/output module of the first wafer-scale processing module, a second optical input/output module of the second wafer-scale processing module, and an optical fiber cable that connects the first optical input/output module to the second optical input/output module.

In another general aspect, a system includes: a processing module including: at least one data processor coupled directly or indirectly to a first substrate; and a first optical input/output module including at least three photonic integrated circuits coupled directly or indirectly to a second substrate, the at least three photonic integrated circuits arranged in a two-dimensional pattern, the at least three photonic integrated circuits including three photonic integrated circuits arranged in a pattern forming a triangle. Each of the at least three photonic integrated circuits includes at least three vertical couplers arranged in a two-dimensional pattern, the at least three vertical couplers including three vertical couplers arranged in a pattern forming a triangle. The photonic integrated circuits are configured to convert input optical signals received at the vertical couplers to input electrical signals that are transmitted directly or indirectly to the at least one data processor.

Implementations can include one or more of the following features. The at least one data processor can include a plurality of data processors arranged in a two dimensional pattern, and the plurality of data processors can include three data processors arranged in a pattern forming a triangle.

The at least three photonic integrated circuits can include N1 photonic integrated circuits, N1 is an integer that is greater than or equal to 3, each photonic integrated circuit can include at least N2 vertical couplers configured to receive input optical signals from fiber cores, N1 is an integer that is greater than or equal to 3. The first optical input/output module can provide an interface between the at least one data processor and N1 bundles of fiber cores, each bundle of fiber cores can be coupled to the vertical couplers of a corresponding photonic integrated circuit, and each bundle of fiber cores can include at least N2 fiber cores.

The at least three photonic integrated circuits can include at least 10 photonic integrated circuits, and each photonic integrated circuit can include at least 10 vertical couplers configured to receive input optical signals from corresponding fiber cores. The first optical input/output module can provide an interface between the at least one data processor and 10 bundles of fiber cores, and each bundle of fiber cores can include at least 10 fiber cores.

The at least one data processor can include a wafer-scale processor including a plurality of data processors. The processing module can include an edge processing module positioned near an edge of the wafer-scale processor, and the edge processing module can include the first optical input/output module.

The wafer-scale processor can include a plurality of data processors that have a footprint of at least 10 cm×10 cm, and each data processor can include at least one million transistors.

The plurality of data processors can have a footprint of at least 15 cm×15 cm.

The plurality of data processors can have a footprint of at least 20 cm×20 cm.

The edge processing module can be configured to support a communication interface of at least 500 Gbps data throughput between the wafer-scale processor and a plurality of optical fibers.

The edge processing module can be configured to support a communication interface of at least 1 tetra bps data throughput between the wafer-scale processor and a plurality of optical fibers.

The edge processing module can be configured to support a communication interface of at least 1.5 tetra bps data throughput between the wafer-scale processor and a plurality of optical fibers.

In another general aspect, a system includes: a processing module including: a wafer-scale processor including an array of at least 4 rows and 4 columns of data processors, in which each data processor includes at least one million transistors, the wafer-scale processor includes 4 edges, the wafer-scale processor is configured to be capable of a data processing throughput of at least 500 Gbps. The processing module includes four edge processing modules, in which each edge processing module is positioned near a corresponding edge of the wafer scale processor, each edge processing module includes an array of at least 2 rows and at least 8 columns of photonic integrated circuits, each photonic integrated circuit includes at least 2 rows and at least 8 columns of vertical couplers that are configured to receive input optical signals from optical fiber cores or transmit output optical signals to optical fiber cores. The four edge processing modules provide communication interfaces between the wafer-scale processor and the optical fiber cores.

Other aspects include other combinations of the features recited above and other features, expressed as methods, apparatus, systems, program products, and in other ways.

Interconnecting electronic chip packages using optical signals can have the advantage that the optical signals can be delivered with a higher input/output capacity per unit area compared to electrical input/outputs.

Particular embodiments of the subject matter described in this specification can be implemented to realize one or more of the following advantages. The data processing system has a high power efficiency, a low construction cost, a low operation cost, and high flexibility in reconfiguring optical network connections. The thermal solutions described in this document allow efficient dissipation of heat generated by data processors that process large amounts of data carried by fiber optic cables.

The details of one or more embodiments of the subject matter described in this specification are set forth in the accompanying drawings and the description below. Other features, aspects, and advantages of the invention will become apparent from the description, the drawings, and the claims.

Unless otherwise defined, all technical and scientific terms used herein have the same meaning as commonly understood by one of ordinary skill in the art to which this invention belongs. In case of conflict with patent applications or patent application publications incorporated herein by reference, the present specification, including definitions, will control.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. The dimensions of the various features can be arbitrarily expanded or reduced for clarity.

FIG. 1 is a block diagram of an example optical communication system.

FIG. 2 is a schematic side view of an example data processing system.

FIG. 3 is a schematic side view of an example integrated optical device.

FIG. 4 is a schematic side view of an example data processing system.

FIG. 5 is a schematic side view of an example integrated optical device.

FIGS. 6 and 7 are schematic side views of examples of data processing systems.

FIG. 8 is an exploded perspective view of an integrated optical communication device.

FIGS. 9 and 10 are diagrams of example layout patterns of optical and electrical terminals of integrated optical devices.

FIGS. 11, 12, 13, and 14 are schematic side views of examples of data processing systems.

FIGS. 15 and 16 are bottom views of examples of integrated optical devices.

FIG. 17 is a diagram showing various types of integrated optical communication devices that can be used in a data processing system.

FIG. 18 is a diagram of an example octal serializers/deserializers block.

FIG. 19 is a diagram of an example electronic communication integrated circuit.

FIG. 20 is a functional block diagram of an example data processing system.

FIG. 21 is a diagram of an example rackmount data processing system.

FIGS. 22, 23, 24, 25, 26A, 26B, 26C, 27, 28A, and 28B are top view diagrams of examples of rackmount data processing systems incorporating optical interconnect modules.

FIGS. 29A and 29B are diagrams of an example rackmount data processing system incorporating multiple optical interconnect modules.

FIGS. 30 and 31 are block diagrams of example data processing systems.

FIG. 32 is a schematic side view of an example data processing system.

FIG. 33 is a diagram of an example electronic communication integrated circuit that includes octal serializers/deserializers blocks.

FIG. 34 is a flow diagram of an example process for processing optical and electrical signals using a data processing system.

FIG. 35A is a diagram an optical communications system.

FIGS. 35B and 35C are diagrams of co-packaged optical interconnect modules.

FIGS. 36 and 37 are diagrams of examples of optical communications systems.

FIGS. 38 and 39 are diagrams of examples of serializers/deserializers blocks.

FIGS. 40A, 40B, 41A, 41B, and 42 are diagrams of examples of bus processing units.

FIG. 43 is an exploded view of an example of a front-mounted module of a data processing system.

FIG. 44 is an exploded view of an example of the internals of an optical module.

FIG. 45 is an assembled view of the internals of an optical module.

FIG. 46 is an exploded view of an optical module.

FIG. 47 is an assembled view of an optical module.

FIG. 48 is a diagram of a portion of a grid structure and a circuit board.

FIG. 49 is a diagram showing a lower mechanical part prior to insertion into the grid structure.

FIG. 50 is a diagram of an example of a partially populated front-view of an assembled system.

FIG. 51A is a front view of an example of the mounting of the module.

FIG. 51B is a side view of an example of the mounting of the module.

FIG. 52A is a front view of an example of the mechanical connector structure and an optical module mounted within a grid structure.

FIG. 52B is a side view of an example of the mechanical connector structure and an optical module mounted within a grid structure.

FIGS. 53 and 54 are diagrams of an example of an assembly that includes a fiber cable, an optical fiber connector, a mechanical connector module, and a grid structure.

FIGS. 55A and 55B are perspective views of the mechanisms shown in FIGS. 53 and 54 before the optical fiber connector is inserted into the mechanical connector structure.

FIG. 56 is a perspective view showing that the optical module and the mechanical connector structure are inserted into the grid structure.

FIG. 57 is a perspective view showing that the optical fiber connector is mated with the mechanical connector structure.

FIGS. 58A to 58D are diagrams of an example an optical module that includes a latch mechanism.

FIG. 59 is a diagram of an alternative example of the optical module.

FIGS. 60A and 60B are diagrams of an example implementation of the lever and the latch mechanism in the optical module with connector.

FIG. 61 is a diagram of cross section of the module viewed from the front mounted in the assembly with the connector.

FIGS. 62 to 65 are diagrams showing cross-sectional views of an example of a fiber cable connection design.

FIG. 66 is a map of electrical contact pads.

FIG. 67 is a diagram of an example of a vertically mounted processor blade.

FIG. 68 is a top view of an example of a rack system that includes several vertically mounted processor blades.

FIGS. 69 to 74D are diagrams of examples of packaging configurations for compact co-packaged optical modules.

FIG. 75 is a diagram of an example of a wafer-scale processor.

FIG. 76 is a diagram of an example of a wafer-scale processing system.

FIG. 77 is a side view of an example of a portion of an edge interface module and a wafer-scale processor.

FIGS. 78A and 78B are top and side views of an example of a portion of an edge interface module and a wafer-scale processor.

FIGS. 79A and 79B are top and side views of an example of a portion of an edge interface module and a wafer-scale processor.

FIG. 80 is a side view of an example of a portion of an edge interface module and a wafer-scale processor.

FIGS. 81A and 81B are top and side views of an example of a portion of an edge interface module and a wafer-scale processor.

FIGS. 82A and 82B are top and side views of an example of a portion of an edge interface module and a wafer-scale processor.

FIGS. 83 and 84 are diagrams of an example of an edge interface module and data processors positioned near an edge of the wafer-scale processor.

FIGS. 85A to 85D are diagrams of examples of bump patterns.

FIGS. 86A and 86B are diagrams of examples of arrays of CPO modules.

FIG. 87 is a diagram of an example of an arrays of CPO modules.

FIG. 88 is a diagram of an example of a wafer-scale processing system.

FIG. 89 is a diagram of an example of a wafer-scale processing system.

FIGS. 90 to 93 are diagrams of an example of an edge interface module and data processors positioned near an edge of the wafer-scale processor.

FIGS. 94 to 96 are diagrams of examples of edge interface modules.

FIG. 97 is a top view diagram of an example of an array of CPO modules.

FIG. 98 is a diagram of an example data processing system that includes split-up edge cards.

FIG. 99A is a top view of an example system that includes a data processor surrounded by a two-dimensional arrangement of co-packaged optical modules.

FIG. 99B is a side view of a data processor positioned adjacent to co-packaged optical modules.

FIG. 99C is a top view of an example system that includes multiple data processors each surrounded by co-packaged optical modules.

FIG. 100 is a diagram of an example wafer-scale processing system.

FIG. 101 is a diagram of an example wafer-scale processing system.

FIGS. 102 and 103 are diagrams of examples of edge interface sub-modules or tiles.

FIG. 104 is a diagram of a multi-wafer data processing system.

FIG. 105 is a diagram of an example wafer-scale processing system.

FIGS. 106 to 108 are diagrams of examples of multi-wafer data processing systems.

### DETAILED DESCRIPTION

This document describes a novel thermal design for a system for high bandwidth data processing. The system includes novel input/output interface modules for coupling bundles of optical fibers to data processing integrated circuits (e.g., network switches, central processing units, graphics processor units, tensor processing units, digital signal processors, and/or other application specific integrated circuits (ASICs)) that process the data transmitted through the optical fibers. In some implementations, the data processing integrated circuit is mounted on a circuit board (or substrate or a combination of circuit board(s) and substrate(s)) positioned near the input/output interface module through a relatively short electrical signal path on the circuit board (or substrate or a combination of circuit board(s) and substrate(s)). The input/output interface module can include a first connector that allows a user to conveniently connect or disconnect the input/output interface module to or from the circuit board (or substrate or a combination of circuit board(s) and substrate(s)). The input/output interface module can also include a second connector that allows the user to conveniently connect or disconnect the bundle of optical fibers to or from the input/output interface module. In some implementations, a rack mount system having a front panel is provided in which the circuit board (which supports the input/output interface modules and the data processing integrated circuits) (or substrate or a combination of circuit board(s) and substrate(s)) is vertically mounted in an orientation substantially parallel to, and positioned near, the front panel. In some examples, the circuit board (or substrate or a combination of circuit board(s) and substrate(s)) functions as the front panel or part of the front panel. The second connectors of the input/output interface modules face the front side of the rack mount system to allow the user to conveniently connect or disconnect bundles of optical fibers to or from the system.

When many heat-generating components, such as the data processing integrated circuits and the input/output interface modules, are positioned near the front panel of a rackmount system, using the conventional design of placing cooling fans at the rear of the rackmount system may not be sufficient. As described below, in some implementations, the circuit board(s) and/or substrate(s) can be positioned at a distance from the front panel, and many fiber cables and/or fiber guides can be used to connect components coupled to the circuit board(s) and/or substrate(s) to the connectors at the front panel. The multiple fiber cables can impede air flow and reduce heat dissipation. In some implementations, the vertically oriented circuit board(s) and/or substrate(s) are oriented substantially parallel to the front panel and can impede the front-to-back air flow generated by the fans at the rear of the rackmount system. This document describes a novel thermal design that can overcome some of the problems of the conventional thermal design. The novel thermal design provides one or more inlet fans positioned at the front of the rackmount system in addition to the one or more outlet fans at the rear of the rackmount system. The position(s) and orientation(s) of the inlet fan(s), the position(s) and orientation(s) and configuration(s) of the heat dissipating device(s), and (optionally) the use of duct(s) and/or air louver(s) are configured to maximize heat transfer so as to keep the temperature of the data processing integrated circuits and the input/output interface modules within specified temperature limits.

A feature of the novel thermal design is the use of one or more fans that blow air in a direction substantially parallel to the vertically oriented circuit board(s) and/or substrate(s), which can be substantially parallel to the front panel. In this example, a substantial amount of airflow generated by the inlet fan(s) is directed parallel to the front panel of a rackmount system. This is not intuitive since conventional thermal designs have cooling fans that generate front-to-back airflow near the front panel of the rackmount system (which is substantially orthogonal to the front panel). Another feature of the novel thermal design is the use of one or more fans to blow air towards the input/output interface modules coupled to the front side of the circuit board(s) and/or substrate(s), in addition to one or more fans that blow air towards the data processing integrated circuits coupled to the rear side of the circuit board(s) and/or substrate(s). The inventors realized that in a high data throughput system, the amount of heat generated by the input/output interface modules (e.g., optical modules that include photonic integrated circuits that convert optical signals to electrical signals and vice versa, and electronic integrated circuits that condition the electrical signals transmitted to or from the photonic integrated circuits) can be significant, and the cables (or other structures such as fiber guides) coupled to the input/output interface modules may impede air flow, so it is useful to configure one or more fans (and optionally ducts and/or air louvers) dedicated to increase airflow to the input/output interface modules.

In some implementations, a feature of the high bandwidth data processing system is that, by vertically mounting the circuit board that supports the input/output interface modules and the data processing integrated circuits to be near the front panel, or configuring the circuit board as the front panel or part of the front panel, the optical signals can be routed from the optical fibers through the input/output interface modules to the data processing integrated circuits through relatively short electrical signal paths. This allows the signals transmitted to the data processing integrated circuits to have a high bit rate (e.g., over 50 Gbps) while maintaining low crosstalk, distortion, and noise, hence reducing power consumption and footprint of the data processing system.

In some implementations, a feature of the high bandwidth data processing system is that the cost of maintenance and repair can be lower compared to traditional systems. For example, the input/output interface modules and the fiber optic cables are configured to be detachable, a defective input/output interface module can be replaced without taking apart the data processing system and without having to re-route any optical fiber. Another feature of the high bandwidth data processing system is that, because the user can easily connect or disconnect the bundles of the optical fibers to or from the input/output interface modules through the front panel of the rack mount system, the configurations for routing of high bit rate signals through the optical fibers to the various data processing integrated circuits is flexible and can easily be modified. For example, connecting a bundle of hundreds of strands of optical fibers to the optical connector of the rack mount system can be almost as simple as plugging a universal serial bus (USB) cable into a USB port. A further feature of the high bandwidth data processing system is that the input/output interface module can be made using relatively standard, low cost, and energy efficient components so that the initial hardware costs and subsequent operational costs of the input/output interface modules can be relatively low, compared to conventional systems.

In some implementations, optical interconnects can co-package and/or co-integrate optical transponders with electronic processing chips. It is useful to have transponder solutions that consume relatively low power and that are sufficiently robust against significant temperature variations as may be found within an electronic processing chip package. In some implementations, high speed and/or high bandwidth data processing systems can include massively spatially parallel optical interconnect solutions that multiplex information onto relatively few wavelengths and use a relatively large number of parallel spatial paths for chip-to-chip interconnection. For example, the relatively large number of parallel spatial paths can be arranged in two-dimensional arrays using connector structures such as those disclosed in U.S. Pat. No. 11,287,585, and incorporated herein by reference in its entirety.

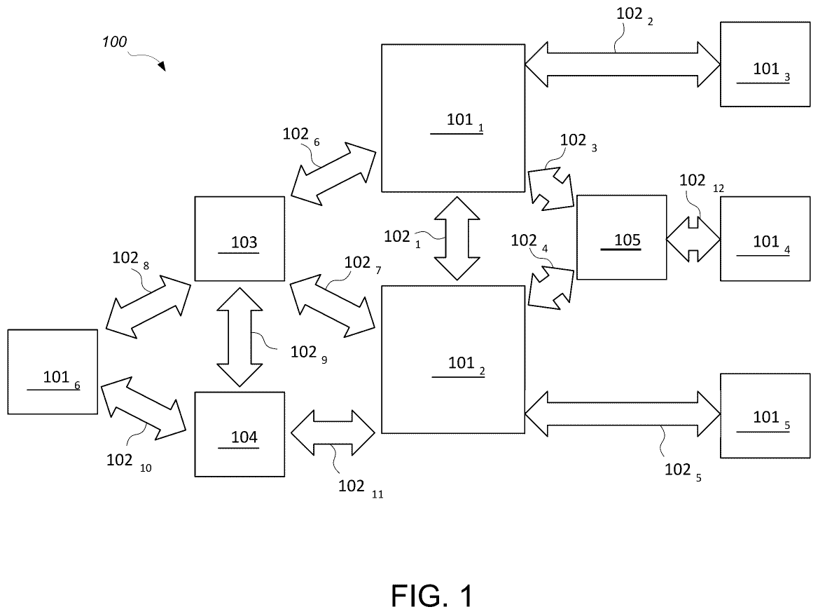

FIG. 1 shows a block diagram of a communication system 100 that incorporates one or more novel features described in this document. In some implementations, the system 100 includes nodes 101_1 to 101_6 (collectively referenced as 101), which in some embodiments can each include one or more of: optical communication devices, electronic and/or optical switching devices, electronic and/or optical routing devices, network control devices, traffic control devices, synchronization devices, computing devices, and data storage devices. The nodes 101_1 to 101_6 can be suitably interconnected by optical fiber links 102_1 to 102_12 (collectively referenced as 102) establishing communication paths between the communication devices within the nodes. The optical fiber links 102 can include the fiber-optic cables described in U.S. Pat. No. 11,194,109, and incorporated herein by reference in its entirety. The system 100 can also include one or more optical power supply modules 103 producing one or more light outputs, each light output comprising one or more continuous-wave (CW) optical fields and/or one or more trains of optical pulses for use in one or more of the optical communication devices of the nodes 101_1 to 101_6. For illustration purposes, only one such optical power supply module 103 is shown in FIG. 1. A person of ordinary skill in the art will understand that some embodiments can have more than one optical power supply module 103 appropriately distributed over the system 100 and that such multiple power supply modules can be synchronized, e.g., using some of the techniques disclosed in U.S. Pat. No. 11,153,670, and incorporated herein by reference in its entirety.

Some end-to-end communication paths can pass through an optical power supply module 103 (e.g., see the communication path between the nodes 101_2 and 101_6). For example, the communication path between the nodes 101_2 and 101_6 can be jointly established by the optical fiber links 102_7 and 1028, whereby light from the optical power supply module 103 is multiplexed onto the optical fiber links 102_7 and 102_8.

Some end-to-end communication paths can pass through one or more optical multiplexing units 104 (e.g., see the communication path between the nodes 101_2 and 101_6). For example, the communication path between the nodes 101_2 and 101_6 can be jointly established by the optical fiber links 102_10 and 102_11. Multiplexing unit 104 is also connected, through the link 1029, to receive light from the optical power supply module 103 and, as such, can be operated to multiplex said received light onto the optical fiber links 10210 and 102_11.

Some end-to-end communication paths can pass through one or more optical switching units 105 (e.g., see the communication path between the nodes 101_1 and 101_4). For example, the communication path between the nodes 101_1 and 101_4 can be jointly established by the optical fiber links 102_3 and 102_12, whereby light from the optical fiber links 102_3 and 102_4 is either statically or dynamically directed to the optical fiber link 102_12.

As used herein, the term “network element” refers to any element that generates, modulates, processes, or receives light within the system 100 for the purpose of communication. Example network elements include the node 101, the optical power supply module 103, the optical multiplexing unit 104, and the optical switching unit 105.

Some light distribution paths can pass through one or more network elements. For example, optical power supply module 103 can supply light to the node 101_4 through the optical fiber links 1027, 102_4, and 102_12, letting the light pass through the network elements 101_2 and 105.

Various elements of the communication system 100 can benefit from the use of optical interconnects, which can use photonic integrated circuits comprising optoelectronic devices, co-packaged and/or co-integrated with electronic chips comprising integrated circuits.

As used herein, the term “photonic integrated circuit” (or PIC) should be construed to cover planar lightwave circuits (PLCs), integrated optoelectronic devices, wafer-scale products on substrates, individual photonic chips and dies, and hybrid devices. A substrate can be made of, e.g., one or more ceramic materials, or organic “high density build-up” (HDBU). The ceramic materials can include, e.g., low temperature co-fired ceramics (LTCC). Example material systems that can be used for manufacturing various photonic integrated circuits can include but are not limited to III-V semiconductor materials, silicon photonics, silica-on-silicon products, silica-glass-based planar lightwave circuits, polymer integration platforms, lithium niobate and derivatives, nonlinear optical materials, etc. Both packaged devices (e.g., wired-up and/or encapsulated chips) and unpackaged devices (e.g., dies) can be referred to as planar lightwave circuits.

Photonic integrated circuits are used for various applications in telecommunications, instrumentation, and signal-processing fields. In some implementations, a photonic integrated circuit uses optical waveguides to implement and/or interconnect various circuit components, such as for example, optical switches, couplers, routers, splitters, multiplexers/demultiplexers, filters, modulators, phase shifters, lasers, amplifiers, wavelength converters, optical-to-electrical (O/E) and electrical-to-optical (E/O) signal converters, etc. For example, a waveguide in a photonic integrated circuit can be an on-chip solid light conductor that guides light due to an index-of-refraction contrast between the waveguide's core and cladding. A photonic integrated circuit can include a planar substrate onto which optoelectronic devices are grown by an additive manufacturing process and/or into which optoelectronic devices are etched by a subtractive manufacturing processes, e.g., using a multi-step sequence of photolithographic and chemical processing steps.

In some implementations, an “optoelectronic device” can operate on both light and electrical currents (or voltages) and can include one or more of: (i) an electrically driven light source, such as a laser diode; (ii) an optical amplifier; (iii) an optical-to-electrical converter, such as a photodiode; and (iv) an optoelectronic component that can control the propagation and/or certain properties (e.g., amplitude, phase, polarization) of light, such as an optical modulator or a switch. The corresponding optoelectronic circuit can additionally include one or more optical elements and/or one or more electronic components that enable the use of the circuit's optoelectronic devices in a manner consistent with the circuit's intended function. Some optoelectronic devices can be implemented using one or more photonic integrated circuits.

As used herein, the term “integrated circuit” (IC) should be construed to encompass both a non-packaged die and a packaged die. In a typical integrated circuit-fabrication process, dies (chips) are produced in relatively large batches using wafers of silicon or other suitable material(s). Electrical and optical circuits can be gradually created on a wafer using a multi-step sequence of photolithographic and chemical processing steps. Each wafer is then cut (“diced”) into many pieces (chips, dies), each containing a respective copy of the circuit that is being fabricated. Each individual die can be appropriately packaged prior to being incorporated into a larger circuit or be left non-packaged.

The term “hybrid circuit” can refer to a multi-component circuit constructed of multiple monolithic integrated circuits, and possibly some discrete circuit components, all attached to each other to be mountable on and electrically connectable to a common base, carrier, or substrate. A representative hybrid circuit can include (i) one or more packaged or non-packaged dies, with some or all of the dies including optical, optoelectronic, and/or semiconductor devices, and (ii) one or more optional discrete components, such as connectors, resistors, capacitors, and inductors. Electrical connections between the integrated circuits, dies, and discrete components can be formed, e.g., using patterned conducting (such as metal) layers, ball-grid arrays, solder bumps, wire bonds, etc. Electrical connections can also be removable, e.g., by using land-grid arrays and/or compression interposers. The individual integrated circuits can include any combination of one or more respective substrates, one or more redistribution layers (RDLs), one or more interposers, one or more laminate plates, etc.

In some embodiments, individual chips can be stacked. As used herein, the term “stack” refers to an orderly arrangement of packaged or non-packaged dies in which the main planes of the stacked dies are substantially parallel to each other. A stack can typically be mounted on a carrier in an orientation in which the main planes of the stacked dies are parallel to each other and/or to the main plane of the carrier.

A “main plane” of an object, such as a die, a photonic integrated circuit, a substrate, or an integrated circuit, is a plane parallel to a substantially planar surface thereof that has the largest sizes, e.g., length and width, among all exterior surfaces of the object. This substantially planar surface can be referred to as a main surface. The exterior surfaces of the object that have one relatively large size, e.g., length, and one relatively small size, e.g., height, are typically referred to as the edges of the object.

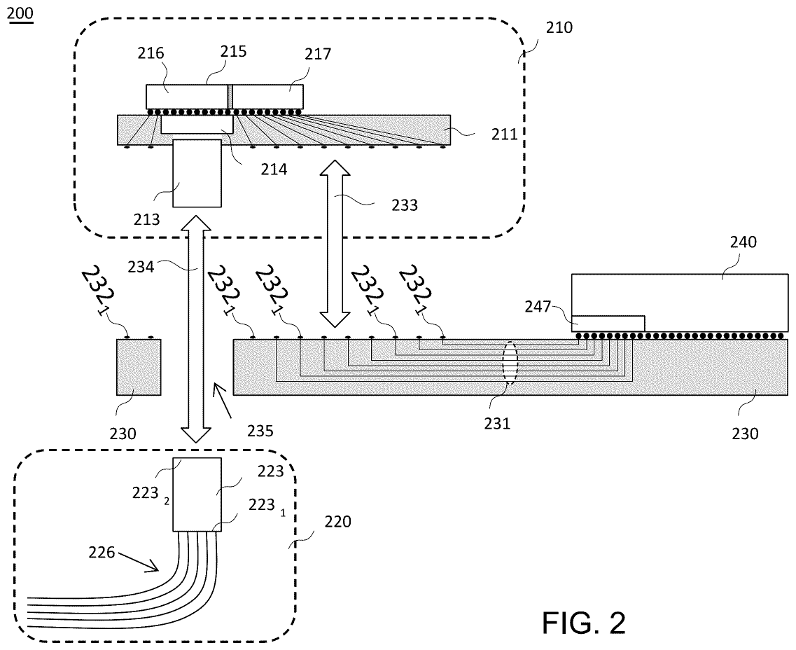

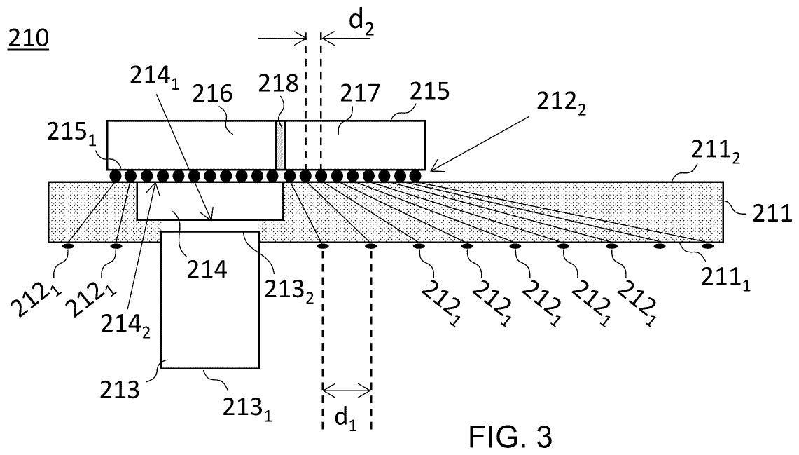

FIG. 2 is a schematic cross-sectional diagram of a data processing system 200 that includes an integrated optical communication device 210 (also referred to as an optical interconnect module), a fiber-optic connector assembly 220, a package substrate 230, and an electronic processor integrated circuit 240. The data processing system 200 can be used to implement, e.g., one or more of devices 101_1 to 101_6 of FIG. 1. FIG. 3 shows an enlarged cross-sectional diagram of the integrated optical communication device 210.

Referring to FIGS. 2 and 3, the integrated optical communication device 210 includes a substrate 211 having a first main surface 211_1 and a second main surface 211_2. The main surfaces 211_1 and 211_2, respectively, include arrays of electrical contacts 212_1 and 212_2. In some embodiments, the minimum spacing d₁ between any two contacts within the array of contacts 212_1 is larger than the minimum spacing d₂ between any two contacts within the array of contacts 212_2. In some embodiments the minimum spacing between any two contacts within the array of contacts 212_2 is between 40 and 200 micrometers. In some embodiments, the minimum spacing between any two contacts within the array of contacts 212_1 is between 200 micrometers and 1 millimeter. At least some of the contacts 212_1 are electrically connected through the substrate 211 with at least some of the contacts 212_2. In some embodiments, the contacts 212_1 can be permanently attached to a corresponding array of electrical contacts 232_1 on the package substrate 230. In some embodiments, the contacts 212_1 can include mechanisms to allow the device 210 to be removably connected to the package substrate 230, as indicated by a double arrow 233. For example, the system can include mechanical mechanisms (e.g., one or more snap-on or screw-on mechanisms) to hold the various modules in place. In some embodiments, the contacts 2121, 212_2, and/or 232_1 can include one or more of solder balls, metal pillars, and/or metal pads, etc. In some embodiments, the contacts 2121, and/or 232_1 can include one or more of spring-loaded elements, compression interposers, and/or land-grid arrays.

In some embodiments, the integrated optical communication device 210 can be connected to the electronic processor integrated circuit 240 using traces 231 embedded in one or more layers of the package substrate 230. In some embodiments, the processor integrated circuit 240 can include monolithically embedded therein an array of serializers/deserializers (SerDes) 247 electrically coupled to the traces 231. In some embodiments, the processor integrated circuit 240 can include electronic switching circuitry, electronic routing circuitry, network control circuitry, traffic control circuitry, computing circuitry, synchronization circuitry, time stamping circuitry, and data storage circuitry. In some implementations, the processor integrated circuit 240 can be a network switch, a central processing unit, a graphics processor unit, a tensor processing unit, a digital signal processor, or an application specific integrated circuit (ASIC).

Because the electronic processor integrated circuit 240 and the integrated communication device 210 are both mounted on the package substrate 230, the electrical connectors or traces 231 can be made shorter, as compared to mounting the electronic processor integrated circuit 240 and the integrated communication device 210 on separate circuit boards. Shorter electrical connectors or traces 231 can transmit signals that have a higher data rate with lower noise, lower distortion, and/or lower crosstalk.

In some implementations, the electrical connectors or traces can be configured as differential pairs of transmission lines, e.g., in a ground-signal-ground-signal-ground configuration. In some examples, the speed of such signal links can be 10 Gbps or more; 56 Gbps or more; 112 Gbps or more; or 224 Gbps or more.

In some implementations, the integrated optical communication device 210 further includes a first optical connector part 213 having a first surface 213_1 and a second surface 213_2. The connector part 213 is configured to receive a second optical connector part 223 of the fiber-optic connector assembly 220, optically coupled to the connector part 213 through the surfaces 213_1 and 223_2. In some embodiments the connector part 213 can be removably attached to the connector part 223, as indicated by a double-arrow 234, e.g., through a hole 235 in the package substrate 230. In some embodiments the connector part 213 can be permanently attached to the connector part 223. In some embodiments, the connector parts 213 and 223 can be implemented as a single connector element combining the functions of both the connector parts 213 and 223.

In some implementations, the optical connector part 223 is attached to an array of optical fibers 226. In some embodiments, the array of optical fibers 226 can include one or more of: single-mode optical fiber, multi-mode optical fiber, multi-core optical fiber, polarization-maintaining optical fiber, dispersion-compensating optical fiber, hollow-core optical fiber, or photonic crystal fiber. In some embodiments, the array of optical fibers 226 can be a linear (1D) array. In some other embodiments, the array of optical fibers 226 can be a two-dimensional (2D) array. For example, the array of optical fibers 226 can include 2 or more optical fibers, 4 or more optical fibers, 10 or more optical fibers, 100 or more optical fibers, 500 or more optical fibers, or 1000 or more optical fibers. Each optical fiber can include, e.g., 2 or more cores, or 10 or more cores, in which each core provides a distinct light path. Each light path can include a multiplex of, e.g., 2 or more, 4 or more, 8 or more, or 16 or more serial optical signals, e.g., by use of wavelength division multiplexing channels, polarization-multiplexed channels, coherent quadrature-multiplexed channels. The connector parts 213 and 223 are configured to establish light paths through the first main surface 211_1 of the substrate 211. For example, the array of optical fibers 226 can includes n1 optical fibers, each optical fiber can include n2 cores, and the connector parts 213 and 223 can establish n1×n2 light paths through the first main surface 211_1 of the substrate 211. Each light path can include a multiplex of n3 serial optical signals, resulting in a total of n1×n2×n3 serial optical signals passing through the connector parts 213 and 223. In some embodiments, the connector parts 213 and 223 can be implemented, e.g., as disclosed in U.S. Pat. No. 11,287,585.

In some implementations, the integrated optical communication device 210 further includes a photonic integrated circuit 214 having a first main surface 214_1 and a second main surface 214_2. The photonic integrated circuit 214 is optically coupled to the connector part 213 through its first main surface 214_1, e.g., as disclosed in in U.S. Pat. No. 11,287,585. For example, the connector part 213 can be configured to optically couple light to the photonic integrated circuit 214 using optical coupling interfaces, e.g., vertical grating couplers or turning mirrors. In the example above, a total of n1×n2×n3 serial optical signals can be coupled through the connector parts 213 and 223 to the photonic integrated circuit 214. Each serial optical signal is converted to a serial electrical signal by the photonic integrated circuit 214, and each serial electrical signal is transmitted from the photonic integrated circuit 214 to a deserializer unit, or a serializer/deserializer unit, described below.

In some embodiments, the connector part 213 can be mechanically connected (e.g., glued) to the photonic integrated circuit 214. The photonic integrated circuit 214 can contain active and/or passive optical and/or opto-electronic components including optical modulators, optical detectors, optical phase shifters, optical power splitters, optical wavelength splitters, optical polarization splitters, optical filters, optical waveguides, or lasers. In some embodiments, the photonic integrated circuit 214 can further include monolithically integrated active or passive electronic elements such as resistors, capacitors, inductors, heaters, or transistors.

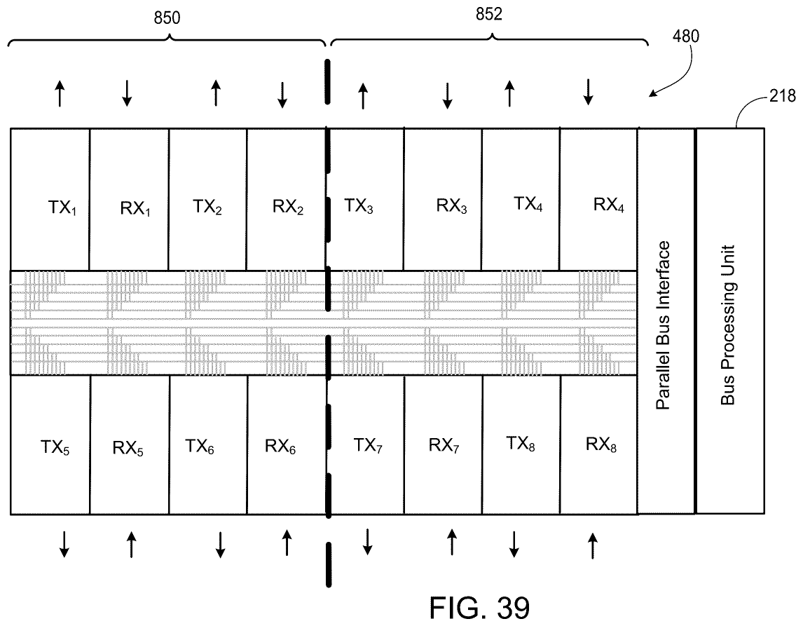

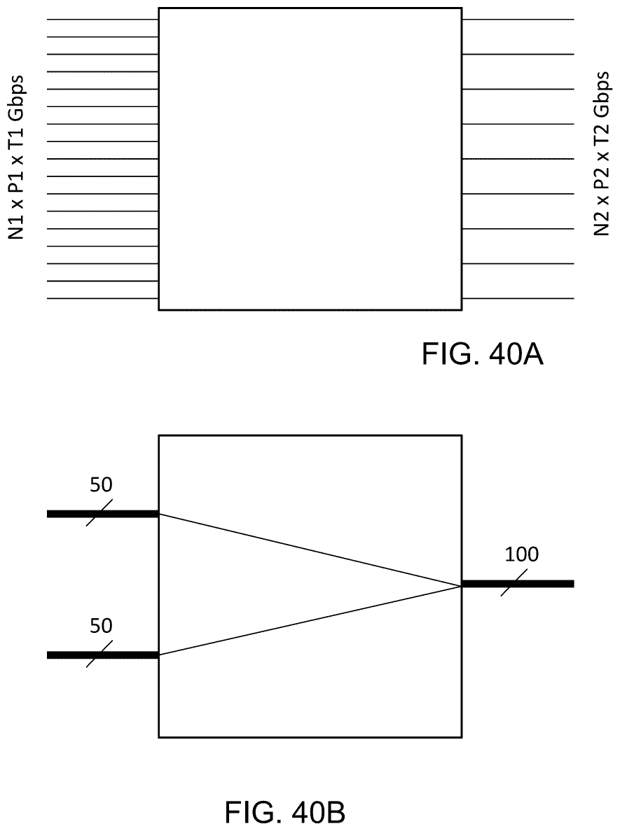

In some implementations, the integrated optical communication device 210 further includes an electronic communication integrated circuit 215 configured to facilitate communication between the array of optical fibers 226 and the electronic processor integrated circuit 240. A first main surface 215_1 of the electronic communication integrated circuit 215 is electrically coupled to the second main surface 214_2 of the photonic integrated circuit 214, e.g., through solder bumps, copper pillars, etc. The first main surface 215_1 of the electronic communication integrated circuit 215 is further electrically connected to the second main surface 211_2 of the substrate 211 through the array of electrical contacts 212_2. In some embodiments, the electronic communication integrated circuit 215 can include electrical pre-amplifiers and/or electrical driver amplifiers electrically coupled, respectively, to photodetectors and modulators within the photonic integrated circuit 214 (see also FIG. 14). In some embodiments, the electronic communication integrated circuit 215 can include a first array of serializers/deserializers (SerDes) 216 (also referred to as a serializers/deserializers module) whose serial inputs/outputs are electrically connected to the photodetectors and the modulators of the photonic integrated circuit 214 and a second array of serializers/deserializers 217, whose serial inputs/outputs are electrically coupled to the contacts 212_1 through the substrate 211. Parallel inputs of the array of serializers/deserializers 216 can be connected to parallel outputs of the array of serializers/deserializers 217 and vice versa through a bus processing unit 218, which can be, e.g., a parallel bus of electrical lanes, a cross-connect device, or a re-mapping device (gearbox). For example, the bus processing unit 218 can be configured to enable switching of the signals, allowing the routing of signals to be re-mapped. For example, N×50 Gbps electrical lanes can be remapped into N/2×100 Gbps electrical lanes, N being a positive even integer. An example of a bus processing unit 218 is shown in FIG. 40A.

For example, the electronic communication integrated circuit 215 includes a first serializers/deserializers module that includes multiple serializer units and multiple deserializer units, and a second serializers/deserializers module that includes multiple serializer units and multiple deserializer units. The first serializers/deserializers module includes the first array of serializers/deserializers 216. The second serializers/deserializers module includes the second array of serializers/deserializers 217.

In some implementations, the first and second serializers/deserializers modules have hardwired functional units so that which units function as serializers and which units function as deserializers are fixed. In some implementations, the functional units can be configurable. For example, the first serializers/deserializers module is capable of operating as serializer units upon receipt of a first control signal, and operating as deserializer units upon receipt of a second control signal. Likewise, the second serializers/deserializers module is capable of operating as serializer units upon receipt of a first control signal, and operating as deserializer units upon receipt of a second control signal.

Signals can be transmitted between the optical fibers 226 and the electronic processor integrated circuit 240. For example, signals can be transmitted from the optical fibers 226 to the photonic integrated circuit 214, to the first array of serializers/deserializers 216, to the second array of serializers/deserializers 217, and to the electronic processor integrated circuit 240. Similarly, signals can be transmitted from the electronic processor integrated circuit 240 to the second array of serializers/deserializers 217, to the first array of serializers/deserializers 216, to the photonic integrated circuit 214, and to the optical fibers 226.

In some implementations, the electronic communication integrated circuit 215 is implemented as a first integrated circuit and a second integrated circuit that are electrically coupled each other. For example, the first integrated circuit includes the array of serializers/deserializers 216, and the second integrated circuit includes the array of serializers/deserializers 217.

In some implementations, the integrated optical communication device 210 is configured to receive optical signals from the array of optical fibers 226, generate electrical signals based on the optical signals, and transmit the electrical signals to the electronic processor integrated circuit 240 for processing. In some examples, the signals can also flow from the electronic processor integrated circuit 240 to the integrated optical communication device 210. For example, the electronic processor integrated circuit 240 can transmit electronic signals to the integrated optical communication device 210, which generates optical signals based on the received electronic signals, and transmits the optical signals to the array of optical fibers 226.

In some implementations, the photodetectors of the photonic integrated circuit 214 convert the optical signals transmitted in the optical fibers 226 to electrical signals. In some examples, the photonic integrated circuit 214 can include transimpedance amplifiers for amplifying the currents generated by the photodetectors, and drivers for driving output circuits (e.g., driving optical modulators). In some examples, the transimpedance amplifiers and drivers are integrated with the electronic communication integrated circuit 215. For example, the optical signal in each optical fiber 226 can be converted to one or more serial electrical signals. For example, one optical fiber can carry multiple signals by use of wavelength division multiplexing. The optical signals (and the serial electrical signals) can have a high data rate, such as 50 Gbps, 100 Gbps, or more. The first serializers/deserializers module 216 converts the serial electrical signals to sets of parallel electrical signals. For example, each serial electrical signal can be converted to a set of N parallel electrical signals, in which N can be, e.g., 2, 4, 8, 16, or more. The first serializers/deserializers module 216 conditions the serial electrical signals upon conversion into sets of parallel electrical signals, in which the signal conditioning can include, e.g., one or more of clock and data recovery, and signal equalization. The first serializers/deserializers module 216 sends the sets of parallel electrical signals to the second serializers/deserializers module 217 through the bus processing unit 218. The second serializers/deserializers module 217 converts the sets of parallel electrical signals to high speed serial electrical signals that are output to the electrical contacts 212_2 and 212_1.

The serializers/deserializers module (e.g., 216, 217) can perform functions such as fixed or adaptive signal pre-distortion on the serialized signal. Also, the parallel-to-serial mapping can use a serialization factor M different from N, e.g., 50 Gbps at the input to the first serializers/deserializers module 216 can become 50×1 Gbps on a parallel bus, and two such parallel buses from two serializers/deserializers modules 216 having a total of 100×1 Gbps can then be mapped to a single 100 Gbps serial signal by the serializers/deserializers module 217. An example of the bus processing unit 218 for performing such mapping is shown in FIG. 40B. Also, the high-speed modulation on the serial side can be different, e.g., the serializers/deserializers module 216 can use 50 Gbps Non-Return-to-Zero (NRZ) modulation whereas the serializers/deserializers module 217 can use 100 Gbps Pulse-Amplitude Modulation 4-Level (PAM4) modulation. In some implementations, coding (line coding or error-correction coding) can be performed at the bus processing unit 218. The first and second serializers/deserializers modules 216 and 217 can be commercially available high quality, low power serializers/deserializers that can be purchased in bulk at a low cost.

In some implementations, the package substrate 230 can include connectors on the bottom side that connects the package substrate 230 to another circuit board, such as a motherboard. The connection can use, e.g., fixed (e.g., by use of solder connection) or removable (e.g., by use of one or more snap-on or screw-on mechanisms). In some examples, another substrate can be provided between the electronic processor integrated circuit 240 and the package substrate 230.

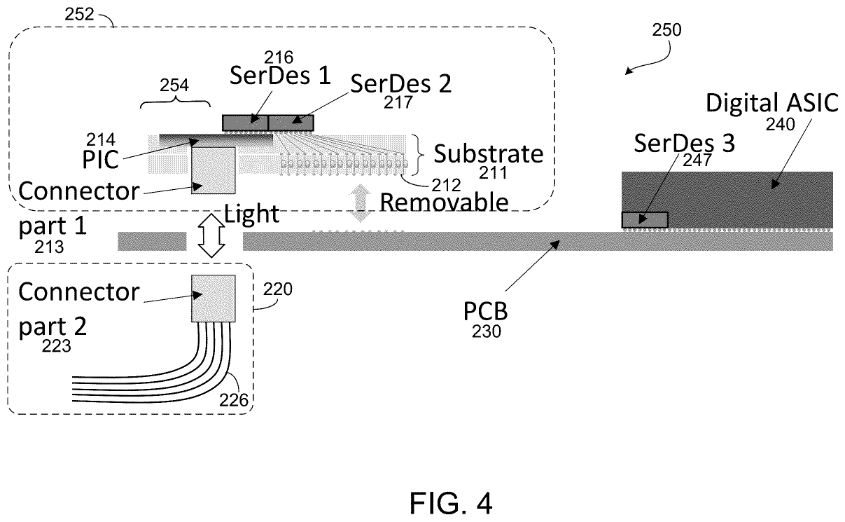

Referring to FIG. 4, in some implementations, a data processing system 250 includes an integrated optical communication device 252 (also referred to as an optical interconnect module), a fiber-optic connector assembly 220, a package substrate 230, and an electronic processor integrated circuit 240. The data processing system 250 can be used, e.g., to implement one or more of devices 101_1 to 101_6 of FIG. 1. The integrated optical communication device 252 is configured to receive optical signals, generate electrical signals based on the optical signals, and transmit the electrical signals to the electronic processor integrated circuit 240 for processing. In some examples, the signals can also flow from the electronic processor integrated circuit 240 to the integrated optical communication device 252. For example, the electronic processor integrated circuit 240 can transmit electronic signals to the integrated optical communication device 252, which generates optical signals based on the received electronic signals, and transmits the optical signals to the array of optical fibers 226.

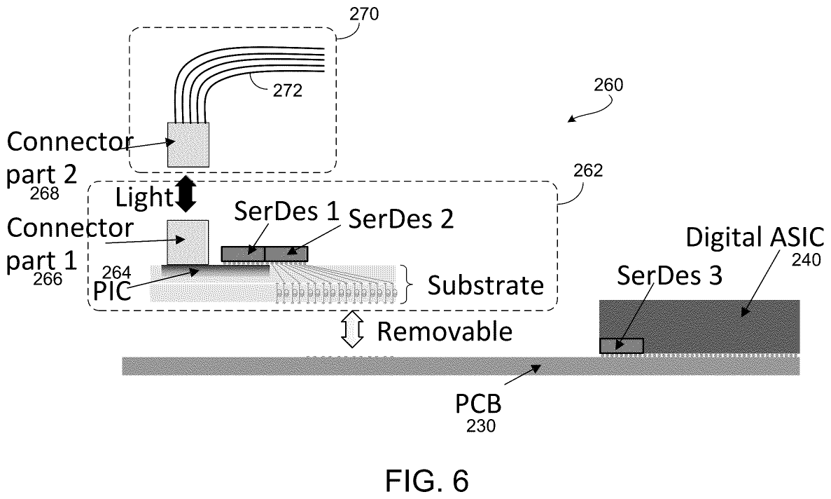

The system 250 is similar to the data processing system 200 of FIG. 2 except that in the system 250, in the direction of the cross section of the figure, a portion 254 of the top surface of the photonic integrated circuit 214 is not covered by the first serializers/deserializers module 216 and the second serializers/deserializers module 217. For example, the portion 254 can be used to couple to other electronic components, optical components, or electro-optical components, either from the bottom (as shown in FIG. 4) or from the top (as shown in FIG. 6). In some examples, the first serializers/deserializers module 216 can have a high temperature during operation. The portion 254 is not covered by the first serializers/deserializers module 216 and can be less thermally coupled to the first serializers/deserializers module 216. In some examples, the photonic integrated circuit 214 can include modulators that modulate the phases of optical signals by modifying the temperature of waveguides and thereby modifying the refractive indices of the waveguides. In such devices, using the design shown in the example of FIG. 4 can allow the modulators to operate in a more thermally stable environment.

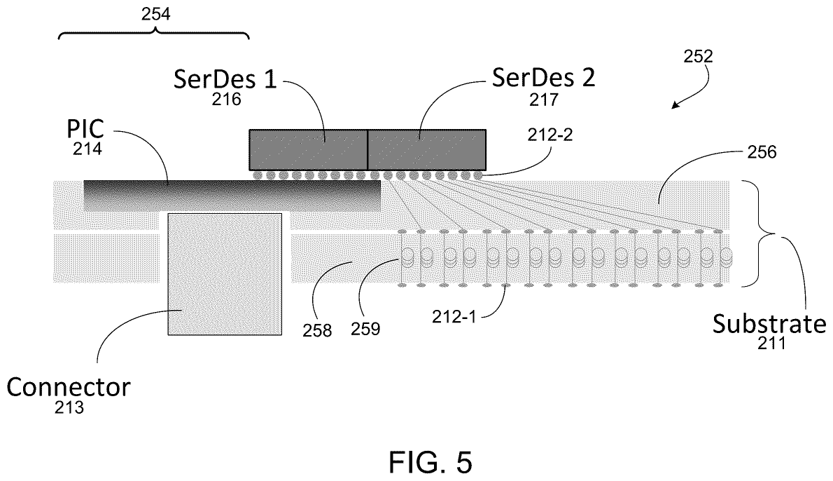

FIG. 5 shows an enlarged cross-sectional diagram of the integrated optical communication device 252. In some implementations, the substrate 211 includes a first slab 256 and a second slab 258. The first slab 256 provides electrical connectors to fan out the electrical contacts, and the second slab 258 provides a removable connection to the package substrate 230. The first slab 256 includes a first set of contacts arranged on the top surface and a second set of contacts arranged on the bottom surface, in which the first set of contacts has a fine pitch and the second set of contacts has a coarse pitch. The minimum distance between contacts in the second set of contacts is greater than the minimum distance between contacts in the first set of contacts. The second slab 258 can include, e.g., spring-loaded contacts 259.

Referring to FIG. 6, in some implementations, a data processing system 260 includes an integrated optical communication device 262 (also referred to as an optical interconnect module), a fiber-optic connector assembly 270, a package substrate 230, and an electronic processor integrated circuit 240. The data processing system 260 can be used, e.g., to implement one or more of devices 101_1 to 101_6 of FIG. 1. The integrated optical communication device 262 includes a photonic integrated circuit 264. The photonic integrated circuit 264 can include components that perform functions similar to those of the photonic integrated circuit 214 of FIGS. 2-5. The integrated optical communication device 262 further includes a first optical connector part 266 that is configured to receive a second optical connector part 268 of the fiber-optic connector assembly 270. For example, snap-on or screw-on mechanisms can be used to hold the first and second optical connector parts 266 and 268 together.

The connector parts 266 and 268 can be similar to the connector parts 213 and 223, respectively, of FIG. 4. In some examples, the optical connector part 268 is attached to an array of optical fibers 272, which can be similar to the fibers 226 of FIG. 4.

The photonic integrated circuit 264 has a top main surface and bottom main surface. The terms “top” and “bottom” refer to the orientations shown in the figure. It is understood that the devices described in this document can be positioned in any orientation, so for example the “top surface” of a device can be oriented facing downwards or sideways, and the “bottom surface” of the device can be oriented facing upwards or sideways. A difference between the photonic integrated circuit 264 and the photonic integrated circuit 214 (FIG. 4) is that the photonic integrated circuit 264 is optically coupled to the connector part 268 through the top main surface, whereas the photonic integrated circuit 214 is optically coupled to the connector part 213 through the bottom main surface. For example, the connector part 266 can be configured to optically couple light to the photonic integrated circuit 214 using optical coupling interfaces, e.g., vertical grating couplers or turning mirrors, similar to the way that the connector part 213 optically couples light to the photonic integrated circuit 214.

The integrated optical communication devices 252 (FIG. 4) and 262 (FIG. 6) provide flexibility in the design of the data processing systems, allowing the fiber-optic connector assembly 220 or 270 to be positioned on either side of the package substrate 230.

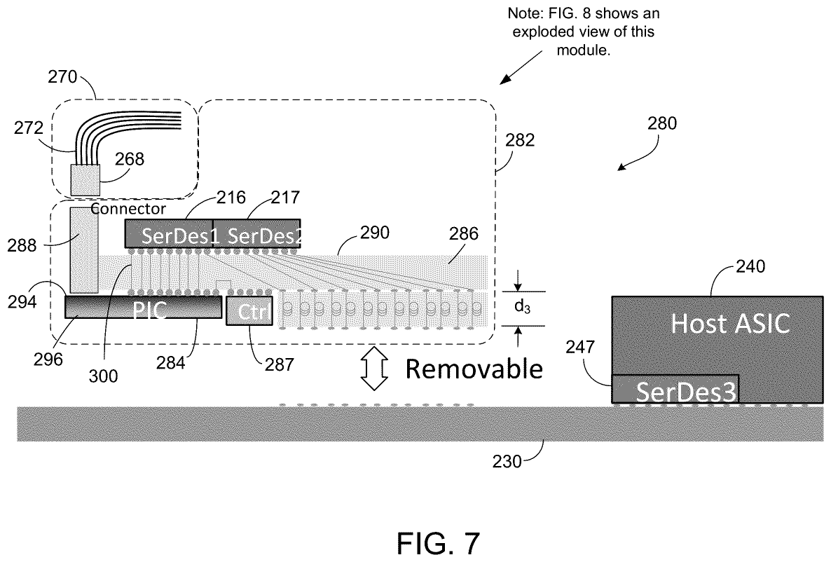

Referring to FIG. 7, in some implementations, a data processing system 280 includes an integrated optical communication device 282 (also referred to as an optical interconnect module), a fiber-optic connector assembly 270, a package substrate 230, and an electronic processor integrated circuit 240. The data processing system 280 can be used, e.g., to implement one or more of devices 101_1 to 101_6 of FIG. 1.

The integrated optical communication device 282 includes a photonic integrated circuit 284, a circuit board 286, a first serializers/deserializers module 216, a second serializers/deserializers module 217, and a control circuit 287. The photonic integrated circuit 284 can include components that perform functions similar to those of the photonic integrated circuit 214 (FIGS. 2-5) and 264 (FIG. 6). The control circuit 287 controls the operation of the photonic integrated circuit 284. For example, the control circuit 287 can control one or more photodetector and/or modulator bias voltages, heater voltages, etc., either statically or adaptively based on one or more sensor voltages that the control circuit 287 can receive from the photonic integrated circuit 284. The integrated optical communication device 282 further includes a first optical connector part 288 that is configured to receive a second optical connector part 268 of the fiber-optic connector assembly 270. The optical connector part 268 is attached to an array of optical fibers 272.

The circuit board 286 has a top main surface 290 and a bottom main surface 292. The photonic integrated circuit 284 has a top main surface 294 and bottom main surface 296. The first and second serializers/deserializers modules 216, 217 are mounted on the top main surface 290 of the circuit board 286. The top main surface 294 of the photonic integrated circuit 284 has electrical terminals that are electrically coupled to corresponding electrical terminals on the bottom main surface 292 of the circuit board 286. In this example, the photonic integrated circuit 284 is mounted on a side of the circuit board 286 that is opposite to the side of the circuit board 286 on which the first and second serializers/deserializers modules 216, 217 are mounted. The photonic integrated circuit 284 is electrically coupled to the first serializers/deserializers 216 by electrical connectors 300 that pass through the circuit board 286 in the thickness direction. In some embodiments, the electrical connectors 300 can be implemented as vias.

The connector part 288 has dimensions that are configured such that the fiber-optic connector assembly 270 can be coupled to the connector part 288 without bumping into other components of the integrated optical communication device 282. The connector part 288 can be configured to optically couple light to the photonic integrated circuit 284 using optical coupling interfaces, e.g., vertical grating couplers or turning mirrors, similar to the way that the connector part 213 or 266 optically couples light to the photonic integrated circuit 214 or 264, respectively.

When the integrated optical communication device 282 is coupled to the package substrate 230, the photonic integrated circuit 284 and the control circuit 287 are positioned between the circuit board 286 and the package substrate 230. The integrated optical communication device 282 includes an array of contacts 298 arranged on the bottom main surface 292 of the circuit board 286. The array of contacts 298 is configured such that after the circuit board 286 is coupled to the package substrate 230, the array of contacts 298 maintains a thickness d3 between the circuit board 286 and the package substrate 230, in which the thickness d3 is slightly larger than the thicknesses of the photonic integrated circuit 284 and the control circuit 287.

FIG. 8 is an exploded perspective view of the integrated optical communication device 282 of FIG. 7. The photonic integrated circuit 284 includes an array of optical coupling components 310, e.g., vertical grating couplers or turning mirrors, as disclosed in U.S. Pat. No. 11,287,585, that are configured to optically couple light from the optical connector part 288 to the photonic integrated circuit 214. The optical coupling components 310 are densely packed and have a fine pitch so that optical signals from many optical fibers can be coupled to the photonic integrated circuit 284. For example, the minimum distance between adjacent optical coupling components 310 can be as small as, e.g., 5 μm, 10 μm, 50 μm, or 100 μm.

An array of electrical terminals 312 arranged on the top main surface 294 of the photonic integrated circuit 284 are electrically coupled to an array of electrical terminals 314 arranged on the bottom main surface 292 of the circuit board 286. The array of electrical terminals 312 and the array of electrical terminals 314 have a fine pitch, in which the minimum distance between two adjacent electrical terminals can be as small as, e.g., 10 μm, 40 μm, or 100 μm. An array of electrical terminals 316 arranged on the bottom main surface of the first serializers/deserializers 216 are electrically coupled to an array of electrical terminals 318 arranged on the top main surface 290 of the circuit board 286. An array of electrical terminals 320 arranged on the bottom main surface of the second serializers/deserializers module 217 are electrically coupled an array of electrical terminals 322 arranged on the top main surface 290 of the circuit board 286.

For example, the arrays of electrical terminals 312, 314, 316, 318, 320, and 322 have a fine pitch (or fine pitches). For simplicity of description, in the example of FIG. 8, for each of the arrays of electrical terminals 312, 314, 316, 318, 320, and 322, the minimum distance between adjacent terminals is d2, which can be in the range of, e.g., 10 μm to 200 μm. In some examples, the minimum distance between adjacent terminals for different arrays of electrical terminals can be different. For example, the minimum distance between adjacent terminals for the arrays of electrical terminals 314 (which are arranged on the bottom surface of the circuit board 286) can be different from the minimum distance between adjacent terminals for the arrays of electrical terminals 318 arranged on the top surface of the circuit board 286. The minimum distance between adjacent terminals for the arrays of electrical terminals 316 of the first serializers/deserializers 216 can be different from the minimum distance between adjacent terminals for the arrays of electrical terminals 320 of the second serializers/deserializers module 217.

An array of electrical terminals 324 arranged on the bottom main surface of the circuit board 286 are electrically coupled to the array of contacts 298. The array of electrical terminals 324 can have a coarse pitch. For example, the minimum distance between adjacent electrical terminals is d1, which can be in the range of, e.g., 200 μm to 1 mm. The array of contacts 298 can be configured as a module that maintains a distance that is slightly larger than the thicknesses of the photonic integrated circuit 284 and the control circuit 287 (which is not shown in FIG. 8) between the integrated optical communication device 282 and the package substrate 230 after the integrated optical communication device 282 is coupled to the package substrate 230. The array of contacts 298 can include, e.g., a substrate that has embedded spring loaded connectors.

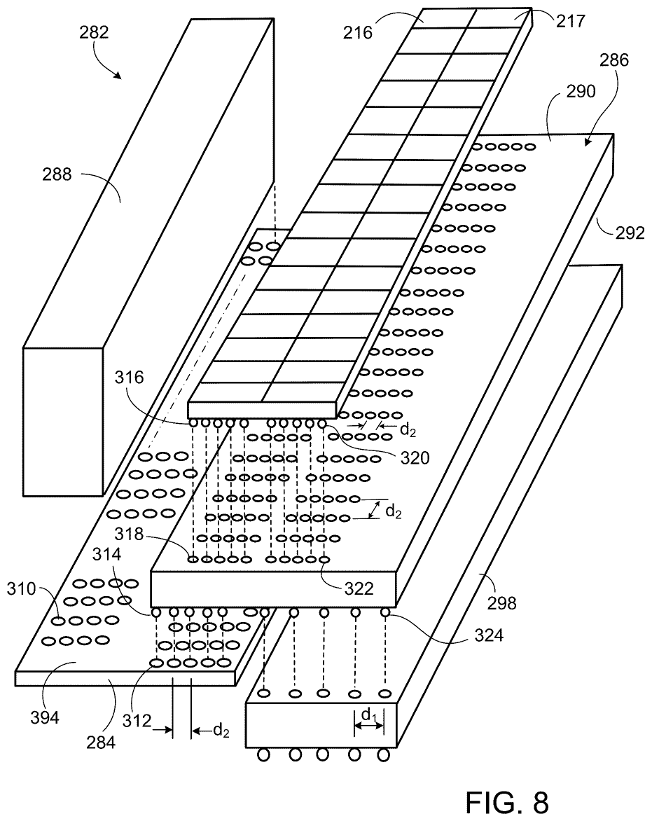

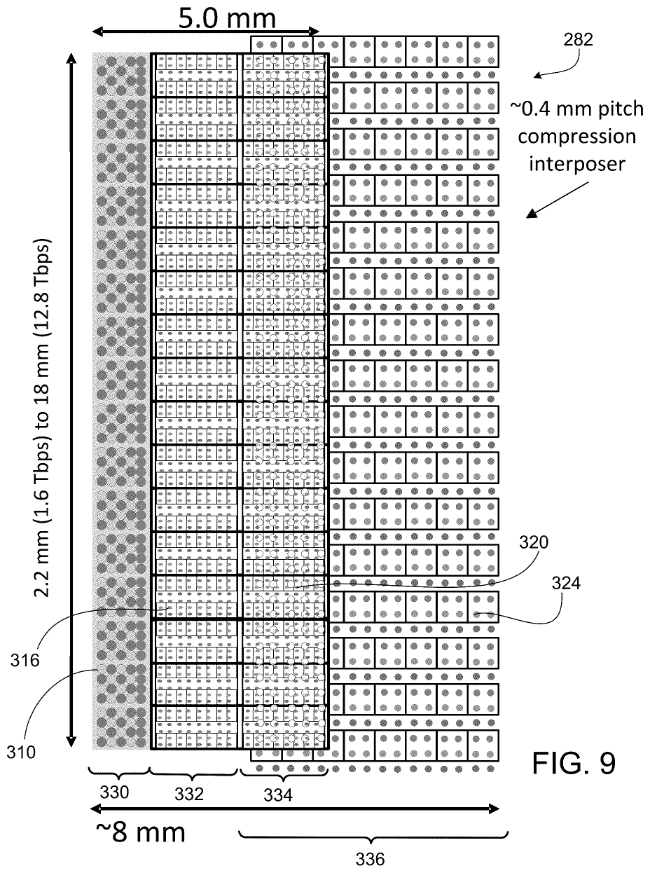

FIG. 9 is a diagram of an example layout design for optical and electrical terminals of the integrated optical communication device 282 of FIGS. 7 and 8. FIG. 9 shows the layout of the optical and electrical terminals when viewed from the top or bottom side of the device 282. In this example, the photonic integrated circuit 284 has a width of about 5 mm and a length of about 2.2 mm to 18 mm. For the example in which the length of the photonic integrated circuit 284 is about 2.2 mm, the optical signals provided to the photonic integrated circuit 284 can have a total bandwidth of about 1.6 Tbps. For the example in which the length of the photonic integrated circuit is about 18 mm, the optical signals provided to the photonic integrated circuit can have a total bandwidth of about 12.8 Tbps. The width of the integrated optical communication device 282 can be about 8 mm.

An array 330 of optical coupling components 310 is provided to allow optical signals to be provided to the photonic integrated circuit 284 in parallel. The first serializers/deserializers 216 include an array 332 of electrical terminals 316 arranged on the bottom surface of the first serializers/deserializers 216. The second serializers/deserializers module 217 include an array 334 of electrical terminals 320 arranged on the bottom surface of the second serializers/deserializers module 217. The arrays 332 and 334 of electrical terminals 316, 320 have a fine pitch, and the minimum distance between adjacent terminals can be in the range of, e.g., 40 μm to 200 μm. An array 336 of electrical terminals 324 is arranged on the bottom main surface of the circuit board 286. The array 336 of electrical terminals 324 has a coarse pitch, and the minimum distance between adjacent terminals can be in the range of, e.g., 200 μm to 1 mm. For example, the array 336 of electrical terminals 324 can be part of a compression interposer that has a pitch of about 400 μm between terminals.

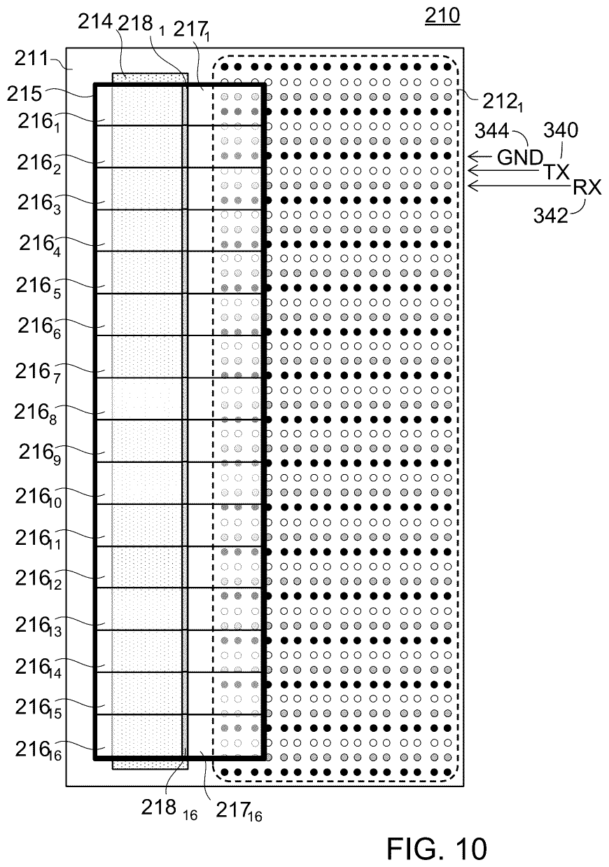

FIG. 10 is a diagram of an example layout design for optical and electrical terminals of the integrated optical communication device 210 of FIG. 2. FIG. 10 shows the layout of the optical and electrical terminals when viewed from the top or bottom side of the device 210. In this embodiment, the photonic integrated circuit 214 is implemented as a single chip. In some embodiments, the photonic integrated circuit 214 can be tiled across multiple chips. Likewise, the electronic communication integrated circuit 215 is implemented as a single chip in this embodiment. In some embodiments, the electronic communication integrated circuit 215 can be tiled cross multiple chips. In this embodiment, the electronic communication integrated circuit 215 is implemented using 16 serializers/deserializers blocks 216_1 to 216_16 that are electrically connected to the photonic integrated circuit 214 and 16 serializers/deserializers blocks 217_1 to 217_16, which are electrically connected to an array of contacts 212_1 by electrical connectors that pass through the substrate 211 in the thickness direction. The 16 serializers/deserializers blocks 216_1 to 216_16 are electrically coupled to the 16 serializers/deserializers blocks 217_1 to 217_16 by bus processing units 218_1 to 218_16, respectively. In this embodiment, each serializers/deserializers block (216 or 217) is implemented using 8 serial differential transmitters (TX) and 8 serial differential receivers (RX). In order to transfer the electrical signals from the serializers/deserializers blocks 217 to ASIC 240, a total of 8×16×2=256 electrical differential signal contacts 212_1 in addition to 8×17×2=272 ground (GND) contacts 212_1 can be used. Other contact arrangements that beneficially reduce crosstalk, e.g., placing a ground contact between every pair of TX and RX contacts, can also be used as will be appreciated by a person skilled in the art. The transmitter contacts are collectively referenced as 340, the receiver contacts are collectively referenced as 342, and the ground contacts are collectively referenced as 344.

The electrical contacts of the serializers/deserializers blocks 216_1 to 216_12 and 217_1 to 217_12 have a fine pitch, and the minimum distance between adjacent terminals can be in the range of, e.g., 40 μm to 200 μm. The electrical contacts 212_1 have a coarse pitch, and the minimum distance between adjacent terminals can be in the range of, e.g., 200 μm to 1 mm.

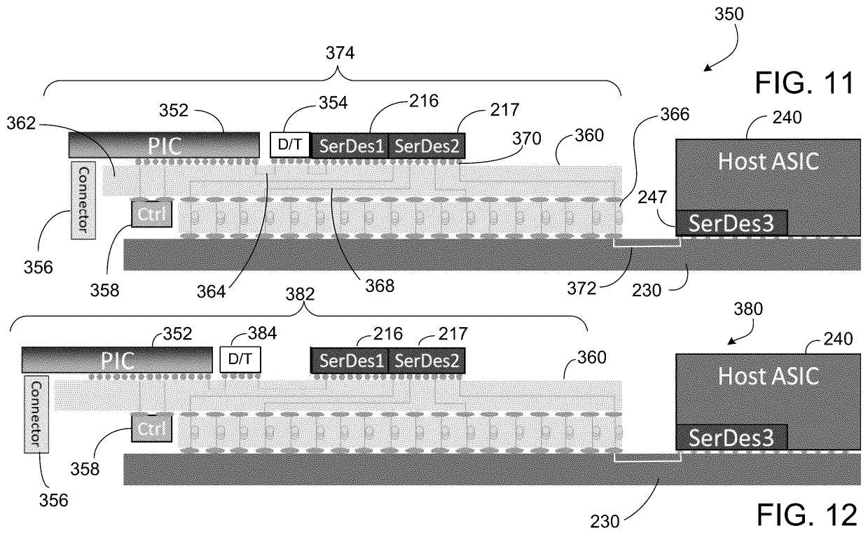

FIG. 11 is a schematic side view of an example data processing system 350, which includes an integrated optical communication device 374, a package substrate 230, and a host application specific integrated circuit 240. The integrated optical communication device 374 and the host application specific integrated circuit 240 are mounted on the top side of the package substrate 230. The integrated optical communication device 374 includes a first optical connector 356 that allows optical signals transmitted in optical fibers to be coupled to the integrated optical communication device 374, in which a portion of the optical fibers connected to the first optical connector 356 are positioned at a region facing the bottom side of the package substrate 230.

The integrated optical communication device 374 includes a photonic integrated circuit 352, a combination of drivers and transimpedance amplifiers (D/T) 354, a first serializers/deserializers module 216, a second serializers/deserializers module 217, the first optical connector 356, a control module 358, and a substrate 360. The host application specific integrated circuit 240 includes an embedded third serializers/deserializers module 247.

In this example, the photonic integrated circuit 352, the drivers and transimpedance amplifiers 354, the first serializers/deserializers module 216, and the second serializers/deserializers module 217 are mounted on the top side of the substrate 360. In some embodiments, the drivers and transimpedance amplifiers 354, the first serializers/deserializers module 216, and the second serializers/deserializers module 217 can be monolithically integrated into a single electrical chip. The first optical connector 356 is optically coupled to the bottom side of the photonic integrated circuit 352. The control module 358 is electrically coupled to electrical terminals arranged on the bottom side of the substrate 360, whereas the photonic integrated circuit 352 is connected to electrical terminals arranged on the top side of the substrate 360. The control module 358 is electrically coupled to the photonic integrated circuit 352 through electrical connectors 362 that pass through the substrate 360 in the thickness direction. In some embodiments, the substrate 360 can be removably connected to the package substrate 230, e.g., using a compression interposer or a land grid array.

The photonic integrated circuit 352 is electrically coupled to the drivers and transimpedance amplifiers 354 through electrical connectors 364 on or in the substrate 360. The drivers and transimpedance amplifiers 354 are electrically coupled to the first serializers/deserializers module 216 by electrical connectors 366 on or in the substrate 360. The second serializers/deserializers module 216 has electrical terminals 370 on the bottom side that are electrically coupled to electrical terminals 366 arranged on the bottom side of the substrate 360 through electrical connectors 368 that pass through the substrate 360 in the thickness direction. The electrical terminals 370 have a fine pitch, whereas the electrical terminals 366 have a coarse pitch. The electrical terminals 366 are electrically coupled to the third serializers/deserializers module 247 through electrical connectors or traces 372 on or in the package substrate 230.

In some implementations, optical signals are converted by the photonic integrated circuit 352 to electrical signals, which are conditioned by the first serializers/deserializers module 216 (or the second serializers/deserializers module 217), and processed by the host application specific integrated circuit 240. The host application specific integrated circuit 240 generates electrical signals that are converted by the photonic integrated circuit 352 into optical signals.

FIG. 12 is a schematic side view of an example data processing system 380, which includes an integrated optical communication device 382, a package substrate 230, and a host application specific integrated circuit 240. The integrated optical communication device 382 is similar to the integrated optical communication device 374 (FIG. 11), except that the transimpedance amplifiers and drivers are implemented in a separate chip 384 from the chip housing the serializers/deserializers modules 216 and 217.

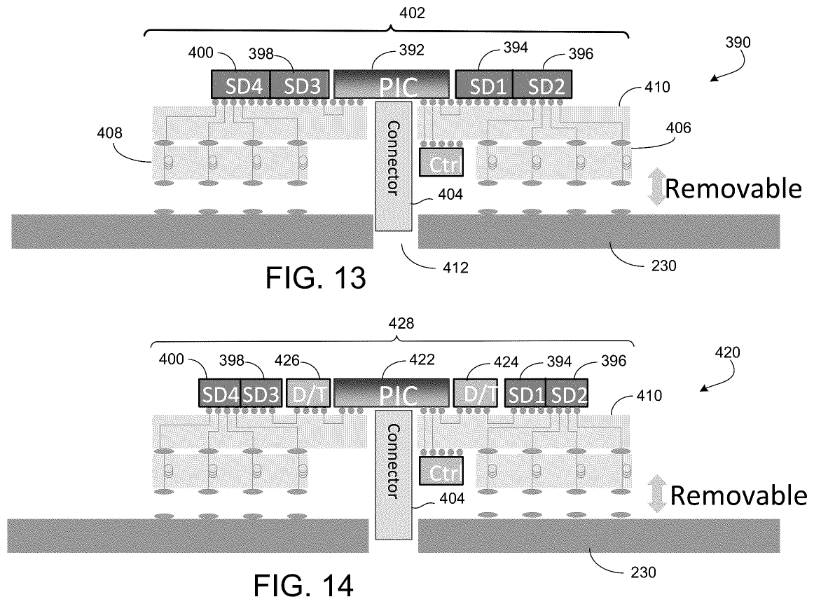

FIG. 13 is a schematic side view of an example data processing system 390 that includes an integrated optical communication device 402, a package substrate 230, and a host application specific integrated circuit (not shown in the figure). The integrated optical communication device 402 includes photonic integrated circuit 392, a first serializers/deserializers module 394, a second serializers/deserializers module 396, a third serializers/deserializers module 398, and a fourth serializers/deserializers module 400 that are mounted on a substrate 410. The photonic integrated circuit 392 can include transimpedance amplifiers and drivers, or such amplifiers and/or drivers can be included in the serializers/deserializers modules 394 and 398. The first serializers/deserializers module 394 and the second serializers/deserializers module 396 are positioned on the right side of the photonic integrated circuit 392. The third serializers/deserializers module 398 and the fourth serializers/deserializers module 400 are positioned on the left side of the photonic integrated circuit 392. Here, the term “left” and “right” refer to the relative positions shown in the figure. It is understood that the system 390 can be positioned in any orientation so that the first serializers/deserializers module 394 and the second serializers/deserializers module 396 are not necessarily at the right side of the photonic integrated circuit 392, and the third serializers/deserializers module 398 and the fourth serializers/deserializers module 400 are not necessarily at the left side of the photonic integrated circuit 392.

The photonic integrated circuit 392 receives optical signals from a first optical connector 404, generates serial electrical signals based on the optical signals, sends the serial electrical signals to the first and second serializers/deserializers modules 394 and 398. The first and second serializers/deserializers modules 394 and 398 generate parallel electrical signals based on the received serial electrical signals, and send the parallel electrical signals to the third and fourth serializers/deserializers modules 396 and 400, respectively. The third and fourth serializers/deserializers modules 396 and 400 generate serial electrical signals based on the received parallel electrical signals, and send the serial electrical signals to electrical terminals 406 and 408, respectively, arranged on the bottom side of the substrate 410.

The first optical connector 404 is optically coupled to the bottom side of the photonic integrated circuit 392. In some embodiments, the optical connector 404 can also be placed on the top of the photonic integrated circuit 392 and couple light to the top side of the photonic integrated circuit 392 (not shown in the figure). The first optical connector 404 is optically coupled to a second optical connector, which in turn is optically coupled to a plurality of optical fibers. In the configuration shown in FIG. 13, the first optical connector 404, the second optical connector, and/or the optical fibers pass through an opening 412 in the package substrate 230. The electrical terminals 406 are arranged on the right side of the first optical connector 404, and the electrical terminals 408 are arranged on the left side of the first optical connector 404. The electrical terminals 406 and 408 are configured such that the substrate 410 can be removably coupled to the package substrate 230.

FIG. 14 is a schematic side view of an example data processing system 420 that includes an integrated optical communication device 428, a package substrate 230, and a host application specific integrated circuit (not shown in the figure). The integrated optical communication device 428 includes a photonic integrated circuit 422 (which does not include a transimpedance amplifier and driver), a first serializers/deserializers module 394, a second serializers/deserializers module 396, a third serializers/deserializers module 398, and a fourth serializers/deserializers module 400 that are mounted on a substrate 410. The integrated optical communication device 428 includes a first set of transimpedance amplifiers and driver circuits 424 positioned at the right of the photonic integrated circuit 422, and a second set of transimpedance amplifiers and driver circuits 426 positioned at the left of the photonic integrated circuit 422. The first set of transimpedance amplifiers and driver circuits 424 is positioned between the photonic integrated circuit 422 and a first serializers/deserializers module 394. The second set of transimpedance amplifiers and driver circuits 424 is positioned between the photonic integrated circuit 422 and a third serializers/deserializers module 398.

In some implementations, the integrated optical communication device 402 (or 408) can be modified such that the first optical connector 404 couples optical signals to the top side of the photonic integrated circuit 392 (or 422).

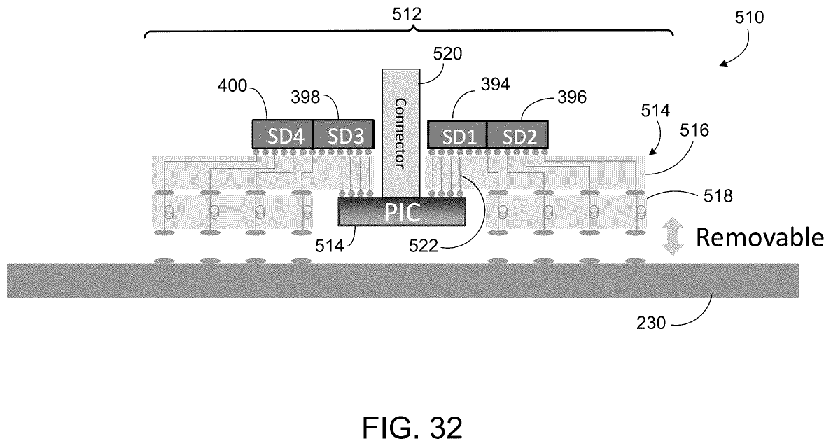

FIG. 32 is a schematic side view of an example data processing system 510 that includes an integrated optical communication device 512, a package substrate 230, and a host application specific integrated circuit (not shown in the figure). The integrated optical communication device 512 includes a substrate 514 that includes a first slab 516 and a second slab 518. The first slab 516 provides electrical connectors to fan out the electrical contacts. The first slab 516 includes a first set of contacts arranged on the top surface and a second set of contacts arranged on the bottom surface, in which the first set of contacts has a fine pitch and the second set of contacts has a coarse pitch. The second slab 518 provides a removable connection to the package substrate 230. A photonic integrated circuit 524 is mounted on the bottom side of the first slab 516. A first optical connector 520 passes through an opening in the substrate 514 and couples optical signals to the top side of the photonic integrated circuit 524.

A first serializers/deserializers module 394, a second serializers/deserializers module 396, a third serializers/deserializers module 398, and a fourth serializers/deserializers module 400 are mounted on the top side of the first slab 516. The photonic integrated circuit 524 is electrically coupled to the first and third serializers/deserializers modules 394 and 398 by electrical connectors 522 that pass through the substrate 514 in the thickness direction. For example, the electrical connectors 522 can be implemented as vias. In some examples, drivers and transimpedance amplifiers can be integrated in the photonic integrated circuit 524, or integrated in the serializers/deserializers modules 394 and 398. In some examples, the drivers and transimpedance amplifiers can be implemented in a separate chip (not shown in the figure) positioned between the photonic integrated circuit 524 and the serializers/deserializers modules 394 and 398, similar to the example in FIG. 14. A control chip (not shown in the figure) can be provided to control the operation of the photonic integrated circuit 512.

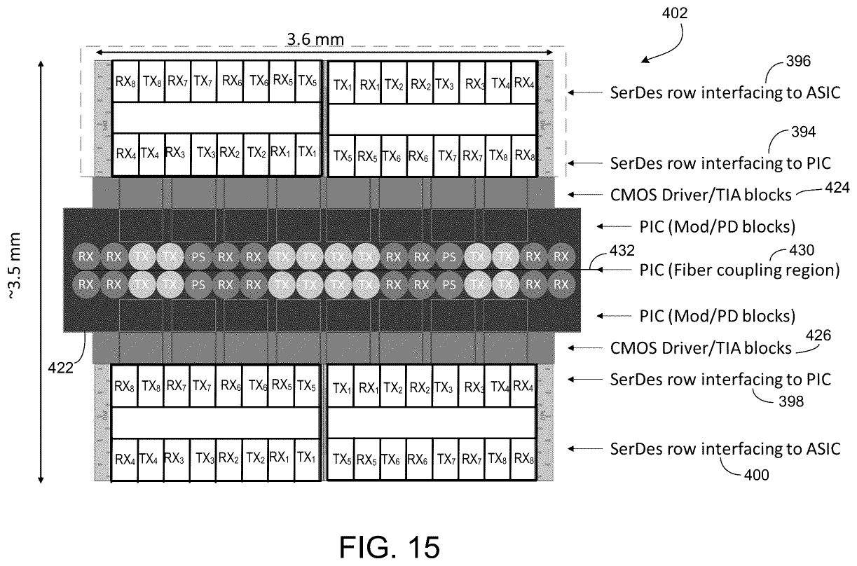

FIG. 15 is a bottom view of an example of the integrated optical communication device 428 of FIG. 14. The photonic integrated circuit 422 includes modulator and photodetector blocks on both sides of a center line 432 in the longitudinal direction. The photonic integrated circuit 422 includes a fiber coupling region 430 arranged either at the bottom side of the photonic integrated circuit 392 or at the top side of the photonic integrated circuit (see FIG. 32), in which the fiber coupling region 430 includes multiple optical coupling elements 310, e.g., receiver optical coupling elements (RX), transmitter optical coupling elements (TX), and remote optical power supply (e.g., 103 in FIG. 1) optical coupling elements (PS).

Complementary metal oxide semiconductor (CMOS) transimpedance amplifier and driver blocks 424 are arranged on the right side of the photonic integrated circuit 424, and CMOS transimpedance amplifier and driver blocks 426 are arranged on the left side of the photonic integrated circuit 424. A first serializers/deserializers module 394 and a second serializers/deserializers module 396 are arranged on the right side of the CMOS transimpedance amplifier and driver blocks 424. A third serializers/deserializers module 398 and a fourth serializers/deserializers module 400 are arranged on the left side of the CMOS transimpedance amplifier and driver blocks 426.

In this example, each of the first, second, third, and fourth serializers/deserializers module 394, 396, 398, 400 includes 8 serial differential transmitter blocks and 8 serial differential receiver blocks. The integrated optical communication device 428 has a width of about 3.5 mm and a length of slightly more than about 3.6 mm.

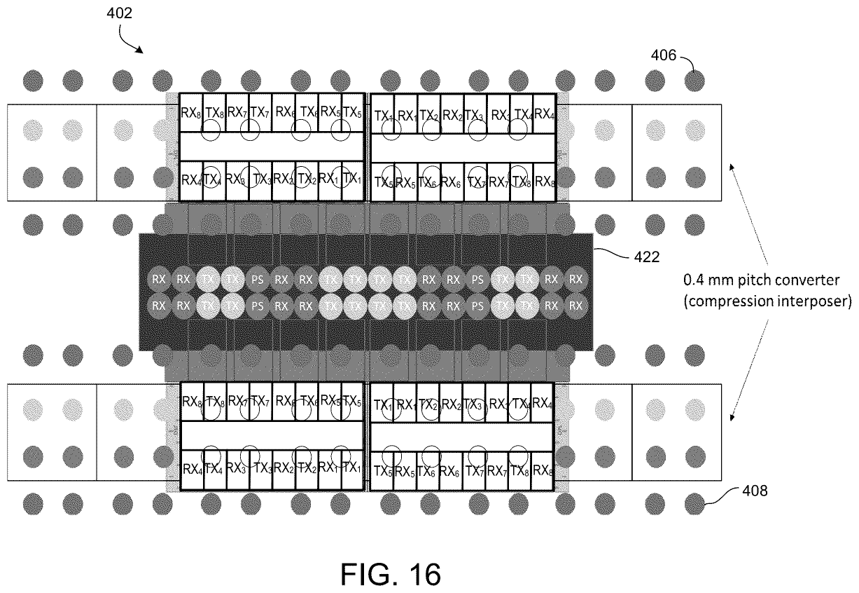

FIG. 16 is a bottom view of an example of the integrated optical communication device 428 of FIG. 14, in which the electrical terminals 406 and 408 are also shown. As shown in the figure, the electrical terminals 406 and 408 have a coarse pitch, the minimum distance between terminals in the array of electrical terminals 406 or 408 is much larger than the minimum distance between terminals in the array of electrical terminals of the first, second, third, and fourth serializers/deserializers modules 394, 396, 398, and 400. For example, the array of electrical terminals 406 and 408 can be part of a compression interposer that has a pitch of about 400 μm between terminals.

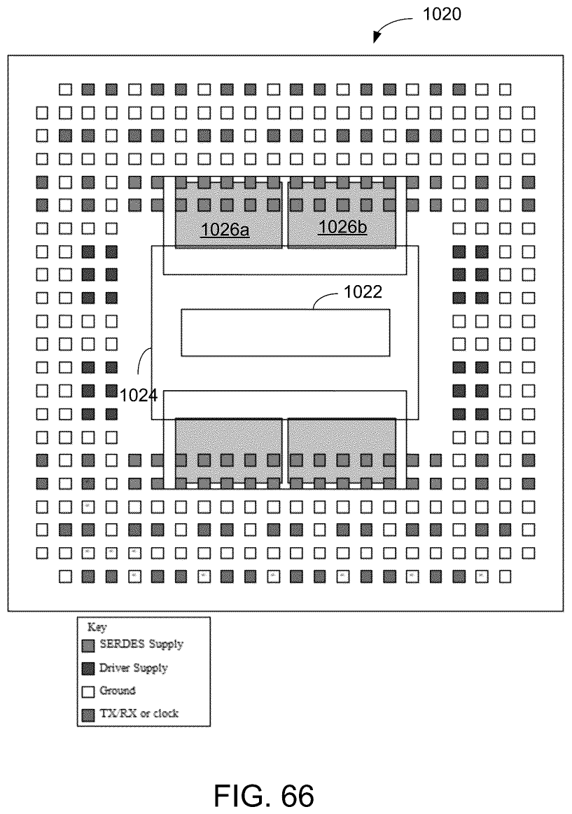

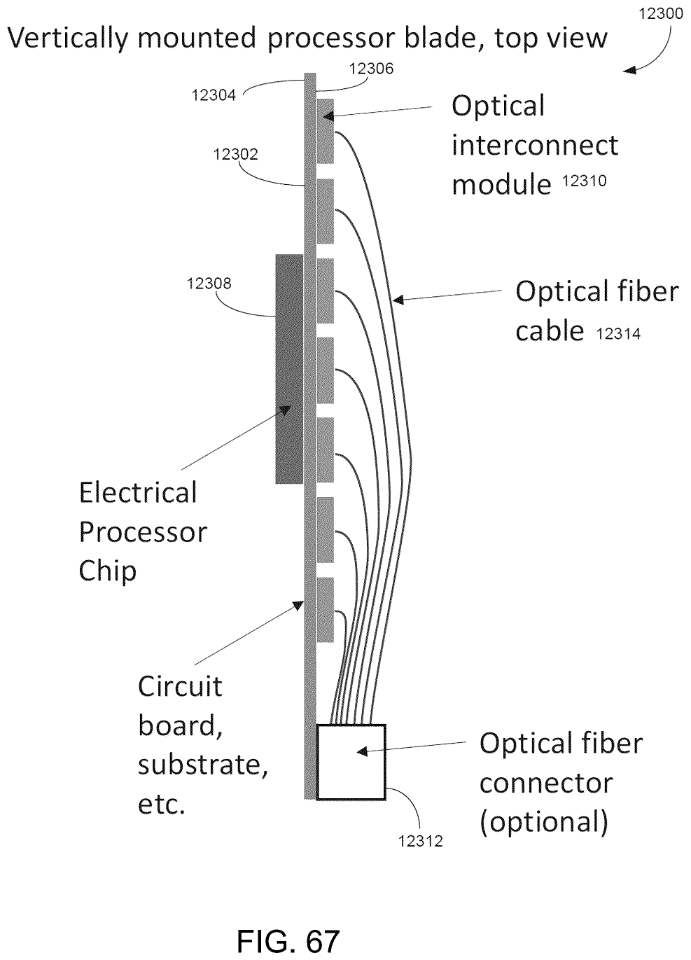

In some implementations, the electrical terminals (e.g., 406 and 408) can be arranged in a configuration as shown in FIG. 66. FIG. 66 shows a pad map 1020 that shows the locations of various contact pads as viewed from the bottom of the package. The contact pads occupy an area that is about 9.8 mm×9.8 mm, in which 400 μm pitch pads are used.

The middle rectangle 1022 is a cutout that connects the photonic integrated circuit to the optics that leave from the top of the module. The bigger rectangle 1024 represents the photonic integrated circuit. The two gray rectangles 1026a, 1026b represent circuitry in a serializers/deserializers chip 1028a. The two gray rectangles 1026c, 1026d represent circuitry in another serializers/deserializers chip 1028b. The serializers/deserializers chips are positioned on the top of the package, and the photonic integrated circuit is positioned on the bottom of the package. The overlap between the photonic integrated circuit and the serializers/deserializers chips 1028a, 1028b is designed so that vias (not shown in the figure) can directly connect these integrated circuits through the package. In some implementations, the serializers/deserializers chips 1028a, 1028b and/or other electronic integrated circuits can be placed around three or four sides of the optical connector (represented by the rectangle 1022), similar to the examples shown in FIGS. 168 to 170.

In the examples of the data processing systems shown in FIGS. 2-8, 11-14, and 32, the integrated optical communication device (e.g., 210, 252, 262, 282, 374, 382, 402, 428, 512, which includes the photonic integrated circuit and the serializers/deserializers modules) is mounted on the package substrate 230 on the same side (top side in the examples shown in the figures) as the electronic processor integrated circuit (or host application specific integrated circuit) 240. The data processing systems can also be modified such that the integrated optical communication device is mounted on the package substrate 230 on the opposite side as the electronic processor integrated circuit (or host application specific integrated circuit) 240. For example, the electronic processor integrated circuit 240 can be mounted on the top side of the package substrate 230 and one or more integrated optical communication devices of the form disclosed in FIGS. 2-8, 11-14, and 32 can be mounted on the bottom side of the package substrate 230.

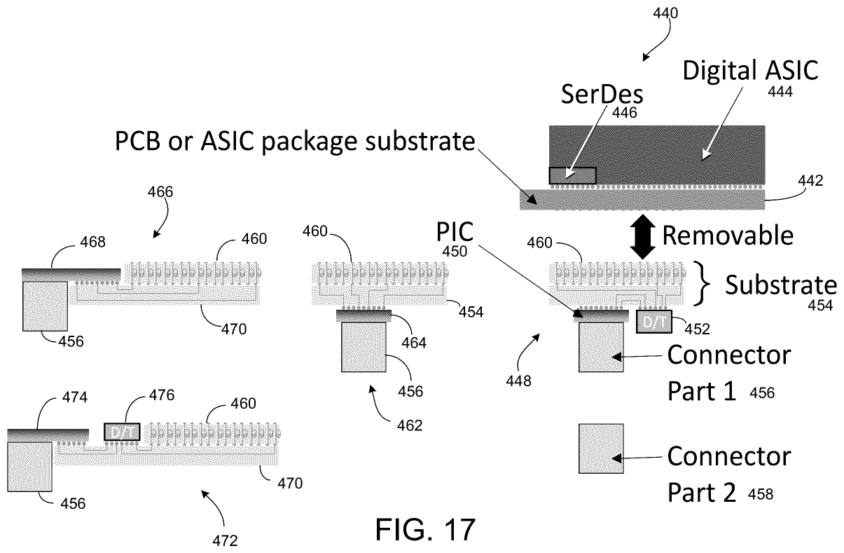

FIG. 17 is a diagram showing four types of integrated optical communication devices that can be used in a data processing system 440. In these examples, the integrated optical communication device does not include serializers/deserializers modules. At least some of the signal conditioning is performed by the serializers/deserializers module(s) in the digital application specific integrated circuit. The integrated optical communication device is mounted on the side of the printed circuit board that is opposite to the side on which the digital application specific integrated circuit is mounted, allowing the connectors to be short.

In a first example, the data processing system includes a digital application specific integrated circuit 444 mounted on the top side of a substrate 442, and an integrated optical communication device 448 mounted on the bottom side of the first circuit board. In some implementations, the integrated optical communication device 448 includes a photonic integrated circuit 450 and a set of transimpedance amplifiers and drivers 452 that are mounted on the bottom side of a substrate 454 (e.g., a second circuit board). The top side of the photonic integrated circuit 450 is electrically coupled to the bottom side of the substrate 454. A first optical connector part 456 is optically coupled to the bottom side of the photonic integrated circuit 450. The first optical connector part 456 is configured to be optically coupled to a second optical connector part 458 that is optically coupled to a plurality of optical fibers (not shown in the figure). An array of electrical terminals 460 is arranged on the top side of the substrate 454 and configured to enable the integrated optical communication device 448 to be removably coupled to the substrate 442.

The optical signals from the optical fibers are processed by the photonic integrated circuit 450, which generates serial electrical signals based on the optical signals. The serial electrical signals are amplified by the set of transimpedance amplifiers and drivers 452, which drives the output signals that are transmitted to a serializers/deserializers module 446 embedded in the digital application specific integrated circuit 444.

In a second example, an integrated optical communication device 462 can be mounted on the bottom side of the substrate 442 to provide an optical/electrical communications interface between the optical fibers and the digital application specific integrated circuit 444. The integrated optical communication device 462 includes a photonic integrated circuit 464 that is mounted on the bottom side of a substrate 454 (e.g., a second circuit board). The top side of the photonic integrated circuit 464 is electrically coupled to the bottom side of the substrate 454. A first optical connector part 456 is optically coupled to the bottom side of the photonic integrated circuit 450. An array of electrical terminals 460 is arranged on the top side of the substrate 454 and configured to enable the integrated optical communication device 462 to be removably coupled to the substrate 442. The integrated optical communication device 462 is similar to the integrated optical communication device 448, except that either the photonic integrated circuit 464 or the serializers/deserializers module 446 includes the set of transimpedance amplifiers and driver circuitry. In some examples, the serializers/deserializers module 446 is configured to directly accept electrical signals emerging from photonic integrated circuit 464, e.g., by having a high enough receiver input impedance that converts the photocurrent generated within the photonic integrated circuit 464 to a voltage swing suitable for further electrical processing. For example, the serializers/deserializers module 446 is configured to have a low transmitter output impedance, and provide an output voltage swing that allows direct driving of optical modulators embedded within the photonic integrated circuit 464.

In a third example, an integrated optical communication device 466 can be mounted on the bottom side of the substrate 442 to provide an optical/electrical communications interface between the optical fibers and the digital application specific integrated circuit 444. The integrated optical communication device 466 includes a photonic integrated circuit 468 that is mounted on the top side of a substrate 470 (e.g., a second circuit board). The bottom side of the photonic integrated circuit 468 is electrically coupled to the top side of the substrate 470. A first optical connector part 456 is optically coupled to the bottom side of the photonic integrated circuit 468. An array of electrical terminals 460 is arranged on the top side of the substrate 470 and configured to enable the integrated optical communication device 466 to be removably coupled to the substrate 442. In some examples, either the photonic integrated circuit 468 or the serializers/deserializers module 446 includes the set of transimpedance amplifiers and driver circuitry. In some examples, the serializers/deserializers module 446 is configured to directly accept electrical signals emerging from the photonic integrated circuit 464.

In a fourth example, an integrated optical communication device 472 can be mounted on the bottom side of the substrate 442 to provide an optical/electrical communications interface between the optical fibers and the digital application specific integrated circuit 444. The integrated optical communication device 472 includes a photonic integrated circuit 474 and a set of transimpedance amplifiers and drivers 476 that are mounted on the top side of a substrate 470 (e.g., a second circuit board). The bottom side of the photonic integrated circuit 474 is electrically coupled to the top side of the substrate 470. A first optical connector part 456 is optically coupled to the bottom side of the photonic integrated circuit 468. An array of electrical terminals 460 is arranged on the top side of the substrate 470 and configured to enable the integrated optical communication device 466 to be removably coupled to the substrate 442. The integrated optical communication device 472 is similar to the integrated optical communication device 466, except that neither the photonic integrated circuit 464 nor the serializers/deserializers module 446 include a set of transimpedance amplifiers and driver circuitry, and the set of transimpedance amplifiers and drivers 476 is implemented as a separate integrated circuit.

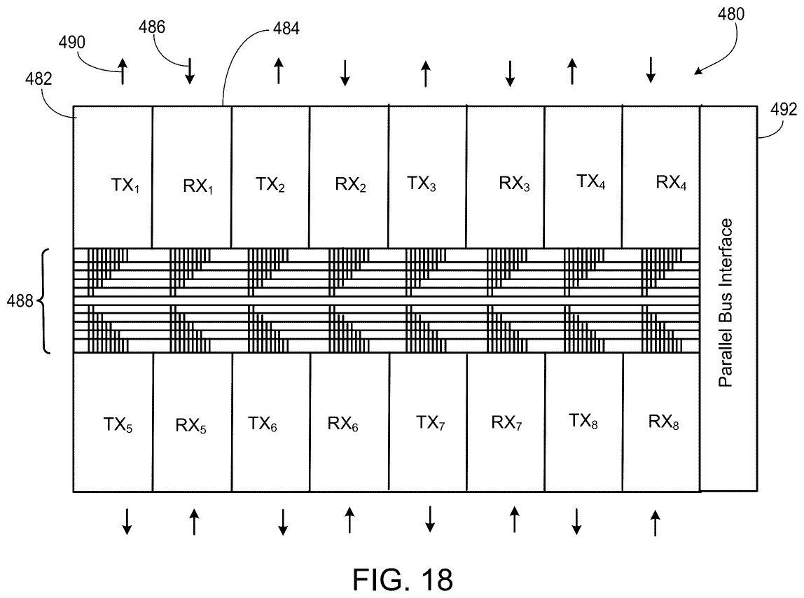

FIG. 18 is a diagram of an example octal serializers/deserializers block 480 that includes 8 serial differential transmitters (TX) 482 and 8 serial differential receivers (RX) 484. Each serial differential receiver 484 receives a serial differential signal, generates parallel signals based on the serial differential signal, and provides the parallel signals on the parallel bus 488. Each serial differential transmitter 482 receives parallel signals from the parallel bus 488, generates a serial differential signal based on the parallel signals, and provides the serial differential signal on an output electrical terminal 490. The serializers/deserializers block 480 outputs and/or receives parallel signals through a parallel bus interface 492.

In the examples described above, such as those shown in FIGS. 2-14, the integrated optical communication device (e.g., 210, 252, 262, 282, 374, 382, 402, 428) includes a first serializers/deserializers module (e.g., 216, 394, 398) and a second serializers/deserializers module (e.g., 217, 396, 400). The first serializers/deserializers module serially interfaces with the photonic integrated circuit, and the second serializers/deserializers module serially interfaces with the electronic processor integrated circuit or host application specific integrated circuit (e.g., 240). In some implementations, the electronic communication integrated circuit 215 includes an array of serializers/deserializers that can be logically partitioned into a first sub-array of serializers/deserializers and a second sub-array of serializers/deserializers. The first sub-array of serializers/deserializers corresponds to the serializers/deserializers module (e.g., 216, 394, 398), and the second sub-array of serializers/deserializers corresponds to the second serializers/deserializers module (e.g., 217, 396, 400).

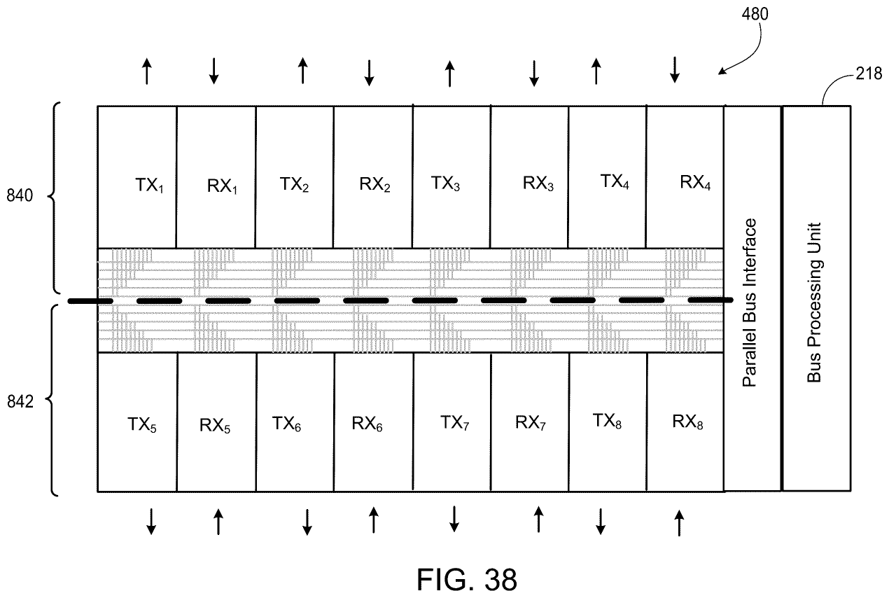

FIG. 38 is a diagram of an example octal serializers/deserializers block 480 coupled to a bus processing unit 218. The octal serializers/deserializers block 480 includes 8 serial differential transmitters (TX1 to TX8) 482 and 8 serial differential receivers (RX1 to RX4) 484. In some implementations, the transmitters and receivers are partitioned such that the transmitters TX1, TX2, TX3, TX4 and receivers RX1, RX2, RX3, RX4 form a first serializers/deserializers module 840, and the transmitters TX5, TX6, TX7, TX8 and receivers RX5, RX6, RX7, RX8 form a second serializers/deserializers module 842. Serial electrical signals received at the receivers RX1, RX2, RX3, RX4 are converted to parallel electrical signals and routed by the bus processing unit 218 to the transmitters TX5, TX6, TX7, TX8, which convert the parallel electrical signals to serial electrical signals. For example, the photonic integrated circuit can send serial electrical signals to the receivers RX1, RX2, RX3, RX4, and the transmitters TX5, TX6, TX7, TX8 can transmit serial electrical signals to the electronic processor integrated circuit or host application specific integrated circuit.

For example, the bus processing unit 218 can re-map the lanes of signals and perform coding on the signals, such that the bit rate and/or modulation format of the serial signals output from the transmitters TX5, TX6, TX7, TX8 can be different from the bit rate and/or modulation format of the serial signals received at the receivers RX1, RX2, RX3, RX4. For example, 4 lanes of T Gbps NRZ serial signals received at the receivers RX1, RX2, RX3, RX4 can be re-encoded and routed to transmitters TX5, TX6 to output 2 lanes of 2×T Gbps PAM4 serial signals.

Similarly, serial electrical signals received at the receivers RX5, RX6, RX7, RX8 are converted to parallel electrical signals and routed by the bus processing unit 218 to the transmitters TX1, TX2, TX3, TX4, which convert the parallel electrical signals to serial electrical signals. For example, the electronic processor integrated circuit or host application specific integrated circuit can send serial electrical signals to the receivers RX5, RX6, RX7, RX8, and the transmitters TX1, TX2, TX3, TX4 can transmit serial electrical signals to the photonic integrated circuit.

For example, the bus processing unit 218 can re-map the lanes of signals and perform coding on the signals, such that the bit rate and/or modulation format of the serial signals output from the transmitters TX1, TX2, TX3, TX4 can be different from the bit rate and/or modulation format of the serial signals received at the receivers RX5, RX6, RX7, RX8. For example, 2 lanes of 2×T Gbps PAM4 serial signals received at receivers RX5, RX6 can be re-encoded and routed to the transmitters TX5, TX6, TX7, TX8 to output 4 lanes of T Gbps NRZ serial signals.

FIG. 39 is a diagram of another example octal serializers/deserializers block 480 coupled to a bus processing unit 218, in which the transmitters and receivers are partitioned such that the transmitters TX1, TX2, TX5, TX6 and receivers RX1, RX2, RX5, RX6 form a first serializers/deserializers module 850, and the transmitters TX3, TX4, TX7, TX8 and receivers RX3, RX4, RX7, RX8 form a second serializers/deserializers module 852. Serial electrical signals received at the receivers RX1, RX2, RX5, RX6 are converted to parallel electrical signals and routed by the bus processing unit 218 to the transmitters TX3, TX4, TX7, TX8, which convert the parallel electrical signals to serial electrical signals. For example, the photonic integrated circuit can send serial electrical signals to the receivers RX1, RX2, RX5, RX6, and the transmitters TX3, TX4, TX7, TX8 can transmit serial electrical signals to the electronic processor integrated circuit or host application specific integrated circuit.

Similarly, serial electrical signals received at the receivers RX3, RX4, RX7, RX8 are converted to parallel electrical signals and routed by the bus processing unit 218 to the transmitters TX1, TX2, TX5, TX6, which convert the parallel electrical signals to serial electrical signals. For example, the electronic processor integrated circuit or host application specific integrated circuit can send serial electrical signals to the receivers RX3, RX4, RX7, RX8, and the transmitters TX1, TX2, TX5, TX6 can transmit serial electrical signals to the photonic integrated circuit.

In some implementations, the bus processing unit 218 can re-map the lanes of signals and perform coding on the signals, such that the bit rate and/or modulation format of the serial signals output from the transmitters TX3, TX4, TX7, TX8 can be different from the bit rate and/or modulation format of the serial signals received at the receivers RX1, RX2, RX5, RX6. Similarly, the bus processing unit 218 can re-map the lanes of signals and perform coding on the signals such that the bit rate and/or modulation format of the serial signals output from the transmitters TX1, TX2, TX5, TX6 can be different from the bit rate and/or modulation format of the serial signals received at the receivers RX4, RX4, RX7, RX8.

FIGS. 38 and 39 show two examples of how the receivers and transmitters can be partitioned to form the first serializers/deserializers module and the second serializers/deserializers module. The partitioning can be arbitrarily determined based on application, and is not limited to the examples shown in FIGS. 38 and 39. The partitioning can be programmable and dynamically changed by the system.

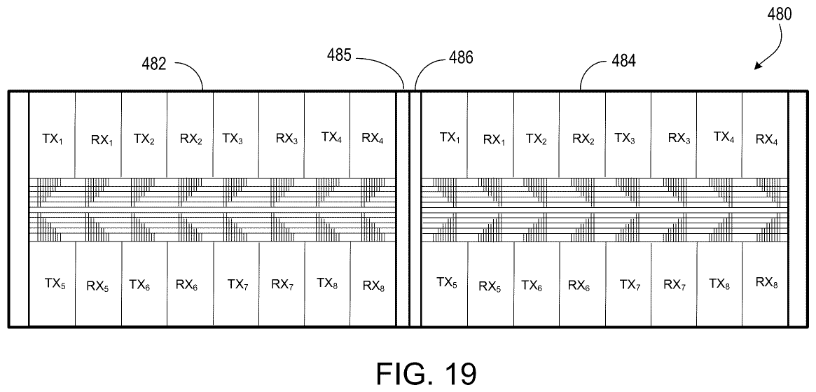

FIG. 19 is a diagram of an example electronic communication integrated circuit 480 that includes a first octal serializers/deserializers block 482 electrically coupled to a second octal serializers/deserializers block 484. For example, the electronic communication integrated circuit 480 can be used as the electronic communication integrated circuit 215 of FIGS. 2 and 3. The first octal serializers/deserializers block 482 can be used as the first serializers/deserializers module 216, and the second octal serializers/deserializers block 484 can be used as the second serializers/deserializers module 217. For example, the first octal serializers/deserializers block 482 can receive 8 serial differential signals, e.g., through electrical terminals arranged at the bottom side of the block, and generate 8 sets of parallel signals based on the 8 serial differential signals, in which each set of parallel signals is generated based on the corresponding serial differential signal. The first octal serializers/deserializers block 482 can condition serial electrical signals upon conversion into the 8 sets of parallel signals, such as performing clock and data recovery, and/or signal equalization. The first octal serializers/deserializers block 482 transmits the 8 sets of parallel signals to the second octal serializers/deserializers block 484 through a parallel bus 485 and a parallel bus 486. The second octal serializers/deserializers block 484 can generate 8 serial differential signals based on the 8 sets of parallel signals, in which each serial differential signal is generated based on the corresponding set of parallel signals. The second octal serializers/deserializers block 484 can output the 8 serial differential signals through, e.g., electrical terminals arranged at the bottom side of the block.

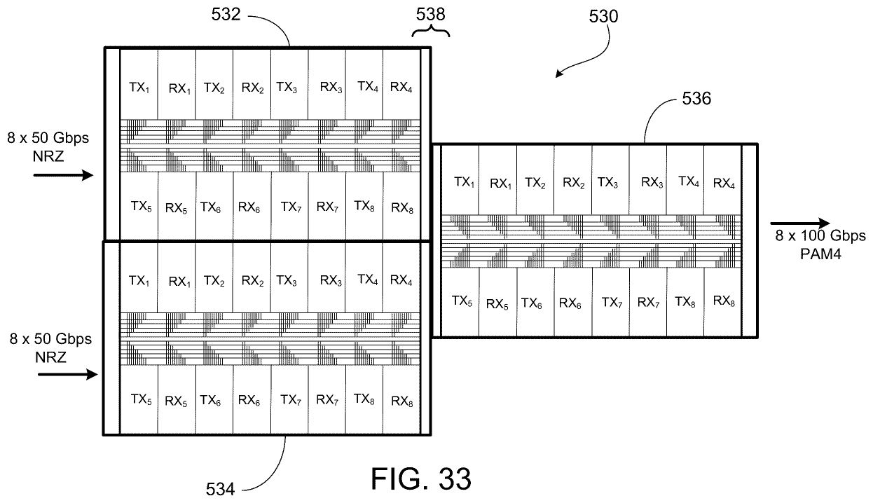

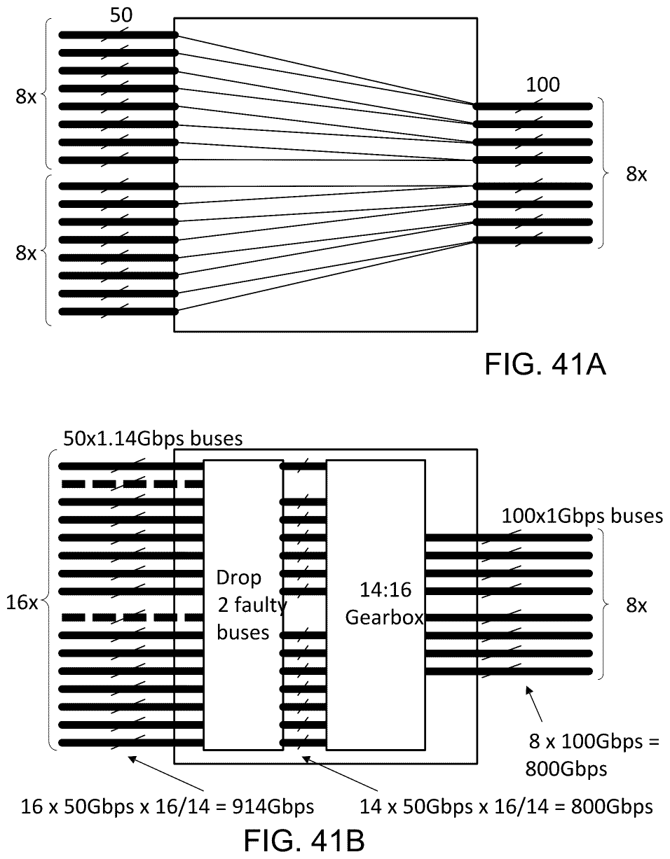

Multiple serializers/deserializers blocks can be electrically coupled to multiple serializers/deserializers blocks through a bus processing unit that can be, e.g., a parallel bus of electrical lanes, a static or a dynamically reconfigurable cross-connect device, or a re-mapping device (gearbox). FIG. 33 is a diagram of an example electronic communication integrated circuit 530 that includes a first octal serializers/deserializers block 532 and a second octal serializers/deserializers block 534 electrically coupled to a third octal serializers/deserializers block 536 through a bus processing unit 538. In this example, the bus processing unit 538 is configured to enable switching of the signals, allowing the routing of signals to be re-mapped, in which 8×50 Gbps serial electrical signals using NRZ modulation that are serially interfaced to the first and second octal serializers/deserializers blocks 532 and 534 are re-routed or combined into 8×100 Gbps serial electrical signals using PAM4 modulation that are serially interfaced to the third octal serializers/deserializers block 536. An example of the bus processing unit 538 is shown in FIG. 41A. In some examples, the bus processing unit 538 enables N lanes of T Gbps serial electrical signals to be remapped into N/M lanes of M×T Gbps serial electrical signals, N and M being positive integers, T being a real value, in which the N serially interfacing electrical signals can be modulated using a first modulation format and the M serially interfacing electrical signals can be modulated using a second modulation format.

In some other examples, the bus processing unit 538 can allow for redundancy to increase reliability. For example, the first and the second serializers/deserializers blocks 532 and 534 can be jointly configured to serially interface to a total of N lanes of T×N (N−k) Gbps electrical signals, while the third serializers/deserializers block 536 can be configured to serially interface to N lanes of T Gbps electrical signals. The bus processing unit 538 can then be configured to remap the data from only N−k out of the N lanes serially interfacing to the first and the second serializers/deserializers blocks 532 and 534 (carrying an aggregate bit rate of (N−k)×T×N (N−k)=T×N) to the third serializers/deserializers block 536. This way, the bus processing unit 538 allows for k out of N serially interfacing electrical links to the first and the second serializers/deserializers blocks 532 and 534 to fail while still maintaining an aggregate of T×N Gbps of data serially interfacing to the third serializers/deserializers block 536. The number k is a positive integer. In some embodiments, k can be approximately 1% of N. In some other embodiments, k can be approximately 10% of N. In some embodiment, the selection of which N-k of the N serially interfacing electrical links to the first and the second serializers/deserializers blocks 532 and 534 to remap to the third serializers/deserializers block 536 using bus processing unit 538 can be dynamically selected, e.g., based on signal integrity and signal performance information extracted from the serially interfacing signals by the serializers/deserializers blocks 532 and 534. An example of the bus processing unit 538 is shown in FIG. 41B, in which N=16, k=2, T=50 Gbps.

In some examples, using the redundancy technique discussed above, the bus processing unit 538 enables N lanes of T×N (N−k) Gbps serial electrical signals to be remapped into N/M lanes of M×T Gbps serial electrical signals. The bus processing unit 538 enables k out of N serially interfacing electrical links to fail while still maintaining an aggregate of T×N Gbps of data serially interfacing to the third serializers/deserializers block 536.

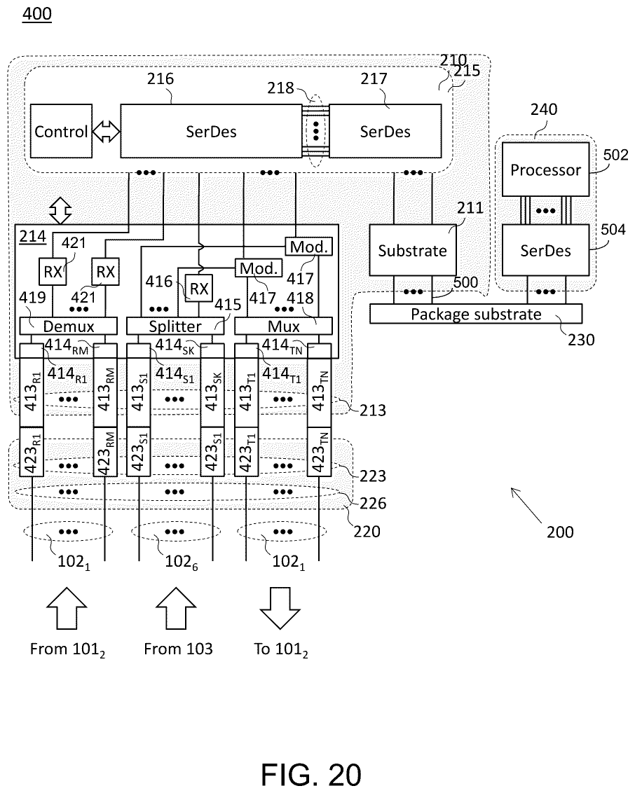

FIG. 20 is a functional block diagram of an example data processing system 200, which can be used to implement, e.g., one or more of devices 101_1 to 101_6 of FIG. 1. Without implied limitation, the data processing system 200 is shown as part of the node 101_1 for illustration purposes. The data processing system 200 can be part of any other network element of the system 100. The data processing system 200 includes an integrated communication device 210, a fiber-optic connector assembly 220, a package substrate 230, and an electronic processor integrated circuit 240.

The connector assembly 220 includes a connector 223 and a fiber array 226. The connector 223 can include multiple individual fiber-optic connectors 423_i (i∈{R1 . . . RM; S1 . . . SK; T1 . . . TN} with K, M, and N being positive integers). In some embodiments, some or all of the individual connectors 423_i can form a single physical entity. In some embodiments some or all of the individual connectors 423_i can be separate physical entities. When operating as part of the network element 101_1 of the system 100, (i) the connectors 423_S1 through 423_SK can be connected to optical power supply 103, e.g., through link 1026, to receive supply light; (ii) the connectors 423_R1 through 423_RM can be connected to the transmitters of the node 101_2, e.g., through the link 102_1, to receive from the node 1012 optical communication signals; and (iii) the connectors 423_T1 through 423_TN can be connected to the receivers of the node 101_2, e.g., through the link 102_1, to transmit to the node 101_2 optical communication signals.

In some implementations, the communication device 210 includes an electronic communication integrated circuit 215, a photonic integrated circuit 214, a connector part 213, and a substrate 211. The connector part 213 can include multiple individual optical connectors 413_i to photonic integrated circuit 214 (i∈{R1 . . . RAM; S1 . . . SK; T1 . . . TN} with K, M, and N being positive integers). In some embodiments, some or all of the individual connectors 413_i can form a single physical entity. In some embodiments some or all of the individual connectors 413_i can be separate physical entities. The optical connectors 413_i are configured to optically couple light to the photonic integrated circuit 214 using optical coupling interfaces 414, e.g., vertical grating couplers, turning mirrors, etc., as disclosed in U.S. Pat. No. 11,287,585.

In operation, light entering the photonic integrated circuit 214 from the link 102_6 through coupling interfaces 414_S1 through 414_SK can be split using an optical splitter 415. The optical splitter 415 can be an optical power splitter, an optical polarization splitter, an optical wavelength demultiplexer, or any combination or cascade thereof, e.g., as disclosed in U.S. Pat. No. 11,153,670 and in U.S. published patent application US2021/0376950, which is incorporated herein by reference in its entirety. In some embodiments, one or more splitting functions of the splitter 415 can be integrated into the optical coupling interfaces 414 and/or into optical connectors 413. For example, in some embodiments, a polarization-diversity vertical grating coupler can be configured to simultaneously act as a polarization splitter 415 and as a part of optical coupling interface 414. In some other embodiments, an optical connector that includes a polarization-diversity arrangement can simultaneously act as an optical connector 413 and as a polarization splitter 415.

In some embodiments, light at one or more outputs of the splitter 415 can be detected using a receiver 416, e.g., to extract synchronization information as disclosed in U.S. Pat. No. 11,153,670. In various embodiments, the receiver 416 can include one or more p-i-n photodiodes, one or more avalanche photodiodes, one or more self-coherent receivers, or one or more analog (heterodyne/homodyne) or digital (intradyne) coherent receivers. In some embodiments, one or more opto-electronic modulators 417 can be used to modulate onto light at one or more outputs of the splitter 415 data for communication to other network elements.

Modulated light at the output of the modulators 417 can be multiplexed in polarization or wavelength using a multiplexer 418 before leaving the photonic integrated circuit 214 through optical coupling interfaces 414_T1 through 414_TN. In some embodiments, the multiplexer 418 is not provided, i.e., the output of each modulator 417 can be directly coupled to a corresponding optical coupling interface 414.

On the receiver side, light entering the photonic integrated circuit 214 through a coupling interfaces 414_R1 through 414_RM from, e.g., the link 101_2, can first be demultiplexed in polarization and/or in wavelength using an optical demultiplexer 419. The outputs of the demultiplexer 419 are then individually detected using receivers 421. In some embodiments, the demultiplexer 419 is not provided, i.e., the output of each coupling interface 414_R1 through 414_RM can be directly coupled to a corresponding receiver 421. In various embodiments, the receiver 421 can include one or more p-i-n photodiodes, one or more avalanche photodiodes, one or more self-coherent receivers, or one or more analog (heterodyne/homodyne) or digital (intradyne) coherent receivers.

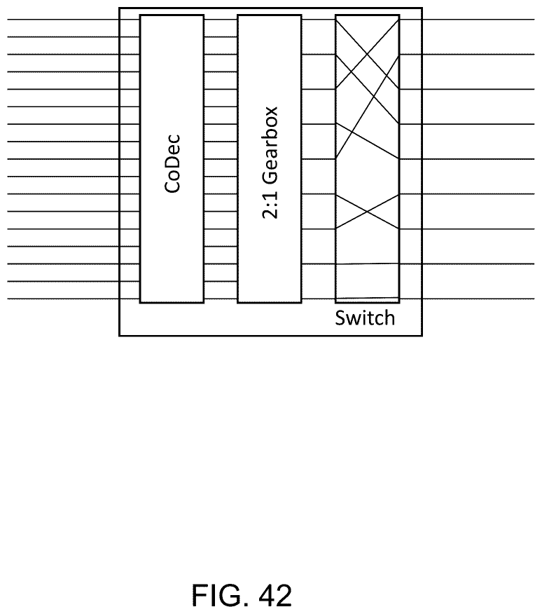

The photonic integrated circuit 214 is electrically coupled to the integrated circuit 215. In some implementations, the photonic integrated circuit 214 provides a plurality of serial electrical signals to the first serializers/deserializers module 216, which generates sets of parallel electrical signals based on the serial electrical signals, in which each set of parallel electrical signal is generated based on a corresponding serial electrical signal. The first serializers/deserializers module 216 conditions the serial electrical signals, demultiplexes them into the sets of parallel electrical signals and sends the sets of parallel electrical signals to the second serializers/deserializers module 217 through a bus processing unit 218. In some implementations, the bus processing unit 218 enables switching of signals and performs line coding and/or error-correcting coding functions. An example of the bus processing unit 218 is shown in FIG. 42.

The second serializers/deserializers module 217 generates a plurality of serial electrical signals based on the sets of parallel electrical signals, in which each serial electrical signal is generated based on a corresponding set of parallel electrical signal. The second serializers/deserializers module 217 sends the serial electrical signals through electrical connectors that pass through the substrate 211 in the thickness direction to an array of electrical terminals 500 that are arranged on the bottom surface of the substrate 211. For example, the array of electrical terminals 500 configured to enable the integrated communication device 210 to be easily coupled to, or removed from, the package substrate 230.

In some implementations, the electronic processor integrated circuit 240 includes a data processor 502 and an embedded third serializers/deserializers module 504. The third serializers/deserializers module 504 receives the serial electrical signals from the second serializers/deserializers module 217, and generates sets of parallel electrical signals based on the serial electrical signals, in which each set of parallel electrical signal is generated based on a corresponding serial electrical signal. The data processor 502 processes the sets of parallel signals generated by the third serializers/deserializers module 504.

In some implementations, the data processor 502 generates sets of parallel electrical signals, and the third serializers/deserializers module 504 generates serial electrical signals based on the sets of parallel electrical signals, in which each serial electrical signal is generated based on a corresponding set of parallel electrical signal. The serial electrical signals are sent to the second serializers/deserializers module 217, which generates sets of parallel electrical signals based on the serial electrical signals, in which each set of parallel electrical signal is generated based on a corresponding serial electrical signal. The second serializers/deserializers module 217 sends the sets of parallel electrical signals to the first serializers/deserializers module 216 through the bus processing unit 218. The first serializers/deserializers module 216 generates serial electrical signals based on the sets of parallel electrical signals, in which each serial electrical signal is generated based on a corresponding set of parallel electrical signals. The first serializers/deserializers module 216 sends the serial electrical signals to the photonic integrated circuit 214. The opto-electronic modulators 417 modulate optical signals based on the serial electrical signals, and the modulated optical signals are output from the photonic integrated circuit 214 through optical coupling interfaces 414_T1 through 414_TN.

In some embodiments, supply light from the optical power supply 103 includes an optical pulse train, and synchronization information extracted by the receiver 416 can be used by the serializers/deserializers module 216 to align the electrical output signals of the serializers/deserializers module 216 with respective copies of the optical pulse trains at the outputs of the splitter 415 at the modulators 417. For example, the optical pulse train can be used as an optical power supply at the optical modulator. In some such implementations, the first serializers/deserializers module 216 can include interpolators or other electrical phase adjustment elements.

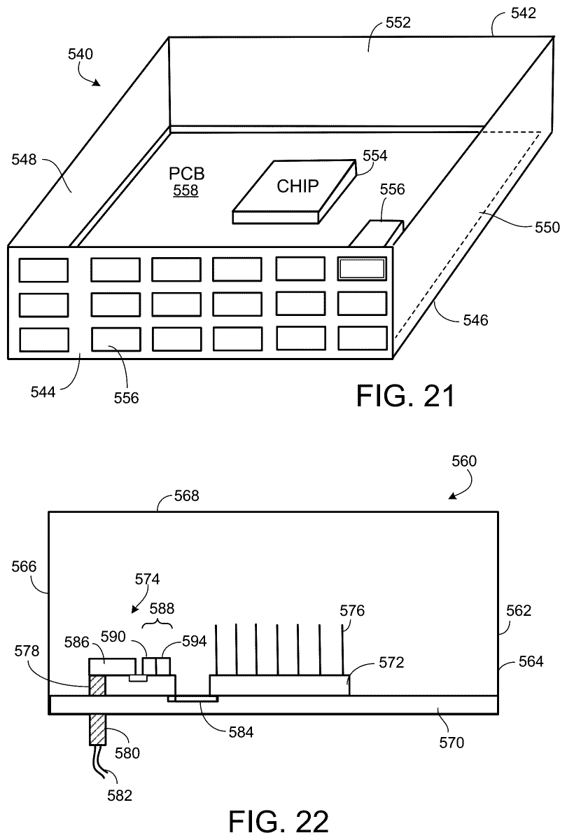

Referring to FIG. 21, in some implementations, a data processing system 540 includes an enclosure or housing 542 that has a front panel 544, a bottom panel 546, side panels 548 and 550, a rear panel 552, and a top panel (not shown in the figure). The system 540 includes a printed circuit board 558 that extends substantially parallel to the bottom panel 546. A data processing chip 554 is mounted on the printed circuit board 558, in which the chip 554 can be, e.g., a network switch, a central processor unit, a graphics processor unit, a tensor processing unit, a neural network processor, an artificial intelligence accelerator, a digital signal processor, a microcontroller, or an application specific integrated circuit (ASIC).

At the front panel 544 are pluggable input/output interfaces 556 that allow the data processing chip 554 to communicate with other systems and devices. For example, the input/output interfaces 556 can receive optical signals from outside of the system 540 and convert the optical signals to electrical signals for processing by the data processing chip 554. The input/output interfaces 556 can receive electrical signals from the data processing chip 554 and convert the electrical signals to optical signals that are transmitted to other systems or devices. For example, the input/output interfaces 556 can include one or more of small form-factor pluggable (SFP), SFP+, SFP28, QSFP, QSFP28, or QSFP56 transceivers. The electrical signals from the transceiver outputs are routed to the data processing chip 554 through electrical connectors on or in the printed circuit board 558.

In the examples shown in FIGS. 21 to 29B, 69A, 70, 71A, 72, 72A, 74A, 75A, 75C, 76, 77A, 77B, 78, 96 to 98, 100, 110, 112, 113, 115, 117 to 122, 125A to 127, 129, 136 to 149, 159, and 160, various embodiments can have various form factors, e.g., in some embodiments the top panel and the bottom panel 546 can have the largest area, in other embodiments the side panels 548 and 550 can have the largest area, and in yet other embodiments the front panel 544 and the rear panel 552 can have the largest area. In various embodiments, the printed circuit board 558 can be substantially parallel to the two side panels, e.g., the data processing system 540 as shown in FIG. 21 can stand on one of its side panels during normal operation (such that the side panel 550 is positioned at the bottom, and the bottom panel 546 is positioned at the side). In various embodiments, the data processing system 540 can comprise two or more printed circuit boards some of which can be substantially parallel to the bottom panel and some of which can be substantially parallel to the side panels. For example, in some computer systems for machine learning/artificial intelligence applications have vertical circuit boards that are plugged into the systems. As used herein, the distinction between “front” and “back” is made based on where the majority of input/output interfaces 556 are located, irrespective of what a user may consider the front or back of data processing system 540.

FIG. 22 is a diagram of a top view of an example data processing system 560 that includes a housing 562 having side panels 564 and 566, and a rear panel 568. The system 560 includes a vertically mounted printed circuit board 570 that can also function as the front panel. The surface of the printed circuit board 570 is substantially perpendicular to the bottom panel of the housing 562. The term “substantially perpendicular” is meant to take into account of manufacturing and assembly tolerances, so that if a first surface is substantially perpendicular to a second surface, the first surface is at an angle in a range from 85° to 95° relative to the second surface. On the printed circuit board 570 are mounted a data processing chip 572 and an integrated communication device 574. In some examples, the data processing chip 572 and the integrated communication device 574 are mounted on a substrate (e.g., a ceramic or high-density build-up substrate), and the substrate is attached (e.g., electrically coupled) to the printed circuit board 570. The data processing chip 572 can be, e.g., a network switch, a central processor unit, a graphics processor unit, a tensor processing unit, a neural network processor, an artificial intelligence accelerator, a digital signal processor, a microcontroller, or an application specific integrated circuit (ASIC). A heat sink 576 is provided on the data processing chip 572.

In some implementations, the integrated communication device 574 includes a photonic integrated circuit 586 and an electronic communication integrated circuit 588 mounted on a substrate 594. The electronic communication integrated circuit 588 includes a first serializers/deserializers module 590 and a second serializers/deserializers module 592. The printed circuit board 570 can be similar to the package substrate 230 (FIGS. 2, 4, 11-14), the data processing chip 572 can be similar to the electronic processor integrated circuit or application specific integrated circuit 240, and the integrated communication device 574 can be similar to the integrated communication device 210, 252, 374, 382, 402, 428. In some embodiments, the integrated communication device 574 is soldered to the printed circuit board 570. In some other embodiments, the integrated communication device 574 is removably connected to the printed circuit board 570, e.g., via a land grid array or a compression interposer. Related holding fixtures including snap-on or screw-on mechanisms are not shown in the figure.

In some examples, the integrated communication device 574 includes a photonic integrated circuit without serializers/deserializers modules, and drivers/transimpedance amplifiers (TIA) are provided separately. In some examples, the integrated communication device 574 includes a photonic integrated circuit and drivers/transimpedance amplifiers but without serializers/deserializers modules.

The integrated communication device 574 includes a first optical connector 578 that is configured to receive a second optical connector 580 that is coupled to a bundle of optical fibers 582. The integrated communication device 574 is electrically coupled to the data processing chip 572 through electrical connectors or traces 584 on or in the printed circuit board 570. Because the data processing chip 572 and the integrated communication device 574 are both mounted on the printed circuit board 570, the electrical connectors or traces 584 can be made shorter, compared to the electrical connectors that electrically couple the transceivers 556 to the data processing chip 554 of FIG. 21. Using shorter electrical connectors or traces 584 allows the signals to have a higher data rate with lower noise, lower distortion, and/or lower crosstalk. Mounting the printed circuit board 570 perpendicular to the bottom panel of the housing allows for more easily accessible connections to the integrated communication device 574 that may be removed and re-connected without, e.g., removing the housing from a rack.

In some examples, the bundle of optical fibers 582 can be firmly attached to the photonic integrated circuit 586 without the use of the first and second optical connectors 578, 580.

The printed circuit board 570 can be secured to the side panels 564 and 566, and the bottom and top panels of the housing using, e.g., brackets, screws, clips, and/or other types of fastening mechanisms. The surface of the printed circuit board 570 can be oriented perpendicular to bottom panel of the housing, or at an angle (e.g., between −60° to 60°) relative to the vertical direction (the vertical direction being perpendicular to the bottom panel). The printed circuit board 570 can have multiple layers, in which the outermost layer (i.e., the layer facing the user) has an exterior surface that is configured to be aesthetically pleasing.

The first optical connector 578, the second optical connector 580, and the bundle of optical fibers 582 can be similar to those shown in FIGS. 2, 4, and 11-16. As described above, the bundle of fibers 582 can include 10 or more optical fibers, 100 or more optical fibers, 500 or more optical fibers, or 1000 or more optical fibers. The optical signals provided to the photonic integrated circuit 586 can have a high total bandwidth, e.g., about 1.6 Tbps, or about 12.8 Tbps, or more.

Although FIG. 22 shows one integrated communication device 574, there can be additional integrated communication devices 574 that are electrically coupled to the data processing chip 572. The data processing system 560 can include a second printed circuit board (not shown in the figure) oriented parallel to the bottom panel of the housing 562. The second printed circuit board can support other optical and/or electronic devices, such as storage devices, memory chips, controllers, power supply modules, fans, and other cooling devices.

In some examples of the data processing system 540 (FIG. 21), the transceiver 556 can include circuitry (e.g., integrated circuits) that perform some type of processing of the signals and/or the data contained in the signals. The signals output from the transceiver 556 need to be routed to the data processing chip 554 through longer signal paths that place a limit on the data rate. In some data processing systems, the data processing chip 554 outputs processed data that are routed to one of the transceivers and transmitted to another system or device. Again, the signals output from the data processing chip 554 need to be routed to the transceiver 556 through longer signal paths that place a limit on the data rate. By comparison, in the data processing system 560 (FIG. 22), the electrical signals that are transmitted between the integrated communication devices 574 and the data processing chip 572 pass through shorter signal paths and thus support a higher data rate.

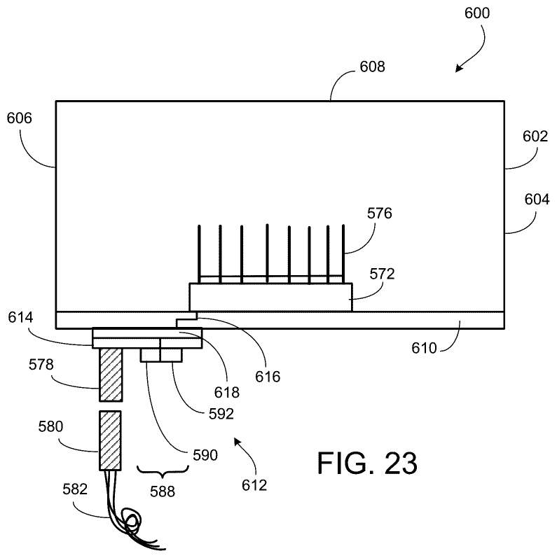

FIG. 23 is a diagram of a top view of an example data processing system 600 that includes a housing 602 having side panels 604 and 606, and a rear panel 608. The system 600 includes a vertically mounted printed circuit board 610 that functions as the front panel. The surface of the printed circuit board 610 is substantially perpendicular to the bottom panel of the housing 602. A data processing chip 572 is mounted on an interior side of the printed circuit board 610, and an integrated communication device 612 is mounted on an exterior side of the printed circuit board 610. In some examples, the data processing chip 572 is mounted on a substrate (e.g., a ceramic or high-density build-up substrate), and the substrate is attached to the printed circuit board 610. In some embodiments, the integrated communication device 612 is soldered to the printed circuit board 610. In some other embodiments, the integrated communication device 612 is removably connected to the printed circuit board 610, e.g., via a land grid array or a compression interposer. Related holding fixtures including snap-on or screw-on mechanisms are not shown in the figure. A heat sink 576 is provided on the data processing chip 572.

In some implementations, the integrated communication device 612 includes a photonic integrated circuit 614 and an electronic communication integrated circuit 588 mounted on a substrate 618. The electronic communication integrated circuit 588 includes a first serializers/deserializers module 590 and a second serializers/deserializers module 592. The integrated communication device 612 includes a first optical connector 578 that is configured to receive a second optical connector 580 that is coupled to a bundle of optical fibers 582. The integrated communication device 612 is electrically coupled to the data processing chip 572 through electrical connectors or traces 616 that pass through the printed circuit board 610 in the thickness direction. Because the data processing chip 572 and the integrated communication device 612 are both mounted on the printed circuit board 610, the electrical connectors or traces 616 can be made shorter, thereby allowing the signals to have a higher data rate with lower noise, lower distortion, and/or lower crosstalk. Mounting the integrated communication device 612 on the outside of the printed circuit board 610 perpendicular to the bottom panel of the housing and accessible from outside the housing allows for more easily accessible connections to the integrated communication device 612 that may be removed and re-connected without, e.g., removing the housing from a rack.

In some examples, the integrated communication device 612 includes a photonic integrated circuit without serializers/deserializers modules, and drivers and transimpedance amplifiers (TIA) are provided separately. In some examples, the integrated communication device 612 includes a photonic integrated circuit and drivers/transimpedance amplifiers but without serializers/deserializers modules. In some examples, the bundle of optical fibers 582 can be firmly attached to the photonic integrated circuit 614 without the use of the first and second optical connectors 578, 580.

In some examples, the data processing chip 572 is mounted on the rear side of the substrate, and the integrated communication device 612 are removably attached to the front side of the substrate, in which the substrate provides high speed connections between the data processing chip 572 and the integrated communication device 612. For example, the substrate can be attached to a front side of a printed circuit board, in which the printed circuit board includes an opening that allows the data processing chip 572 to be mounted on the rear side of the substrate. The printed circuit board can provide from a motherboard electrical power to the substrate (and hence to the data processing chip 572 and the integrated communication device 612, and allow the data processing chip 572 and the integrated communication device 612 to connect to the motherboard using low-speed electrical links.

The printed circuit board 610 can be secured to the side panels 604 and 606, and the bottom and top panels of the housing using, e.g., brackets, screws, clips, and/or other types of fastening mechanisms. The surface of the printed circuit board 610 can be oriented perpendicular to bottom panel of the housing, or at an angle (e.g., between −60° to 60°) relative to the vertical direction (the vertical direction being perpendicular to the bottom panel). The printed circuit board 610 can have multiple layers, in which the portion of the outermost layer (i.e., the layer facing the user) not covered by the integrated communication device 612 has an exterior surface that is configured to be aesthetically pleasing.

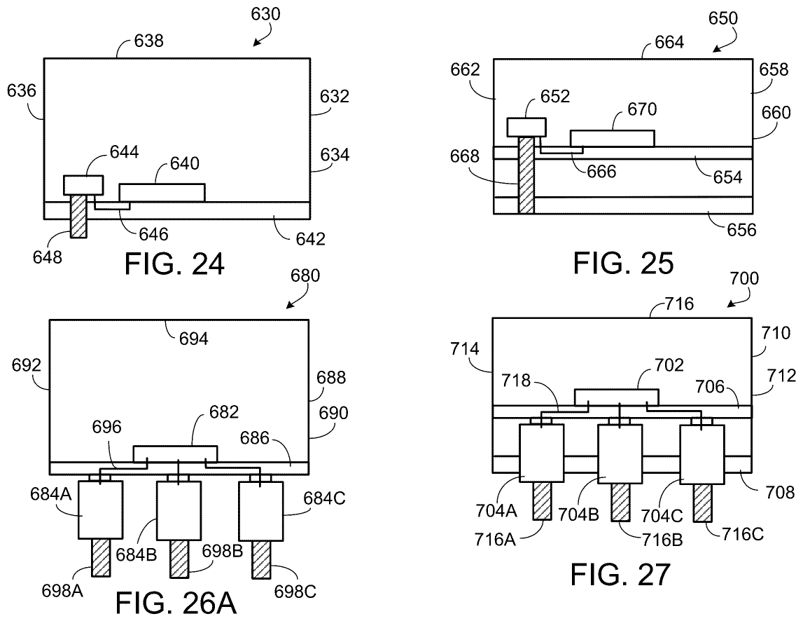

FIGS. 24-27 below illustrate four general designs in which the data processing chips are positioned near the input/output communication interfaces. FIG. 24 is a top view of an example data processing system 630 in which a data processing chip 640 is mounted near an optical/electrical communication interface 644 to enable high bandwidth data paths (e.g., one, ten, or more Gigabits per second per data path) between the data processing chip 640 and the optical/electrical communication interface 644. In this example, the data processing chip 640 and the optical/electrical communication interface 644 are mounted on a circuit board 642 that functions as the front panel of an enclosure 632 of the system 630, thus allowing optical fibers to be easily coupled to the optical/electrical communication interface 644. In some examples, the data processing chip 640 is mounted on a substrate (e.g., a ceramic or high-density build-up substrate), and the substrate is attached to the circuit board 642.

The enclosure 632 has side panels 634 and 636, a rear panel 638, a top panel, and a bottom panel. In some examples, the circuit board 642 is perpendicular to the bottom panel. In some examples, the circuit board 642 is oriented at an angle in a range −60° to 60° relative to a vertical direction of the bottom panel. The side of the circuit board 642 facing the user is configured to be aesthetically pleasing.

The optical/electrical communication interface 644 is electrically coupled to the data processing chip 640 by electrical connectors or traces 646 on or in the circuit board 642. The circuit board 642 can be a printed circuit board that has one or more layers. The electrical connectors or traces 646 can be signal lines printed on the one or more layers of the printed circuit board 642 and provide high bandwidth data paths (e.g., one or more Gigabits per second per data path) between the data processing chip 640 and the optical/electrical communication interface 644.

In a first example, the data processing chip 640 receives electrical signals from the optical/electrical communication interface 644 and does not send electrical signals to the optical/electrical communication interface 644. In a second example, the data processing chip 640 receives electrical signals from, and sends electrical signals to, the optical/electrical communication interface 644. In the first example, the optical/electrical communication interface 644 receives optical signals from optical fibers, generates electrical signals based on the optical signals, and sends the electrical signals to the data processing chip 640. In the second example, the optical/electrical communication interface 644 also receives electrical signals from the data processing chip, generates optical signals based on the electrical signals, and sends the optical signals to the optical fibers.

An optical connector 648 is provided to couple optical signals from the optical fibers to the optical/electrical communication interface 644. In this example, the optical connector 648 passes through an opening in the circuit board 642. In some examples, the optical connector 648 is securely fixed to the optical/electrical communication interface 644. In some examples, the optical connector 648 is configured to be removably coupled to the optical/electrical communication interface 644, e.g., by using a pluggable and releasable mechanism, which can include one or more snap-on or screw-on mechanisms. In some other examples, an array of 10 or more fibers is securely or fixedly attached to the optical connector 648.

The optical/electrical communication interface 644 can be similar to, e.g., the integrated communication device 210 (FIG. 2), 252 (FIG. 4), 374 (FIG. 11), 382 (FIG. 12), 402 (FIG. 13), and 428 (FIG. 14). In some examples, the optical/electrical communication interface 644 can be similar to the integrated optical communication device 448, 462, 466, 472 (FIG. 17), except that the optical/electrical communication interface 644 is mounted on the same side of the circuit board 642 as the data processing chip 640. The optical connector 648 can be similar to, e.g., the first optical connector part 213 (FIGS. 2, 4), the first optical connector 356 (FIGS. 11, 12), the first optical connector 404 (FIGS. 13, 14), and the first optical connector part 456 (FIG. 17). In some examples, a portion of the optical connector 648 can be part of the optical/electrical communication interface 644. In some examples, the optical connector 648 can also include the second optical connector part 223 (FIGS. 2, 4), 458 (FIG. 17) that is optically coupled to the optical fibers. FIG. 24 shows that the optical connector 648 passes through the circuit board 642. In some examples, the optical connector 648 can be short so that the optical fibers pass through, or partly through, the circuit board 642. In some examples, the optical connector is not attached vertically to a photonic integrated circuit that is part of the optical/electrical communication interface 644 but rather can be attached in-plane to the photonic integrated circuit using, e.g., V-groove fiber attachments, tapered or un-tapered fiber edge coupling, etc., followed by a mechanism to direct the light interfacing to the photonic integrated circuit to a direction that is substantially perpendicular to the photonic integrated circuit, such as one or more substantially 90-degree turning mirrors, one or more substantially 90-degree bent optical fibers, etc. Any such solution is conceptually included in the vertical optical coupling attachment schematically visualized in FIGS. 24-27.

FIG. 25 is a top view of an example data processing system 650 in which a data processing chip 670 is mounted near an optical/electrical communication interface 652 to enable high bandwidth data paths (e.g., one, ten, or more Gigabits per second per data path) between the data processing chip 670 and the optical/electrical communication interface 652. In this example, the data processing chip 670 and the optical/electrical communication interface 652 are mounted on a circuit board 654 that is positioned near a front panel 656 of an enclosure 658 of the system 630, thus allowing optical fibers to be easily coupled to the optical/electrical communication interface 652. In some examples, the data processing chip 670 is mounted on a substrate (e.g., a ceramic or high-density build-up substrate), and the substrate is attached to the circuit board 654.

The enclosure 658 has side panels 660 and 662, a rear panel 664, a top panel, and a bottom panel. In some examples, the circuit board 654 and the front panel 656 are perpendicular to the bottom panel. In some examples, the circuit board 654 and the front panel 656 are oriented at an angle in a range −60° to 60° relative to a vertical direction of the bottom panel. In some examples, the circuit board 654 is substantially parallel to the front panel 656, e.g., the angle between the surface of the circuit board 654 and the surface of the front panel 656 can be in a range of −5° to 5°. In some examples, the circuit board 654 is at an angle relative to the front panel 656, in which the angle is in a range of −45° to 45°.

The optical/electrical communication interface 652 is electrically coupled to the data processing chip 670 by electrical connectors or traces 666 on or in the circuit board 654, similar to those of the system 630. The signal path between the data processing chip 670 and the optical/electrical communication interface 652 can be unidirectional or bidirectional, similar to that of the system 630.

An optical connector 668 is provided to couple optical signals from the optical fibers to the optical/electrical communication interface 652. In this example, the optical connector 668 passes through an opening in the front panel 656 and an opening in the circuit board 654. The optical connector 668 can be securely fixed, or releasably connected, to the optical/electrical communication interface 652, similar to that of the system 630.

The optical/electrical communication interface 652 can be similar to, e.g., the integrated communication device 210 (FIG. 2), 252 (FIG. 4), 374 (FIG. 11), 382 (FIG. 12), 402 (FIG. 13), and 428 (FIG. 14). In some examples, the optical/electrical communication interface 652 can be similar to the integrated optical communication device 448, 462, 466, 472 (FIG. 17), except that the optical/electrical communication interface 652 is mounted on the same side of the circuit board 654 as the data processing chip 640. The optical connector 668 can be similar to, e.g., the first optical connector part 213 (FIGS. 2, 4), the first optical connector 356 (FIGS. 11, 12), the first optical connector 404 (FIGS. 13, 14), and the first optical connector part 456 (FIG. 17). In some examples, the optical connector is not attached vertically to a photonic integrated circuit that is part of the optical/electrical communication interface 652 but rather can be attached in-plane to the photonic integrated circuit using, e.g., V-groove fiber attachments, tapered or un-tapered fiber edge coupling, etc., followed by a mechanism to direct the light interfacing to the photonic integrated circuit to a direction that is substantially perpendicular to the photonic integrated circuit, such as one or more substantially 90-degree turning mirrors, one or more substantially 90-degree bent optical fibers, etc. In some examples, a portion of the optical connector 668 can be part of the optical/electrical communication interface 652. In some examples, the optical connector 668 can also include the second optical connector part 223 (FIGS. 2, 4), 458 (FIG. 17) that is optically coupled to the optical fibers. FIG. 25 shows that the optical connector 668 passes through the front panel 656 and the circuit board 654. In some examples, the optical connector 668 can be short so that the optical fibers pass through, or partly through, the front panel 656. The optical fibers can also pass through, or partly through, the circuit board 654.

In the examples of FIGS. 24 and 25, only one optical/electrical communication interface (544, 652) is shown in the figures. It is understood that the systems 630, 650 can include multiple optical/electrical communication interfaces that are mounted on the same circuit board as the data processing chip to enable high bandwidth data paths (e.g., one, ten, or more Gigabits per second per data path) between the data processing chip and each of the optical/electrical communication interfaces.

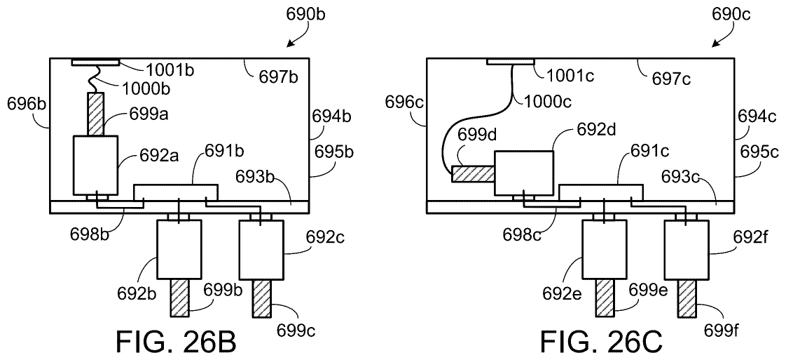

FIG. 26A is a top view of an example data processing system 680 in which a data processing chip 681 is mounted near optical/electrical communication interfaces 682a, 682b, 682c (collectively referenced as 682) to enable high bandwidth data paths (e.g., one, ten, or more Gigabits per second per data path) between the data processing chip 681 and each of the optical/electrical communication interfaces 682. The data processing chip 681 is mounted on a first side of a circuit board 683 that functions as a front panel of an enclosure 684 of the system 680. In some examples, the data processing chip 681 is mounted on a substrate (e.g., a ceramic or high-density build-up substrate), and the substrate is attached to the circuit board 683. The optical/electrical communication interfaces 682 are mounted on a second side of the circuit board 683, in which the second side faces the exterior of the enclosure 684. In this example, the optical/electrical communication interfaces 682 are mounted on an exterior side of the enclosure 684, allowing optical fibers to be easily coupled to the optical/electrical communication interfaces 682.

The enclosure 684 has side panels 685 and 686, a rear panel 687, a top panel, and a bottom panel. In some examples, the circuit board 683 is perpendicular to the bottom panel. In some examples, the circuit board 683 is oriented at an angle in a range −60° to 60° (or −30° to 30°, or −10° to 10°, or −1° to 1°) relative to a vertical direction of the bottom panel.

Each of the optical/electrical communication interfaces 682 is electrically coupled to the data processing chip 681 by electrical connectors or traces 688 that pass through the circuit board 683 in the thickness direction. For example, the electrical connectors or traces 688 can be configured as vias of the circuit board 683. The signal paths between the data processing chip 681 and each of the optical/electrical communication interfaces 682 can be unidirectional or bidirectional, similar to those of the systems 630 and 650.

For example, the system 680 can be configured such that signals are transmitted unidirectionally between the data processing chip 681 and one of the optical/electrical communication interfaces 682, and bidirectionally between the data processing chip 681 and another one of the optical/electrical communication interfaces 682. For example, the system 680 can be configured such that signals are transmitted unidirectionally from the optical/electrical communication interface 682a to the data processing chip 681, and unidirectionally from the data processing chip to the optical/electrical communication interface 682b and/or optical/electrical communication interface 682c.

Optical connectors 689a, 689b, 689c (collectively referenced as 689) are provided to couple optical signals from the optical fibers to the optical/electrical communication interfaces 682a, 682b, 682c, respectively. The optical connectors 689 can be securely fixed, or releasably connected, to the optical/electrical communication interfaces 682, similar to those of the systems 630 and 650.

The optical/electrical communication interface 682 can be similar to, e.g., the integrated communication device 210 (FIG. 2), 252 (FIG. 4), 374 (FIG. 11), 382 (FIG. 12), 402 (FIG. 13), 428 (FIG. 14), and 512 (FIG. 32), except that the optical/electrical communication interface 682 is mounted on the side of the circuit board 683 opposite to the side of the data processing chip 681. In some examples, the optical/electrical communication interface 682 can be similar to the integrated optical communication device 448, 462, 466, 472 (FIG. 17). The optical connector 689 can be similar to, e.g., the first optical connector part 213 (FIGS. 2, 4), the first optical connector 356 (FIGS. 11, 12), the first optical connector 404 (FIGS. 13, 14), the first optical connector part 456 (FIG. 17), and the first optical connector part 520 (FIG. 32). In some examples, the optical connector is not attached vertically to a photonic integrated circuit that is part of the optical/electrical communication interface 682 but rather can be attached in-plane to the photonic integrated circuit using, e.g., V-groove fiber attachments, tapered or un-tapered fiber edge coupling, etc., followed by a mechanism to direct the light interfacing to the photonic integrated circuit to a direction that is substantially perpendicular to the photonic integrated circuit, such as one or more substantially 90-degree turning mirrors, one or more substantially 90-degree bent optical fibers, etc. In some examples, a portion of the optical connector 689 can be part of the optical/electrical communication interface 682. In some examples, the optical connector 689 can also include the second optical connector part 223 (FIGS. 2, 4), 458 (FIG. 17) that is optically coupled to the optical fibers.

In some examples, the optical/electrical communication interfaces 682 are securely fixed (e.g., by soldering) to the circuit board 683. In some examples, the optical/electrical communication interfaces 682 are removably connected to the circuit board 683, e.g., by use of mechanical mechanisms such as one or more snap-on or screw-on mechanisms. An advantage of the system 680 is that in case of a malfunction at one of the optical/electrical communication interfaces 682, the faulty optical/electrical communication interface 682 can be replaced without opening the enclosure 684.

FIG. 26B is a top view of an example data processing system 690b in which a data processing chip 691b is mounted near optical/electrical communication interfaces 692a, 692b, 692c (collectively referenced as 692) to enable high bandwidth data paths (e.g., one, ten, or more Gigabits per second per data path) between the data processing chip 691b and each of the optical/electrical communication interfaces 692. The data processing chip 691 is mounted on a first side of a circuit board 693b that functions as a front panel of an enclosure 694b of the system 690b. In this example, the optical/electrical communication interface 692a is mounted on the first side of the circuit board 693b and the optical/electrical communication interfaces 692b and 692c are mounted on a second side of the circuit board 693b, in which the second side faces the exterior of the enclosure 694b. In this example, the optical/electrical communication interfaces 692b and 692c are mounted on an exterior side of the enclosure 694b, allowing connection to optical fiber from the front of the enclosure 694b while the optical/electrical communication interface 692a is located internal to the enclosure 694b, for example, to allow connection to optical fiber at the rear of the enclosure 694b. In some examples, two or more of the optical/electrical communication interfaces 692 can be located internal to the enclosure 694b and connect to optical fibers at the rear of the enclosure 694b.

The enclosure 694b has side panels 695b and 696b, a rear panel 697b, a top panel, and a bottom panel. In some examples, the circuit board 693b is perpendicular to the bottom panel. In some examples, the circuit board 693b is oriented at an angle in a range −60° to 60° (or −30° to 30°, or −10° to 10°, or −1° to 1°) relative to a vertical direction of the bottom panel.

Each of the optical/electrical communication interfaces 692 is electrically coupled to the data processing chip 691b by electrical connectors or traces 698b that pass through the circuit board 693b in the thickness direction. For example, the electrical connectors or traces 698b can be configured as vias of the circuit board 693b. In this example, the electrical connectors or traces 698b extend to both sides of the circuit board 693b (e.g., for connecting to optical/electrical communication interfaces 692 located internal to and external of the enclosure 694b). The signal paths between the data processing chip 691b and each of the optical/electrical communication interfaces 692 can be unidirectional or bidirectional, similar to those of the systems 630, 650 and 680.

For example, the system 690b can be configured such that signals are transmitted unidirectionally between the data processing chip 691b and one of the optical/electrical communication interfaces 692, and bidirectionally between the data processing chip 691b and another one of the optical/electrical communication interfaces 692. For example, the system 690b can be configured such that signals are transmitted unidirectionally from the optical/electrical communication interface 692a to the data processing chip 691b, and unidirectionally from the data processing chip 691b to the optical/electrical communication interface 692b and/or optical/electrical communication interface 692c.

Optical connectors 699a, 699b, 699c (collectively referenced as 699) are provided to couple optical signals from the optical fibers to the optical/electrical communication interfaces 692a, 692b, 692c, respectively. The optical connectors 699 can be securely fixed, or releasably connected, to the optical/electrical communication interfaces 692, similar to those of the systems 630, 650, and 680. In this example, optical connector 699b and optical connector 699c can connect to optical fibers at the front of the enclosure 694b and the optical connector 699a can connect to optical fibers at the rear of the enclosure 694b. In the illustrated example, the optical connector 699a connects to an optical fiber at the rear of the enclosure 694b by being connected to a fiber 1000b that connects to a rear panel interface 1001b (e.g., a backplane, etc.) that is mounted to the rear panel 697b. In some examples, the optical connectors 699 can be securely or fixedly attached to communication interfaces 692. In some examples, the optical connectors 699 can be securely or fixedly attached to an array of optical fibers.

The optical/electrical communication interface 692 can be similar to, e.g., the integrated communication device 210 (FIG. 2), 252 (FIG. 4), 374 (FIG. 11), 382 (FIG. 12), 402 (FIG. 13), 428 (FIG. 14), and 512 (FIG. 32), except that the optical/electrical communication interfaces 692b and 692c are mounted on the side of the circuit board 693b opposite to the side of the data processing chip 691b. In some examples, the optical/electrical communication interface 692 can be similar to the integrated optical communication device 448, 462, 466, 472 (FIG. 17). The optical connector 699 can be similar to, e.g., the first optical connector part 213 (FIGS. 2, 4), the first optical connector 356 (FIGS. 11, 12), the first optical connector 404 (FIGS. 13, 14), the first optical connector part 456 (FIG. 17), and the first optical connector part 520 (FIG. 32). In some examples, the optical connector is not attached vertically to a photonic integrated circuit that is part of the optical/electrical communication interface 692 but rather can be attached in-plane to the photonic integrated circuit using, e.g., V-groove fiber attachments, tapered or un-tapered fiber edge coupling, etc., followed by a mechanism to direct the light interfacing to the photonic integrated circuit to a direction that is substantially perpendicular to the photonic integrated circuit, such as one or more substantially 90-degree turning mirrors, one or more substantially 90-degree bent optical fibers, etc. In some examples, a portion of the optical connector 699 can be part of the optical/electrical communication interface 692. In some examples, the optical connector 699 can also include the second optical connector part 223 (FIGS. 2, 4), 458 (FIG. 17) that is optically coupled to the optical fibers.

In some examples, the optical/electrical communication interfaces 692 are securely fixed (e.g., by soldering) to the circuit board 693b. In some examples, the optical/electrical communication interfaces 692 are removably connected to the circuit board 693b, e.g., by use of mechanical mechanisms such as one or more snap-on or screw-on mechanisms. An advantage of the system 690b is that in case of a malfunction at one of the optical/electrical communication interfaces 692, the faulty optical/electrical communication interface 692 can be replaced without opening the enclosure 694b.

FIG. 26C is a top view of an example data processing system 690c in which a data processing chip 691c is mounted near optical/electrical communication interfaces 692d, 692e, 692f (collectively referenced as 692) to enable high bandwidth data paths (e.g., one, ten, or more Gigabits per second per data path) between the data processing chip 691c and each of the optical/electrical communication interfaces 692. The data processing chip 691c is mounted on a first side of a circuit board 693c that functions as a front panel of an enclosure 694c of the system 690c. In this example, the optical/electrical communication interface 692d is mounted on the first side of the circuit board 693c and the optical/electrical communication interfaces 692e and 692f are mounted on a second side of the circuit board 693c, in which the second side faces the exterior of the enclosure 694c. In this example, the optical/electrical communication interfaces 692e and 692f are mounted on an exterior side of the enclosure 694c, allowing connection to optical fibers from the front of the enclosure 694c while the optical/electrical communication interface 692d is located internal to the enclosure 694c, for example, to allow connection to optical fiber at the rear of the enclosure 694c. In some examples, two or more of the optical/electrical communication interfaces 692 can be located internal to the enclosure 694c and connect to optical fibers at the rear of the enclosure 694c.

The enclosure 694c has side panels 695c and 696c, a rear panel 697c, a top panel, and a bottom panel. In some examples, the circuit board 693c is perpendicular to the bottom panel. In some examples, the circuit board 693c is oriented at an angle in a range −60° to 60° (or −30° to 30°, or −10° to 10°, or −1° to 1°) relative to a vertical direction of the bottom panel.

Each of the optical/electrical communication interfaces 692 is electrically coupled to the data processing chip 691c by electrical connectors or traces 698c that pass through the circuit board 693c in the thickness direction. For example, the electrical connectors or traces 698c can be configured as vias of the circuit board 693c. In this example, the electrical connectors or traces 698c extend to both sides of the circuit board 693b (e.g., for connecting to optical/electrical communication interfaces 692 located internal to and external of the enclosure 694b. The signal paths between the data processing chip 691c and each of the optical/electrical communication interfaces 692 can be unidirectional or bidirectional, similar to those of the systems 630, 650 and 680.

For example, the system 690c can be configured such that signals are transmitted unidirectionally between the data processing chip 691c and one of the optical/electrical communication interfaces 692, and bidirectionally between the data processing chip 691c and another one of the optical/electrical communication interfaces 692. For example, the system 690c can be configured such that signals are transmitted unidirectionally from the optical/electrical communication interface 692d to the data processing chip 691c, and unidirectionally from the data processing chip 691c to the optical/electrical communication interface 692e and/or optical/electrical communication interface 692f.

Optical connectors 699d, 699e, 699f (collectively referenced as 699) are provided to couple optical signals from the optical fibers to the optical/electrical communication interfaces 692d, 692e, 692f, respectively. The optical connectors 699 can be securely fixed, or releasably connected, to the optical/electrical communication interfaces 692, similar to those of the systems 630, 650, and 680. In the illustrated example, the optical/electrical communication interfaces 692d and optical connector 699d are oriented differently compared to the optical/electrical communication interfaces 692a and optical connector 699a of FIG. 26B. Here the orientation change is a counter clockwise rotation of 90 degrees. Other types of orientation changes (e.g., rotations, pitches, tipping, etc.) may be implemented. Position changes (e.g., translations) and other types of location changes may also be employed. In this example, optical connector 699e and optical connector 699f can connect to optical fibers at the front of the enclosure 694c and the optical connector 699d can connect to optical fibers the rear of the enclosure 694c. In the illustrated example, the optical connector 699d connects to an optical fiber at the rear of the enclosure 694c by being connected to a fiber 1000c that connects to a rear panel interface 1001c (e.g., a backplane, etc.) that is mounted to the rear panel 697c.

The optical/electrical communication interface 692 can be similar to, e.g., the integrated communication device 210 (FIG. 2), 252 (FIG. 4), 374 (FIG. 11), 382 (FIG. 12), 402 (FIG. 13), 428 (FIG. 14), and 512 (FIG. 32), except that the optical/electrical communication interface 692e and 692f are mounted on the side of the circuit board 693c opposite to the side of the data processing chip 691c. In some examples, the optical/electrical communication interface 692 can be similar to the integrated optical communication device 448, 462, 466, 472 (FIG. 17). The optical connector 699 can be similar to, e.g., the first optical connector part 213 (FIGS. 2, 4), the first optical connector 356 (FIGS. 11, 12), the first optical connector 404 (FIGS. 13, 14), the first optical connector part 456 (FIG. 17), and the first optical connector part 520 (FIG. 32). In some examples, the optical connector is not attached vertically to a photonic integrated circuit that is part of the optical/electrical communication interface 692 but rather can be attached in-plane to the photonic integrated circuit using, e.g., V-groove fiber attachments, tapered or un-tapered fiber edge coupling, etc., followed by a mechanism to direct the light interfacing to the photonic integrated circuit to a direction that is substantially perpendicular to the photonic integrated circuit, such as one or more substantially 90-degree turning mirrors, one or more substantially 90-degree bent optical fibers, etc. In some examples, a portion of the optical connector 699 can be part of the optical/electrical communication interface 692. In some examples, the optical connector 699 can also include the second optical connector part 223 (FIGS. 2, 4), 458 (FIG. 17) that is optically coupled to the optical fibers.

In some examples, the optical/electrical communication interfaces 692 are securely fixed (e.g., by soldering) to the circuit board 693c. In some examples, the optical/electrical communication interfaces 692 are removably connected to the circuit board 693c, e.g., by use of mechanical mechanisms such as one or more snap-on or screw-on mechanisms. An advantage of the system 690c is that in case of a malfunction at one of the optical/electrical communication interfaces 692, the faulty optical/electrical communication interface 692 can be replaced without opening the enclosure 694c.

FIG. 27 is a top view of an example data processing system 700 in which a data processing chip 702 is mounted near optical/electrical communication interfaces 704a, 704b, 704c (collectively referenced as 704) to enable high bandwidth data paths (e.g., one, ten, or more Gigabits per second per data path) between the data processing chip 702 and each of the optical/electrical communication interfaces 704. The data processing chip 702 is mounted on a first side of a circuit board 706 that is positioned near a front panel of an enclosure 710 of the system 700, similar to the configuration of the system 650 (FIG. 25). In some examples, the data processing chip 702 is mounted on a substrate (e.g., a ceramic or high-density build-up substrate), and the substrate is attached to the circuit board 706. The optical/electrical communication interfaces 704 are mounted on a second side of the circuit board 708. In this example, the optical/electrical communication interfaces 704 pass through openings in the front panel 708, allowing optical fibers to be easily coupled to the optical/electrical communication interfaces 704.

The enclosure 710 has side panels 712 and 714, a rear panel 716, a top panel, and a bottom panel. In some examples, the circuit board 706 and the front panel 708 are oriented at an angle in a range −60° to 60° relative to a vertical direction of the bottom panel. In some examples, the circuit board 706 is substantially parallel to the front panel 708, e.g., the angle between the surface of the circuit board 706 and the surface of the front panel 708 can be in a range of −5° to 5°. In some examples, the circuit board 706 is at an angle relative to the front panel 708, in which the angle is in a range of −45° to 45°.

For example, the angle can refer to a rotation around an axis that is parallel to the larger dimension of the front panel (e.g., the width dimension in a typical 1U, 2U, or 4U rackmount device), or a rotation around an axis that is parallel to the shorter dimension of the front panel (e.g., the height dimension in the 1U, 2U, or 4U rackmount device). The angle can also refer to a rotation around an axis along any other direction. For example, the circuit board 706 is positioned relative to the front panel such that components such as the interconnection modules, including optical modules or photonic integrated circuits, mounted on or attached to the circuit board 706 can be accessed through the front side, either through one or more openings in the front panel, or by opening the front panel to expose the components, without the need to separate the top or side panels from the bottom panel. Such orientation of the circuit board (or a substrate on which a data processing module is mounted) relative to the front panel also applies to the examples shown in FIGS. 21 to 26, 28B to 29B, 69A, 70, 71A, 72, 72A, 74A, 75A, 75C, 76, 77A, 77B, 78, 96 to 98, 100, 110, 12, 113, 115, 117 to 122, 125A to 127, 129, 136 to 149, 159, and 160.

Each of the optical/electrical communication interfaces 704 is electrically coupled to the data processing chip 702 by electrical connectors or traces 718 that pass through the circuit board 706 in the thickness direction, similar to those of the system 680 (FIG. 26). The signal paths between the data processing chip 702 and each of the optical/electrical communication interfaces 704 can be unidirectional or bidirectional, similar to those of the system 630 (FIG. 24), 650 (FIG. 25), and 680 (FIG. 26).

Optical connectors 716a, 716b, 716c (collectively referenced as 716) are provided to couple optical signals from the optical fibers to the optical/electrical communication interfaces 704a, 704b, 704c, respectively. The optical connectors 716 can be securely fixed, or releasably connected, to the optical/electrical communication interfaces 704, similar to those of the systems 630, 650, and 680.

The optical/electrical communication interface 704 can be similar to, e.g., the integrated communication device 210 (FIG. 2), 252 (FIG. 4), 374 (FIG. 11), 382 (FIG. 12), 402 (FIG. 13), 428 (FIG. 14), and 512 (FIG. 32), except that the optical/electrical communication interface 704 is mounted on the side of the circuit board 706 opposite to the side of the data processing chip 702. In some examples, the optical/electrical communication interface 704 can be similar to the integrated optical communication device 448, 462, 466, 472 (FIG. 17). The optical connector 716 can be similar to, e.g., the first optical connector part 213 (FIGS. 2, 4), the first optical connector 356 (FIGS. 11, 12), the first optical connector 404 (FIGS. 13, 14), the first optical connector part 456 (FIG. 17), and the first optical connector part 520 (FIG. 32). In some examples, the optical connector is not attached vertically to a photonic integrated circuit that is part of the optical/electrical communication interface 704 but rather can be attached in-plane to the photonic integrated circuit using, e.g., V-groove fiber attachments, tapered or un-tapered fiber edge coupling, etc., followed by a mechanism to direct the light interfacing to the photonic integrated circuit to a direction that is substantially perpendicular to the photonic integrated circuit, such as one or more substantially 90-degree turning mirrors, one or more substantially 90-degree bent optical fibers, etc. In some examples, a portion of the optical connector 716 can be part of the optical/electrical communication interface 704. In some examples, the optical connector 716 can also include the second optical connector part 223 (FIGS. 2, 4), 458 (FIG. 17) that is optically coupled to the optical fibers.

In some examples, the optical/electrical communication interfaces 704 are securely fixed (e.g., by soldering) to the circuit board 706. In some examples, the optical/electrical communication interfaces 704 are removably connected to the circuit board 706, e.g., by use of mechanical mechanisms such as one or more snap-on or screw-on mechanisms. An advantage of the system 700 is that in case of a malfunction at one of the optical/electrical communication interfaces 704, the faulty optical/electrical communication interface 704 can unplugged or decoupled from the circuit board 706 and replaced without opening the enclosure 710.

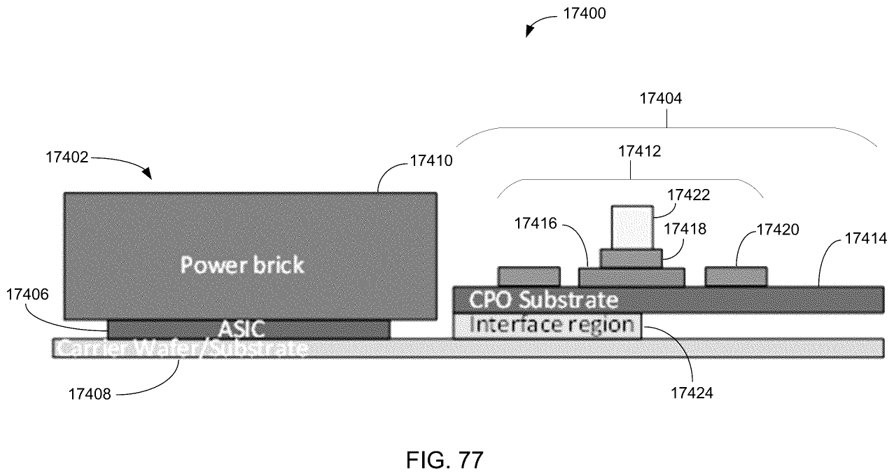

In some implementations, the optical/electrical communication interfaces 704 do not protrude through openings in the front panel 708. For example, each optical/electrical communication interface 704 can be at a distance behind the front panel 708, and a fiber patchcord or pigtail can connect the optical/electrical communication interface 704 to an optical connector on the front panel 708, similar to the examples shown in FIGS. 77A, 77B, 78, 125A, 125B, 129, and 159. In some examples, the front panel 708 is configured to be removable or to be able to open to allow servicing of communication interface 704, similar to the examples shown in FIGS. 77A, 125A, and 159.

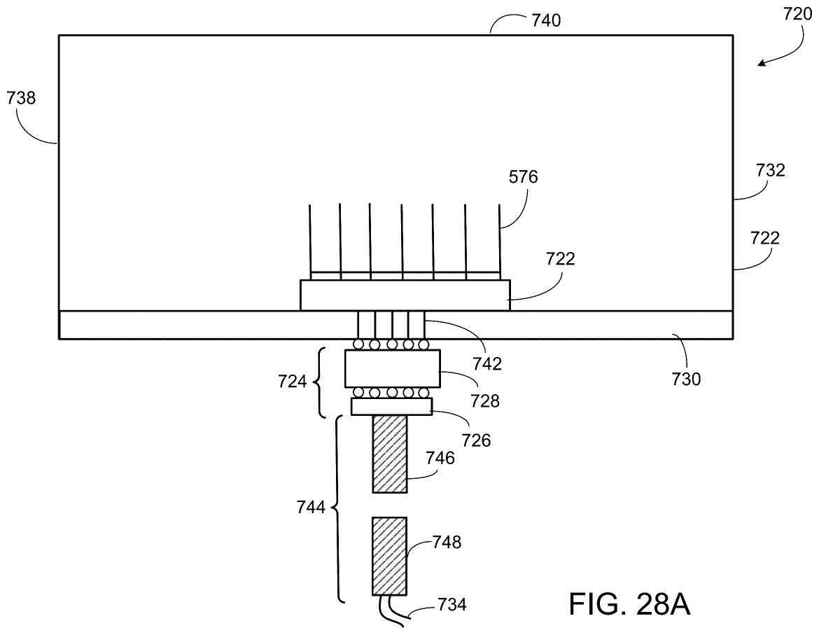

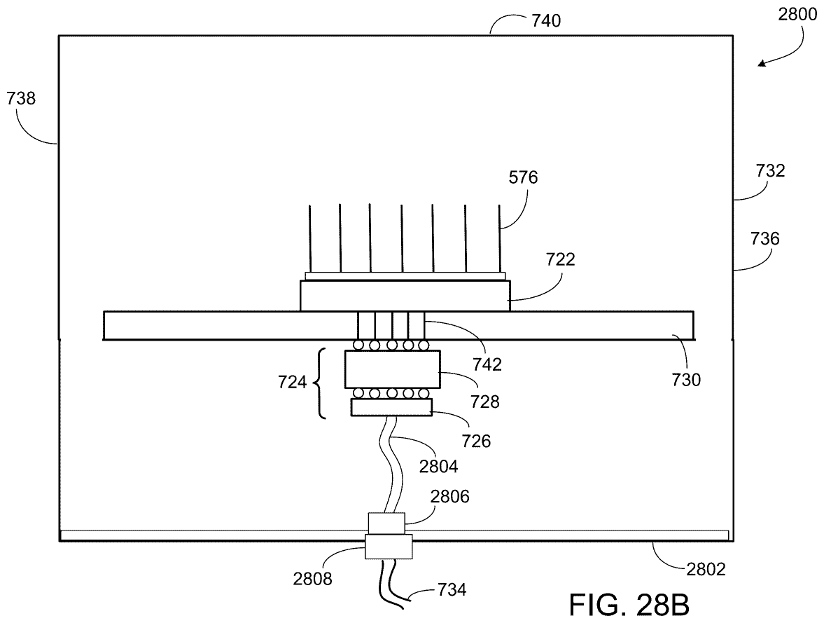

FIG. 28A is a top view of an example data processing system 720 in which a data processing chip 722 is mounted near an optical/electrical communication interface 724 to enable high bandwidth data paths (e.g., one, ten, or more Gigabits per second per data path) between the data processing chip 720 and the optical/electrical communication interface 724. The data processing chip 722 is mounted on a first side of a circuit board 730 that functions as a front panel of an enclosure 732 of the system 720. In some examples, the data processing chip 722 is mounted on a substrate (e.g., a ceramic or high-density build-up substrate), and the substrate is attached to the circuit board 730. The optical/electrical communication interface 724 is mounted on a second side of the circuit board 730, in which the second side faces the exterior of the enclosure 732. In this example, the optical/electrical communication interface 724 is mounted on an exterior side of the enclosure 732, allowing optical fibers 734 to be easily coupled to the optical/electrical communication interface 724.

The enclosure 732 has side panels 736 and 738, a rear panel 740, a top panel, and a bottom panel. In some examples, the circuit board 730 is perpendicular to the bottom panel. In some examples, the circuit board 730 is oriented at an angle in a range −60° to 60° relative to a vertical direction of the bottom panel.

The optical/electrical communication interface 724 includes a photonic integrated circuit 726 mounted on a substrate 728 that is electrically coupled to the circuit board 730. The optical//electrical communication interface 724 is electrically coupled to the data processing chip 722 by electrical connectors or traces 742 that pass through the circuit board 730 in the thickness direction. For example, the electrical connectors or traces 742 can be configured as vias of the circuit board 730. The signal paths between the data processing chip 722 and the optical/electrical communication interface 724 can be unidirectional or bidirectional, similar to those of the systems 630, 650, 680, and 700.

An optical connector 744 is provided to couple optical signals from the optical fibers 734 to the optical/electrical communication interface 724. The optical connector 744 can be securely fixed, or removably connected, to the optical/electrical communication interface 744, similar to those of the systems 630, 650, 680, and 700.

In some implementations, the optical/electrical communication interface 724 can be similar to, e.g., the integrated communication device 448, 462, 466, and 472 of FIG. 17. The optical signals from the optical fibers are processed by the photonic integrated circuit 726, which generates serial electrical signals based on the optical signals. For example, the serial electrical signals are amplified by a set of transimpedance amplifiers and drivers (which can be part of the photonic integrated circuit 726 or a serializers/deserializers module in the data processing chip 722), which drives the output signals that are transmitted to the serializers/deserializers module embedded in the data processing chip 722.

The optical connector 744 includes a first optical connector 746 and a second optical connector 748, in which the second optical connector 748 is optically coupled to the optical fibers 734. The first optical connector 746 can be similar to, e.g., the first optical connector part 213 (FIGS. 2, 4), the first optical connector 356 (FIGS. 11, 12), the first optical connector 404 (FIGS. 13, 14), the first optical connector part 456 (FIG. 17), and the first optical connector part 520 (FIG. 32). The second optical connector 748 can be similar to the second optical connector part 223 (FIGS. 2, 4) and 458 (FIG. 17). In some examples, the optical connectors 746 and 748 can form a single piece such that the optical/electrical communication interface 724 is securely or fixedly attached to a fiber bundle. In some examples, the optical connector is not attached vertically to the photonic integrated circuit 726 but rather can be attached in-plane to the photonic integrated circuit using, e.g., V-groove fiber attachments, tapered or un-tapered fiber edge coupling, etc., followed by a mechanism to direct the light interfacing to the photonic integrated circuit to a direction that is substantially perpendicular to the photonic integrated circuit, such as one or more substantially 90-degree turning mirrors, one or more substantially 90-degree bent optical fibers, etc.

In some examples, the optical/electrical communication interface 724 is securely fixed (e.g., by soldering) to the circuit board 730. In some examples, the optical/electrical communication interface 724 is removably connected to the circuit board 730, e.g., by use of mechanical mechanisms such as one or more snap-on or screw-on mechanisms. An advantage of the system 720 is that in case of a malfunction of the optical/electrical communication interface 724, the faulty optical/electrical communication interface 724 can be replaced without opening the enclosure 732.

FIG. 28B is a top view of an example data processing system 2800 that is similar to the system 720 of FIG. 28A, except that the circuit board 730 that is recessed from a front panel 2802 of an enclosure 732 of the system 2800. The photonic integrated circuit 726 is optically coupled through a fiber patchcord or pigtail 2804 to a first optical connector 2806 attached to the inner side of the front panel 2802. The first optical connector 2806 is optically coupled to a second optical connector 2808 attached to the outer side of the front panel 2802. The second optical connector 2808 is optically coupled to the exterior optical fibers 734.

The technique of using a fiber patchcord or pigtail to optically couple the photonic integrated circuit to the optical connector attached to the inner side of the front panel can also be applied to the data processing system 700 of FIG. 27. For example, the modified system can have a recessed substrate or circuit board, multiple co-packaged optical modules (e.g., 704) mounted on the opposite side of the data processing chip 702 relative to the substrate or circuit board, and fiber jumpers (e.g., 2804) optically coupling the co-packaged optical modules to the front panel.

In the examples of FIGS. 28A and 28B, the data processing chip 722 can be mounted on a substrate that is electrically coupled to the circuit board 730, similar to the example shown in FIG. 150.

In each of the examples in FIGS. 24, 25, 26, 27, and 28, the optical/electrical communication interface 644, 652, 684, 704, and 724 can be electrically coupled to the circuit board 642, 654, 686, 706, and 730, respectively, using electrical contacts that include one or more of spring-loaded elements, compression interposers, and/or land-grid arrays.

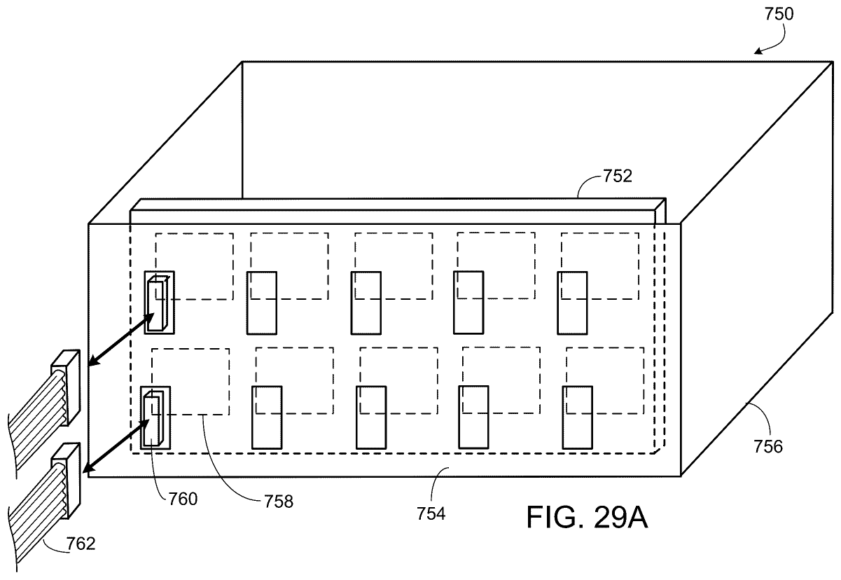

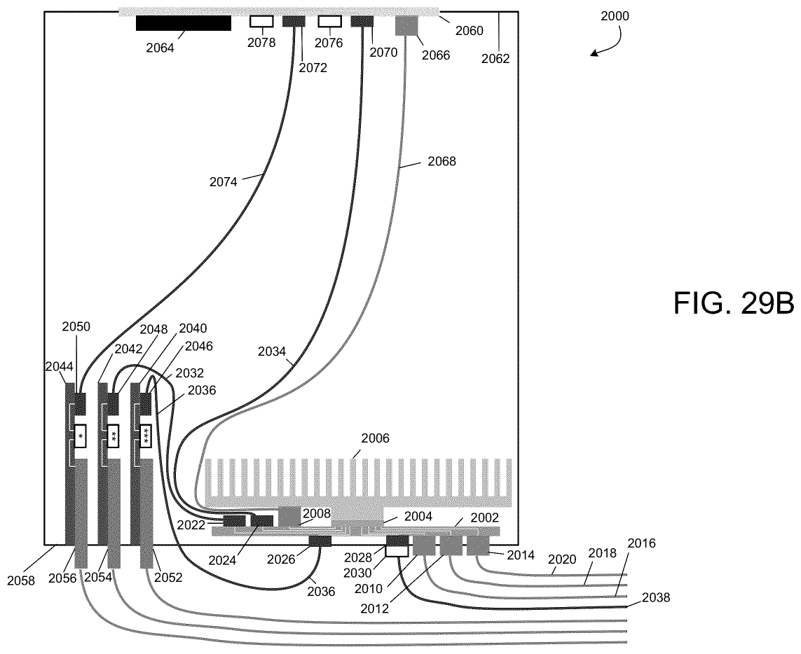

FIG. 29A is a diagram of an example data processing system 750 that includes a vertically mounted circuit board 752 that enables high bandwidth data paths (e.g., one, ten, or more Gigabits per second per data path) between data processing chips 758 and optical/electrical communication interfaces 760. The data processing chips 758 and the optical/electrical communication interfaces 760 are mounted on the circuit board 752, in which each data processing chip 758 is electrically coupled to a corresponding optical/electrical communication interface 760. The data processing chips 758 are electrically coupled to one another by electrical connectors (e.g., electrical signal lines on one or more layers of the circuit board 752).

The data processing chips 758 can be similar to, e.g., the electronic processor integrated circuit, data processing chip, or host application specific integrated circuit 240 (FIGS. 2, 4, 6, 7, 11, 12), digital application specific integrated circuit 444 (FIG. 17), data processor 502 (FIG. 20), data processing chip 572 (FIGS. 22, 23), 640 (FIG. 24), 670 (FIG. 25), 681 (FIG. 26), 702 (FIG. 27), and 722 (FIG. 28). Each of the data processing chips 758 can be, e.g., a network switch, a central processor unit, a graphics processor unit, a tensor processing unit, a neural network processor, an artificial intelligence accelerator, a digital signal processor, a microcontroller, or an application specific integrated circuit (ASIC).

Although the figure shows that the optical/electrical communication interfaces 760 are mounted on the side of the circuit board 752 facing the front panel 754, the optical/electrical communication interfaces 760 can also be mounted on the side of the circuit board 752 facing the interior of the enclosure 756. The optical/electrical communication interfaces 760 can be similar to, e.g., the integrated communication devices 210 (FIGS. 2, 3, 10), 252 (FIGS. 4, 5), 262 (FIG. 6), the integrated optical communication devices 282 (FIGS. 7-9), 374 (FIG. 11), 382 (FIG. 12), 390 (FIG. 13), 428 (FIG. 14), 402 (FIGS. 15, 16), 448, 462, 466, 472 (FIG. 17), the integrated communication devices 574 (FIG. 22), 612 (FIG. 23), and the optical/electrical communication interfaces 644 (FIG. 24), 652 (FIG. 25), 684 (FIG. 26), 704 (FIG. 27).

The circuit board 752 is positioned near a front panel 754 of an enclosure 756, and optical signals are coupled to the optical/electrical communication interfaces 760 through optical paths that pass through openings in the front panel 754. This allows users to conveniently removably connect optical fiber cables 762 to the input/output interfaces 760. The position and orientation of the circuit board 752 relative to the enclosure 756 can be similar to, e.g., those of the circuit board 654 (FIG. 25) and 706 (FIG. 27).

In some implementations, the data processing system 750 can include multiple types of optical/electrical communication interfaces 760. For example, some of the optical/electrical communication interfaces 760 can be mounted on the same side of the circuit board 752 as the corresponding data processing chip 758, and some of the optical/electrical communication interfaces 760 can be mounted on the opposite side of the circuit board 752 as the corresponding data processing chip 758. Some of the optical/electrical communication interfaces 760 can include first and second serializers/deserializers modules, and the corresponding data processing chips 758 can include third serializers/deserializers modules, similar to the examples in FIGS. 2-8, 11-14, 20, 22, and 23. Some of the optical/electrical communication interfaces 760 can include no serializers/deserializers module, and the corresponding data processing chips 758 can include serializers/deserializers modules, similar to the example of FIG. 17. Some of the optical/electrical communication interfaces 760 can include sets of transimpedance amplifiers and drivers, either embedded in the photonic integrated circuits or in separate chips external to the photonic integrated circuits. Some of the optical/electrical communication interfaces 760 do not include transimpedance amplifiers and drivers, in which sets of transimpedance amplifiers and drivers are included in the corresponding data processing chips 758. The data processing system 750 can also include electrical communication interfaces that interface to electrical cables, such as high speed PCIe cables, Ethernet cables, or Thunderbolt™ cables. The electrical communication interfaces can include modules that perform various functions, such as translation of communication protocols and/or conditioning of signals.

Other types of connections may be present and associated with circuit board 752 and other boards included in the enclosure 756. For example, two or more circuit boards (e.g., vertically mounted circuit boards) can be connected which may or may not include the circuit board 752. For instances in which circuit board 752 is connected to at least one other circuit board (e.g., vertically mounted in the enclosure 756), one or more connection techniques can be employed. For example, an optical/electrical communication interface (e.g., similar to optical/electrical communication interfaces 760) can be used to connect data processing chips 758 to other circuit boards. Interfaces for such connections can be located on the same side of the circuit board 752 that the processing chips 758 are mounted. In some implementations, interfaces can be located on another portion of the circuit board (e.g., a side that is opposite from the side that the processing chips 758 are mounted). Connections can utilize other portions of the circuit board 752 and/or one or more other circuit boards present in the enclosure 756. For example an interface can be located on an edge of one or more of the boards (e.g., an upper edge of a vertically mounted circuit board) and the interface can connect with one or more other interfaces (e.g., the optical/electrical communication interfaces 760, another edge mounted interface, etc.). Through such connections, two or more circuit boards can connect, receive and send signals, etc.

In the example shown in FIG. 29A, the circuit board 752 is placed near the front panel 754. In some examples, the circuit board 752 can also function as the front panel, similar to the examples in FIGS. 22-24, 26, and 28.

FIG. 29B is a diagram of an example data processing system 2000 that illustrates some of the configurations described with respect to FIGS. 26A to 26C and FIG. 29A along with other capabilities. The system 2000 includes a vertically mounted printed circuit board 2002 (or, e.g., a substrate) upon which is mounted a data processing chip 2004 (e.g., an ASIC), and a heat sink 2006 is thermally coupled to the data processing chip 2004. Optical/electrical communication interfaces are mounted on both sides of the printed circuit board 2002. In particular, optical/electrical communication interface 2008 is mounted on the same side of the printed circuit board 2002 as the data processing chip 2004. In this example, optical/electrical communication interfaces 2010, 2012, and 2014 are mounted on an opposite side of the printed circuit board 2002. To send and receive signals (e.g., with other optical/electrical communication interfaces), each of the optical/electrical communication interfaces 2010, 2012, and 2014 connects to optical fibers 2016, 2018, 2020, respectively. Electrical connection sockets/connectors can also be mounted to one or more sides of the printed circuit board 2002 for sending and receiving electrical signals, for example. In this example, two electrical connection sockets/connectors 2022 and 2024 are mounted to the side of the printed circuit board 2002 that the data processing chip 2004 is mounted and two electrical connection sockets/connectors 2026 and 2028 are mounted to the opposite side of the printed circuit board 2002. In this example, electrical connection sockets/connector 2028 is connected (or includes) a timing module 2030 that provides various functionality (e.g., regenerate data, retime data, maintain signal integrity, etc.). To send and receive electrical signals, each of the electrical connection sockets/connectors 2022-2028 are connected to electrical connection cables 2032, 2034, 2036, 2038, respectively. One or more types of connection cables can be implemented, for example, fly-over cables can be employed for connecting to one or more of the electrical connection sockets/connectors 2022-2028.

In this example, the system 2000 includes vertically mounted line cards 2040, 2042, 2044. In this particular example, line card 2040 includes an electrical connection sockets/connector 2046 that is connected to electrical cable 2036, and line card 2042 includes an electrical connection sockets/connector 2048 that is connected to electrical cable 2032. Line card 2044 includes an electrical connection sockets/connector 2050. Each of the line cards 2040, 2042, 2044 include pluggable optical modules 2052, 2054, 2056 that can implement various interface techniques (e.g., QSFP, QSFP-DD, XFP, SFP, CFP).

In this particular example, the printed circuit board 2002 is approximate to a forward panel 2058 of the system 2000; however, the printed circuit board 2002 can be positioned in other locations within the system 2000. Multiple printed circuit boards can also be included in the system 2000. For example, a second printed circuit board 2060 (e.g., a backplane) is included in the system 2000 and is located approximate to a back panel 2062. By locating the printed circuit board 2060 towards the rear, signals (e.g., data signals) can be sent to and received from other systems (e.g., another switch box) located, for example, in the same switch rack or other location as the system 2000. In this example, a data processing chip 2064 is mounted to the printed circuit board 2060 that can perform various operations (e.g., data processing, prepare data for transmission, etc.). Similar to the printed circuit board 2002 located forward in the system 2000, the printed circuit board 2060 includes an optical/electrical communication interface 2066 that communicates with the optical/electrical communication interface 2008 (located on the same side on printed circuit board 2002 as data processing chip 2004) using optical fibers 2068. The printed circuit board 2060 includes electrical connection sockets/connectors 2070 that uses the electrical connection cable 2034 to send electrical signals to and receive electrical signals from the electrical connection sockets/connectors 2024. The printed circuit board 2060 can also communicate with other components of the system 2000, for example, one or more of the line cards. As illustrated in the figure, electrical connection sockets/connectors 2072 located on the printed circuit board 2060 uses the electrical connection cable 2074 to send electrical signals to and/or receive electrical signals from the electrical connection sockets/connector 2050 of the line card 2044. Similar to the printed circuit board 2002, other portions of the system 2000 can include timing modules. For example, the line cards 2040, 2042, and 2044 can include timing modules (respectively identified with symbol “*”, “**”, and “***”). Similarly, the second circuit board 2060 can include timing modules such as timing modules 2076 and 2078 for regenerating data, re-timing data, maintaining signal integrity, etc.

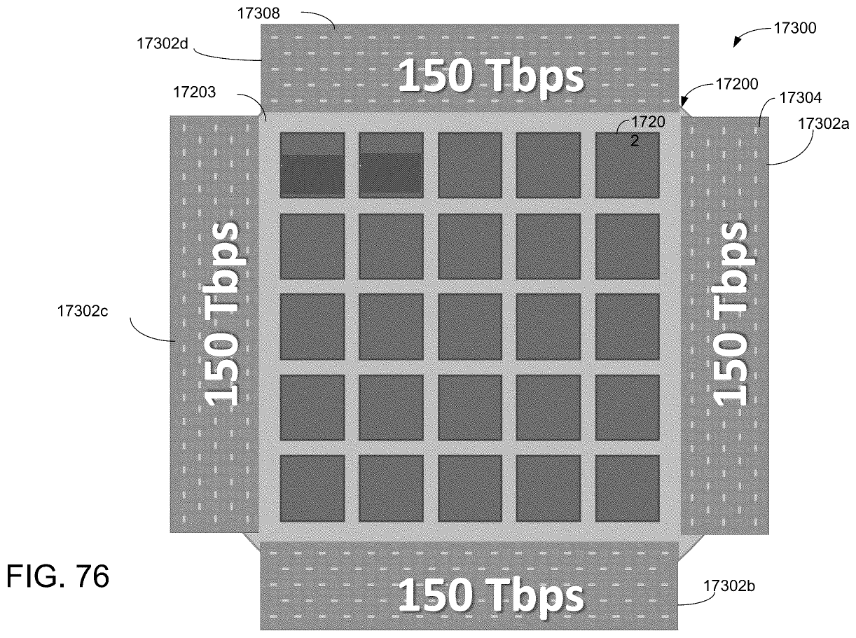

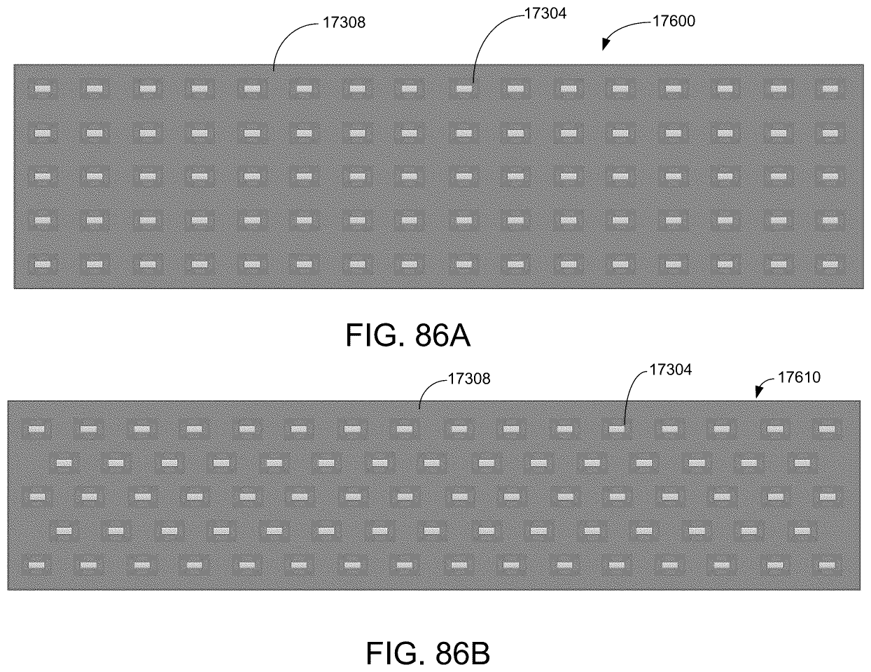

A feature of some of the systems described in this document is that the main data processing module(s) of a system, such as switch chip(s) in a switch server, and the communication interface modules that support the main data processing module(s), are configured to allow convenient access by users. In the examples shown in FIGS. 21 to 29B, 69A, 70, 71A 72, 72A, 74A, 75A, 75C, 76, 77A, 77B, 78, 96 to 98, 100, 110, 112, 113, 115, 117 to 122, 125A to 127, 129, 136 to 149, 159, and 160, the main data processing module and the communication interface modules are positioned near the front panel, the rear panel, or both, and allow easy access by the user through the front/rear panel. However, it is also possible to position the main data processing module and the communication interface modules near one or more side panels, the top panel, the bottom panel, or two or more of the above, depending on how the system is placed in the environment. In a system that includes multiple racks of rackmount devices (see e.g., FIGS. 76 and 86), the communication interfaces (e.g., co-packaged optical modules) in each rackmount device can be conveniently accessed without the need to remove the rackmount device from the rack and opening up the housing in order to expose the inner components.

In some implementations, for a single rack of rackmount servers where there is open space at the front, rear, left, and right side of the rack, in each rackmount server, it is possible to place a first main data processing module and the communication interface modules supporting the first main data processing module near the front panel, place a second main data processing module and the communication interface modules supporting the second main data processing module near the left panel, place a third main data processing module and the communication interface modules supporting the third main data processing module near the right panel, and place a fourth main data processing module and the communication interface modules supporting the fourth main data processing module near the rear panel. The thermal solutions, including the placement of fans and heat dissipating devices, and the configuration of airflows around the main data processing modules and the communication interface modules, are adjusted accordingly.

For example, if a data processing server is mounted to the ceiling of a room or a vehicle, the main data processing module and the communication interface modules can be positioned near the bottom panel for easy access. For example, if a data processing server is mounted beneath the floor panel of a room or a vehicle, the main data processing module and the communication interface modules can be positioned near the top panel for easy access. The housing of the data processing system does not have to be in a box shape. For example, the housing can have curved walls, be shaped like a globe, or have an arbitrary three-dimensional shape.

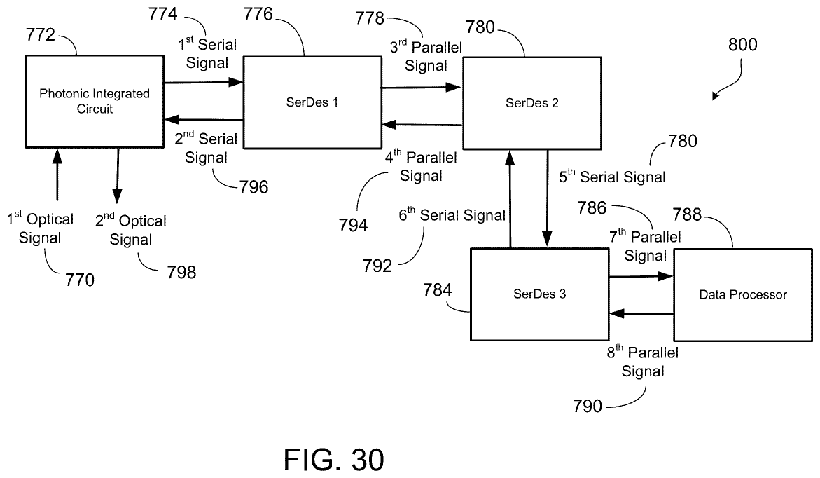

FIG. 30 is a diagram of an example high bandwidth data processing system 800 that can be similar to, e.g., systems 200 (FIGS. 2, 20), 250 (FIG. 4), 260 (FIG. 6), 280 (FIG. 7), 350 (FIG. 11), 380 (FIG. 12), 390 (FIG. 13), 420 (FIG. 14), 560 (FIG. 22), 600 (FIG. 23), 630 (FIG. 24), and 650 (FIG. 25) described above. A first optical signal 770 is transmitted from an optical fiber to a photonic integrated circuit 772, which generates a first serial electrical signal 774 based on the first optical signal. The first serial electrical signal 774 is provided to a first serializers/deserializers module 776, which converts the first serial electrical signal 774 to a third set of parallel signals 778. The first serializers/deserializers module 776 conditions the serial electrical signal upon conversion into the parallel electrical signals, in which the signal conditioning can include, e.g., one or more of clock and data recovery, and signal equalization. The third set of parallel signals 778 is provided to a second serializers/deserializers module 780, which generates a fifth serial electrical signal 782 based on the third set of parallel signals 778. The fifth serial electrical signal 782 is provided to a third serializers/deserializers module 784, which generates a seventh set of parallel signals 786 that is provided to a data processor 788.

In some implementations, the photonic integrated circuit 772, the first serializers/deserializers module 776, and the second serializers/deserializers module 780 can be mounted on a substrate of an integrated communication device, an optical/electrical communication interface, or an input/output interface module. The first serializers/deserializers module 776 and the second serializers/deserializers module 780 can be implemented in a single chip. In some implementations, the third serializers/deserializers module 784 can be embedded in the data processor 788, or the third serializers/deserializers module 784 can be separate from the data processor 788.

The data processor 788 generates an eighth set of parallel signals 790 that is sent to the third serializers/deserializers module 784, which generates a sixth serial electrical signal 792 based on the eighth set of parallel signals 790. The sixth serial electrical signal 792 is provided to the second serializers/deserializers module 780, which generates a fourth set of parallel signals 794 based on the sixth serial electrical signal 792. The second serializers/deserializers module 780 can condition the serial electrical signal 792 upon conversion into the fourth set of parallel electrical signals 794. The fourth set of parallel signals 794 is provided to the first serializers/deserializers module 780, which generates a second serial electrical signal 796 based on the fourth set of parallel signals 794 that is sent to the photonic integrated circuit 772. The photonic integrated circuit 772 generates a second optical signal 798 based on the second serial electrical signal 796, and sends the second optical signal 798 to an optical fiber. The first and second optical signals 770, 798 can travel on the same optical fiber or on different optical fibers.

A feature of the system 800 is that the electrical signal paths traveled by the first, fifth, sixth, and second serial electrical signals 774, 782, 792, 796 are short (e.g., less than 5 inches), to allow the first, fifth, sixth, and second serial electrical signals 782, 792 to have a high data rate (e.g., up to 50 Gbps).

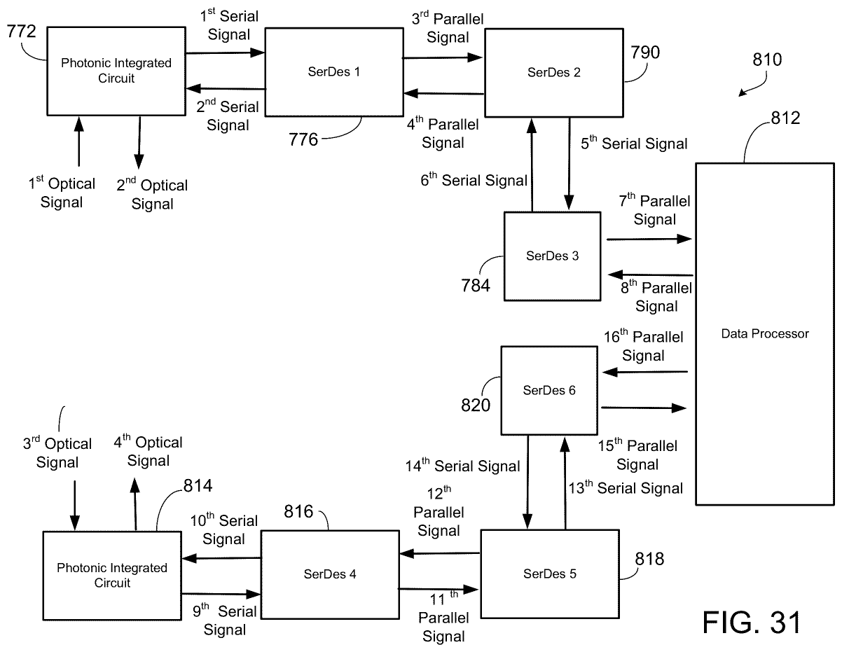

FIG. 31 is a diagram of an example high bandwidth data processing system 810 that can be similar to, e.g., systems 680 (FIG. 26), 700 (FIG. 27), and 750 (FIG. 29) described above. The system 810 includes a data processor 812 that receives and sends signals from and to multiple photonic integrated circuits. The system 810 includes a second photonic integrated circuit 814, a fourth serializers/deserializers module 816, a fifth serializers/deserializers module 818, and a sixth serializers/deserializers module 820. The operations of the second photonic integrated circuit 814, a fourth serializers/deserializers module 816, a fifth serializers/deserializers module 818, and a sixth serializers/deserializers module 820 can be similar to those of the first photonic integrated circuit 772, the first serializers/deserializers module 776, the second serializers/deserializers module 780, and the third serializers/deserializers module 784. The third serializers/deserializers module 784 and the sixth serializers/deserializers module 820 can be embedded in the data processor 812, or be implemented in separate chips.

In some examples, the data processor 812 processes first data carried in the first optical signal received at the first photonic integrated circuit 772, and generates second data that is carried in the fourth optical signal output from the second photonic integrated circuit 814.

The examples in FIGS. 30 and 31 include three serializers/deserializers modules between the photonic integrated circuit and the data processor, it is understood that the same principles can be applied to systems that has only one serializers/deserializers module between the photonic integrated circuit and the data processor.

In some implementations, signals are transmitted unidirectionally from the photonic integrated circuit 772 to the data processor 788 (FIG. 30). In that case, the first serializers/deserializers module 776 can be replaced with a serial-to-parallel converter, the second serializers/deserializers module 780 can be replaced with a parallel-to-serial converter, and the third serializers/deserializers module 784 can be replaced with a serial-to-parallel converter. In some implementations, signals are transmitted unidirectionally from the data processor 812 (FIG. 31) to the second photonic integrated circuit 814. In that case, the sixth serializers/deserializers module 820 can be replaced with a parallel-to-serial converter, the fifth serializers/deserializers module 818 can be replaced with a serial-to-parallel converter, and the fourth serializers/deserializers module 816 can be replaced with a parallel-to-serial converter.

It should be appreciated by those of ordinary skill in the art that the various embodiments described herein in the context of coupling light from one or more optical fibers, e.g., 226 (FIGS. 2 and 4) or 272 (FIGS. 6 and 7) to the photonic integrated circuit, e.g., 214 (FIGS. 2 and 4), 264 (FIG. 6), or 296 (FIG. 7) will be equally operable to couple light from the photonic integrated circuit to one or more optical fibers. This reversibility of the coupling direction is a general feature of at least some embodiments described herein, including some of those using polarization diversity.

The example optical systems disclosed herein should only be viewed as some of many possible embodiments that can be used to perform polarization demultiplexing and independent array pattern scaling, array geometry re-arrangement, spot size scaling, and angle-of-incidence adaptation using diffractive, refractive, reflective, and polarization-dependent optical elements, 3D waveguides and 3D printed optical components. Other implementations achieving the same set of functionalities are also covered by the spirit of this disclosure.

For example, the optical fibers can be coupled to the edges of the photonic integrated circuits, e.g., using fiber edge couplers. The signal conditioning (e.g., clock and data recovery, signal equalization, or coding) can be performed on the serial signals, the parallel signals, or both. The signal conditioning can also be performed during the transition from serial to parallel signals.

In some implementations, the data processing systems described above can be used in, e.g., data center switching systems, supercomputers, internet protocol (IP) routers, Ethernet switching systems, graphics processing work stations, and systems that apply artificial intelligence algorithms.

In the examples described above in which the figures show a first serializers/deserializers module (e.g., 216) placed adjacent to a second serializers/deserializers module (e.g., 217), it is understood that a bus processing unit 218 can be positioned between the first and second serializers/deserializers modules and perform, e.g., switching, re-routing, and/or coding functions described above.

In some implementations, the data processing systems described above includes multiple data generators that generate large amounts of data that are sent through optical fibers to the data processors for processing. For example, an autonomous driving vehicle (e.g., car, truck, train, boat, ship, submarine, helicopter, drone, airplane, space rover, or space ship) or a robot (e.g., an industrial robot, a helper robot, a medical surgery robot, a merchandise delivery robot, a teaching robot, a cleaning robot, a cooking robot, a construction robot, an entertainment robot) can include multiple high resolution cameras and other sensors (e.g., LIDARs (Light Detection and Ranging), radars) that generate video and other data that have a high data rate. The cameras and/or sensors can send the video data and/or sensor data to one or more data processing modules through optical fibers. The one or more data processing modules can apply artificial intelligence technology (e.g., using one or more neural networks) to recognize individual objects, collections of objects, scenes, individual sounds, collections of sounds, and/or situations in the environment of the vehicle and quickly determine appropriate actions for controlling the vehicle or robot.

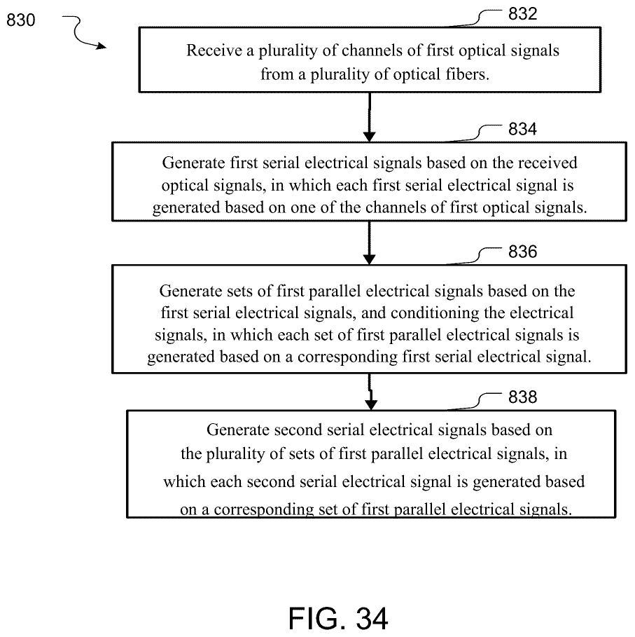

FIG. 34 is a flow diagram of an example process for processing high bandwidth data. A process 830 includes receiving 832 a plurality of channels of first optical signals from a plurality of optical fibers. The process 830 includes generating 834 a plurality of first serial electrical signals based on the received optical signals, in which each first serial electrical signal is generated based on one of the channels of first optical signals. The process 830 includes generating 836 a plurality of sets of first parallel electrical signals based on the plurality of first serial electrical signals, and conditioning the electrical signals, in which each set of first parallel electrical signals is generated based on a corresponding first serial electrical signal. The process 830 includes generating 838 a plurality of second serial electrical signals based on the plurality of sets of first parallel electrical signals, in which each second serial electrical signal is generated based on a corresponding set of first parallel electrical signals.

In some implementations, a data center includes multiple systems, in which each system incorporates the techniques disclosed in FIGS. 22 to 29 and the corresponding description. Each system includes a vertically mounted printed circuit board, e.g., 570 (FIG. 22), 610 (FIG. 23), 642 (FIG. 24), 654 (FIG. 25), 686 (FIG. 26), 706 (FIG. 27), 730 (FIG. 28), 752 (FIG. 29) that functions as the front panel of the housing or is substantially parallel to the front panel. At least one data processing chip and at least one integrated communication device or optical/electrical communication interface are mounted on the printed circuit board. The integrated communication device or optical/electrical communication interface can incorporate techniques disclosed in FIGS. 2-22 and 30-34 and the corresponding description. Each integrated communication device or optical/electrical communication interface includes a photonic integrated circuit that receives optical signals and generates electrical signals based on the optical signals. The optical signals are provided to the photonic integrated circuit through one or more optical paths (or spatial paths) that are provided by, e.g., cores of the fiber-optic cables, which can incorporate techniques described in U.S. patent Ser. No. 11/194,109. A large number of parallel optical paths (or spatial paths) can be arranged in two-dimensional arrays using connector structures, which can incorporate techniques described in U.S. patent Ser. No. 11/287,585.

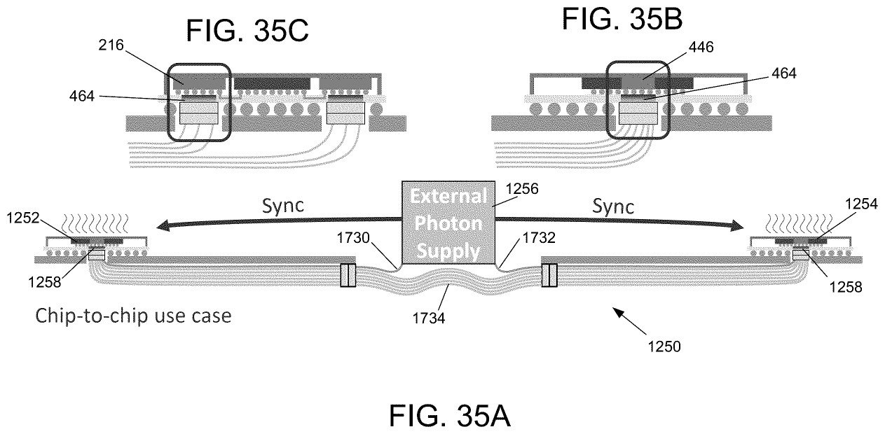

FIG. 35A shows an optical communications system 1250 providing high-speed communications between a first chip 1252 and a second chip 1254 using co-packaged optical (CPO) interconnect modules 1258 similar to those shown in, e.g., FIGS. 2-5 and 17. Each of the first and second chips 1252, 1254 can be a high-capacity chip, e.g., a high bandwidth Ethernet switch chip. The first and second chips 1252, 1254 communicate with each other through an optical fiber interconnection cable 1734 that includes a plurality of optical fibers. In some implementations, the optical fiber interconnection cable 1734 can include optical fiber cores that transmit data and control signals between the first and second chips 802, 804. The optical fiber interconnection cable 1734 also includes one or more optical fiber cores that transmit optical power supply light from an optical power supply or photon supply to photonic integrated circuits that provide optoelectronic interfaces for the first and second chips 1252, 1254. The optical fiber interconnection cable 1734 can include single-core fibers or multi-core fibers. Each single-core fiber includes a cladding and a core, typically made from glasses of different refractive indices such that the refractive index of the cladding is lower than the refractive index of the core to establish a dielectric optical waveguide. Each multi-core optical fiber includes a cladding and multiple cores, typically made from glasses of different refractive indices such that the refractive index of the cladding is lower than the refractive index of the core. More complex refractive index profiles, such as index trenches, multi-index profiles, or gradually changing refractive index profiles can also be used. More complex geometric structures such as non-circular cores or claddings, photonic crystal structures, photonic bandgap structures, or nested antiresonant nodeless hollow core structures can also be used.

The example of FIG. 35A illustrates a switch-to-switch use case. An external optical power supply or photon supply 1256 provides optical power supply signals, which can be, e.g., continuous-wave light, one or more trains of periodic optical pulses, or one or more trains of non-periodic optical pulses. The power supply light is provided from the photon supply 1256 to the co-packaged optical interconnect modules 1258 through optical fibers 1730 and 1732, respectively. For example, the optical power supply 1256 can provide continuous wave light, or both pulsed light for data modulation and synchronization, as described in U.S. patent Ser. No. 11/153,670. This allows the first chip 1252 to be synchronized with the second chip 1254.

For example, the photon supply 1256 can correspond to the optical power supply 103 of FIG. 1. The pulsed light from the photon supply 1256 can be provided to the link 102_6 of the data processing system 200 of FIG. 20. In some implementations, the photon supply 1256 can provide a sequence of optical frame templates, in which each of the optical frame templates includes a respective frame header and a respective frame body, and the frame body includes a respective optical pulse train. The modulators 417 can load data into the respective frame bodies to convert the sequence of optical frame templates into a corresponding sequence of loaded optical frames that are output through optical fiber link 102_1.

The implementation shown in FIG. 35A uses a packaging solution corresponding to FIG. 35B, whereby in contrast to FIG. 17 substrates 454 and 460 are not used and the photonic integrated circuit 464 is directly attached to the serializers/deserializers module 446. FIG. 35C shows an implementation similar to FIG. 5, in which the photonic integrated circuit 464 is directly attached to the serializers/deserializers 216.

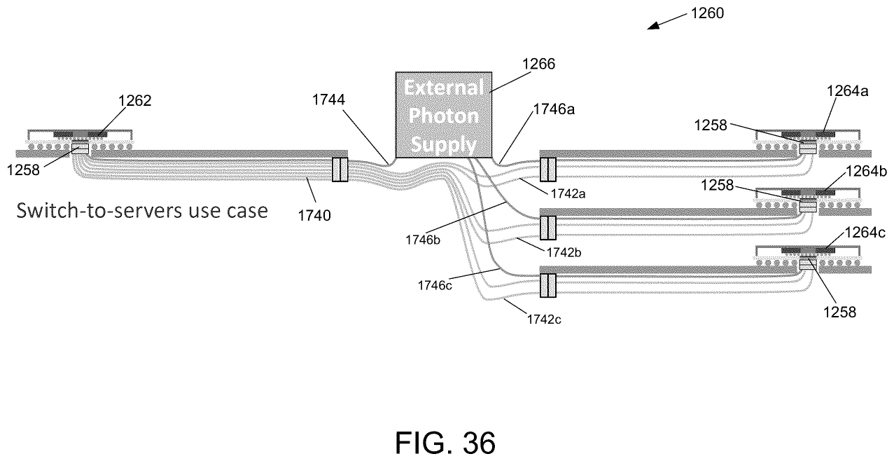

FIG. 36 shows an example of an optical communications system 1260 providing high-speed communications between a high-capacity chip 1262 (e.g., an Ethernet switch chip) and multiple lower-capacity chips 1264a, 1264b, 1264c, e.g., multiple network interface cards (NICs) attached to computer servers) using co-packaged optical interconnect modules 1258 similar to those shown in FIG. 35A. The high-capacity chip 1262 communicates with the lower-capacity chips 1264a, 1264b, 1264c through a high-capacity optical fiber interconnection cable 1740 that later branches out into several lower-capacity optical fiber interconnection cables 1742a, 1742b, 1742c that are connected to the lower-capacity chips 1264a, 1264b, 1264c, respectively. This example illustrates a switch-to-servers use case.

An external optical power supply or photon supply 1266 provides optical power supply signals, which can be continuous-wave light, one or more trains of periodic optical pulses, or one or more trains of non-periodic optical pulses. The power supply light is provided from the photon supply 1266 to the optical interconnect modules 1258 through optical fibers 1744, 1746a, 1746b, 1746c, respectively. For example, the optical power supply 1266 can provide both pulsed light for data modulation and synchronization, as described in U.S. patent Ser. No. 11/153,670. This allows the high-capacity chip 1262 to be synchronized with the lower-capacity chips 1264a, 1264b, and 1264c.

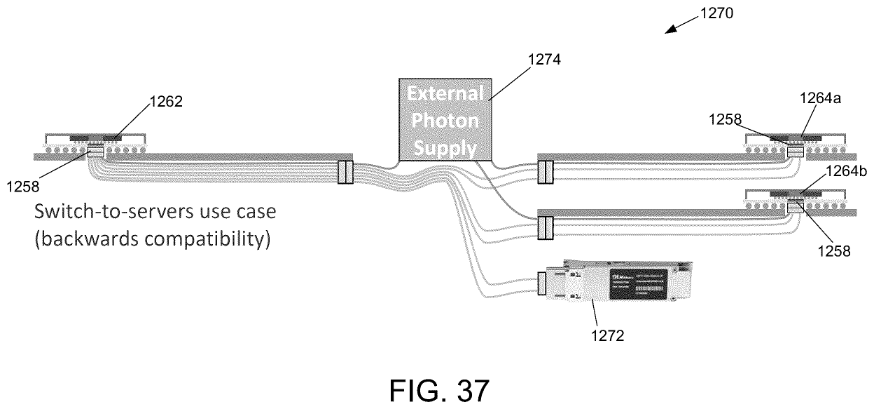

FIG. 37 shows an optical communications system 1270 providing high-speed communications between a high-capacity chip 1262 (e.g., an Ethernet switch chip) and multiple lower-capacity chips (1264a, 1264b, e.g., multiple network interface cards (NICs) attached to computer servers) using a mix of co-packaged optical interconnect modules 1258 similar to those shown in FIG. 35 as well as conventional pluggable optical interconnect modules 1272.

An external optical power supply or photon supply 1274 provides optical power supply signals, which can be continuous-wave light, one or more trains of periodic optical pulses, or one or more trains of non-periodic optical pulses. For example, the optical power supply 1274 can provide both pulsed light for data modulation and synchronization, as described in U.S. patent Ser. No. 11/153,670. This allows the high-capacity chip 1262 to be synchronized with the lower-capacity chips 1264a and 1264b.

Some aspects of the systems 1250, 1260, and 1270 are described in more detail in connection with FIGS. 79 to 84B.

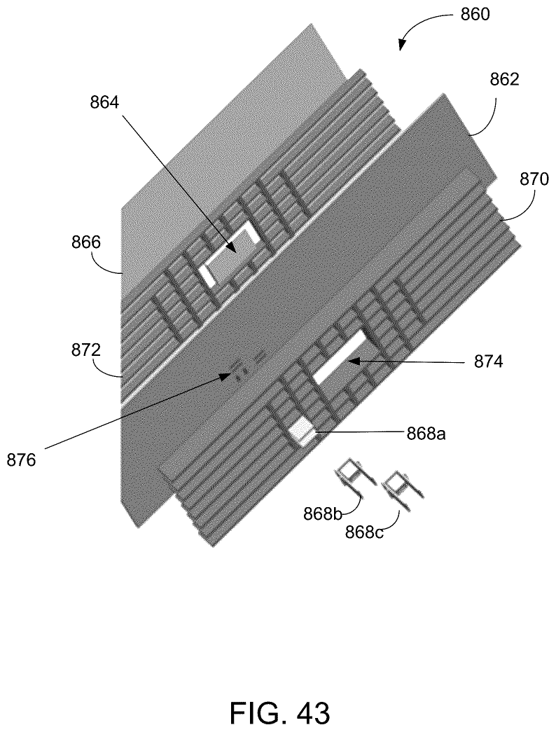

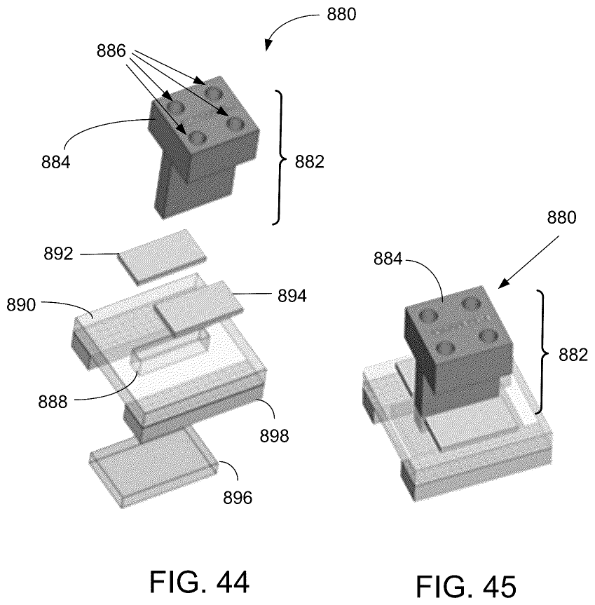

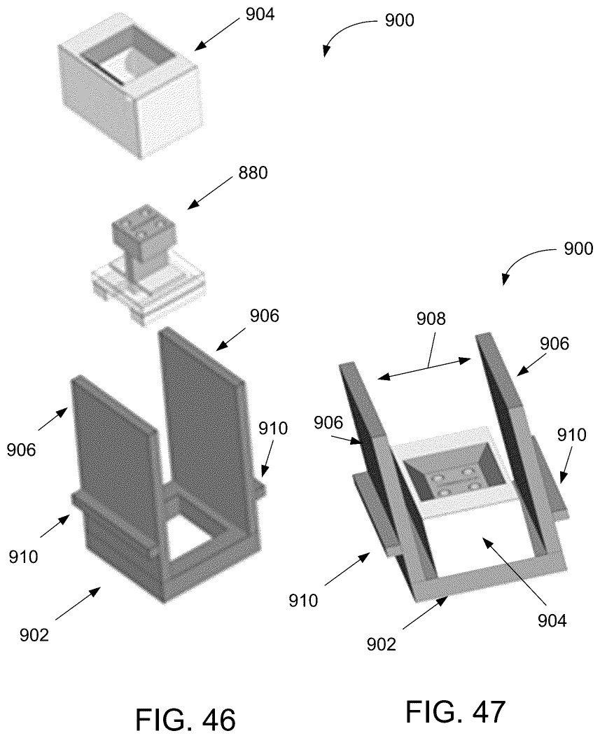

FIG. 43 shows an exploded view of an example of a front-mounted module 860 of a data processing system that includes a vertically mounted printed circuit board 862 (or substrate made of, e.g., organic or ceramic high-density build-up material), a host application specific integrated circuit 864 mounted on the back-side of the circuit board 862, and a heat sink 866. In some examples, the host application specific integrated circuit 864 is mounted on a substrate (e.g., a ceramic or high-density build-up substrate), and the substrate is attached to the circuit board 862. The front-mounted module 860 can be, e.g., the front panel of the housing of the data processing system, similar to the configuration shown in FIGS. 26A, 28A or positioned near the front panel of the housing, similar to the configuration shown in FIGS. 27, 28B. Three optical modules with connectors, e.g., 868a, 868b, 868c, collectively referenced as 868, are shown in the figure. Additional optical modules with connectors can be used. The data processing system can be similar to, e.g., the data processing system 680 (FIG. 26A) or 700 (FIG. 27). The printed circuit board 862 can be similar to, e.g., the printed circuit board 683 (FIG. 26) or 708 (FIG. 27). The application specific integrated circuit 864 can be similar to, e.g., the application specific integrated circuit 681 (FIG. 26) or 702 (FIG. 27). The heat sink 866 can be similar to, e.g., the heat sink 576 (FIG. 23). The optical modules with connectors 868 each include an optical module 880 (see FIGS. 44, 45) and a mechanical connector structure 900 (see FIGS. 46, 47). The optical module 880 can be similar to, e.g., the optical/electrical communication interfaces 682 (FIG. 26) or 704 (FIG. 27), or the integrated optical communication device 512 of FIG. 32.

The optical module with connector 868 can be inserted into a first grid structure 870, which can function as both (i) a heat spreader/heat sink and (ii) a mechanical holding fixture for the optical modules with connectors 868. The first grid structure 870 includes an array of receptors, and each receptor can receive an optical module with connector 868. When assembled, the first grid structure 870 is connected to the printed circuit board 862. The first grid structure 870 can be firmly held in place relative to the printed circuit board 862 by sandwiching the printed circuit board 862 in between the first grid structure 870 and a second structure 872 (e.g., a second grid structure) located on the opposite side of the printed circuit board 862 and connected to the first grid structure 870 through the printed circuit board 862, e.g., by use of screws. Thermal vias between the first grid structure 870 and the second structure 872 can conduct heat from the front-side of the printed circuit board 862 to the heat sink 866 on the back-side of the printed circuit board 862. Additional heat sinks can also be mounted directly onto the first grid structure 870 to provide cooling in the front.

The printed circuit board 862 includes electrical contacts 876 configured to electrically connect to the removable optical module with connectors 868 after the removable optical module with connectors 868 are inserted into the first grid structure 870. The first grid structure 870 can include an opening 874 at the location in which the host application specific integrated circuit 864 is mounted on the other side of the printed circuit board 862 to allow for components such as voltage regulators, filters, and/or decoupling capacitors to be mounted on the printed circuit board 862 in immediate lateral vicinity to the host application specific integrated circuit 864.

In some examples, the host application specific integrated circuit 864 is mounted on a substrate (e.g., a ceramic or high-density build-up substrate), and the substrate is attached to the circuit board 862, similar to the examples shown in FIGS. 136 to 159. The substrate can be similar to the substrate 13602 of FIGS. 136 to 159, the second grid structure 872 can be similar to the rear lattice structure 13626, the circuit board 862 can be similar to the printed circuit board 13604, the host application specific integrated circuit 864 can be similar to the data processing chip 12312, and the heat sink 866 can be similar to the heat dissipating device 13610. The first grid structure 870 can have an overall shape similar to the front lattice structure 13606 of FIGS. 136 to 159, except that the first grid structure 870 includes mechanisms for coupling to the removable optical module with connectors 868.

FIGS. 44 and 45 show an exploded view and an assembled view, respectively, of an example optical module 880, which can be similar to the integrated optical communication device 512 of FIG. 32. The optical module 880 includes an optical connector part 882 (which can be similar to the first optical connector 520 of FIG. 32) that can either directly or through an (e.g., geometrically wider) upper connector part 884 receive light from fibers embedded in a second optical connector part (not shown in FIGS. 44, 45), which can be similar to, e.g., the optical connector part 268 of FIGS. 6 and 7). In the example shown in FIGS. 44, 45, a matrix of fibers, e.g., 2×18 fibers, can be optically coupled to the optical connector part 882. The matrix of fibers can have other configurations, such as a 3×12, 1×12, 3×12, 6×12, 12×12, 16×16, or 32×32 array of fibers. For example, the optical connector part 882 can have a configuration similar to the fiber coupling region 430 of FIG. 15 that is configured to couple 2×18 fibers, or any other number of fibers. The upper connector part 884 can also include alignment structures 886 (e.g., holes, grooves, posts) to receive corresponding mating structures of the second optical connector part.

The optical module 880 can have any of various configurations, including an optical module containing silicon photonics integrated optics, indium phosphide integrated optics, one or more vertical-cavity surface-emitting lasers (VCSEL)s, one or more direct-detection optical receivers, or one or more coherent optical receivers. The optical module 880 can include any of the optical modules, co-packaged optical modules, integrated optical communication devices (e.g., 448, 462, 466, or 472 of FIG. 17, or 210 of FIG. 20), integrated communication devices (e.g., 612 of FIG. 23), or optical/electrical communication interfaces (e.g., 684 of FIG. 26, 724 of FIG. 28, or 760 of FIG. 29) described in this specification and the documents incorporated by reference.

The optical connector part 882 is inserted through an opening 888 of a substrate 890 and optically coupled to a photonic integrated circuit 896 mounted on the underside of the substrate 890. The substrate 890 can be similar to the substrate 514 of FIG. 32, and the photonic integrated circuit 896 can be similar to the photonic integrated circuit 524. A first serializers/deserializers chip 892 and a second serializers/deserializers chip 894 are mounted on the substrate 890, in which the chip 892 is positioned on one side of the optical connector part 882, and the chip 894 is positioned on the other side of the optical connector part 882. The first serializers/deserializers chip 892 can include circuitry similar to, e.g., the third serializers/deserializers module 398 and the fourth serializers/deserializers module 400 of FIG. 32. The second serializers/deserializers chip 894 can include circuitry similar to, e.g., the first serializers/deserializers module 394 and the second serializers/deserializers module 396. A second slab 898 (which can be similar to the second slab 518 of FIG. 32) can be provided on the underside of the substrate 890 to provide a removable connection to a package substrate (e.g., 230).

FIGS. 46 and 47 show an exploded view and an assembled view, respectively, of a mechanical connector structure 900 built around the functional optical module 880 of FIGS. 44, 45. In this example embodiment, the mechanical connector structure 900 includes a lower mechanical part 902 and an upper mechanical part 904 that together receive the optical module 880. Both lower and upper mechanical connector parts 902, 904 can be made of a heat-conducting and rigid material, e.g., a metal.

In some implementations, the upper mechanical part 904, at its underside, is brought in thermal contact with the first serializers/deserializers chip 892 and the second serializers/deserializers chip 894. The upper mechanical part 904 is also brought in thermal contact with the lower mechanical part 902. The lower mechanical part 902 includes a removable latch mechanism, e.g., two wings 906 that can be elastically bent inwards (the movement of the wings 906 are represented by a double-arrow 908 in FIG. 47), and each wing 906 includes a tongue 910 on an outer side.

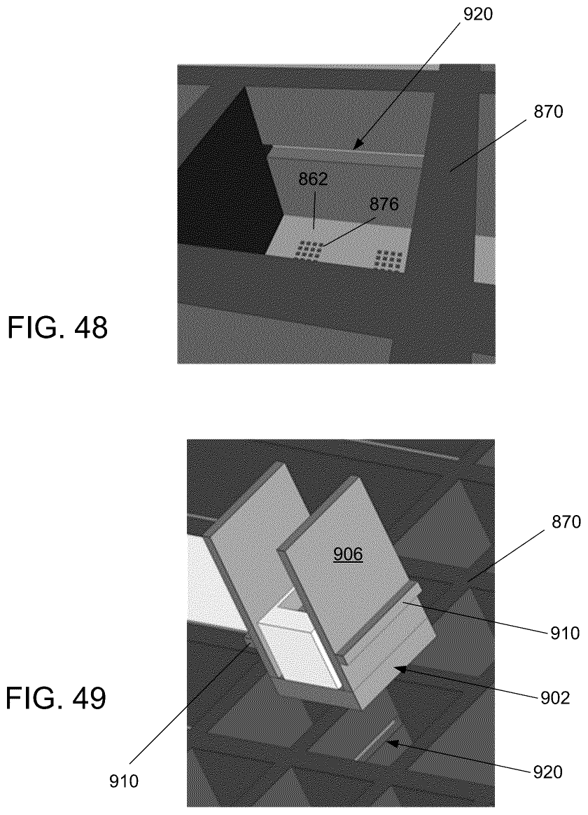

FIG. 48 is a diagram of a portion of the first grid structure 870 and the circuit board 862. In some examples, a substrate (e.g., a ceramic or high-density build-up substrate) can be used in place of the circuit board 862. Grooves 920 are provided on the walls of the first grid structure 870. As shown in the figure, the printed circuit board 862 (or substrate) has electrical contacts 876 that can be electrically coupled to electrical contacts on the second slab 898 of the optical module 880. For example, the electrical contacts 876 can include an array of electrical contacts that has at least four rows and four columns of electrical contacts. For example, the array of electrical contacts can have ten or more rows or columns of electrical contacts. The electrical contacts 876 can be arranged in any two-dimensional pattern and do not necessarily have to be arranged in rows and columns. The circuit board 862 (or substrate) can also have three-dimensional features, such as on protruding elements or recessed elements, and the electrical contacts can be provided on the three-dimensional features. The optical module with connectors 868 can have three-dimensional features with electrical contacts that mate with the corresponding three-dimensional features with electrical contacts on the circuit board 862 (or substrate).

Referring to FIG. 49, when the lower mechanical part 902 is inserted into the first grid structure 870, the tongues 910 (on the wings 906 of the lower mechanical part 902) can snap into corresponding grooves 920 within the first grid structure 870 to mechanically hold the optical module 880 in place. The position of the tongues 910 on the wings 906 is selected such that when the mechanical connector structure 900 and the optical module 880 are inserted into the first grid structure 870, the electrical connectors at the bottom of the second slab 898 are electrically coupled to the electrical contacts 876 on the printed circuit board 862 (or substrate). For example, the second slab 898 can include spring-loaded contacts that are mated with the contacts 876.

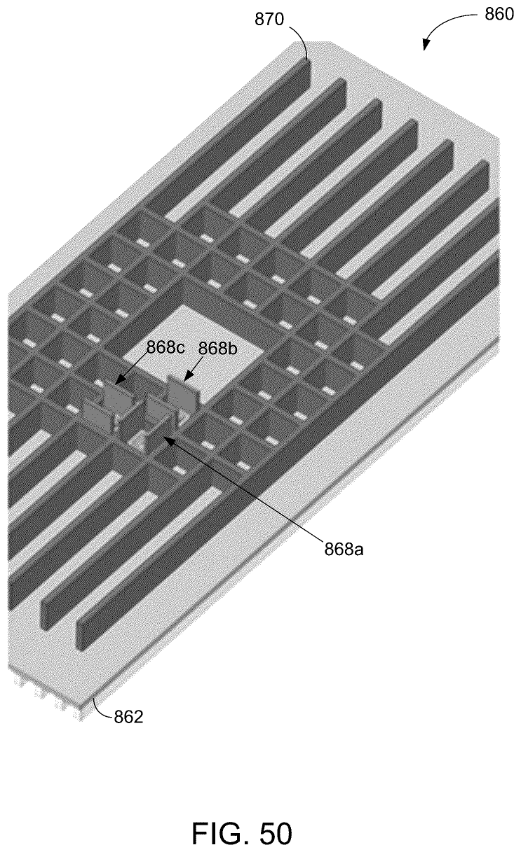

FIG. 50 shows the front-view of an assembled front module 860. Three optical module with connectors (e.g., 868a, 868b, 868c) are inserted into the first grid structure 870. In some embodiments, the optical modules 880 are arranged in a checkerboard pattern, whereby adjacent optical modules 880 and the corresponding mechanical connector structures 900 are rotated by 90 degrees such as to not allow any two wings to touch. This facilitates the removal of individual modules. In this example, the optical module with connector 868a is rotated 90 degrees relative to the optical module with connectors 868b, 868c.

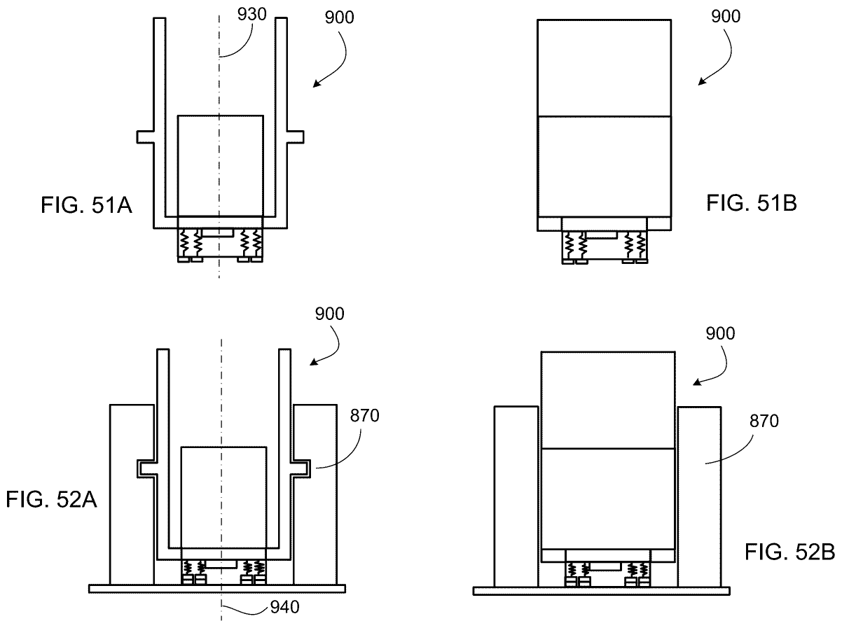

FIG. 51A shows a first side view of the mechanical connector structure 900. FIG. 51B shows a cross-sectional view of the mechanical connector structure 900 along a plane 930 shown in FIG. 51A. In some examples, the compression interposer (e.g., spring-loaded contacts) can be part of the receiving structure (e.g., mounted on the circuit board or substrate) as opposed to the removable module.

FIG. 52A shows a first side view of the mechanical connector structure 900 mounted within the first grid structure 870. FIG. 52B shows a cross-sectional view of the mechanical connector structure 900 mounted within the first grid structure 870 along a plane 940 shown in FIG. 52A.

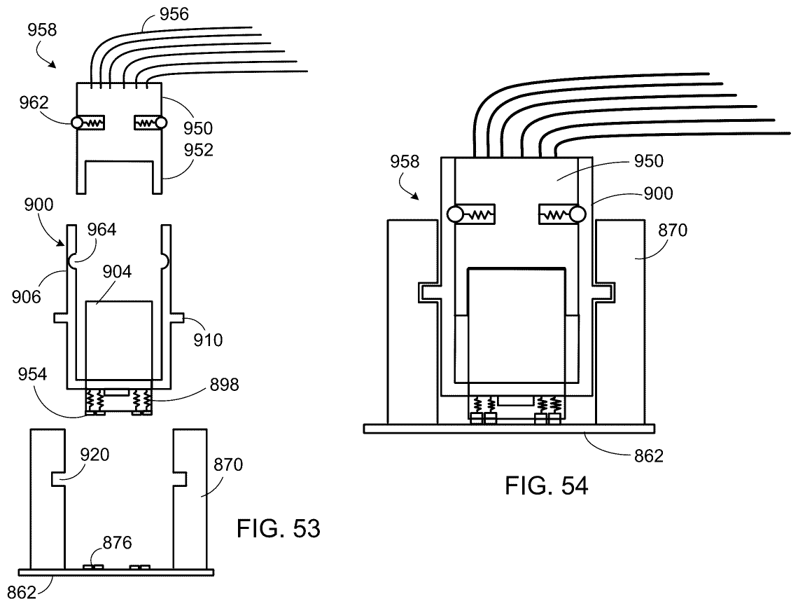

FIG. 53 is a diagram of an assembly 958 that includes a fiber cable 956 that includes a plurality of optical fibers, an optical fiber connector 950, the mechanical connector module 900, and the first grid structure 870. The optical fiber connector 950 can be inserted into the mechanical connector module 900, which can be further inserted into the first grid structure 870. The printed circuit board 862 (or substrate) is attached to the first grid structure 870, in which the electrical contacts 876 face electrical contacts 954 on the bottom side of the second slab 898 of the optical module 880.

FIG. 53 shows the individual components before they are connected. FIG. 54 is a diagram that shows the components after they are connected. The optical fiber connector 950 includes a lock mechanism 952 that disables the snap-in mechanism of the mechanical connector structure 900 so as to lock in place the mechanical connector structure 900 and the optical module 880. In this example embodiment, the lock mechanism 952 includes studs on the optical fiber connector 950 that insert between the wings 906 and the upper mechanical part 904 of the mechanical connector module 900, hence disabling the wings 906 from elastically bending inwards and consequentially locking the mechanical connector structure 900 and the optical module 880 in place. Further, the mechanical connector structure 900 includes a mechanism to hold the optical fiber connector 950 in place, such as a ball-detent mechanism as shown in the figure. When the optical fiber connector 950 is inserted into the mechanical connector structure 900, spring-loaded balls 962 on the optical fiber connector 950 engage detents 964 in the wings 906 of the mechanical connector structure 900. The springs push the balls 962 against the detents 964 and secure the optical fiber connector 950 in place.

To remove the optical module 880 from the first grid structure 870, the user can pull the optical fiber connector 950 and cause the balls 962 to disengage from the detents 964. The user can then bend the wings 906 inwards so that the tongues 910 disengage from the grooves 920 on the walls of the first grid structure 870.

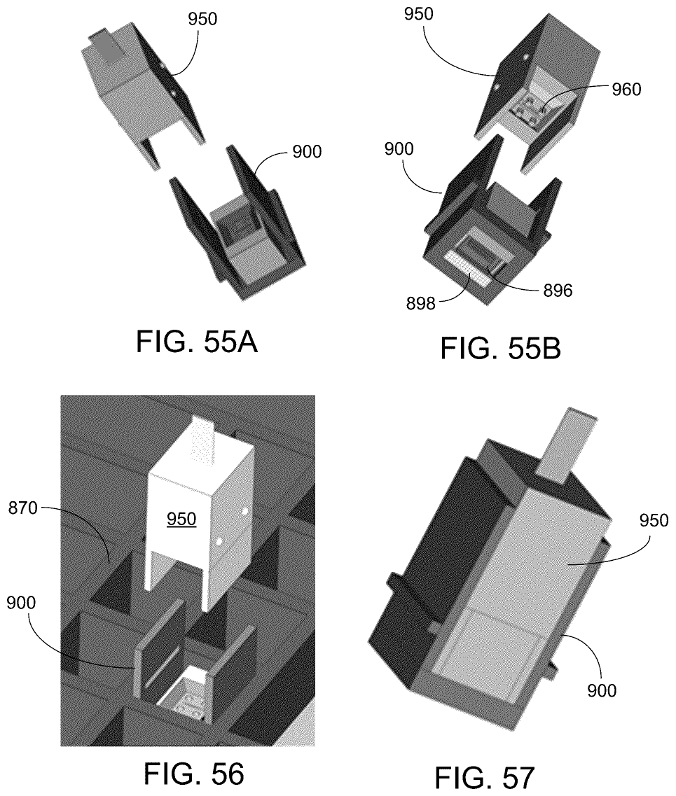

FIGS. 55A and 55B show perspective views of the mechanisms shown in FIGS. 53 and 54 before the optical fiber connector 950 is inserted into the mechanical connector structure 900. As shown in FIG. 55B, the lower side of the optical connector 950 includes alignment structures 960 that mate with the alignment structures 886 (FIG. 44) on the upper connector part 884 of the optical module 880. FIG. 55B also shows the photonic integrated circuit 896 and the second slab 898 that includes electrical contacts (e.g., spring-loaded electrical contacts).

FIG. 56 is a perspective view showing that the optical module 880 and the mechanical connector structure 900 are inserted into the first grid structure 870, and the optical fiber connector 950 is separated from the mechanical connector structure 900.

FIG. 57 is a perspective view showing that the optical fiber connector 950 is mated with the mechanical connector structure 900, locking the optical module 880 within the mechanical connector structure 900.

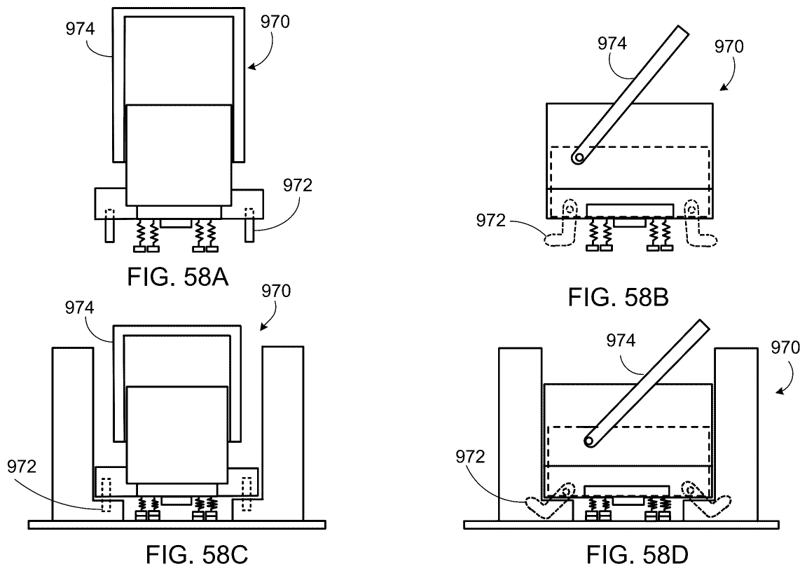

FIGS. 58A to 58D show an alternate embodiment in which an optical module with connector 970 includes a latch mechanism 972 that acts as a mechanical fastener that joins the optical module 880 to the printed circuit board 862 (or substrate) using the first grid structure 870 as a support. FIGS. 58A and 58B show various views of the optical module with connector 970 that includes the latch mechanism 972. FIGS. 58C and 58D show various views of the optical module with connector 970 coupled to the printed circuit board 862 (or substrate) and the first grid structure 870. For example, the user can easily attach or remove the optical module with connector 970 by pressing a lever 974 activating the latch mechanism 972. The lever 974 is built in a way that it does not block the optical fibers (not shown in the figure) coming out of the optical module with connector 970. Alternatively, an external tool can be used as a removable lever.

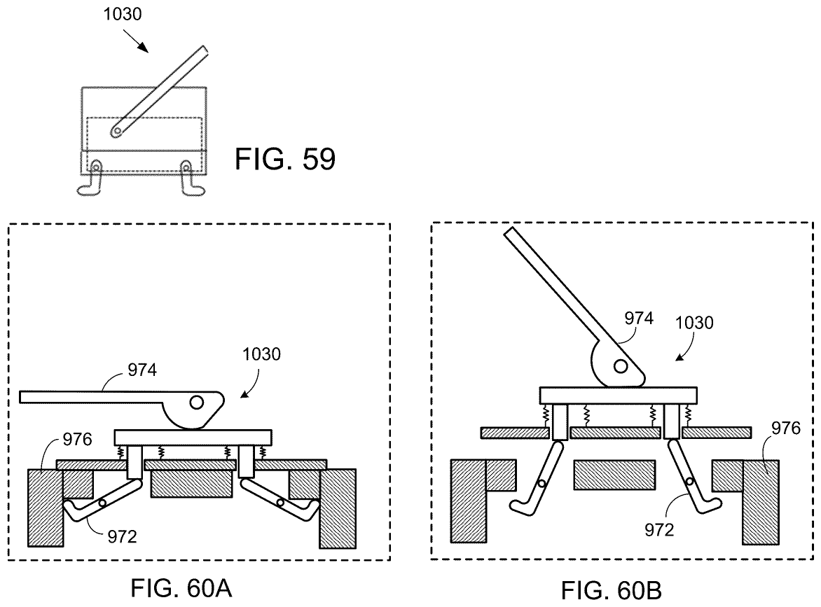

FIG. 59 is a view of an optical module 1030 that includes an optical engine with a latch mechanism used to realize the compression and attachment of the optical engine to the printed circuit board. The module 1030 is similar to the example shown in FIG. 58B but without the compression interposer. FIGS. 60A and 60B show an example latch mechanism that can be used for securing (with enough compression force) and removing the optical engine.

FIGS. 60A and 60B show an example implementation of the lever 974 and the latch mechanism 972 in the optical module 1030. FIG. 60A shows an example in which the lever 974 is pushed down, causing the latch mechanism 972 to latch on to a support structure 976, which can be part of the first grid structure 870. FIG. 60B shows an example in which the lever 974 is pulled up, causing the latch mechanism 972 to be released from the support structure 976.

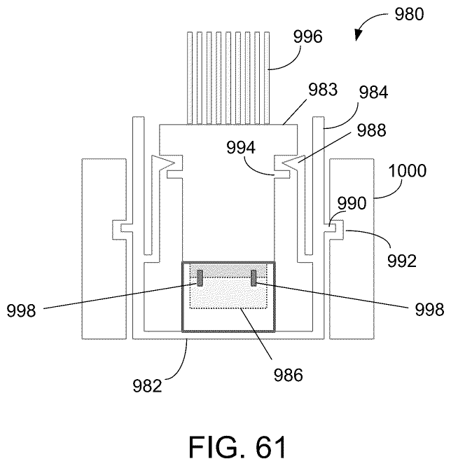

FIG. 61 is a diagram of an example of a fiber cable connection design 980 that includes nested fiber optic cable and co-packaged optical module connections. In this design, a co-packaged optical module 982 is removably coupled to a co-packaged optical port 1000 formed in a support structure, such as the first grid structure 870, and a fiber connector 983 is removably coupled to the co-packaged optical module 982. The fiber connector 983 is coupled to a fiber cable 996 that includes a plurality of optical fibers. The fiber cable connection can be designed to be, e.g., MTP/MPO (Multi-fiber Termination Push-on/Multi-fiber Push On) compatible, or compatible to new standards as they emerge. Multi-fiber push on (MPO) connectors are commonly used to terminate multi-fiber ribbon connections in indoor environments and conforms to IEC-61754-7; EIA/TIA-604-5 (FOCIS 5) standards.

In some implementations, the co-packaged optical module 982 includes a mechanical connector structure 984 and a smart optical assembly 986. The smart optical assembly 986 includes, e.g., a photonic integrated circuit (e.g., 896 of FIG. 44), and components for guiding light, power splitting, polarization management, optical filtering, and other light beam management before the photonic integrated circuit. The components can include, e.g., optical couplers, waveguides, polarization optics, filters, and/or lenses. Additional examples of the components that can be included in the co-packaged optical module 982 are described in U.S. patent Ser. No. 11/287,585. The mechanical connector structure 984 includes one or more fiber connector latches 988 and one or more co-packaged optical module latches 990. The mechanical connector structure 984 can be inserted into the co-packaged optical port 1000 (e.g., formed in the first grid structure 870), in which the co-packaged optical module latches 990 engage grooves 992 in the walls of the first grid structure 870, thus securing the co-packaged optical module 982 to the co-packaged optical port 1000, and causing the electrical contacts of the smart optical assembly 986 to be electrically coupled to the electrical contacts 876 on the printed circuit board 862 (or substrate). When the fiber connector 983 is inserted into the mechanical connector structure 984, the fiber connector latches 988 engage grooves 994 in the fiber connector 983, thus securing the fiber connector 983 to the co-packaged optical module 982, and causing the fiber cable 996 to be optically coupled to the smart optical assembly 986, e.g., through optical paths in the fiber connector 983.

In some examples, the fiber connector 983 includes guide pins 998 that are inserted into holes in the smart optical assembly 986 to improve alignment of optical components (e.g., waveguides and/or lenses) in the fiber connector 983 to optical components (e.g., optical couplers and/or waveguides) in the smart optical assembly 986. In some examples, the guide pins 998 can be chamfered shaped, or elliptical shaped that reduces wear.

In some implementations, after the fiber connector 983 is installed in the co-packaged optical module 982, the fiber connector 983 prevents the co-packaged optical module latches 990 from bending inwards, thus preventing the co-packaged optical module 982 from being inserted into, or released from, the co-packaged optical port 1000. To couple the fiber cable 996 to the data processing system, the co-packaged optical module 982 is first inserted into the co-packaged optical port 1000 without the fiber connector 983, then the fiber connector 983 is inserted into the mechanical connector structure 984. To remove the fiber cable 996 from the data processing system, the fiber connector 983 can be removed from the mechanical connector structure 984 while the co-packaged optical module 982 is still coupled to the co-packaged optical port 1000.

In some implementations, the nested connection latches can be designed to allow the co-packaged optical module 982 to be inserted in, or removed from, the co-packaged optical port 1000 when a fiber cable is connected to the co-packaged optical module 982.

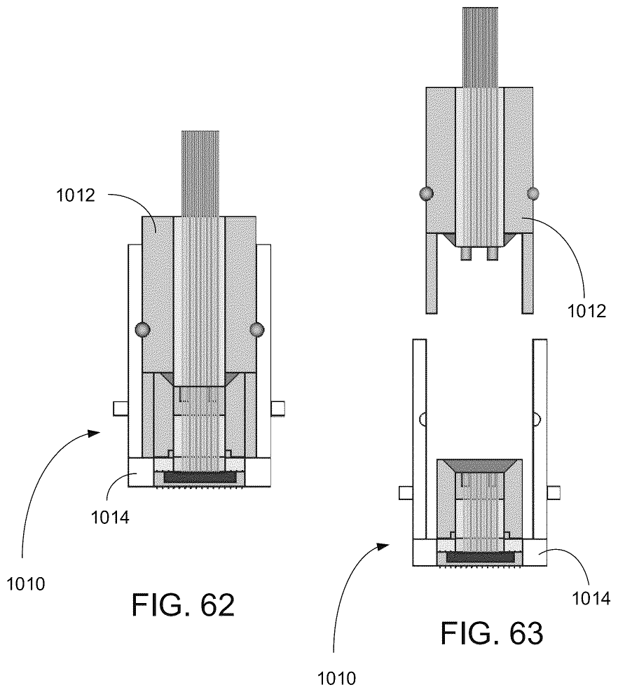

FIGS. 62 and 63 are diagrams showing cross-sectional views of an example of a fiber cable connection design 1010 that includes nested fiber optic cable and co-packaged optical module connections. FIG. 62 shows an example in which a fiber connector 1012 is removably coupled to a co-packaged optical module 1014. FIG. 63 shows an example in which the fiber connector 1012 is separated from the co-packaged optical module 1014.

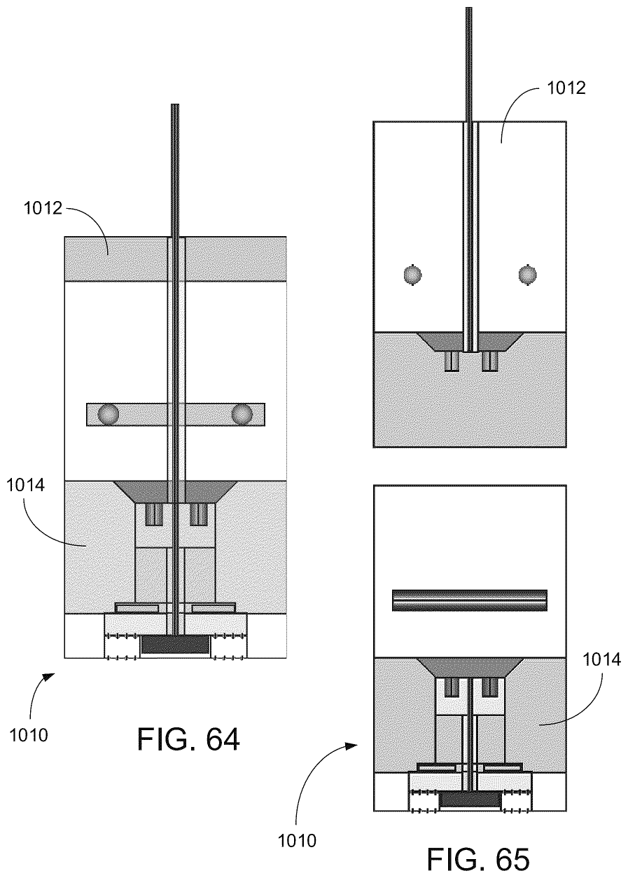

FIGS. 64 and 65 are diagrams showing additional cross-sectional views of the fiber cable connection design 1010. The cross-sections are made along planes that vertically cut through the middle of the components shown in FIGS. 62 and 63. FIG. 64 shows an example in which the fiber connector 1012 is removably coupled to the co-packaged optical module 1014. FIG. 65 shows an example in which the fiber connector 1012 is separated from the co-packaged optical module 1014.

The rackmount systems and rackmount devices described in this document can include, and are not limited to, e.g., rackmount computer servers, rackmount network switches, rackmount controllers, and rackmount signal processors.

For example, the at least one data processing chip can include a network switch, a central processor unit, a graphics processor unit, a tensor processing unit, a neural network processor, an artificial intelligence accelerator, a digital signal processor, a microcontroller, or an application specific integrated circuit (ASIC). The rackmount server can be, and not limited to, e.g., a rackmount computer server, a rackmount switch, a rackmount controller, a rackmount signal processor, a rackmount storage server, a rackmount multi-purpose processing unit, a rackmount graphics processor, a rackmount tensor processor, a rackmount neural network processor, or a rackmount artificial intelligence accelerator. For example, each co-packaged optical module can include a module similar to the integrated optical communication device 448, 462, 466, or 472 of FIG. 17, the integrated optical communication device 210 of FIG. 20, the integrated communication device 612 of FIG. 23, the optical/electrical communication interface 684 of FIG. 26, 724 of FIG. 28, or 760 of FIG. 29, the integrated optical communication device 512 of FIG. 32, or the optical module with connector 868 of FIG. 43. For example, each fiber cable 1076 can include the optical fibers 226 (FIGS. 2, 4), 272 (FIGS. 6, 7), 582 (FIGS. 22, 23), or 734 (FIG. 28), or the optical fiber cable 762 (FIG. 762), 956 (FIG. 53), or 996 (FIG. 61).

For example, the co-packaged optical module can include a first optical connector part (e.g., 456 of FIG. 17, 578 of FIG. 22 or 23, 746 of FIG. 28) that is configured to be removably coupled to a second optical connector part (e.g., 458 of FIG. 17, 580 of FIG. 22 or 23, 748 of FIG. 28) that is attached to the external fiber cable 1076. For example, the co-packaged optical module 1074 includes a photonic integrated circuit (e.g., 450, 464, 468, or 474 of FIG. 17, 586 of FIG. 22, 618 of FIG. 23, or 726 of FIG. 28) that is optically coupled to the first optical connector part. The photonic integrated circuit receives input optical signals from the first optical connector part and generates input electrical signals based on the input optical signals. At least a portion of the input electrical signals generated by the photonic integrated circuit are transmitted to the at least one data processing chip through electrical signal lines in or on the vertical printed circuit board. For example, the photonic integrated circuit can be configured to receive output electrical signals from the at least one data processing chip and generate output optical signals based on the output electrical signals. The output optical signals are transmitted through the first and second optical connector parts to the external fiber cable.

In some examples, the fiber cable can include, e.g., 10 or more cores of optical fibers, and the first optical connector part is configured to couple 10 or more channels of optical signals to the photonic integrated circuit. In some examples, the fiber cable 1076 can include 100 or more cores of optical fibers, and the first optical connector part is configured to couple 100 or more channels of optical signals to the photonic integrated circuit. In some examples, the fiber cable can include 500 or more cores of optical fibers, and the first optical connector part is configured to couple 500 or more channels of optical signals to the photonic integrated circuit. In some examples, the fiber cable can include 1000 or more cores of optical fibers, and the first optical connector part is configured to couple 1000 or more channels of optical signals to the photonic integrated circuit.

In some implementations, the photonic integrated circuit can be configured to generate first serial electrical signals based on the received optical signals, in which each first serial electrical signal is generated based on one of the channels of first optical signals. Each co-packaged optical module can include a first serializers/deserializers module that includes serializer units and deserializer units, in which the first serializers/deserializers module is configured to generate sets of first parallel electrical signals based on the first serial electrical signals and condition the electrical signals, and each set of first parallel electrical signals is generated based on a corresponding first serial electrical signal. Each co-packaged optical module can include a second serializers/deserializers module that includes serializer units and deserializer units, in which the second serializers/deserializers module is configured to generate second serial electrical signals based on the sets of first parallel electrical signals, and each second serial electrical signal is generated based on a corresponding set of first parallel electrical signals.

In some examples, the rackmount server can include 4 or more co-packaged optical modules that are configured to be removably coupled to corresponding second optical connector parts that are attached to corresponding fiber cables. For example, the rackmount server can include 16 or more co-packaged optical modules that are configured to be removably coupled to corresponding second optical connector parts that are attached to corresponding fiber cables. In some examples, each fiber cable can include 10 or more cores of optical fibers. In some examples, each fiber cable can include 100 or more cores of optical fibers. In some examples, each fiber cable can include 500 or more cores of optical fibers. In some examples, each fiber cable can include 1000 or more cores of optical fibers. Each optical fiber can transmit one or more channels of optical signals. For example, the at least one data processing chip can include a network switch that is configured to receive data from an input port associated with a first one of the channels of optical signals, and forward the data to an output port associated with a second one of the channels of optical signals.

In some implementations, the co-packaged optical modules are removably coupled to the vertical printed circuit board. For example, the co-packaged optical modules can be electrically coupled to the vertical printed circuit board using electrical contacts that include, e.g., spring-loaded elements, compression interposers, or land-grid arrays.

A feature of the rackmount units described above is the use of co-packaged optical modules or optical/electrical communication interfaces that have higher bandwidth per module or interface, as compared to conventional designs. For example, each co-packaged optical module or optical/electrical communication interface can be coupled to a fiber cable that carries a large number of densely packed optical fiber cores. FIG. 9 shows an example of the integrated optical communication device 282 in which the optical signals provided to the photonic integrated circuit can have a total bandwidth of about 12.8 Tbps. By using co-packaged optical modules or optical/electrical communication interfaces that have higher bandwidth per module or interface, the number of co-packaged optical modules or optical/electrical communication interfaces required for a given total bandwidth for the rackmount unit is reduced, so the amount of area on the front panel of the housing reserved for connecting to optical fibers can be reduced.

Referring to FIG. 67, in some implementations, a vertically mounted processor blade 12300 can include a substrate 12302 having a first side 12304 and a second side 12306. The substrate 12302 can be, e.g., a printed circuit board. An electronic processor 12308 is mounted on the first side 12304 of the substrate 12302, in which the electronic processor 12308 is configured to process or store data. For example, the electronic processor 12308 can be a network switch, a central processor unit, a graphics processor unit, a tensor processing unit, a neural network processor, an artificial intelligence accelerator, a digital signal processor, a microcontroller, or an application specific integrated circuit (ASIC). For example, the electronic processor 12308 can be a memory device or a storage device. In this context, processing of data includes writing data to, or reading data from, the memory or storage device, and optionally performing error correction. The memory device can be, e.g., random access memory (RAM), which can include, e.g., dynamic RAM (DRAM) or static RAM (SRAM). The storage device can include, e.g., solid state memory or drive, which can include, e.g., one or more non-volatile memory (NVM) Express® (NVMe) SSD (solid state drive) modules, or Intel® Optane™ persistent memory. The example of FIG. 67 shows one electronic processor 12308, through there can also be multiple electronic processors 12308 mounted on the substrate 12302.

The vertically mounted processor blade 12300 includes one or more optical interconnect modules or co-packaged optical modules 12310 mounted on the second side 12306 of the substrate 12302. For example, the optical interconnect module 12310 includes an optical port configured to receive optical signals from an external optical fiber cable, and a photonic integrated circuit configured to generate electrical signals based on the received optical signals, and transmit the electrical signals to the electronic processor 12308. The photonic integrated circuit can also be configured to generate optical signals based on electrical signals received from the electronic processor 12308, and transmit the optical signals to the external optical fiber cable. The optical interconnect module or co-packaged optical module 12310 can be similar to, e.g., the integrated optical communication device 262 of FIG. 6; 282 of FIGS. 7-9; 462, 466, 448, 472 of FIG. 17; 612 of FIG. 23; 684 of FIG. 26; 704 of FIG. 27; 724 of FIG. 28. In the example of FIG. 67, the optical interconnect module or co-packaged optical module 12310 does not necessarily have to include serializers/deserializers (SerDes), e.g., 216, 217 of FIGS. 2 to 8 and 10 to 12. The optical interconnect module or co-packaged optical module 12310 can include the photonic integrated circuit 12314 without any serializers/deserializers. For example, the serializers/deserializers can be mounted on the substrate separate from the optical interconnect module or co-packaged optical module 12310.

For example, the substrate 12302 can include electrical connectors that extend from the first side 12304 to the second side 12306 of the substrate 12302, in which the electrical connectors pass through the substrate 12302 in a thickness direction. For example, the electrical connectors can include vias of the substrate 12302. The optical interconnect module 12310 is electrically coupled to the electronic processor 12308 by the electrical connectors. For example, the vertically mounted processor blade 12300 can include an optional optical fiber connector 12312 for connection to an optical fiber cable bundle. The optical fiber connector 12312 can be optically coupled to the optical interconnector modules 12310 through optical fiber cables 12314. The optical fiber cables 12314 can be connected to the optical interconnect modules 12310 through a fixed connector (in which the optical fiber cable 12314 is securely fixed to the optical interconnect module 12310) or a removable connector in which the optical fiber cable 12314 can be easily detached from the optical interconnect module 12310, such as with the use of an optical connector part 266 as shown in FIG. 6. The removable connector can include a structure similar to the mechanical connector structure 900 of FIGS. 46, 47 and 51A to 57.

For example, the substrate 12302 can be positioned near from front panel of the housing of the server that includes the vertically mounted processor blade 12300, or away from the front panel and located anywhere inside the housing. For example, the substrate 12302 can be parallel to the front panel of the housing, perpendicular to the front panel, or oriented in any angle relative to the front panel. For example, the substrate 12302 can be oriented vertically to facilitate the flow of hot air and improve dissipation of heat generated by the electronic processor 12308 and/or the optical interconnect modules 12310.

For example, the optical interconnect module or co-packaged optical module 12310 can receive optical signals through vertical or edge coupling. FIG. 67 shows an example in which the optical fiber cables are vertically coupled to the optical interconnect modules or co-packaged optical modules 12310. It is also possible to connect the optical fiber cables to the edges of the optical interconnect modules or co-packaged optical modules 12310. For example, optical fibers in the optical fiber cable can be attached in-plane to the photonic integrated circuit using, e.g., V-groove fiber attachments, tapered or un-tapered fiber edge coupling, etc., followed by a mechanism to direct the light interfacing to the photonic integrated circuit to a direction that is substantially perpendicular to the photonic integrated circuit, such as one or more substantially 90-degree turning mirrors, one or more substantially 90-degree bent optical fibers, etc.

For example, the optical interconnect modules 12310 can receive optical power from an optical power supply. For example, the optical interconnect modules 12310 can include one or more of optical coupling interfaces 414, demultiplexers 419, splitters 415, multiplexers 418, receivers 421, or modulators 417 of FIG. 20.

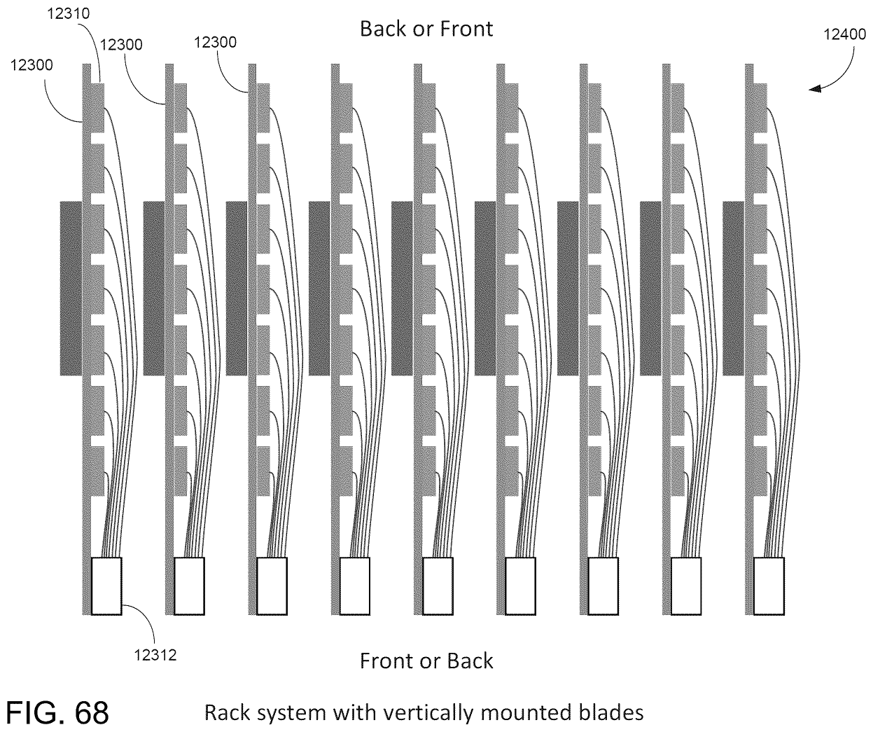

FIG. 68 is a top view of an example of a rack system 12400 that includes several vertically mounted processor blades 12300. The vertically mounted processor blades 12300 can be positioned such that the optical fiber connectors 12312 are near the front of the rack system 12400 (which allows external optical fiber cables to be optically coupled to the front of the rack system 12400), or near the back of the rack system 12400 (which allows external optical fiber cables to be optically coupled to the back of the rack system 12400). Several rack systems 12400 can be stacked vertically, in which the server rack 1214 includes several servers 1212 stacked vertically. For example, the optical interconnect modules 12310 can receive optical power from an optical power supply.

In some implementations, the vertically mounted processor blades 12300 can include blade pairs, in which each blade pair includes a switch blade and a processor blade. The electronic processor of the switch blade includes a switch, and the electronic processor of the processor blade is configured to process data provided by the switch. For example, the electronic processor of the processor blade is configured to send processed data to the switch, which switches the processed data with other data, e.g., data from other processor blades.

In the examples shown in FIGS. 67 and 68, the optical interconnect module or co-packaged optical module 12310 is mounted on the second side of the substrate 12302. In some implementations, the optical interconnect module 12310 or the optical fiber cable 12314 extends through or partially through an opening in the substrate 12302, similar to the example shown in FIGS. 35A to 35C. The photonic integrated circuit in the optical interconnect module 12310 is electrically coupled to the electronic processor 12308 or to another electronic circuit, such as a serializers/deserializers module positioned at or near the first side of the substrate 12302. The optical interconnect module 12310 and the optical fiber cable 12314 define a signal path that allows a signal from the optical fiber cable 12314 to be transmitted from the second side of the substrate 12302 through the opening to the electronic processor 12308. The signal is converted from an optical signal to an electric signal by the photonic integrated circuit, which defines part of the signal path. This allows the optical fiber cables to be positioned on the second side of the substrate 12302.

For example, the electronic processor can be a network switch, a central processor unit, a graphics processor unit, a tensor processing unit, a neural network processor, an artificial intelligence accelerator, a digital signal processor, a microcontroller, or an application specific integrated circuit (ASIC). For example, the electronic processor can be a memory device or a storage device. In this context, processing of data includes writing data to, or reading data from, the memory or storage device, and optionally performing error correction. The memory device can be, e.g., random access memory (RAM), which can include, e.g., dynamic RAM (DRAM) or static RAM (SRAM). The storage device can include, e.g., solid state memory or drive, which can include, e.g., one or more non-volatile memory (NVM) Express® (NVMe) SSD (solid state drive) modules, or Intel® Optane™ persistent memory.

The co-packaged optical module (or optical interconnect module) 12316 can be similar to, e.g., the integrated optical communication device 262 of FIG. 6; 282 of FIGS. 7-9; 462, 466, 448, 472 of FIG. 17; 612 of FIG. 23; 684 of FIG. 26; 704 of FIG. 27; 724 of FIG. 28. The optical interconnect module or co-packaged optical module can include the photonic integrated circuit without any serializers/deserializers. For example, the serializers/deserializers can be mounted on the circuit board separate from the optical interconnect module or co-packaged optical module.

In some implementations, each co-packaged optical module can receive optical signals from a large number of fiber cores, and each co-packaged optical module can be optically coupled to external fiber optic cables through three or more array connectors that occupy an overall area at the front panel that is larger than the overall area occupied by the co-packaged optical module on the printed circuit board.

In the examples shown in FIGS. 2, 4, 6, 7, 12, 17, 20, 22 to 31, 35A to 37, 43, 67, and 68, one or more data processing modules are mounted on a substrate or circuit board that is positioned near the front panel (or any panel that is accessible to the user), and the communication interfaces such as co-packaged optical modules support the one or more data processing modules. Each data processing module can be, e.g., a network switch, a central processor unit, a graphics processor unit, a tensor processing unit, a neural network processor, an artificial intelligence accelerator, a digital signal processor, a microcontroller, a storage device, or an application specific integrated circuit (ASIC). Each data processing module can include an electronic processor and/or a photonic processor. The data processing modules can be mounted on the substrate or circuit board using various types of contacts, such as ball grid arrays or sockets. The data processing modules can also be mounted on smaller substrates or circuit boards that are in turn mounted on larger substrates or circuit boards. The following describes an example in which the communication interface(s) support memory modules mounted in smaller circuit boards that are electrically coupled to a larger circuit board positioned near the front panel.

In the examples shown in FIGS. 6 and 23, an optical fiber cable is optically coupled to the top side of the photonic integrated circuit, and the bottom side of the photonic integrated circuit is mounted on a substrate. One or more electronic integrate circuits, such as a serializer/deserialize module, is/are mounted on or partially on the photonic integrated circuit adjacent to or near the optical fiber cable or the optical connector that connects to the optical fiber cable. In the examples shown in FIGS. 7 and 32, the photonic integrated circuit and the electronic integrated circuit(s) are mounted on opposite sides of the substrate, in which the electronic integrated circuit(s) is/are mounted adjacent to or near the optical fiber cable or the optical connector that connects to the optical fiber cable. In the examples shown in FIGS. 35A to 37, an optical fiber cable is optically coupled to the bottom side of the photonic integrated circuit, and the electronic integrated circuit is coupled to the top side of the photonic integrated circuit. These examples illustrate how one or more electronic integrated circuits can be vertically stacked on a photonic integrated circuit (either directly or indirectly through a substrate) in a way that accommodates the optical path from the optical fiber cable to the photonic integrated circuit. The following describes such packaging for the co-packaged optical module in which ASICs are placed adjacent to, near, or around the vertical fiber connector.

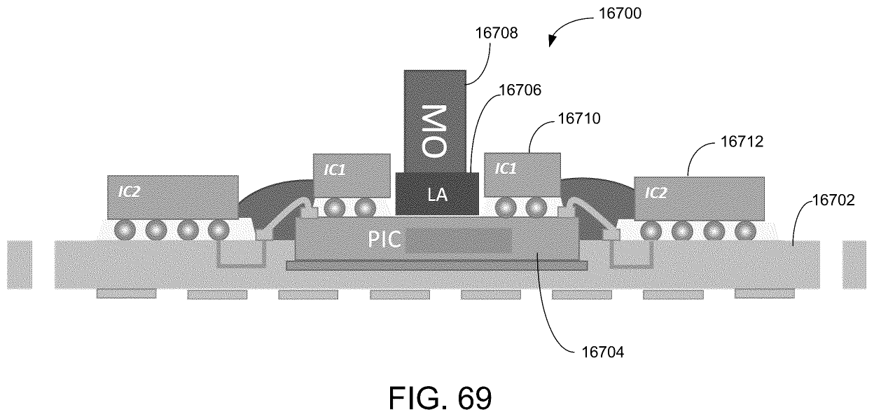

Referring to FIG. 69, a co-packaged optical module 16700 includes a substrate 16702 and a photonic integrated circuit 16704 mounted on the substrate 16702. A lens array 16706 and a micro optics connector 16708 optically couples the photonic integrated circuit 16704 to an optical fiber cable. The lens array 16706 and the micro optics connector 16708 will be referred to as the optical connector. A first set of one or more integrated circuits 16710 are mounted on the top side of the photonic integrated circuit 16704 using, e.g., copper pillars, or solder bumps. The first set of one or more integrated circuits 16710 is positioned adjacent to or near the optical connector. For example, two or more integrated circuits 16710 can be positioned on two or more sides of the optical connector, surrounding or partially surrounding the optical connector. A second set of integrated circuits 16712 is mounted on the substrate 16702 and electrically coupled to the photonic integrated circuit 16704.

For example, each integrated circuit 16710 (mounted on the photonic integrated circuit 16704) can include an electrical drive amplifier or a transimpedance amplifier. Each integrated circuits 16712 (mounted on the substrate) can include a SerDes or a DSP chip or a combination of SerDes/DSP chips.

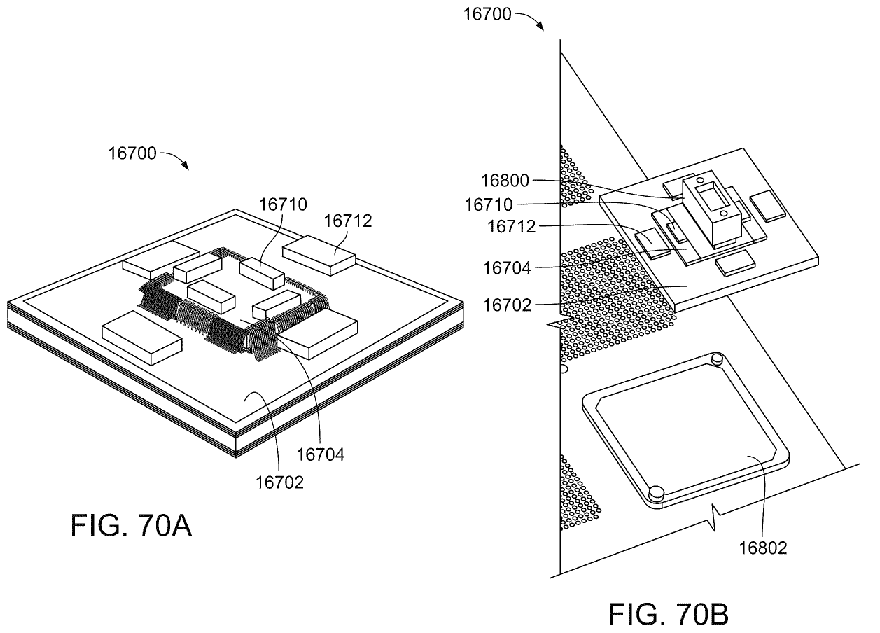

FIGS. 70A and 70B show perspective views of an example of the co-packaged optical module 16700. FIG. 70A shows the substrate 16702, the photonic integrated circuit 16704, the first set of electrical integrated circuits 16710 mounted on the photonic integrate circuit 16704, and a second set of electrical integrated circuits 16712 mounted on the substrate 16702. FIG. 70B shows the same components as those shown in FIG. 70A, with the addition of a smart connector 16800 that connects to an optical fiber cable, and a socket 16802 that electrically couples to the electrical contacts on the bottom side of the substrate 16702.

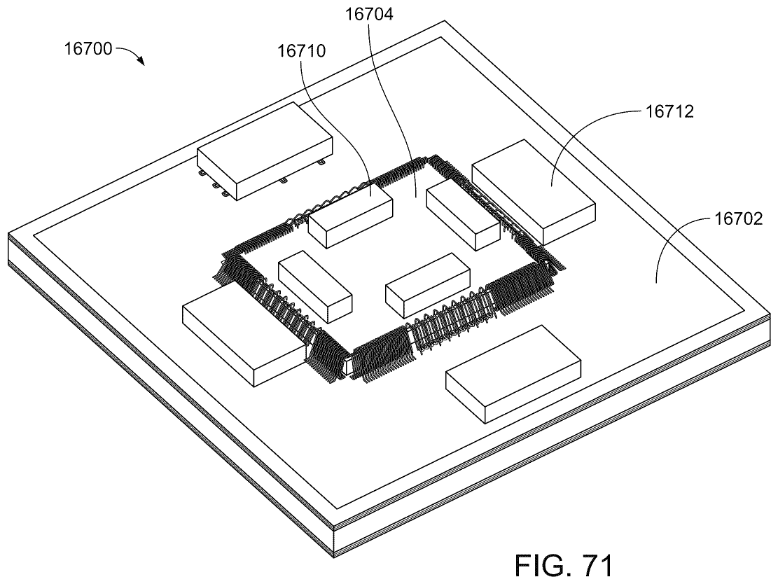

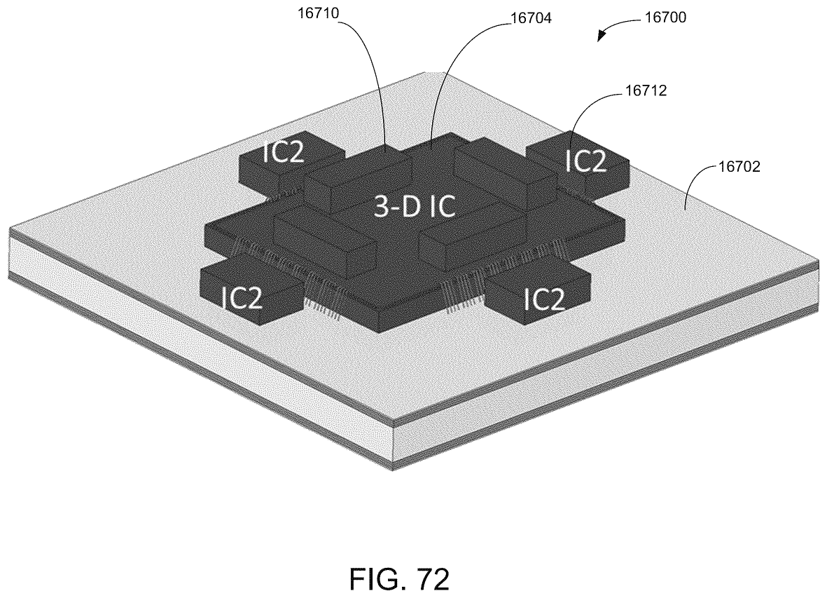

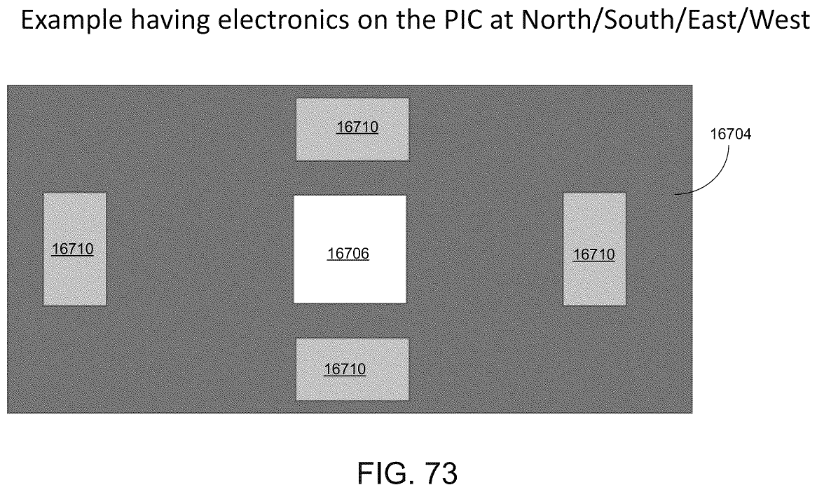

FIGS. 71 and 72 shows additional examples of perspective views of the co-packaged optical module 16700. FIG. 73 shows a top view of an example of the placement of the electrical integrated circuits 16710 on the photonic integrated circuit 16704. In this example, the lens array 16706 is positioned near the center of the photonic integrated circuit 16704, and the electrical integrated circuits 16710 are placed at the north, south, east, and west positions relative to the lens array 16706. By placing the electrical integrated circuits 16710 on top of the photonic integrated circuit 16704 and surrounding the lens array 16706 (or any other type of optical connector), the co-packaged optical module 16700 can be made more compact.

Furthermore, the conductive traces between the electrical integrated circuits 16710 and active components in the photonic integrated circuit 16704 can be made shorter, resulting in better performance, e.g., higher data rate, higher signal-to-noise ratio, and lower power required to transmit the signals, as compared to a configuration in which the electrical signals have to travel longer distances.

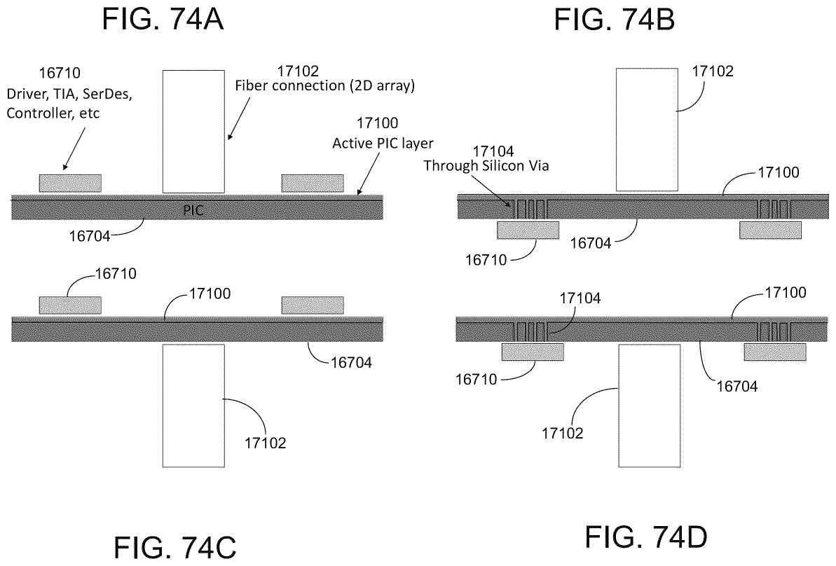

There are several ways to package the electrical integrated circuits and the photonic integrated circuit in order to achieve a compact, small-size, and energy efficient co-packaged optical module. FIG. 74A shows an example in which a photonic integrated circuit 16704 has an active layer 17100 that is positioned near the top surface of the photonic integrated circuit 16704. The fiber connection 17102 (which can include, e.g., a 2D array of focusing lenses) is coupled to the fiber connection 17102 from the top side. For example, grating couplers in the active PIC layer 17100 can be positioned under the fiber connection 17102 to couple the optical signals from the fiber connection 17102 into optical waveguides on the active PIC layer 17100, and from the optical waveguides out to the fiber connection 17102. The electrical integrated circuits 16710 are mounted on the top side of the photonic integrated circuit 16704 and are coupled to the active PIC layer 17100 through contact pads and optionally short conductive traces. For example, the active PIC layer 17100 can include photodetectors that convert the optical signals received from the fiber connection 17102 to electrical current signals that are transmitted to the drivers and transimpedance amplifiers in the electrical integrated circuits 16710. Similarly, the electrical integrated circuits 16710 can send electrical signals to the electro-optic modulators in the active PIC layer 17100 that convert the electrical signals to optical signals that are output through the fiber connection 17102.

FIG. 74B shows an example in which the electrical integrated circuits 16710 are coupled to the bottom surface of the photonic integrated circuit 16704 and electrically coupled to the active PIC layer 17100 using through silicon vias 17104. The through silicon vias 17104 provide signal conduction paths in the thickness direction through the silicon die or substrate of the photonic integrated circuit 16704. The drivers and transimpedance amplifiers in the electrical integrated circuits 16710 can be positioned directly under the photonic integrated circuit active components, such as the photodiodes and the electro-optic modulators, so that the shortest electrical signal paths can be used between the photonic integrated circuit 16704 and the electrical integrated circuits 16710.

FIG. 74C shows an example in which the fiber connection 17102 is coupled to the photonic integrated circuit 16704 through the bottom side (in a configuration referred to as “backside illumination”), such that the optical signals from the fiber connection 17102 pass through the silicon die or substrate before being received by the photodetectors in the active PIC layer 17100. Likewise, the modulators in the active PIC layer 17100 transmit modulated optical signals through the silicon die or substrate to the fiber connection 17102. The portion of the active PIC layer 17100 directly above the fiber connection 17102 can include grating couplers. The photodetectors and modulators are positioned at a distance from the grating couplers. The electrical integrated circuits 16710 are positioned directly above or near the photodetectors and the modulators, so the locations of the electrical integrated circuits 16710 relative to the active PIC layer 17100 in the example of FIG. 74C will be similar to those in the example of FIG. 74A.

FIG. 74D shows an example in which backside illumination is used, and the electrical integrated circuits 16710 are coupled to the bottom side of the photonic integrated circuit 16704. The electrical integrated circuits 16710 are electrically coupled to the active components (e.g., photodetectors and electro-optic modulators) in the active PIC layer 17100 using through silicon vias 17104, similar to the example in FIG. 74B.

In some implementations, an integrated circuit is configured to surround or partially surround the vertical fiber connector. For example, the integrated circuit can have an L-shape that surrounds two sides of the vertical fiber connector (e.g., two of north, east, south, and west sides). For example, the integrated circuit can have a U-shape that surrounds three sides of the vertical fiber connector (e.g., three of north, east, south, and west sides). For example, the integrated circuit can have an opening in the center region to allow the vertical fiber connector to pass through, in which the integrated circuit completely surrounds the vertical fiber connector. The dimensions of the opening in the integrated circuit are selected to allow the optical fiber connector to pass through to enable an optical fiber to be optically coupled to the photonic integrated circuit. For example, the integrated circuit with an opening in the center region can have a circular or polygonal shape at the outer perimeter. A feature of the integrated circuit mounted on the same surface as the vertical fiber connector is that it takes advantage of the space available on the surface of the photonic integrated circuit that is not occupied by the vertical fiber connector so that the electrical integrated circuit can be placed near or adjacent to the active components (e.g., photodetectors and/or modulators) of the photonic integrated circuit.

In some implementations, an integrated circuit defining an opening can be manufactured by the following process:

Step 1: Use semiconductor lithography to form an integrated circuit on a semiconductor die (or wafer or substrate), in which a first interior region of the semiconductor die does not have integrated circuit component intended to be used for the final integrated circuit (but can have components intended to be used for other products).

Step 2: Use a laser (or any other suitable cutting tool) to cut an opening in the first interior region of the semiconductor die.

Step 3: Place the semiconductor die on a lower mold resin that defines an opening in an interior region. A lead frame or electrical connectors are attached to the lower mold resin.

Step 4: Wire bond electrical contacts on the semiconductor die to the lead frame or electrical connectors attached to the lower mold resin.

Step 5: Attach an upper mold resin to the lower mold resin, and enclose the semiconductor die between the lower and upper mold resins. The upper mold resin defines an opening in an interior region that corresponds to the opening in the lower mold resin. In some examples, the footprint of the semiconductor die is within the footprint of the lower/upper mold resins so that the semiconductor die is completely enclosed inside the lower and upper mold resins. In some examples, the lower and/or upper mold resin can have additional openings, and the opening(s) in the lower and/or upper mold resins can be configured to expose one or more portions of the semiconductor die.

An integrated circuit having an L-shape or a U-shape can be manufactured using a similar process. For example, in step 1, circuitry is formed in an L-shaped or U-shaped footprint. In step 2, the laser or cutting tool cuts the die according to the L-shape or U-shape footprint. In steps 3 and 5, a lower mold resin and an upper mold resin having the desired L-shape or U-shape are used.

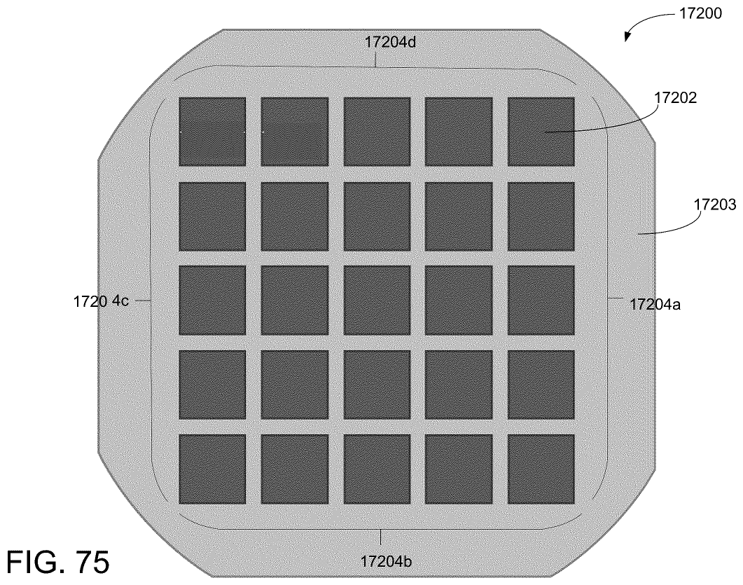

Referring to FIG. 75, in some implementations, a wafer-scale processor 17200 can include multiple data processors 17202 formed on a semiconductor wafer or substrate 17203, or mounted on the semiconductor wafer or substrate 17203. The figure shows an example that includes an array of 5 rows and 5 columns (a total of 25) data processors 17202. It is understood that the wafer-scale processor can have any number of data processors, such as having an array of 2, 3, 4, 5, 6, 7, 8, 9, 10, or more rows and 2, 3, 4, 5, 6, 7, 8, 9, 10, or more columns of data processors, as long as they can fit in the area provided by the wafer or substrate 17203.

Semiconductor manufacturing technologies and microprocessor designs improve year after year, enabling the wafer-scale processor to process ever increasing amounts of data. There is a need to improve the mechanism for transmitting the large amounts of data to and from the data processors 17202 in the wafer-scale processor 17200. In some examples, electrical input/output interfaces are positioned at the four edges 17204a, 17204b, 17204c, and 17204d of the wafer-scale processor 17200. In some examples, the electrical input/output interfaces at each edge can provide a bandwidth of several terabytes per second, with an aggregate bandwidth of tens of terabytes per second on all four edges 17204a, 17204b, 17204c, and 17204d. The following describes a technology for using optical interfaces to further increase the input/output bandwidth of the wafer-scale processor 17200.

Referring to FIG. 76, in some implementations, a wafer-scale processing system 17300 includes a wafer-scale processor 17200 and a plurality of optical input/output modules, referred to as edge interface modules 17302 that function as input/output interfaces between the wafer-scale processor 17200 and a plurality of external optical links. The wafer-scale processor 17200 includes an array of data processors 17202 formed or disposed on a semiconductor wafer or substrate 17203. In this example, the wafer-scale processor 17200 includes four edges, and four edge interface modules 17302a, 17302b, 17302c, 17302d are provided near the four edges of the wafer-scale processor 17200.

In some examples, the wafer-scale processor can have data processors arranged in a substantially triangular shape and have three edges, and three edge interface modules are provided near the three edges of the wafer-scale processor. In some examples, the wafer-scale processor can have data processors arranged in a shape similar to a pentagon and have five edges, and five edge interface modules are provided near the five edges of the wafer-scale processor. In some examples, the wafer-scale processor can have data processors arranged in a shape similar to a hexagon and have six edges, and six edge interface modules are provided near the six edges of the wafer-scale processor. In some examples, the wafer-scale processor can have data processors arranged in a shape similar to an N1-polygon having N1 edges, N1 being a positive integer greater than 6, and N1 edge interface modules are provided near the N1 edges of the wafer-scale processor. In some examples, the wafer-scale processor can have N1 edges, and M1 edge interface modules are provided near M1 of the N1 edges of the wafer-scale processor, in which M1<N1.

In some examples, the wafer-scale processor has one or more curved edges, and the edge interface modules also have one or more curved edges that match those of the wafer-scale processor. In some examples, the wafer-scale processor has a substantially circular outer edge, and the edge interface module forms a ring that surrounds the wafer-scale processor.

Each edge interface module (e.g., 17302a, 17302b, 17302c, or 17302d) includes a plurality of optical input/output (I/O) interfaces 17304. In some examples, the plurality of optical I/O interfaces 17304 include a two-dimensional arrangement of optical I/O interfaces 17304. In some examples, the two-dimensional arrangement of optical I/O interfaces 17304 includes a two-dimensional array of optical I/O interfaces 17304. In some examples, the two-dimensional array of optical I/O interfaces 17304 includes a plurality of rows and a plurality of columns of optical I/O interfaces 17304. The two-dimensional arrangement does not necessarily have to be a two-dimensional rectilinear arrangement of rows and columns. For example, a two-dimensional arrangement of optical I/O interfaces can include optical I/O interfaces arranged at arbitrary positions on a two-dimensional plane. In some implementations, each optical I/O interface 17304 includes a co-packaged optical module (CPO). For example, the CPO module 17304 can be, or be similar to, any CPO module, integrated optical communication device, or optical module previously described, such as the integrated optical communication device 210 (FIGS. 2, 3, 10), 252 (FIGS. 4, 5), 262 (FIG. 6), 282 (FIGS. 7-9), 374 (FIG. 11), 382 (FIG. 12), 402 (FIGS. 13, 15, 16), 428 (FIG. 14), optical module 868 (FIG. 43), 880 (FIGS. 44, 45), CPO module 16700 (FIGS. 69-72).

For example, each co-packaged optical module includes a photonic integrated circuit that converts optical signals received from one or more optical fibers to electrical signals that are transmitted to one or more data processors 17202, and converts electrical signals received from one or more data processors 17202 to optical signals that are transmitted to one or more optical fibers. In the following, as an example, the optical I/O interface 17304 is described as a co-packaged optical module 17304. It is understood that the optical I/O interface 17304 can include other types of optical interfaces.

In some implementations, the edge interface module 17302 includes a substrate 17308, and the CPO modules 17304 are attached to the substrate 17308 using any of the techniques previously described for attaching a CPO module to a substrate or circuit board. The CPO module can be removably attached to the substrate or circuit board (e.g., by use of compression interposers), or permanently attached to the substrate or circuit board (e.g., by use of solder).

FIG. 77 shows a side view of an example of a data processing system 17400 that includes a wafer-scale processor 17402 and an edge interface module 17404. In some implementations, the wafer-scale processor 17402 includes one or more application specific integrated circuits 17406 attached to a carrier wafer or substrate 17408. A power brick 17410 is electrically coupled to the one or more application specific integrated circuits 17406 to provide power to the one or more application specific integrated circuits 17406. The edge interface module 17404 includes one or more co-packaged optical modules 17412 (only one is shown in the figure) attached to a CPO substrate 17414. The co-packaged optical module 17412 includes a photonic integrated circuit 17416, a first set of one or more electronic integrated circuits 17418, a second set of one or more integrated circuits 17420, and an optical connector 17422, similar to the co-packaged optical module 16700 of FIG. 69. In this example, the CPO substrate 17414 is attached to the top surface of the carrier wafer or substrate 17408 through an interface region 17424, in which electrical contacts on the underside of the CPO substrate 17414 connects with bump contacts on the top surface of the wafer 17408. The bump contacts are electrically connected to the one or more data processors 17406 through metal signal lines or conductive traces. For example, the CPO modules 17412 can be attached to the surface of the carrier wafer or substrate 17408 using any of the techniques previously described for attaching a CPO module to a substrate or a circuit board. The CPO substrate can be made of, e.g., one or more ceramic materials, or organic “high density build-up” (HDBU). For example, the CPO substrate can be made of materials similar to those used in the substrate 211 of FIG. 2 or the substrate 16702 of FIG. 69.

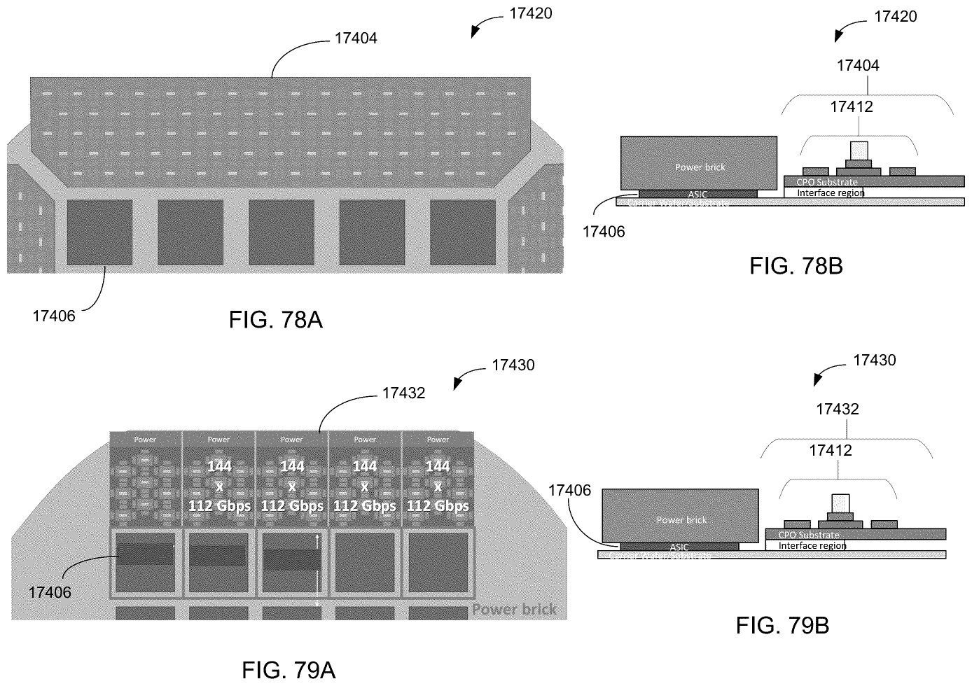

FIGS. 78A and 78B illustrate an example of a single side solution in which the co-packaged optical modules are attached to one side of the carrier wafer or substrate. FIG. 78A shows a top view of a portion of an example data processing system 17420, including a row of data processors 17406 and an edge interface module 17404. FIG. 78B shows a side view of the portion of the data processing system 17420.

FIGS. 79A and 79B illustrate another example of a single side solution in which the co-packaged optical modules are attached to one side of the carrier wafer or substrate. FIG. 79A shows a top view of a portion of an example data processing system 17430, including a row of data processors 17406 and an edge interface module 17432. FIG. 79B shows a side view of the portion of the data processing system 17430.

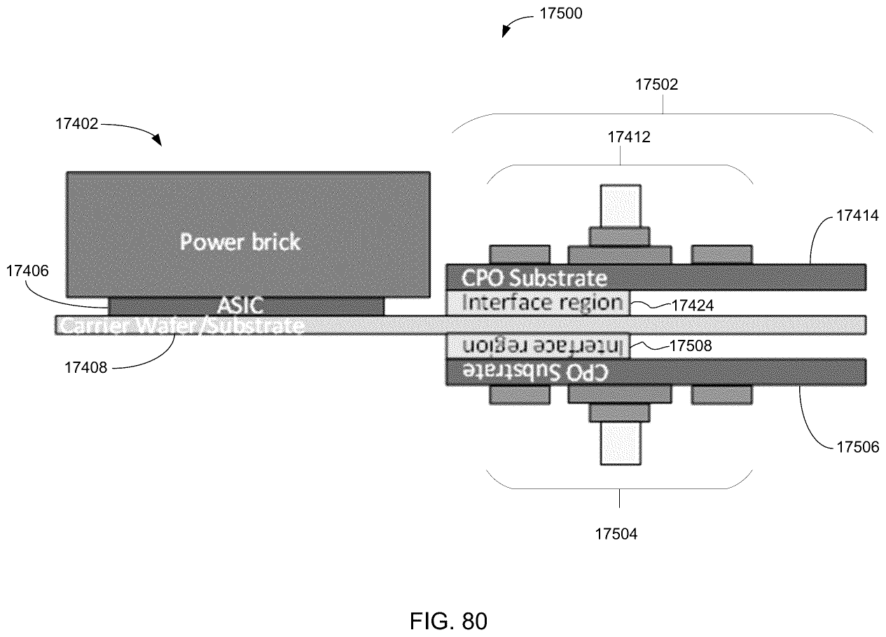

FIG. 80 shows a side view of an example of a data processing system 17500 that includes a wafer-scale processor 17402 and an edge interface module 17502. In some implementations, the wafer-scale processor 17402 includes one or more application specific integrated circuits 17406 attached to a carrier wafer or substrate 17408. The edge interface module 17502 includes a first set of one or more co-packaged optical modules 17412 attached to a first substrate that is attached to the top side of the carrier wafer or substrate 17408 through a first interface region 17414. The edge interface module 17502 includes a second set of one or more co-packaged optical modules 17504 attached to a second substrate 17506 that is attached to the bottom side of the carrier wafer or substrate 17408 through a second interface region 17508. The second set of one or more co-packaged optical modules 17504 can be configured similar to the first set of one or more co-packaged optical modules 17412. By using co-packaged optical modules on both sides of the carrier wafer or substrate 17406, the data throughput provided by the edge interface module 17502 to the one or more application specific integrated circuits 17406 can be increased.

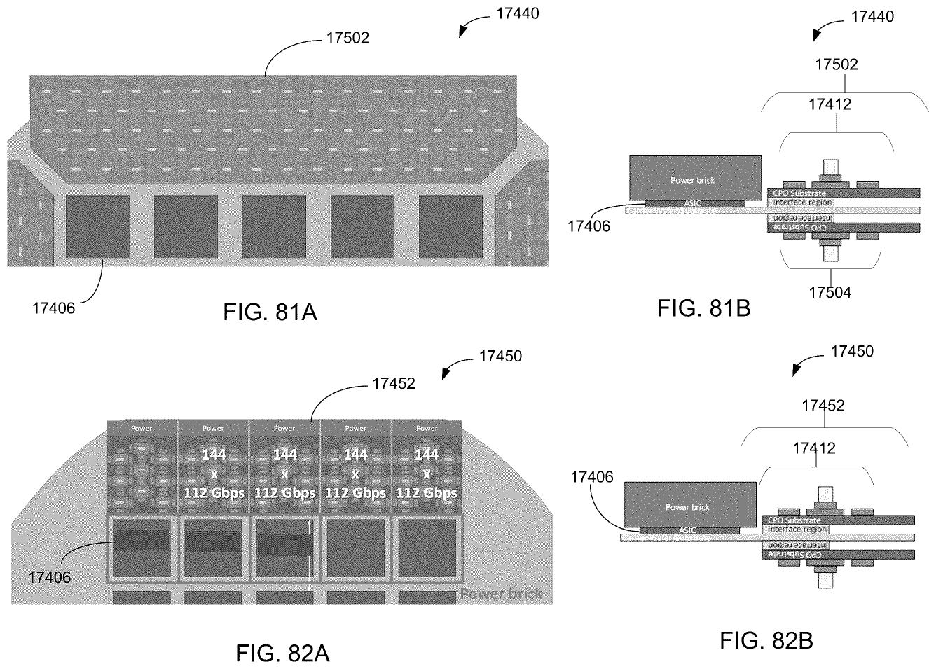

FIGS. 81A and 81B illustrate an example of a double side solution in which the co-packaged optical modules are attached to both sides of the carrier wafer or substrate. FIG. 81A shows a top view of a portion of an example data processing system 17440, including a row of data processors 17406 and an edge interface module 17502. FIG. 81B shows a side view of the portion of the data processing system 17440.

FIGS. 82A and 82B illustrate another example of a double side solution in which the co-packaged optical modules are attached to both sides of the carrier wafer or substrate. FIG. 82A shows a top view of a portion of an example data processing system 17450, including a row of data processors 17406 and an edge interface module 17452. FIG. 82B shows a side view of the portion of the data processing system 17450.

In the following, various examples of the wafer-scale processing systems will be provided. Examples of various parameters of the wafer-scale processing system will be described, such as the rough dimensions of the data processors, the rough dimensions of the edges of the wafer-scale processors, the number of rows of CPO modules included in an edge interface module, the number of CPO modules included in each row, the bandwidth supported by each CPO module, the bandwidth supported by one or more rows of CPO modules, the aggregate bandwidth supported by the edge interface module, the approximate number of bump contacts, the approximate distance between adjacent bump contacts, the approximate distance between adjacent signal lines, etc. It is understood that the values described in this document are merely examples, the invention is not limited to the parameter values described in this document.

In the example of FIG. 76, each data processor 17202 has a substantially square shape. For example, each edge interface module 17302 supports about 150 Tbps bandwidth to the corresponding edge of the wafer-scale data processor 17200. Each edge interface module 17302 can provide up to about 150 Tbps data throughput to the corresponding edge. The four edge interface modules 17302 at the four edges support an aggregate bandwidth of about 600 Tbps to the wafer-scale processor 17200. The four edge interface modules can provide up to about 600 Tbps data throughput to the wafer-scale processor 17200.

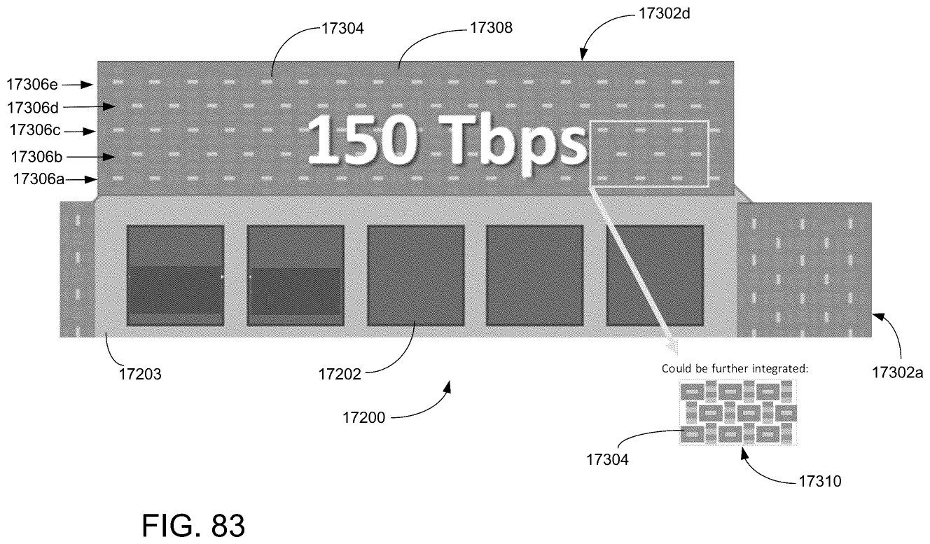

Referring to FIG. 83, in some implementations, each edge interface module 17302 includes multiple rows of co-packaged optical modules 17304. In some implementations, each CPO module 17304 can support a bandwidth of about 1.6 Tbps. It is understood that the CPO modules can also be designed to support other ranges of bandwidths. Different CPO modules 17304 in the edge interface module 17302 can be configured the same or differently, such as supporting different bandwidths, having different photonic integrated circuits, having different driver circuits, and/or having different codecs, etc. Each row extends in a direction parallel to the corresponding edge of the wafer-scale processor 17200. In the example of FIGS. 76 and 83, each row of the co-packaged optical modules in the edge interface modules 17302b and 17302d (which are adjacent to horizontal edges of the wafer-scale processor 17200) extend in the horizontal direction on the drawing sheet, and each row of the co-packaged optical modules in the edge interface modules 17302a and 17302c (which are adjacent to vertical edges of the wafer-scale processor 17200) extend in the vertical direction on the drawing sheet.

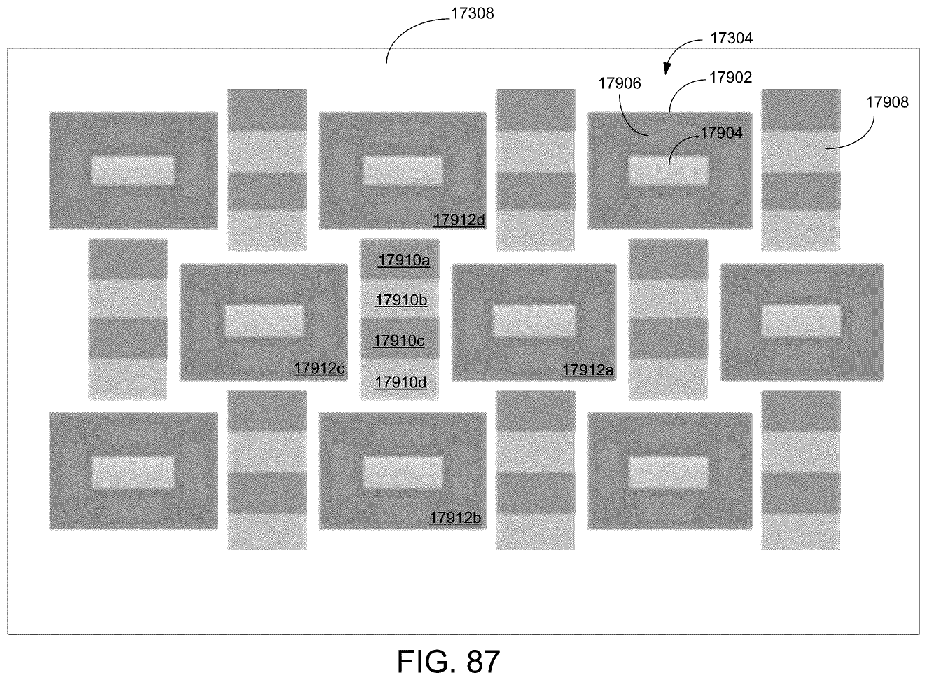

In the example of FIG. 83, each edge interface module 17302 includes a staggered array of 5 rows (17306a, 17306b, 17306c, 17306d, 17306e) of co-packaged optical modules 17304. In this example, the first row 17306a of co-packaged optical modules 17304 support a bandwidth of about 30 Tbps. The first and second rows 17306a, 17306b of co-packaged optical modules 17304 support a bandwidth of about 60 Tbps. The first to third rows 17306a, 17306b, 17306c of co-packaged optical modules 17304 support a bandwidth of about 90 Tbps. The first to fourth rows 17306a, 17306b, 17306c, 17306d of co-packaged optical modules 17304 support a bandwidth of about 120 Tbps. The first to fifth rows 17306a, 17306b, 17306c, 17306d, 17306e of co-packaged optical modules 17304 support a bandwidth of about 150 Tbps. An inset diagram 17310 shows a portion of the 2D array of co-packaged optical modules 17304, which are further enlarged in and described along with FIG. 87.

For example, the staggered array of photonic integrated circuits includes a first row, a second row, and a third row. In the first row, the photonic integrated circuits are positioned at (x, y) coordinates (1, 1), (3, 1), (5, 1), . . . , (n1, 1), n1 being an odd number. In the second row, the photonic integrated circuits are positioned at (x, y) coordinates (2, 2), (4, 2), (6, 2), . . . , (n2, 2), n2 being an even number. In the third row, the photonic integrated circuits are positioned at (x, y) coordinates (1, 3), (3, 3), (5, 3), . . . , (n3, 3), n3 being an odd number. The staggered array of photonic integrated circuits can include additional rows, and the photonic integrated circuits can be positioned in the additional rows in a similar manner.

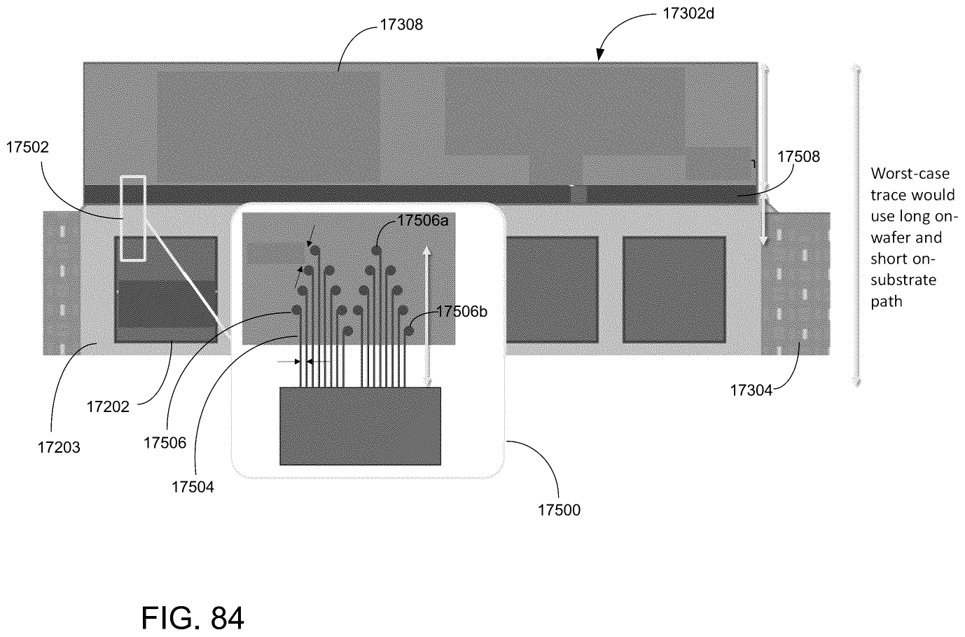

Referring to FIG. 84, metal signal lines or conductive traces 17504 extend from the data processors 17202 positioned at the edge of the wafer-scale processor 17200 to bump contacts 17506 that are electrically coupled to the edge interface module 17302. In examples in which the edge interface modules 17302 are mounted on a substrate 17308, the bump contacts 17506 are electrically coupled to electrical contacts on the underside of the substrate 17308. In the examples in which the edge interface modules 17302 has CPO modules 17304 that are directly mounted on the wafer 17203, the bump contacts 17506 are electrically coupled to electrical contacts on the underside of the co-packaged optical modules 17304. In this example, the co-packaged optical module 17304 includes through-vias that connect the electrical contacts on the underside of the CPO module 17304 to the active components on the top side of the CPO module 17304. In some implementations, contacts on the wafer 17203 are wire bonded to contacts on the top side of the CPO module 17304.

In some implementations, the bump contacts 17506 form a two-dimensional arrangement of bump contacts 17506. For example, the two-dimensional arrangement of bump contacts 17506 include a two-dimensional array of bump contacts 17506. For example, the two-dimensional array of bump contacts 17506 includes a plurality of rows and a plurality of columns of bump contacts 17506. An inset diagram 17500 shows an enlarged view of a portion 17502 near the edge of the substrate 17308 and the edge of the semiconductor wafer 17203.

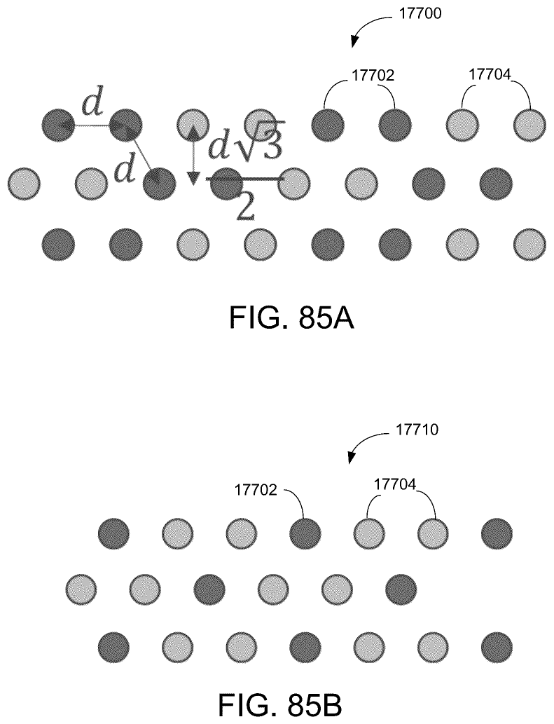

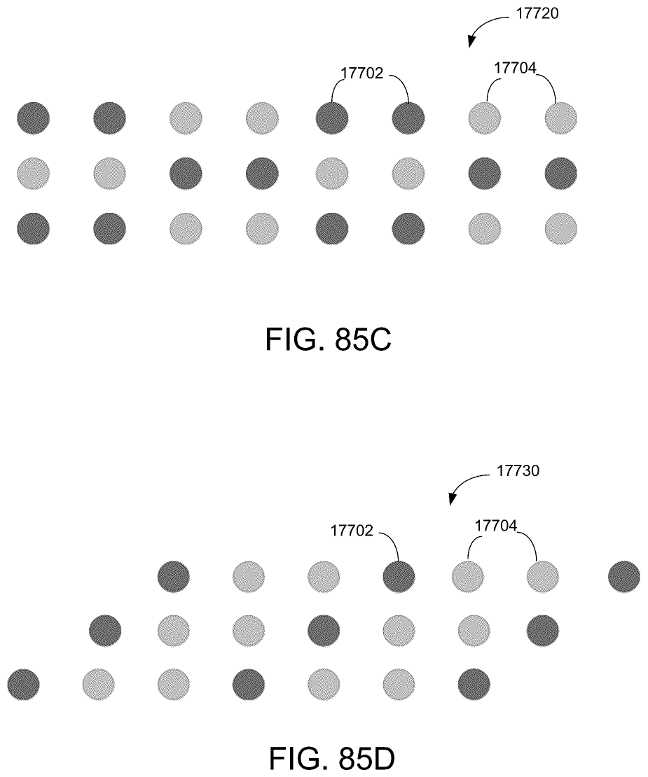

In this example, the edge interface module 17302d supports about 150 Tbps bandwidth to the data processors 17202. For example, about 150 Tbps corresponds to about 1500×100 Gbps, which corresponds to about 6000 lanes (1500×2×2, differential, full-duplex). In some embodiments, ground bumps can be used, which can increase the number of lanes and can consequently reduce the line-to-line spacing. Four example layouts for differential signal bumps and ground bumps with ground bump overheads of 50% and 100%, respectively, are shown in FIGS. 85A to 85D.

FIG. 85A shows a bump pattern 17700 that has a 100% ground bump overhead. The number of group bumps 17702 (shown in blue) is the same as the number of differential signal bumps 17704 (shown in yellow). FIG. 85B shows a bump pattern 17710 that has a 50% ground bump overhead. The number of group bumps 17702 (shown in blue) is about half the number of differential signal bumps 17704 (shown in yellow).

FIG. 85C shows a bump pattern 17720 that has a 100% ground bump overhead. The number of group bumps 17702 (shown in blue) is the same as the number of differential signal bumps 17704 (shown in yellow). FIG. 85D shows a bump pattern 17730 that has a 50% ground bump overhead. The number of group bumps 17702 (shown in blue) is about half the number of differential signal bumps 17704 (shown in yellow).

In the example of FIG. 84, the bump contacts 17506 are arranged in rows on a strip 17508 of area at the edge of the substrate 17308. For example, several hundred bump contacts 17506 can be provided per linear edge. For example, the bump contacts 17506 can be arranged in 12 or more rows.

When high frequency signals (e.g., having a frequency in the gigahertz range) propagate on metal signal lines formed on the semiconductor substrate 17203, the signal degradation can be significant, e.g., about 0.5 dB per mm at 28 GHz. By keeping the lengths of the signal lines 17504 short, the signal loss can be managed within an acceptable range.

The degradation of signals propagating on metal signal lines formed on the ceramic or high-density build-up substrate 17308 can be lower than the signal degradation on metal signal lines formed on the semiconductor wafer 17203. In some implementations, a longer signal line on the wafer 17203 is paired with a shorter signal line on the substrate 17308, and a shorter signal line on the wafer 17203 is paired with a longer signal line on the substrate 17308. For example, the bump contact 17506a is connected to the data processor 17202 with a relatively longer signal line on the wafer 17203, so the bump contact 17506a is electrically coupled to a CPO module 17304 that is positioned closer to the bump contact 17506a. For example, the bump contact 17506b is connected to the data processor 17202 with a relatively shorter signal line on the wafer 17203, so the bump contact 17506b is electrically coupled to a CPO module 17304 that is positioned farther away from the bump contact 17506a. This design allows the maximum signal loss from the CPO module 17304 to the data processors 17202 to be reduced, as compared to another design that connects the bump contact 17506a to a farthest CPO module 17304.

The CPO modules 17304 can be arranged on the substrate 17308 in a number of ways. Referring to FIG. 86A, in some implementations, an edge interface module 17600 includes CPO modules 17304 that are arranged in a regular array of a plurality of rows and a plurality of columns. Referring to FIG. 86B, in some implementations, an edge interface module 17610 includes CPO modules 17304 that are arranged in a staggered array having a plurality of rows and a plurality of columns.

Referring to FIG. 87, in some implementations, the edge interface modules 17302 includes CPO modules 17304 that are similar to the CPO module 16700 of FIG. 69, in which one or more electronic integrated circuits are mounted on the CPO module 17304, and one or more electronic integrated circuits are mounted on the substrate adjacent to the CPO module 17304. For example, the CPO module 17304 includes a photonic integrated circuit 17902 mounted on the substrate 17308. An optical connector 17904 (which can include, e.g., a lens array (e.g., 16706) and a micro optics connector (e.g., 16708), see FIG. 69) optically couples the photonic integrated circuit 17902 to an optical fiber cable, which can include one or more optical fiber cores.

A first set of one or more integrated circuits 17906 are mounted on the top side of the photonic integrated circuit 17902 using, e.g., copper pillars, or solder bumps. The first set of one or more integrated circuits 17906 are positioned adjacent to or near the optical connector 17904. For example, on each photonic integrated circuit 17902, two or more electrical integrated circuits 17906 can be positioned on two or more sides of the optical connector 17904, surrounding or partially surrounding the optical connector 17904. A second set of integrated circuits 17908 are mounted on the substrate 17308 and electrically coupled to the photonic integrated circuit 17902. For example, four integrated circuits 17910a, 17910b, 17910c, 17910d (collectively referenced as 17910) are disposed next to four photonic integrated circuits 17912a, 17912b, 17912c, 17912d (collectively referenced as 17912). For example, the integrated circuit 17910a can process signals transmitted to and/or from the photonic integrated circuit 17912d, the integrated circuit 17910b can process signals transmitted to and/or from the photonic integrated circuit 17912a, the integrated circuit 17910c can process signals transmitted to and/or from the photonic integrated circuit 17912c, and the integrated circuit 17910d can process signals transmitted to and/or from the photonic integrated circuit 17912b.

In some implementations, two or more of the integrated circuits 17910a, 17910b, 17910c, 17910d can be formed as a single integrated circuit that processes signals to/from two or more adjacent photonic integrated circuits 17912.

In some implementations, one or more of the first set of integrated circuits 17906 can include one or more photonic integrated circuits that include both electronic circuitry and optical or optoelectronic components. Similarly, one or more of the second set of integrated circuits 17908 can include one or more photonic integrated circuits that include both electronic circuitry and optical or optoelectronic components. In some embodiments, one or more of photonic integrated circuits 17902 also include integrated electronic circuitry.

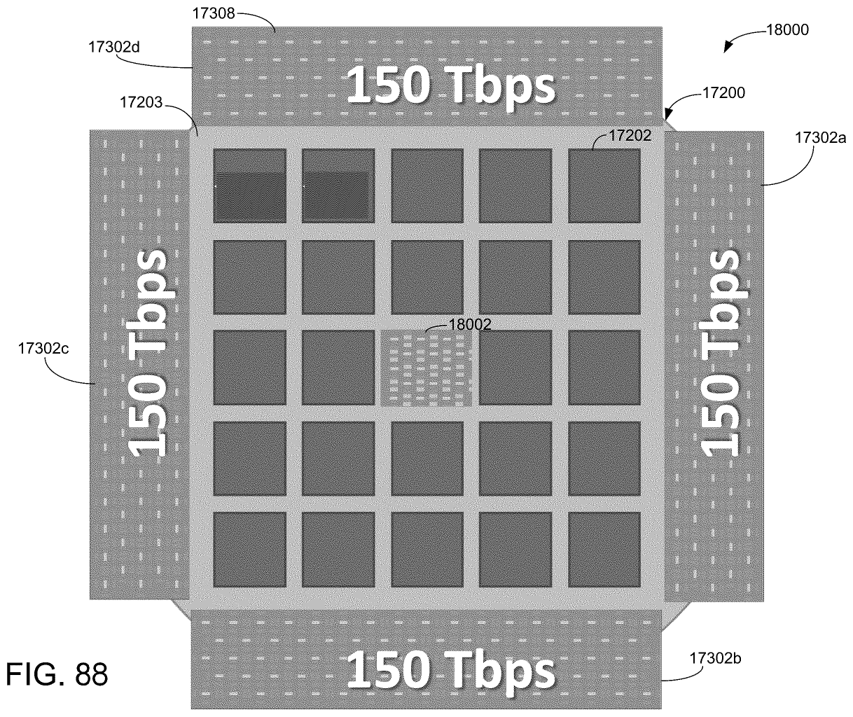

Referring to FIG. 88, in some implementations, in a wafer scale processing system 18000, one or more of the data processors that are not near the edge of the wafer-scale processor are replaced with one or more optical interface modules 18002 that can further increase the input/output bandwidth of the wafer-scale processor. For example, the optical interface module 18002 includes a plurality of CPO modules 17304.

In some implementations, the data processors 17202 in the wafer-scale processor 17200 all have similar configuration and have similar data processing capabilities. In some implementations, the wafer-scale processor includes multiple groups of data processors in which the data processors in different groups having different processing capabilities and different requirements. For example, a first group of data processors can operate at a higher clock frequency and have a higher power consumption, and a second group of data processors can operate at a lower clock frequency and consumes less power. For example, a first group of data processors can be configured with SerDes having less equalization capabilities (sufficient to only bridge the relatively short processor-to-processor links), while a second group of data processors can be configured with SerDes having stronger equalization capabilities (to be able to bridge the relatively longer processor-to-interface module links). The first group of data processors can be positioned near a first set of one or more edges, and the second group of data processors can be positioned near a second set of one or more edges. For example, the edge interface module or modules 17302 that service the first group of data processors can be configured to support a higher bandwidth, and the edge interface module or modules 17302 that service the second group of data processors can be configured to support a lower bandwidth.

For example, a first group of data processors can be configured to process signals encoded according to a first protocol, and a second group of data processors can be configured to process signals encoded according to a second protocol. The first group of data processors can be positioned near a first set of one or more edges, and the second group of data processors can be positioned near a second set of one or more edges. For example, the edge interface module or modules 17302 that service the first group of data processors can be configured to process signals encoded according to the first protocol, and the edge interface module or modules 17302 that service the second group of data processors can be configured to process signals encoded according to the second protocol.

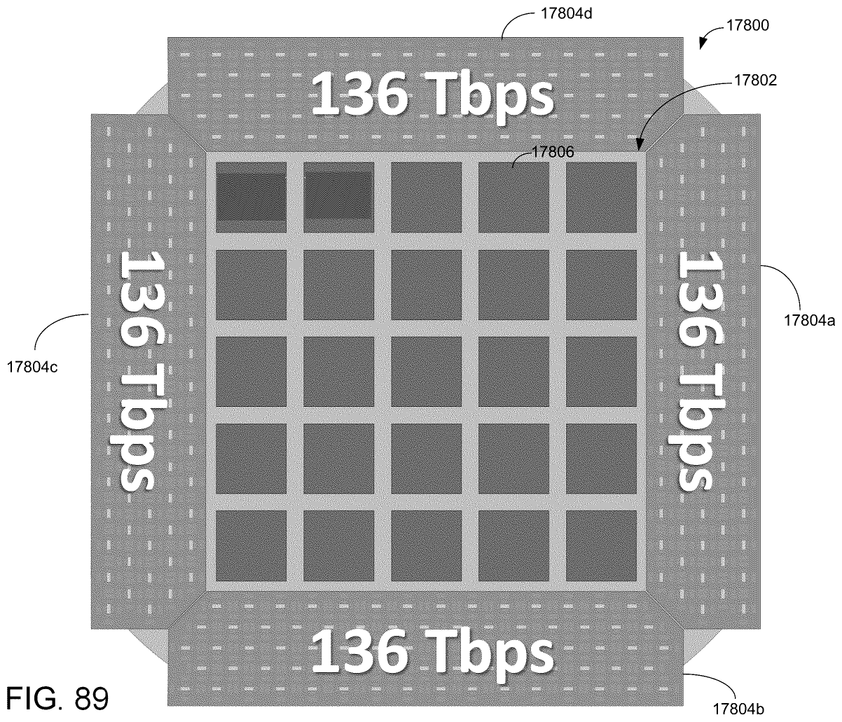

Referring to FIG. 89, in some implementations, a wafer-scale processing system 17800 includes a wafer-scale processor 17802 and edge interface modules 17804a, 17804b, 17804c, 17804d (collectively referenced as 17804) that provide interfaces between the wafer-scale processor 17802 and a plurality of optical links. The wafer-scale processor 17802 includes an array of data processors 17806, and the edge interface modules 17804 are positioned at the edges of the array of data processors 17806. In this example, each data processor 17806 can have a substantially square shape or a rectangular shape. In this example, each edge interface module 17804 is configured to support a bandwidth of about 150 Tbps, and the four edge interface modules 17804 are configured to support an aggregate bandwidth of about 600 Tbps to the wafer-scale processor 17802.

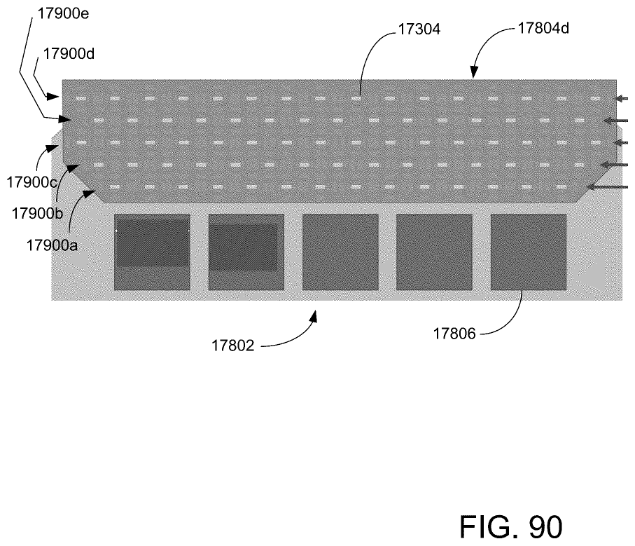

Referring to FIG. 90, for example, the edge interface module 17804d includes 5 rows (17900a, 17900b, 17900c, 17900d, 17900e) of optical interfaces or CPO modules 17304. In this example, the first row 17900a of CPO modules 17304 supports a bandwidth of about 25 Tbps to the edge of the wafer-scale processor 17802. The first and second rows 17900a, 17900b of CPO modules 17304 support a bandwidth of about 50 Tbps. The first to third rows 17900a, 17900b, 17900c of CPO modules 17304 support a bandwidth of about 80 Tbps. The first to fourth rows 17900a, 17900b, 17900c, 17900d of CPO modules 17304 support a bandwidth of about 110 Tbps. The first to fifth rows 17900a, 17900b, 17900c, 17900d, 17900e of CPO modules 17304 support a bandwidth of about 140 Tbps.

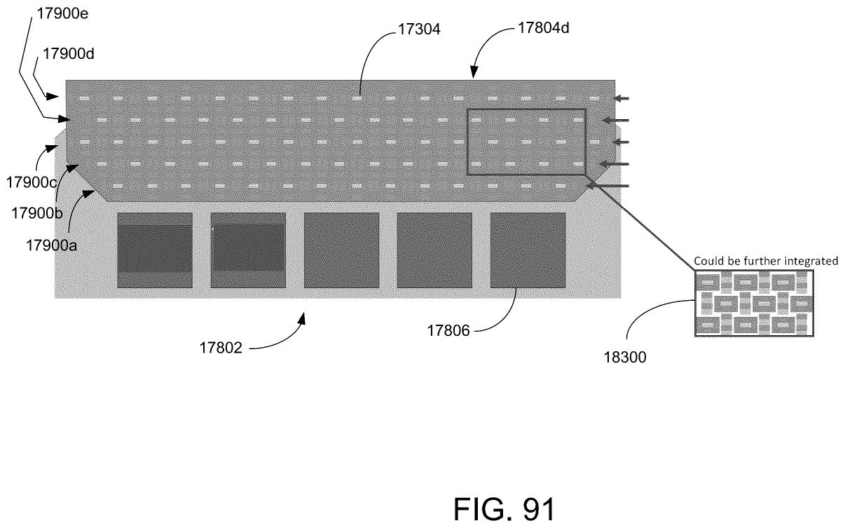

Referring to FIG. 91, an inset diagram 18300 shows a portion of the 2D array of co-packaged optical modules 17304, which can be further integrated. For example, multiple integrated circuits can be integrated into a single integrated circuit or a smaller number of integrated circuits.

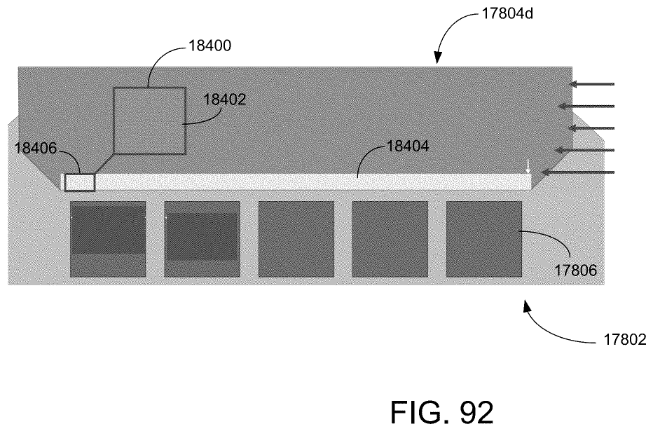

Referring to FIG. 92, in some implementations, the wafer-scale processing system 17800 includes a strip of area 18404 near the edge of the wafer-scale processor 17802, in which a plurality of bump contacts 18402 are provided in the strip of area 18404. For example, the plurality of bump contacts 18402 can include a two-dimensional arrangement of bump contacts 18402. For example, the two-dimensional arrangement of bump contacts 18402 can include an array of bump contacts 18402. For example, the array of bump contacts 18402 can include a plurality of rows and a plurality of columns of bump contacts 18402. An inset diagram 18400 shows an enlarged view of a region 184026 on the strip of area 18404 that includes some of the array of bump contacts 18402.

In some implementations, the edge interface module 17804d supports about 140 Tbps bandwidth, in which 5447 radio frequency signal traces (differential, full-duplex) are used to transmit the signals between the CPO modules in the edge interface module 17804d and the data processors 17806. The number of lanes can depend on the number of ground traces and ground bumps, and/or the width of the strip that is used.

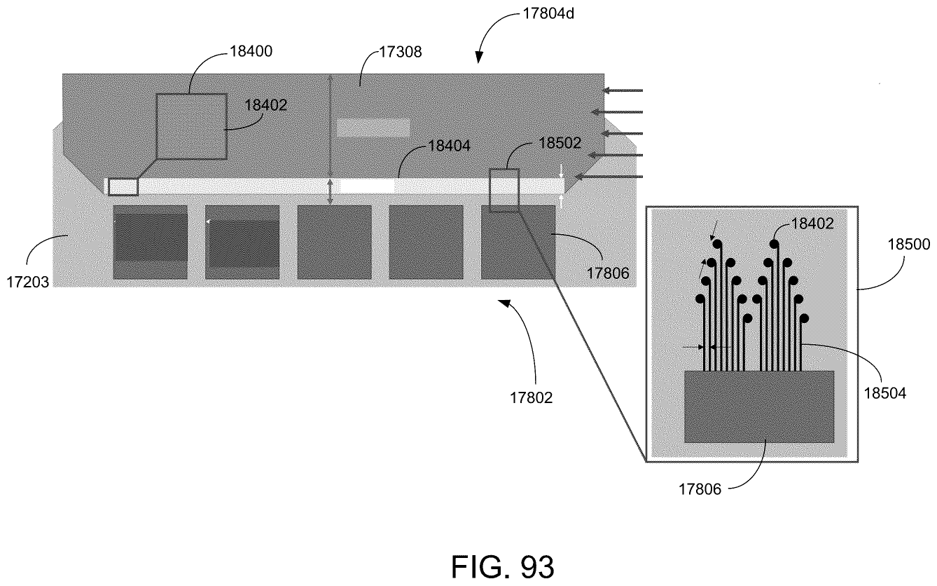

Referring to FIG. 93, an inset diagram 18500 shows an enlarged view of a region 18502 near the edge of the wafer-scale processor 17802 that includes some of the bump contacts 18402 and radio frequency traces 18504 that electrically connects the bump contacts 18402 to the data processor 17806.

In some implementations, a longer signal line on the semiconductor wafer 17203 is paired with a shorter signal line on the substrate 17308, and a shorter signal line on the semiconductor wafer 17203 is paired with a longer signal line on the substrate 17308. This reduces the maximum signal propagation loss for the signals transmitted between the CPO modules of the edge interface module 17804d and the data processors 17806.

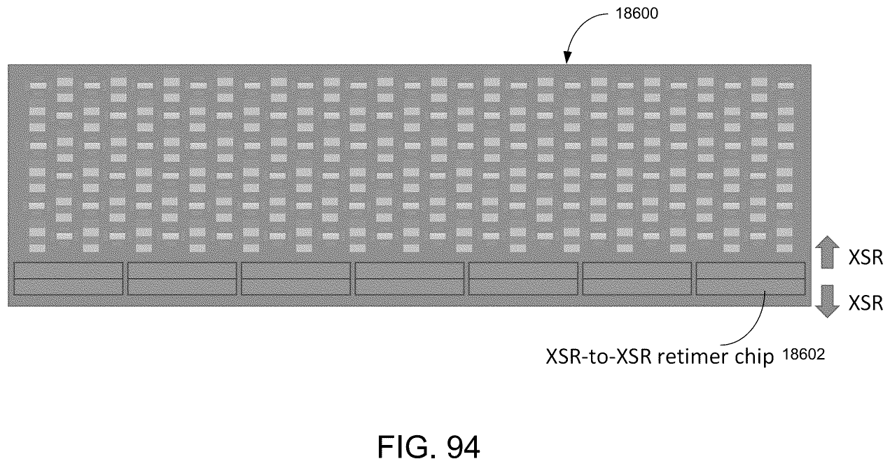

Referring to FIG. 94, in some implementations, an edge interface module 18600 (which corresponds to the edge interface module 17302 of FIGS. 76, 83, 84 or 17804 of FIGS. 89 to 93) includes XSR-to-XSR converters (retimer chips) 18602 near the board edge to regenerate signals.

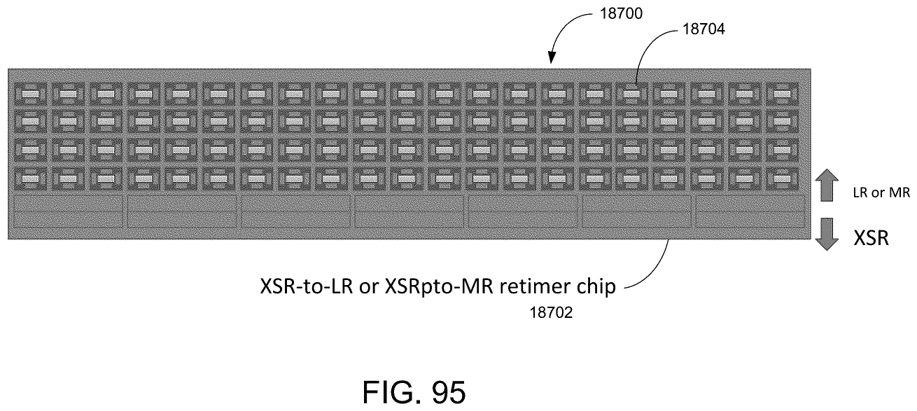

Referring to FIG. 95, in some implementations, an edge interface module 18700 (which corresponds to the edge interface module 17302 of FIGS. 76, 83, 84 or 17804 of FIGS. 89 to 93) includes XSR-to-LR or XSR-to-MR converters (retimer chips) 18702 near the board edge for direct-drive. The edge interface module 18700 includes CPO modules 18704 that do not require XSR retimer chips near the photonic integrated circuits. In this example, the CPO modules do not need to include the integrated circuits 17910 shown in FIG. 87. As a result, the CPO modules 18704 can be arranged more densely, as compared to the configuration shown in FIG. 94. Each row of CPO modules 18704 in the edge interface module 18700 can include more CPO modules 18704 as compared to the example shown in FIG. 94.

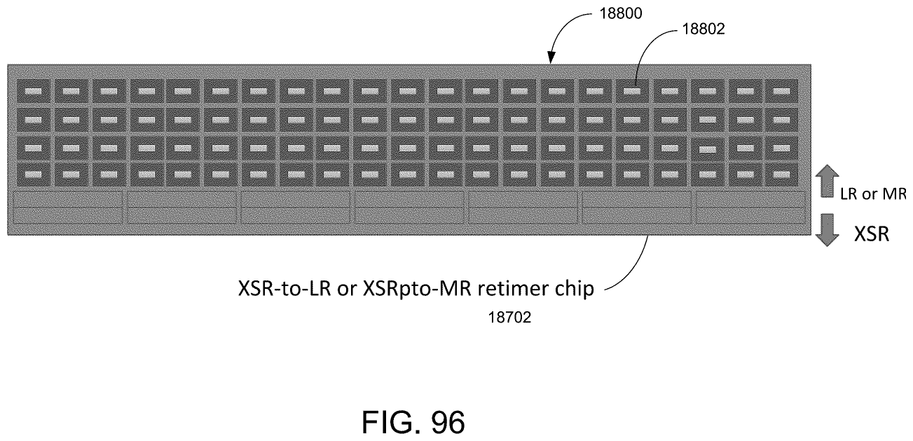

Referring to FIG. 96, in some implementations, an edge interface module 18800 (which corresponds to the edge interface module 17302 of FIGS. 76, 83, 84 or 17804 of FIGS. 89 to 93) includes XSR-to-LR or XSR-to-MR converters (retimer chips) 18702 near the board edge for direct-drive. The edge interface module 18700 includes CPO modules 18802 that do not require XSR retimer chips near the photonic integrated circuits, and also do not require separate driver amplifiers and transimpedance amplifiers (TIAs). In one example, the CPO modules 18802 do not need to include the integrated circuits 17906 and 17910 shown in FIG. 87 because their functionality is integrated into the XSR-to-LR or XSR-to-MR converters. As a result, the CPO modules 18802 can be made simpler at a lower cost, as compared to the configuration shown in FIG. 95. In another example, driver amplifiers and TIAs are monolithically integrated into the photonic integrated circuits.

In some implementations, the photonic integrated circuits (e.g., 17902) can monolithically include driver and TIA electronics, or the driver and TIA electronics can be included in a separate chip. The driver and TIA electronics can directly interface with the data processors (e.g., 17806), referred to as a “direct drive” configuration. For example, the electrical signals output from the driver/TIA electronics associated with the photonic integrated circuits are sent directly to the data processors, and the electrical signals output from the data processors are sent directly to the driver/TIA electronics associated with the photonic integrated circuits.

In some implementations, one or more interface circuits are provided between the photonic integrated circuits and the data processors in order to convert or condition the electrical signals transmitted between the photonic integrated circuits and the data processors. The interface circuits can be, e.g., converters or retimer chips, and can be configured to, e.g., regenerate data, retime data, and/or maintain signal integrity. In some examples, the interface circuits can be positioned on surfaces of the photonic integrated circuits, similar to the integrated circuits 17906 (FIG. 87), or positioned near the photonic integrated circuits, similar to the integrated circuits 17908. In some examples, the interface circuits can be positioned near the edge of the edge interface module near the wafer-scale processor, similar to the examples shown in FIGS. 94 to 96. In some examples, the interface circuits can be integrated into the data processors, similar to the embedded SerDes 247 shown in FIG. 2. In some examples, the interface circuits can be positioned on the wafer-scale processor near the edge interface module. In some examples, the interface circuits can be distributed such that a portion of the interface circuits are positioned on or near the photonic integrated circuits, and another portion of the interface circuits are positioned in or near the data processors. In some examples, the interface circuits can be any combination of the configurations mentioned above.

In some implementations, the photonic integrated circuits output serial electrical signals, and the interface circuits convert the serial electrical signals to parallel electrical signals that are transmitted to the data processors. In some implementations, the photonic integrated circuits output parallel electrical signals, and the interface circuits convert the parallel electrical signals to serial electrical signals that are transmitted to the data processors. In some implementations, the data processors output serial electrical signals, and the interface circuits convert the serial electrical signals to parallel electrical signals that are transmitted to the photonic integrated circuits. In some implementations, the data processors output parallel electrical signals, and the interface circuits convert the parallel electrical signals to serial electrical signals that are transmitted to the photonic integrated circuits. In some implementations, a combination of the configurations described above are used.

The following describes various configurations of interfaces between a photonic integrated circuit and a data processor. It is understood that a single photonic integrated circuit can communicate with one or more data processors, and a single data processor can communicate with one or more photonic integrated circuits. It is understood that an interface circuit can communicate with one or more photonic integrated circuits and one or more data processors. It is understood that a wafer-scale processor can use any combination of the interface circuit configurations described here. In some implementations, the input/output interface of the photonic integrated circuit includes an XLR (extra long reach) SerDes (serializers/deserializers), an LR (long reach) SerDes, an MR (medium reach) SerDes, an XSR (extra short reach) SerDes, or a BoW (bunch of wire) input/output interface. In some implementations, the input/output interface of the data processor includes an XLR SerDes, an LR SerDes, an MR SerDes, an XSR SerDes, or a BoW input/output interface. An interface circuit in the form of a converter or retimer is provided between the photonic integrated circuit and the data processor. The converter or retimer can be, e.g., an XLR-to-XLR retimer, an LR-to-LR retimer, an MR-to-MR retimer, an SR-to-SR retimer, a BoW-to-BoW retimer, an XLR-to-LR converter, an XLR-to-MR converter, an XLR-to-SR converter, an XLR-to-XSR converter, an LR-to-MR converter, an LR-to-SR converter, an LR-to-XSR converter, an MR-to-SR converter, an MR-to-XSR converter, an SR-to-XSR converter, an XLR-to-BoW converter, an LR-to-BoW converter, an MR-to-BoW converter, or an XSR-to-BoW converter.

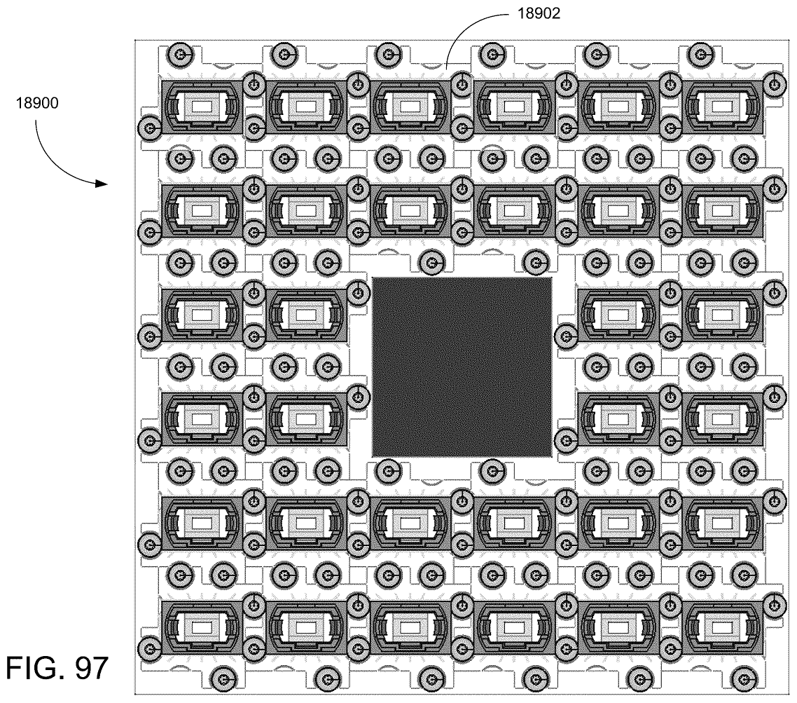

In the edge interface module described above, e.g., 17302 of FIG. 76, 17804 of FIG. 89, 18600 of FIG. 94, 18700 of FIG. 95, 18800 of FIG. 96, the individual photonic integrated circuit can be either pigtailed or connected to the optical fibers. If the photonic integrated circuits are connected to the optical fibers, a single lid 18900 can be built as shown in FIG. 97, with all module lid/heatsink/connector pieces fused together into one single 2D array connector/cooling/lid item. FIG. 97 is a top view of an example of the single lid 18900. The single lid 18900 includes an array of connector/cooling/lid devices 18902 that are combined into a single device.

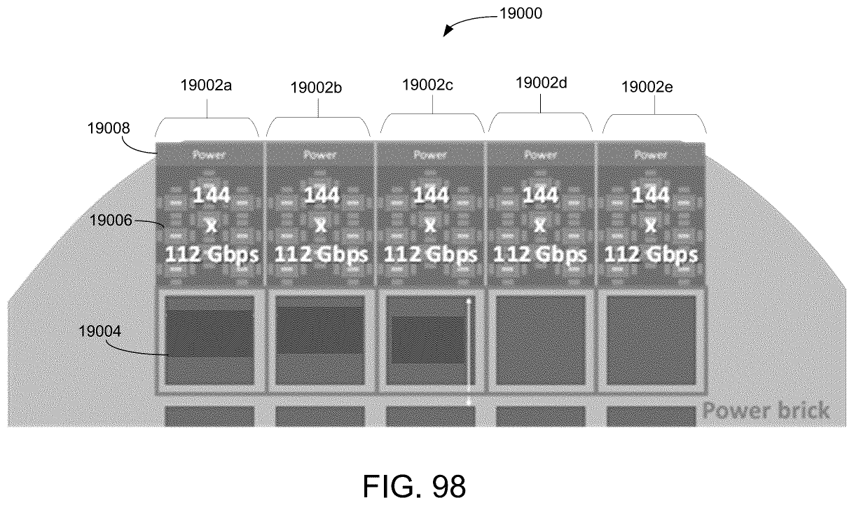

FIG. 98 is a diagram of an example data processing system 19000 that includes split-up edge cards, e.g., 19002a, 19002b, 19002c, 19002d, 19002e (collectively referenced as 19002). In some implementations, the edge card 19002a includes an application specific integrated circuit 19004, a set of one or more co-packaged optical modules 19006, and an optical power supply 19008. The set of one or more co-packaged optical modules 19006 functions as an optical communication interface to the application specific integrated circuit 19004. The optical power supply 19008 provides power supply light to the photonic integrated circuits of the co-packaged optical modules 19006. For example, different edge cards 19002 can be separated from each other prior to being attached to the wafer scale processor. Because each edge card 19002 has a smaller number of co-packaged optical modules, as compared to the entire edge interface module, the yield rate for the edge cards 19002 can be higher than that of an edge interface module that uses a single substrate, so the cost of the multiple edge cards 19002 can be lower compared to using an edge interface module in which all of the co-packaged optical modules are mounted on a single substrate, for a given total number of co-packaged optical modules.

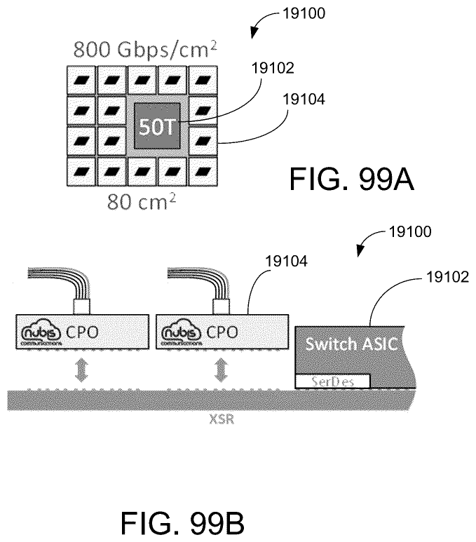

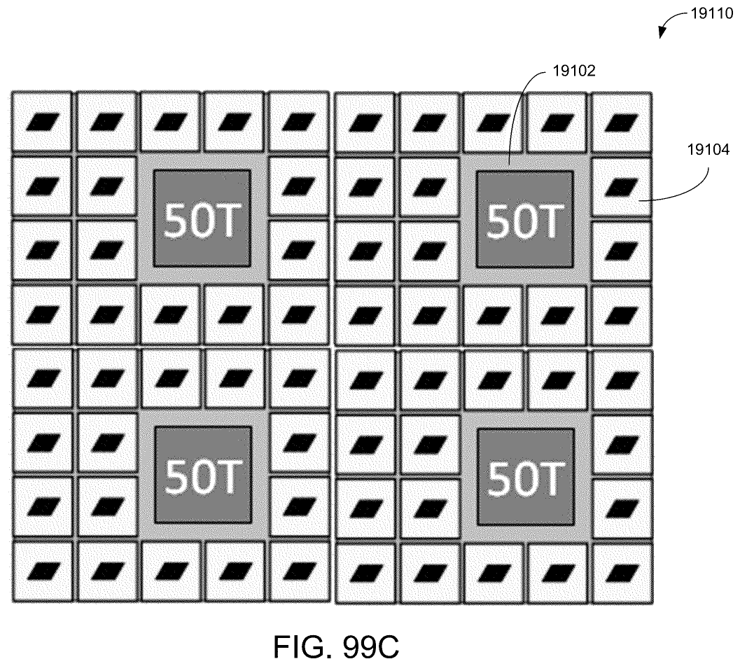

Referring to FIGS. 99A and 99B, in some implementations, two or more co-packaged optical modules can interface with a data processor to increase data throughput to the data processor. FIG. 99A shows a top view of an example system 19100 that includes a data processor 19102 surrounded by a two-dimensional arrangement of, e.g., 16 co-packaged optical modules 19104. FIG. 99B shows a side view of the data processor 19100 positioned adjacent to two of the co-packaged optical modules 19102. For example, the data processor 19100 can have a data processing capability of about 50 Tbps. Each co-packaged optical module 19102 can have a data throughput of about 3.2 Tbps, occupy an area of about 4 cm² and achieve a data throughput density of about 3.2 Tbps/4 cm²=800 Gbps/cm². The data processor 19102 can be configured to fit within a footprint of 4 co-packaged optical modules 19104, or about 16 cm². The data processor 19100 and the 16 co-packaged optical modules 19102 can have an overall footprint of about 80 cm².

FIG. 99C shows a top view of an example system 19110 that includes multiple data processors 19102 each surrounded by a two-dimensional arrangement of, e.g., 16 co-packaged optical modules 19104.

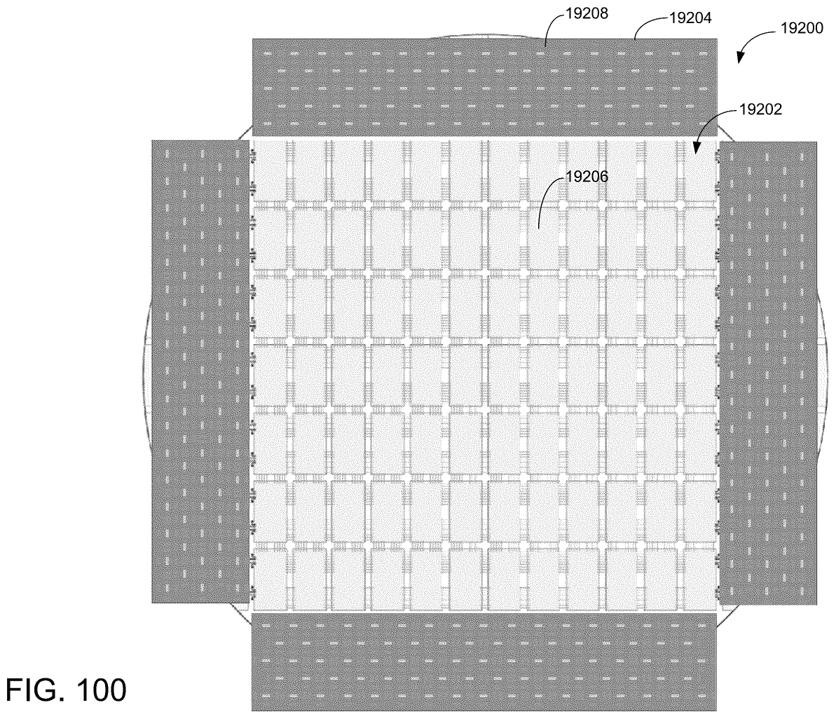

Referring to FIG. 100, an example wafer-scale processing system 19200 includes a wafer-scale processor 19202 and a plurality of edge interface modules 19204 that function as input/output interfaces between the wafer-scale processor 19202 and a plurality of external optical links. In this example, the wafer-scale processor 19202 includes an array of 7 rows and 12 columns of data processors 19206. The wafer-scale processor 19202 can also have a different number of data processors 19206, each data processor 19206 can have a different shape or footprint, and the data processors 19206 can be arranged in a different two-dimensional pattern.

In this example, the wafer-scale processor 19202 includes four edges, and four edge interface modules 19204 are provided near the four edges of the wafer-scale processor 19202. Each edge interface module 19204 includes a plurality of optical input/output (I/O) interfaces 19208, which can be similar to the optical input/output interfaces 17304 of FIG. 76. In some examples, the plurality of optical I/O interfaces 19208 include a two-dimensional arrangement of optical I/O interfaces 19208. In some examples, the two-dimensional arrangement of optical I/O interfaces 19208 includes a two-dimensional array of optical I/O interfaces 19208. In some examples, the two-dimensional array of optical I/O interfaces 19208 includes a plurality of rows and a plurality of columns of optical I/O interfaces 19208. The two-dimensional arrangement does not necessarily have to be a two-dimensional rectilinear arrangement of rows and columns.

In some implementations, each edge interface module 19204 supports about 150 Tbps bandwidth to the corresponding edge of the wafer-scale data processor 19202. Each edge interface module 19204 can provide up to about 150 Tbps data throughput to the corresponding edge. The four edge interface modules 19204 at the four edges support an aggregate bandwidth of about 600 Tbps to the wafer-scale processor 19202. The four edge interface modules can provide up to about 600 Tbps data throughput to the wafer-scale processor 19202.

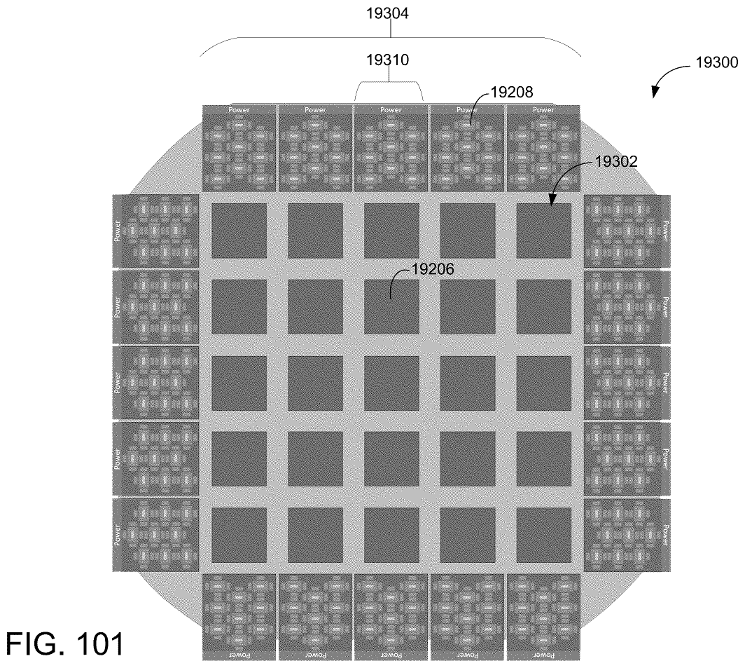

Referring to FIG. 101, an example wafer-scale processing system 19300 includes a wafer-scale processor 19302 and a plurality of edge interface modules 19304 that function as input/output interfaces between the wafer-scale processor 19302 and a plurality of external optical links. In this example, the wafer-scale processor 19302 includes an array of 5 rows and 5 columns of data processors 19306. The wafer-scale processor 19302 can also have a different number of data processors 19306, each data processor 19306 can have a different shape or footprint, and the data processors 19306 can be arranged in a different two-dimensional pattern.

In this example, the wafer-scale processor 19302 includes four edges, and four edge interface modules 19304 are provided near the four edges of the wafer-scale processor 19302. Each edge interface module 19304 includes a plurality of optical input/output (I/O) interfaces 19308, which can be similar to the optical input/output interfaces 17304 of FIG. 76. In some examples, the plurality of optical I/O interfaces 19308 include a two-dimensional arrangement of optical I/O interfaces 19308. In some examples, the two-dimensional arrangement of optical I/O interfaces 19308 includes a two-dimensional array of optical I/O interfaces 19308. In some examples, the two-dimensional array of optical I/O interfaces 19308 includes a plurality of rows and a plurality of columns of optical I/O interfaces 19308. The two-dimensional arrangement does not necessarily have to be a two-dimensional rectilinear arrangement of rows and columns.

In some implementations, each edge interface module 19304 includes 5 edge interface sub-modules 19310 (also referred to as “tiles”), similar to the example shown in FIG. 98. Each edge interface sub-module 19310 includes about 9 optical I/O interfaces 19308, each optical I/O interface 19308 is connected to about 16 optical fibers, resulting in 9×16=144 lanes per edge interface sub-module 19310. Each fiber provides about 112 Gbps data throughput, resulting in about 144×112 Gbps≈16 Tbps data throughput per edge interface sub-module or tile 19310. Each edge interface module 19304 supports about 16*5=80 Tbps bandwidth to the corresponding edge of the wafer-scale data processor 19302. Each edge interface module 19304 provides up to about 80 Tbps data throughput to the corresponding edge. The four edge interface modules 19204 at the four edges support an aggregate bandwidth of about 320 Tbps to the wafer-scale processor 19202. The four edge interface modules can provide up to about 320 Tbps data throughput to the wafer-scale processor 19202.

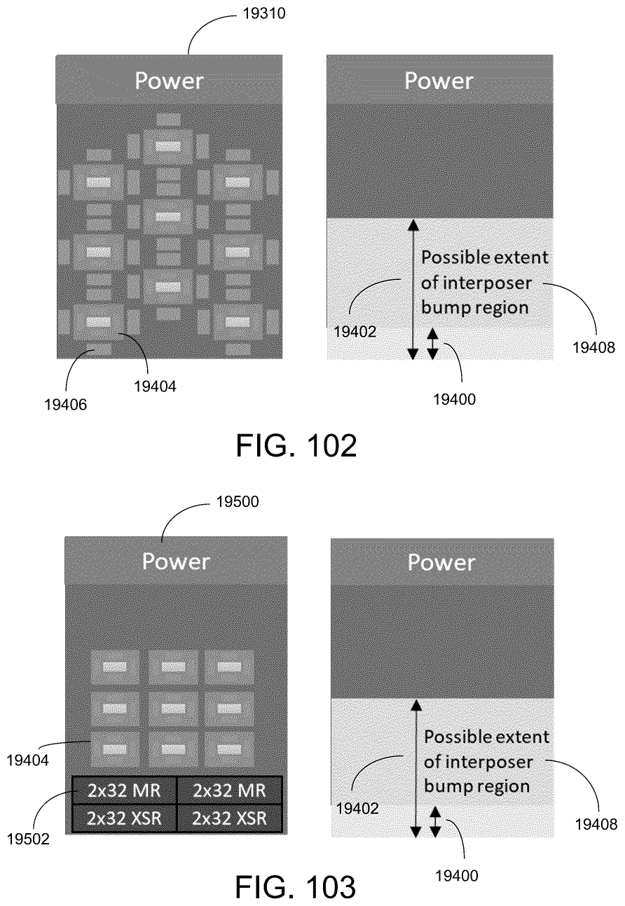

FIG. 102 shows at the left portion of the figure a diagram of the edge interface sub-module or tile 19310 of FIG. 101. In this example, each photonic integrated circuit 19404 is surrounded by individual SerDes chiplets 19406. The right portion of FIG. 102 shows a diagram illustrating the possible extent of interposer bump region 17408, which can have a smaller footprint as indicated by the range 19400, or have a larger footprint as indicated by the range 19402.

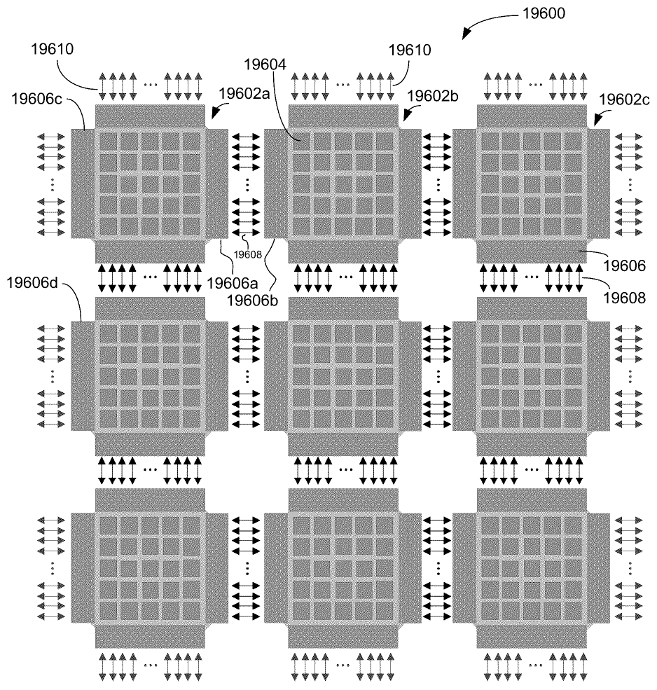

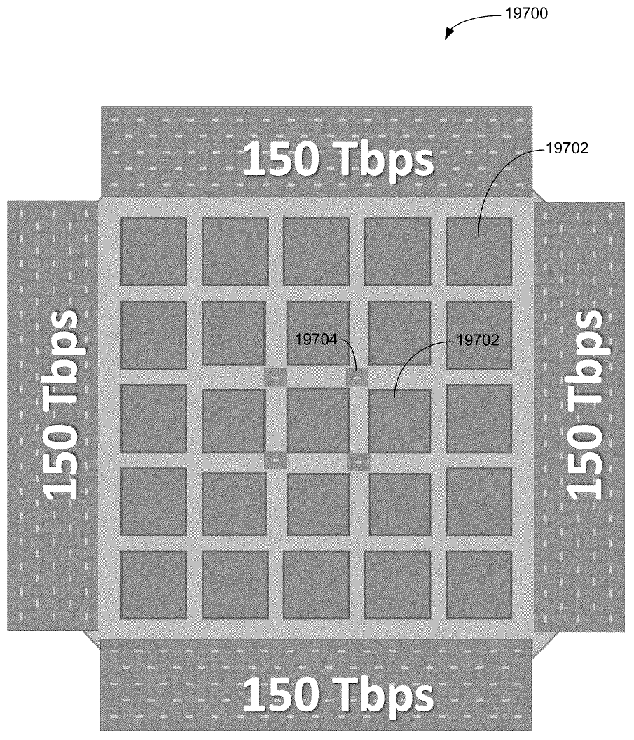

FIG. 103 shows at the left portion of the figure a diagram of an edge interface sub-module or tile 19500 that adopts a direct-drive solution in which no individual SerDes chiplets are provided directly around the photonic integrated circuit 19404, but rather, large SerDes chips 19502 are provided at the card edge. In this example, large XSR-to-MR converters (retimer chips) 19502 are provided near the board edge to regenerate signals. The right portion of FIG. 103 shows a diagram illustrating the possible extent of interposer bump region 17408, which can have a smaller footprint as indicated by the range 19400, or have a larger footprint as indicated by the range 19402.

Referring to FIG. 104, in some implementations, a multi-wafer data processing system 19600 includes multiple wafer scale processing modules, e.g., 19602a, 19602b, 19602c (collectively referenced as 19602) that communicate with one another using optical links. The multiple wafer scale processing modules 19602 can have a two-dimensional arrangement, such as a two-dimensional matrix arrangement of rows and columns of wafer scale processing modules 19602. Each wafer scale processing module 19602 includes multiple data processors 19604 and multiple edge interface modules 19606, similar to the wafer scale processing systems 17300 (FIG. 76), 18000 (FIG. 88), 17800 (FIG. 89), 19200 (FIG. 100), and 19300 (FIG. 101). Edge interface modules, e.g., 19606a and 19606b, that are positioned between two wafer scale processing modules, e.g., 19602a and 19602b, and optical fibers (represented by black double-arrow lines 19608) between the edge interface modules (e.g., 19606a, 19606b), provide optical communication links between the wafer scale processing modules (e.g., 19602a, 19602b). Edge interface modules, e.g., 19606c and 19606d, that are position at the outer edges of the multi-wafer data processing system 19600 connect to optical fibers (represented by red double-arrow lines 19610) that connect to the outside world, e.g., to switches, general-purpose processors, and/or storage devices.

In some implementations, an integrated heat dissipating device or cooling device can be provided for the data processors (e.g., 17202 of FIG. 76) of the wafer-scale processor (e.g., 17200) and the optical I/O interfaces (e.g., 17304) at the edge interface modules (e.g., 17302). For example, the heat dissipating device or cooling device can be cooled by gas (e.g., air) or liquid. For example, a recirculating reservoir can be provided, in which the recirculating reservoir circulates a coolant to carry heat away from the heat dissipating device or cooling device. By integrating the heat dissipating device or cooling device for data processors (e.g., 17202) of the wafer-scale processor and the heat dissipating device or cooling device for the optical I/O interfaces (e.g., 17304) at the edge interface modules (e.g., 17302) into a single integrated heat dissipating device or cooling device, a single recirculating reservoir can be used to circulate a coolant to carry away heat generated by both the data processors and the I/O interface modules.

Referring to FIG. 105, in some implementations, a wafer scale processing system 19700 includes a two-dimensional arrangement of data processors 19702 mounted on a carrier wafer or substrate, and co-packaged optical modules 19704 positioned between the data processors 19702. The data processors 19702 can have, e.g., square or rectangular shapes. The co-packaged optical modules 19704 can increase the communication bandwidth for the data processors 19702 in the vicinity of the co-packaged optical modules 19704. In some examples, at least some of the data processors 19702 have arbitrary shapes that are not necessarily square or rectangular shapes. For example, some of the data processors 19702 can have reduced areas in order to provide more space to accommodate the co-packaged optical modules 19704 positioned near the data processors 19702.

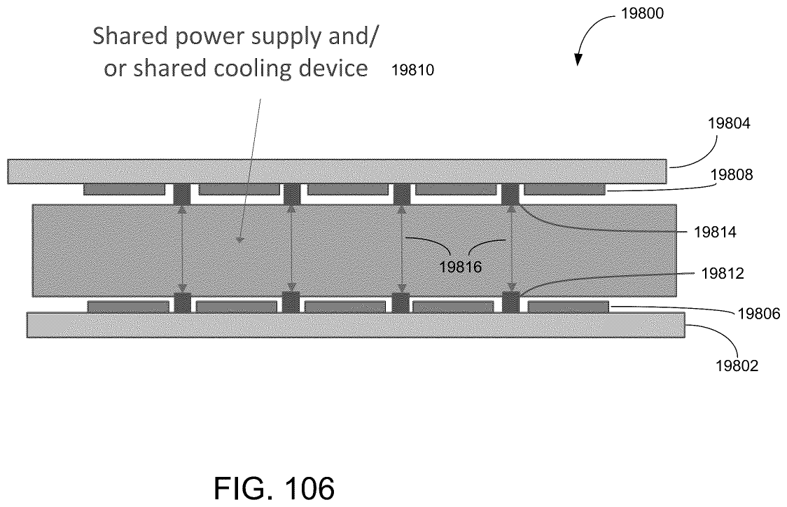

Referring to FIG. 106, in some implementations, a multi-wafer data processing system 19800 includes a first wafer scale processing module 19802 and a second wafer scale processing module 19804. Each of the first and second wafer scale processing module 19802, 19804 includes a plurality of data processors (or any type of application specific integrated circuits) mounted on a carrier wafer or substrate, similar to the examples shown in FIGS. 76, 88, 89, 100, and 101. The data processors of the first wafer scale processing module 19802 can be the same as, similar to, or different from the data processors of the second wafer scale processing module 19804. The second wafer scale processing module 19804 is “flipped over” such that data processors 19806 of the first wafer scale processing module 19802 face data processors 19808 of the second wafer scale processing module 19804. A shared power supply and/or cooling device 19810 is positioned between the data processors 19806 and the data processors 19808. The shared power supply provides power to the data processors 19806 and the data processors 19808. The shared cooling device removes heat generated by the data processors 19806 and the data processors 19808.

One or more co-packaged optical modules 19812 are positioned between the data processors 19806, and one or more co-packaged optical modules 19814 are positioned between the data processors 19808. The co-packaged optical modules 19812 communicate with the co-packaged optical modules 19814 through one or more optical fibers 19816. The co-packaged optical modules 19812 and 19814, and the one or more optical fibers 19816 provide one or more optical communication links between the wafer-scale processing module 19802 and the wafer-scale processing module 19804. In this example, the shared power supply and/or shared cooling device 19810 include one or more openings to allow the one or more optical fibers 19816 to pass through.

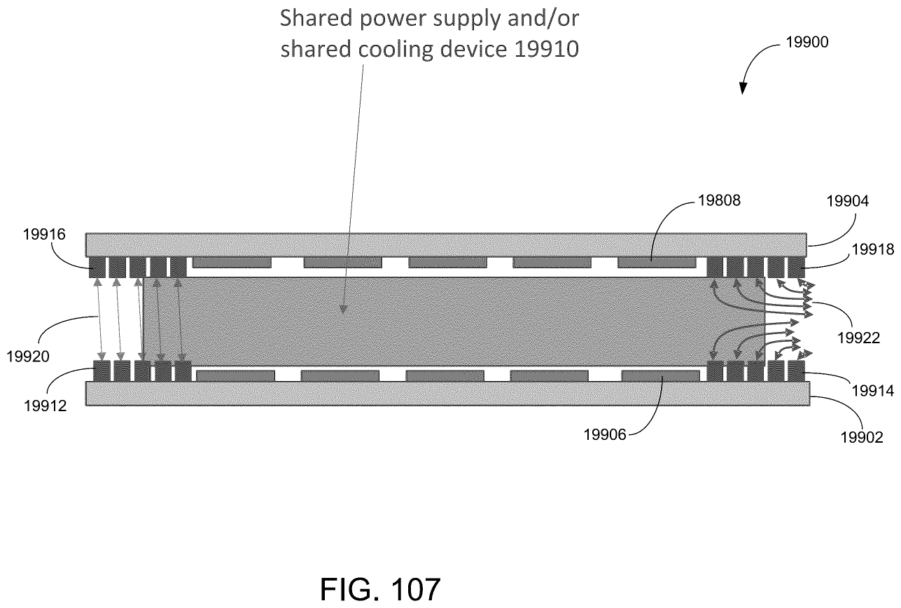

Referring to FIG. 107, in some implementations, a multi-wafer data processing system 19900 includes a first wafer scale processing module 19902 and a second wafer scale processing module 19904. Each of the first and second wafer scale processing module 19902, 19904 includes a plurality of data processors (or any type of application specific integrated circuits) mounted on a carrier wafer or substrate, similar to the example shown in FIG. 106. The second wafer scale processing module 19904 is “flipped over” such that data processors 19906 of the first wafer scale processing module 19902 face data processors 19908 of the second wafer scale processing module 19904. A shared power supply and/or cooling device 19910 is positioned between the data processors 19906 and the data processors 19908. The shared power supply provides power to the data processors 19906 and the data processors 19908. The shared cooling device removes heat generated by the data processors 19906 and the data processors 19908.

The first wafer scale processing module 19902 includes a plurality of co-packaged optical modules, e.g., 19912, 19914, positioned near one or more edges of the wafer scale processing module 19902. The second wafer scale processing module 19904 includes a plurality of co-packaged optical modules, e.g., 19916, 19918, positioned near one or more edges of the wafer scale processing module 19904. One or more of the co-packaged optical modules 19912 of the first wafer scale processing module 19902 and one or more of the co-packaged optical modules 19916 of the second wafer scale processing module 19904 are optically connected through one or more optical fibers 19920. At least some of the co-packaged optical modules 19914 of the first wafer scale processing module 19902 and at least some of the co-packaged optical modules 19918 of the second wafer scale processing module 19904 are connected to optical fibers 19922 that connect to external devices, such as switches, general-purpose processors, and/or storage devices.

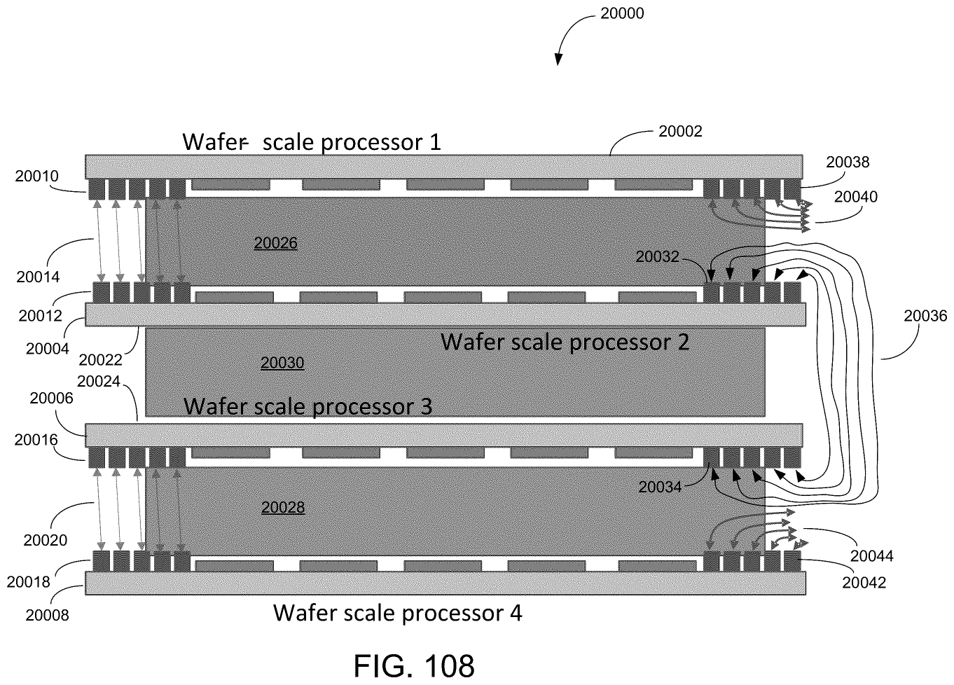

Referring to FIG. 108, in some implementations, a multi-wafer data processing system 20000 includes a first wafer scale processing module 20002, a second wafer scale processing module 20004, a third wafer scale processing module 20006, and a fourth wafer scale processing module 20008. Each of the first, second, third, and fourth wafer scale processing modules 20002, 20004, 20006, 20008 includes a plurality of data processors (or any type of application specific integrated circuits) mounted on a carrier wafer or substrate, similar to the example shown in FIG. 106.

The first wafer scale processing module 20002 is “flipped over” such that the data processors of the first wafer scale processing module 20002 face the data processors of the second wafer scale processing module 20004. A shared power supply and/or cooling device 20026 is positioned between the data processors of the first wafer scale processing module 20002 and the data processors of the second wafer scale processing module 20004. The third wafer scale processing module 20006 is “flipped over” such that the data processors of the third wafer scale processing module 20006 face the data processors of the fourth wafer scale processing module 20008. A shared power supply and/or cooling device 20028 is positioned between the data processors of the third wafer scale processing module 20006 and the data processors of the fourth wafer scale processing module 20008.

In some implementations, the first and second wafer scale processing modules 20002 and 20004 are optically linked through one or more co-packaged optical modules 20010 on the first wafer scale processing module 20002, one or more co-packaged optical modules 20012 on the second wafer scale processing module 20004, and one or more optical fibers 20014 connected between the one or more co-packaged optical modules 20010 and the one or more co-packaged optical modules 20012, similar to the example shown in FIG. 107.

For example, the third and fourth wafer scale processing modules 20006 and 20008 are optically linked through one or more co-packaged optical modules 20016 on the third wafer scale processing module 20006, one or more co-packaged optical modules 20018 on the fourth wafer scale processing module 20008, and one or more optical fibers 20020 connected between the one or more co-packaged optical modules 20016 and the one or more co-packaged optical modules 20018.

In some implementations, the second wafer scale processing module 20004 and the third wafer scale processing module 20006 are positioned back-to-back such that the back side of the carrier wafer or substrate 20022 of the second wafer scale processing module 20004 faces the back side of the carrier wafer or substrate 20024 of the third wafer scale processing module 20006. For example, the second and third wafer scale processing modules 20004 and 20006 are optically linked through one or more co-packaged optical modules 20032 on the second wafer scale processing module 20004, one or more co-packaged optical modules 20034 on the third wafer scale processing module 20006, and one or more optical fibers 20036 connected between the one or more co-packaged optical modules 20032 and the one or more co-packaged optical modules 20034.

A shared power supply and/or cooling device 20030 is positioned between the carrier wafer or substrate 20022 of the second wafer scale processing module 20004 and the carrier wafer or substrate 20024 of the third wafer scale processing module 20006. The shared power supply provides power to the data processors of the second and third wafer scale processing modules 20004, 20006, e.g., through electrical conduction lines that pass through the carrier wafer or substrate 20022 and 20024. The shared cooling device removes heat generated by the data processors of the second and third wafer scale processing modules 20004, 20006, e.g., through thermal conduction paths that pass through the carrier wafer or substrate 20022 and 20024.

In some implementations, the first wafer scale processing module 20002 and the third wafer scale processing module 20006 are optically linked through one or more co-packaged optical modules of the first wafer scale processing module 20002, one or more co-packaged optical modules of the third wafer scale processing module 20006, and one or more optical fibers connected between the one or more co-packaged optical modules of the first wafer scale processing module 20002 and the one or more co-packaged optical modules of the third wafer scale processing module 20006.

In some implementations, the first wafer scale processing module 20002 and the fourth wafer scale processing module 20008 are optically linked through one or more co-packaged optical modules of the first wafer scale processing module 20002, one or more co-packaged optical modules of the fourth wafer scale processing module 20008, and one or more optical fibers connected between the one or more co-packaged optical modules of the first wafer scale processing module 20002 and the one or more co-packaged optical modules of the fourth wafer scale processing module 20008.

In some implementations, the second wafer scale processing module 20004 and the fourth wafer scale processing module 20008 are optically linked through one or more co-packaged optical modules of the second wafer scale processing module 20004, one or more co-packaged optical modules of the fourth wafer scale processing module 20008, and one or more optical fibers connected between the one or more co-packaged optical modules of the second wafer scale processing module 20004 and the one or more co-packaged optical modules of the fourth wafer scale processing module 20008.

In some implementations, some of the co-packaged optical modules 20038 of the first wafer scale processing module 20002 are connected to optical fibers 20040 that connect to external devices, such as switches, general-purpose processors, and/or storage devices. Some of the co-packaged optical modules 20042 of the fourth wafer scale processing module 20008 are connected to optical fibers 20044 that connect to external devices, such as switches, general-purpose processors, and/or storage devices.

In some implementations, some of the co-packaged optical modules of the second wafer scale processing module 20004 are connected to optical fibers that connect to external devices. Some of the co-packaged optical modules of the third wafer scale processing module 20006 are connected to optical fibers that connect to external devices.

In some implementations, the second and/or third wafer scale processing modules 20004, 20006 includes edge interface modules that have co-packaged optical modules mounted to both sides of the carrier wafer or substrate, similar to the example shown in FIG. 80. The co-packaged optical modules on the carrier wafer or substrate of the first wafer scale processing module 20002 that are facing downwards are optically connected to the co-packaged optical modules on the carrier wafer or substrate of the second wafer scale processing module 20004 that are facing upwards. The co-packaged optical modules on the carrier wafer or substrate of the second wafer scale processing module 20002 that are facing downwards are optically connected to the co-packaged optical modules on the carrier wafer or substrate of the third wafer scale processing module 20006 that are facing upwards.

In the example of FIG. 108, the large scale data processing system 20000 includes four wafer-scale processing modules that are vertically stacked together. It is also possible to configure a large scale data processing module to have three, five, six, or more wafer scale processing modules stacked vertically. By using optical fibers and co-packaged optical modules to provide optical communication links between the wafer scale processing modules, three or more wafer scale processing modules can be vertically stacked together while still having a high data throughput among the wafer scale processing modules. By vertically stacking the three or more wafer scale processing modules, the large scale data processing system can be made compact and occupy a small horizontal footprint. The vertical stacking of the three or more wafer scale processing modules allows sharing of resources between two adjacent wafer scale processing modules, such as sharing power supplies and/or cooling devices.

In some implementations, a large scale multi-wafer processing system includes multiple multi-wafer processing modules that are arranged in a two-dimensional array, in which each multi-wafer processing module includes multiple wafer-scale processing modules vertically stacked together. For example, a large scale multi-wafer processing system can include 36 wafer-scale processing modules that are arranged in a 3-by-3 array of multi-wafer processing modules, in which each multi-wafer processing module includes 4 wafer-scale processing modules vertically stacked together. Optical communicate links can be provided between wafer-scale processing modules that are adjacent to each other horizontally, or between wafer-scale processing modules that are adjacent to each other vertically. Optically communication links can also be provided between wafer-scale processing modules that are not adjacent to each other.

In the examples described above, the circuit boards and/or the substrates can be replaced with, or used in combination with, silicon interposers, embedded interposers, and/or glass interposers. For example, the photonic integrated circuits and the electronic integrated circuits of co-packaged optical modules can be mounted on silicon interposers, which in turn can be mounted on other wafers, substrates, or circuit boards.

In this document, when we say that the photonic integrated circuit receives first optical signals and generates first electrical signals based on the first optical signals, and the data processor receives the first electrical signals, it is understood that the data processor can receive the first electrical signals directly (in a direct drive configuration) or through an interface circuit (e.g., an XSR-to-LR or XSR-to-MR converter/retimer, or any other type of converter/retimer described above). The first electrical signals received by the data processor do not necessary have the same format as the first electrical signals generated by the photonic integrated circuit, and the interface circuit performs translation, retiming, or conditioning between the different formats of electrical signals.

While this disclosure includes references to illustrative embodiments, this specification is not intended to be construed in a limiting sense. Various modifications of the described embodiments, as well as other embodiments within the scope of the disclosure, which are apparent to persons skilled in the art to which the disclosure pertains are deemed to lie within the principle and scope of the disclosure, e.g., as expressed in the following claims.

For example, the techniques described above for improving the operations of systems that include rackmount servers can also be applied to systems that include blade servers.

Some embodiments can be implemented as circuit-based processes, including possible implementation on a single integrated circuit.

Unless explicitly stated otherwise, each numerical value and range should be interpreted as being approximate as if the word “about” or “approximately” preceded the value or range.

It will be further understood that various changes in the details, materials, and arrangements of the parts which have been described and illustrated in order to explain the nature of this disclosure can be made by those skilled in the art without departing from the scope of the disclosure, e.g., as expressed in the following claims.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the disclosure. The appearances of the phrase “in one embodiment” in various places in the specification are not necessarily all referring to the same embodiment, nor are separate or alternative embodiments necessarily mutually exclusive of other embodiments. The same applies to the term “implementation.”

Unless otherwise specified herein, the use of the ordinal adjectives “first,” “second,” “third,” etc., to refer to an object of a plurality of like objects merely indicates that different instances of such like objects are being referred to, and is not intended to imply that the like objects so referred-to have to be in a corresponding order or sequence, either temporally, spatially, in ranking, or in any other manner.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

As used herein in reference to an element and a standard, the term compatible means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

The described embodiments are to be considered in all respects as only illustrative and not restrictive. In particular, the scope of the disclosure is indicated by the appended claims rather than by the description and figures herein. All changes that come within the meaning and range of equivalency of the claims are to be embraced within their scope.

The description and drawings merely illustrate the principles of the disclosure. It will thus be appreciated that those of ordinary skill in the art will be able to devise various arrangements that, although not explicitly described or shown herein, embody the principles of the disclosure and are included within its spirit and scope. Furthermore, all examples recited herein are principally intended expressly to be only for pedagogical purposes to aid the reader in understanding the principles of the disclosure and the concepts contributed by the inventor(s) to furthering the art, and are to be construed as being without limitation to such specifically recited examples and conditions. Moreover, all statements herein reciting principles, aspects, and embodiments of the disclosure, as well as specific examples thereof, are intended to encompass equivalents thereof.

The functions of the various elements shown in the figures, including any functional blocks labeled or referred to as “processors” and/or “controllers,” can be provided through the use of dedicated hardware as well as hardware capable of executing software in association with appropriate software. When provided by a processor, the functions can be provided by a single dedicated processor, by a single shared processor, or by a plurality of individual processors, some of which can be shared. Moreover, explicit use of the term “processor” or “controller” should not be construed to refer exclusively to hardware capable of executing software, and can implicitly include, without limitation, digital signal processor (DSP) hardware, network processor, application specific integrated circuit (ASIC), field programmable gate array (FPGA), read only memory (ROM) for storing software, random access memory (RAM), and non-volatile storage. Other hardware, conventional and/or custom, can also be included. Similarly, any switches shown in the figures are conceptual only. Their function can be carried out through the operation of program logic, through dedicated logic, through the interaction of program control and dedicated logic, or even manually, the particular technique being selectable by the implementer as more specifically understood from the context.

As used in this application, the term “circuitry” can refer to one or more or all of the following: (a) hardware-only circuit implementations (such as implementations in only analog and/or digital circuitry); (b) combinations of hardware circuits and software, such as (as applicable): (i) a combination of analog and/or digital hardware circuit(s) with software/firmware and (ii) any portions of hardware processor(s) with software (including digital signal processor(s)), software, and memory(ies) that work together to cause an apparatus, such as a mobile phone or server, to perform various functions); and (c) hardware circuit(s) and or processor(s), such as a microprocessor(s) or a portion of a microprocessor(s), that requires software (e.g., firmware) for operation, but the software does not need to be present when it is not needed for operation.” This definition of circuitry applies to all uses of this term in this application, including in any claims. As a further example, as used in this application, the term circuitry also covers an implementation of merely a hardware circuit or processor (or multiple processors) or portion of a hardware circuit or processor and its (or their) accompanying software and/or firmware. The term circuitry also covers, for example and if applicable to the particular claim element, a baseband integrated circuit or processor integrated circuit for a mobile device or a similar integrated circuit in server, a cellular network device, or other computing or network device.

It should be appreciated by those of ordinary skill in the art that any block diagrams herein represent conceptual views of illustrative circuitry embodying the principles of the disclosure.

Although the present invention is defined in the attached claims, it should be understood that the present invention can also be defined in accordance with the following embodiments:

Embodiment 1: A system comprising:
a first optical input/output module comprising a plurality of photonic integrated circuits arranged in a two-dimensional pattern comprising at least three photonic integrated circuits, in which each of at least some of the photonic integrated circuits is configured to receive first optical signals and generate first electrical signals based on the first optical signals, each of at least some of the photonic integrated circuits is configured to receive second electrical signals and generate second optical signals based on the second electrical signals; and
at least one data processor that is configured to receive, directly or through an interface circuit, the first electrical signals generated by at least some of the photonic integrated circuits, and to transmit, directly or through the interface circuit, the second electrical signals to at least some of the photonic integrated circuits.

Embodiment 2: The system of embodiment 1 in which the first optical input/output module comprises a plurality of photonic integrated circuits arranged in a two-dimensional array comprising at least two rows and at least two columns of photonic integrated circuits.

Embodiment 3: The system of embodiment 1 or 2 in which the first optical input/output module comprises:
a plurality of optical connectors, in which each optical connector is associated with a photonic integrated circuit, the optical connector is coupled to a first surface of the photonic integrated circuit, and
a plurality of sets of first electronic integrated circuits, in which each set of the first electronic integrated circuit is associated with one of the photonic integrated circuits, each set of the first electronic integrated circuits includes at least two electronic integrated circuits that are coupled to the first surface of the associated photonic integrated circuit.

Embodiment 4: The system of embodiment 3 in which each set of first electronic integrated circuits comprises two electronic integrated circuits that are positioned on opposite sides of the optical connector along a plane parallel to the first surface of the associated photonic integrated circuit.

Embodiment 5: The system of embodiment 3 in which each set of first electronic integrated circuits comprises three electronic integrated circuits that surround three sides of the optical connector along a plane parallel to the first surface of the photonic integrated circuit.

Embodiment 6: The system of embodiment 3 in which each set of first electronic integrated circuits comprises four electronic integrated circuits that surround four sides of the optical connector along a plane parallel to the first surface of the photonic integrated circuit.

Embodiment 7: The system of any of embodiments 3 to 6 in which each set of first electronic integrated circuits comprises at least one of an electrical drive amplifier or a transimpedance amplifier.

Embodiment 8: The system of any of embodiments 1 to 7 in which the first optical input/output module comprises:
a substrate, in which the plurality of photonic integrated circuits are mounted on the substrate, and
a plurality of sets of second electronic integrated circuits mounted on the substrate, each set of second electronic integrated circuits is associated with a photonic integrated circuit and electrically coupled to the photonic integrated circuit through one or more signal conductors and/or traces.

Embodiment 9: The system of embodiment 8 in which each set of second electronic integrated circuits comprises three electronic integrated circuits that surround three sides of the photonic integrated circuit along a plane parallel to a first surface of the substrate.

Embodiment 10: The system of embodiment 8 in which each set of second electronic integrated circuits comprises four electronic integrated circuits that surround four sides of the photonic integrated circuit along a plane parallel to a first surface of the substrate.

Embodiment 11: The system of any of embodiments 8 to 10 in which each set of second electronic integrated circuits comprises a serializers/deserializers module.

Embodiment 12: The system of any of embodiments 1 to 11 in which each of at least some of the photonic integrated circuits comprises an array of grating couplers, a plurality of optical waveguides coupled to the array of grating couplers, and a plurality of photodetectors coupled to the plurality of optical waveguides.

Embodiment 13: The system of any of embodiments 1 to 12 in which each of the at least one data processor comprises at least one of a network switch, a central processor unit, a graphics processor unit, a tensor processing unit, a neural network processor, an artificial intelligence accelerator, a digital signal processor, a microcontroller, an application specific integrated circuit (ASIC), or a data storage device.

Embodiment 14: The system of any of embodiments 1 to 13, comprising a wafer-scale processing module comprising a plurality of data processors, in which the first optical input/output module is configured to receive a plurality of first optical signals through at least some of a plurality of optical links, generate a plurality of first electrical signals based on the plurality of first optical signals, and transmit the plurality of first electrical signals to the data processors directly or through the interface circuit.

Embodiment 15: The system of embodiment 14 in which the plurality of data processors are configured to generate a plurality of second electrical signals that are transmitted to the first optical input/output modules directly or through the interface circuit, the first optical input/output module is configured to generate a plurality of second optical signals based on the plurality of second electrical signals, and output the plurality of optical signals through at least some of the plurality of optical links.

Embodiment 16: The system of embodiment 14 or 15 in which the wafer-scale processing module comprises a wafer and a two-dimensional arrangement of at least three data processors formed on the wafer.

Embodiment 17: The system of embodiment 16 in which the two-dimensional arrangement of at least three data processors comprises an array of at least two rows and at least two columns of data processors.

Embodiment 18: The system of embodiment 17 in which the array of data processors comprise at least three rows and at least three columns of data processors.

Embodiment 19: The system of embodiment 18 in which the array of data processors comprise at least four rows and at least four columns of data processors.

Embodiment 20: The system of any of embodiments 14 to 19 in which the first optical input/output module comprises at least four photonic integrated circuits that are configured to transmit electrical signals to and receive electrical signals from the wafer-scale processing module.

Embodiment 21: The system of embodiment 20 in which the first optical input/output module comprises at least eight photonic integrated circuits that are configured to transmit electrical signals to and receive electrical signals from the wafer-scale processing module.

Embodiment 22: The system of embodiment 21 in which the first optical input/output module comprises at least sixteen photonic integrated circuits that are configured to transmit electrical signals to and receive electrical signals from the wafer-scale processing module.

Embodiment 23: The system of embodiment 22 in which the first optical input/output module comprises at least thirty-two photonic integrated circuits that are configured to transmit electrical signals to and receive electrical signals from the wafer-scale processing module.

Embodiment 24: The system of embodiment 23 in which the first optical input/output module comprises at least sixty-four photonic integrated circuits that are configured to transmit electrical signals to and receive electrical signals from the wafer-scale processing module.

Embodiment 25: The system of any of embodiments 14 to 24 in which each of more than half of the photonic integrated circuits in the first optical input/output module has electronic integrated circuits arranged at four sides of the photonic integrated circuit.

Embodiment 26: The system of embodiment 25 in which each of more than 80% of the photonic integrated circuits in the first optical input/output module has electronic integrated circuits arranged at four sides of the photonic integrated circuit.

Embodiment 27: The system of any of embodiments 1 to 26 in which the plurality of photonic integrated circuits are arranged in a staggered array configuration.

Embodiment 28: The system of embodiment 27 in which the plurality of photonic integrated circuits comprises a staggered array of photonic integrated circuits,
wherein the staggered array comprising a first row, a second row, and a third row,
wherein in the first row, the photonic integrated circuits are positioned at (x, y) coordinates (1, 1), (3, 1), (5, 1), . . . , (n1, 1), n1 being an odd number,
wherein in the second row, the photonic integrated circuits are positioned at (x, y) coordinates (2, 2), (4, 2), (6, 2), . . . , (n2, 2), n2 being an even number,
wherein in the third row, the photonic integrated circuits are positioned at (x, y) coordinates (1, 3), (3, 3), (5, 3), . . . , (n3, 3), n3 being an odd number.

Embodiment 29: The system of any of embodiments 14 to 28 in which the wafer-scale processing module has a first edge and a second edge, the first optical input/output module is positioned in a vicinity of the first edge,
wherein the system comprises a second optical input/output module that is positioned in a vicinity of the second edge of the wafer-scale processing module,
wherein the second optical input/output module comprises a plurality of photonic integrated circuits arranged in a two-dimensional pattern comprising at least three photonic integrated circuits, in which each of at least some of the photonic integrated circuits is configured to receive third optical signals and generate third electrical signals based on the third optical signals, each of at least some of the photonic integrated circuits is configured to receive fourth electrical signals and generate fourth optical signals based on the fourth electrical signals,
wherein at least some of the data processors in the wafer-scale processing module are configured to receive the third electrical signals generated by the second optical input/output module, and to transmit the fourth electrical signals to the second optical input/output module.

Embodiment 30: The system of embodiment 29 in which the wafer-scale processing module has a third edge,
wherein the system comprises a third optical input/output module that is positioned in a vicinity of the third edge of the wafer-scale processing module,
wherein the third optical input/output module comprises a plurality of photonic integrated circuits arranged in a two-dimensional pattern comprising at least three photonic integrated circuits, in which each of at least some of the photonic integrated circuits is configured to receive 5^{th} optical signals and generate 5^{th} electrical signals based on the 5^{th} optical signals, each of at least some of the photonic integrated circuits is configured to receive 6^{th} electrical signals and generate 6^{th} optical signals based on the 6^{th} electrical signals,
wherein at least some of the data processors in the wafer-scale processing module are configured to receive the 5^{th} electrical signals generated by the third optical input/output module, and to transmit the 5^{th} electrical signals to the third optical input/output module.

Embodiment 31: The system of embodiment 30 in which the wafer-scale processing module has a fourth edge,
wherein the system comprises a fourth optical input/output module that is positioned in a vicinity of the fourth edge of the wafer-scale processing module,
wherein the fourth optical input/output module comprises a plurality of photonic integrated circuits arranged in a two-dimensional pattern comprising at least three photonic integrated circuits, in which each of at least some of the photonic integrated circuits is configured to receive 7^{th} optical signals and generate 7^{th} electrical signals based on the 7^{th} optical signals, each of at least some of the photonic integrated circuits is configured to receive 8^{th} electrical signals and generate 8^{th} optical signals based on the 8^{th} electrical signals,
wherein at least some of the data processors in the wafer-scale processing module are configured to receive the 7^{th} electrical signals generated by the fourth optical input/output module, and to transmit the 8^{th} electrical signals to the fourth optical input/output module.

Embodiment 32: The system of any of embodiments 29 to 31 in which the first optical input/output module is configured to support at least 50 Tbps data throughput to the first edge of the wafer-scale processing module.

Embodiment 33: The system of any of embodiments 29 to 32 in which the second optical input/output module is configured to support at least 50 Tbps data throughput to the second edge of the wafer-scale processing module.

Embodiment 34: The system of any of embodiments 30 to 33 in which the third optical input/output module is configured to support at least 50 Tbps data throughput to the third edge of the wafer-scale processing module.

Embodiment 35: The system of any of embodiments 31 to 34 in which the fourth optical input/output module is configured to support at least 50 Tbps data throughput to the fourth edge of the wafer-scale processing module.

Embodiment 36: The system of embodiment 35 in which the first, second, third, and fourth optical input/output modules are configured to support an aggregate data throughput of at least 200 Tbps to the wafer-scale processing module.

Embodiment 37: The system of any of embodiments 8 to 36 in which each of some of the second electronic integrated circuits is electrically interconnected to two or more photonic integrated circuits.

Embodiment 38: The system of embodiment 37 in which each of some of the second electronic integrated circuits comprises a serializers/deserializers module that is configured to condition the electrical signals transmitted to or from two or more photonic integrated circuits.

Embodiment 39: The system of any of embodiments 14 to 38 in which the first optical input/output module comprises two rows of photonic integrated circuits that support an aggregate data throughput of approximately 59.1 Tbps.

Embodiment 40: The system of embodiment 39 in which the wafer-scale processing module has a first edge, the first optical input/output module is positioned in a vicinity of the first edge, and the first optical input/output module is configured to support an aggregate data throughput per unit edge length of approximately 288 Gbps/mm.

Embodiment 41: The system of any of embodiments 14 to 40 in which the first optical input/output module comprises three rows of photonic integrated circuits that support an aggregate data throughput of approximately 89.6 Tbps.

Embodiment 42: The system of embodiment 41 in which the wafer-scale processing module has a first edge, the first optical input/output module is positioned in a vicinity of the first edge, and the first optical input/output module is configured to support an aggregate data throughput per unit edge length of approximately 437 Gbps/mm.

Embodiment 43: The system of any of embodiments 14 to 42 in which the first optical input/output module comprises four rows of photonic integrated circuits that support an aggregate data throughput of approximately 118.3 Tbps.

Embodiment 44: The system of embodiment 43 in which the wafer-scale processing module has a first edge, the first optical input/output module is positioned in a vicinity of the first edge, and the first optical input/output module is configured to support an aggregate data throughput per unit edge length of approximately 576 Gbps/mm.

Embodiment 45: The system of any of embodiments 14 to 43 in which the first optical input/output module comprises five rows of photonic integrated circuits that support an aggregate data throughput of approximately 148.7 Tbps.

Embodiment 46: The system of embodiment 45 in which the wafer-scale processing module has a first edge, the first optical input/output module is positioned in a vicinity of the first edge, and the first optical input/output module is configured to support an aggregate data throughput per unit edge length of approximately 725 Gbps/mm.

Embodiment 47: The system of any of embodiments 1 to 46 in which the at least one data processor comprises an integrated circuit or a system on a chip (SoC) that includes at least one million transistors.

Embodiment 48: The system of any of embodiments 14 to 47 in which the wafer-scale processing module comprises at least one billion transistors.

Embodiment 49: The system of any of embodiments 1 to 48 in which the first optical input/output module comprises a plurality of co-packaged optical modules, each co-packaged optical module comprises at least one of the photonic integrated circuits.

Embodiment 50: The system of embodiment 49 in which each co-packaged optical module comprises a first optical connector part that is configured to be removably coupled to a second optical connector part that is attached to a first fiber cable that comprises an array of optical fibers.

Embodiment 51: The system of embodiment 50 in which the fiber cable comprises at least 10 cores of optical fibers, and the first optical connector part is configured to couple at least 10 channels of optical signals to the photonic integrated circuit.

Embodiment 52: The system of embodiment 51 in which the fiber cable comprises at least 100 cores of optical fibers, and the first optical connector part is configured to couple at least 100 channels of optical signals to the photonic integrated circuit.

Embodiment 53: The system of embodiment 52 in which the fiber cable comprises at least 500 cores of optical fibers, and the first optical connector part is configured to couple at least 500 channels of optical signals to the photonic integrated circuit.

Embodiment 54: The system of embodiment 53 in which the fiber cable comprises at least 1000 cores of optical fibers, and the first optical connector part is configured to couple at least 1000 channels of optical signals to the photonic integrated circuit.

Embodiment 55: The system of any of embodiments 49 to 54 in which the photonic integrated circuit is configured to generate a plurality of first serial electrical signals based on the received optical signals, in which each first serial electrical signal is generated based on one of the channels of first optical signals;
wherein the co-packaged optical module comprises:
   a first serializers/deserializers module comprising multiple serializer units and deserializer units, the first serializers/deserializers module is configured to generate a plurality of sets of first parallel electrical signals based on the plurality of first serial electrical signals, and condition the electrical signals, and each set of first parallel electrical signals is generated based on a corresponding first serial electrical signal; and
   a second serializers/deserializers module comprising multiple serializer units and deserializer units, in which the second serializers/deserializers module is configured to generate a plurality of second serial electrical signals based on the plurality of sets of first parallel electrical signals, and each second serial electrical signal is generated based on a corresponding set of first parallel electrical signals.

Embodiment 56: The system of any of embodiments 49 to 54 in which the co-packaged optical module is electrically coupled to a circuit board or a substrate using electrical contacts that comprise at least one of spring-loaded elements, compression interposers, or land-grid arrays.

Embodiment 57: The system of any of embodiments 1 to 56 in which the system comprises a rackmount server, the housing comprises an enclosure for the rackmount server, and the rackmount server has an n rack unit form factor, and n is an integer in a range from 1 to 8.

Embodiment 58: The system of any of embodiments 1 to 57 in which the interface circuit comprises at least one of a converter or retimer, and the converter or retimer comprises at least one of an XLR-to-XLR retimer, an LR-to-LR retimer, an MR-to-MR retimer, an SR-to-SR retimer, a BoW-to-BoW retimer, an XLR-to-LR converter, an XLR-to-MR converter, an XLR-to-SR converter, an XLR-to-XSR converter, an LR-to-MR converter, an LR-to-SR converter, an LR-to-XSR converter, an MR-to-SR converter, an MR-to-XSR converter, an SR-to-XSR converter, an XLR-to-BoW converter, an LR-to-BoW converter, an MR-to-BoW converter, or an XSR-to-BoW converter.

Embodiment 59: A supercomputer that comprises the system of any of embodiments 1 to 58.

Embodiment 60: The system of any of embodiments 14 to 58 in which the wafer-scale processing module comprises an artificial intelligence processor.

Embodiment 61: The system of any of embodiments 14 to 58 in which the system is configured to simulate weather.

Embodiment 62: The system of any of embodiments 14 to 58 in which the system is configured to construct and/or support a metaverse that includes one or more virtual environments and enable users to interact with one another in the one or more virtual environments, or interact with objects in the one or more virtual environments.

Embodiment 63: The system of any of embodiments 14 to 58 in which the system is configured to construct and/or support a simulated environment for training autonomous vehicles.

Embodiment 64: An autonomous vehicle that comprises the system of any of embodiments 1 to 58 and 60, or the supercomputer of embodiment 59.

Embodiment 65: The autonomous vehicle of embodiment 64 in which the vehicle comprises at least one of a car, a truck, a train, a boat, a ship, a submarine, a helicopter, a drone, an airplane, a space rover, or a space ship.

Embodiment 66: A robot that comprises the system of any of embodiments 1 to 58 and 60, or the supercomputer of embodiment 59.

Embodiment 67: The robot of embodiment 66 in which the robot comprises at least one of an industrial robot, a helper robot, a medical surgery robot, a merchandise delivery robot, a teaching robot, a cleaning robot, a cooking robot, a construction robot, or an entertainment robot.

Embodiment 68: A system comprising:
a wafer-scale processing module comprising an array of data processors,
a first optical input/output module comprising a plurality of photonic integrated circuits arranged in a two-dimensional pattern comprising at least three photonic integrated circuits, in which each of at least some of the photonic integrated circuits are configured to receive first optical signals and generate first electrical signals based on the first optical signals, each of at least some of the photonic integrated circuits is configured to receive second electrical signals and generate second optical signals based on the second electrical signals; and
wherein at least some of the data processors are configured to receive, directly or through an interface circuit, the first electrical signals generated by at least some of the photonic integrated circuits, and at least some of the data processors are configured to transmit, directly or through the interface circuit, the second electrical signals to at least some of the photonic integrated circuits.

Embodiment 69: The system of embodiment 68 in which the first optical input/output module comprises an edge interface module that is disposed near an edge of the wafer-scale processor, and is configured to transmit electrical signals to and receive electrical signals from data processors positioned near the edge of the wafer-scale processing module.

Embodiment 70: The system of embodiment 68 or 69 in which the first optical input/output module is configured to support at least 50 Tbps data throughput to an edge of the wafer-scale processing module.

Embodiment 71: The system of embodiment 70 in which the first optical input/output module is configured to support at least 100 Tbps data throughput to an edge of the wafer-scale processing module.

Embodiment 72: The system of any of embodiments 68 to 71 in which the wafer-scale processing module comprises a semiconductor wafer, and the data processors are formed on the semiconductor wafer or mounted on the semiconductor wafer, wherein the photonic integrated circuits are mounted on a substrate, wherein electrical contacts on the substrate are electrically coupled to electrical contacts on the semiconductor wafer.

Embodiment 73: The system of any of embodiments 68 to 71 in which the wafer-scale processing module comprises a semiconductor wafer, and the data processors are formed on the semiconductor wafer or mounted on the semiconductor wafer,
wherein some of the photonic integrated circuits are mounted on a first substrate, and electrical contacts on the first substrate are electrically coupled to electrical contacts on a first side of the semiconductor wafer;
wherein the first optical input/output module comprises a second group of plurality of photonic integrated circuits arranged in a two-dimensional pattern comprising at least three photonic integrated circuits, in which each of at least some of the photonic integrated circuits are configured to receive third optical signals and generate third electrical signals based on the third optical signals, each of at least some of the photonic integrated circuits is configured to receive fourth electrical signals and generate fourth optical signals based on the fourth electrical signals; and
wherein at least some of the data processors are configured to receive the third electrical signals generated by at least some of the second group of photonic integrated circuits, and at least some of the data processors are configured to transmit the fourth electrical signals to at least some of the second group of photonic integrated circuits;
wherein some of the second group of photonic integrated circuits are mounted on a second substrate, and electrical contacts on the second substrate are electrically coupled to electrical contacts on a second side of the semiconductor wafer.

Embodiment 74: The system of embodiment 72 or 73 in which the photonic integrated circuits are electrically coupled to the data processors through a first set of signal lines on the substrate and a second set of signal lines on the semiconductor wafer,
wherein signal propagation loss for the second set of signal lines on the semiconductor wafer is higher than the signal propagation loss for the first set of signal lines on the substrate for a given propagation length,
wherein a longer signal line in the first set is coupled to a shorter signal line in the second set, and a shorter signal line in the first set is coupled to a longer signal line in the second set, to reduce the maximum signal propagation loss for the signals transmitted between the photonic integrated circuits and the data processors.

Embodiment 75: The system of any of embodiments 68 to 74 in which the first optical input/output module comprises a plurality of co-packaged optical (CPO) modules, each CPO module includes a photonic integrated circuit and an electronic integrated circuit, the electronic integrated circuit includes at least one of (i) an XSR chip, (ii) a driver amplifier, or (iii) a transimpedance amplifier (TIA).

Embodiment 76: The system of any of embodiments 68 to 74 in which the first optical input/output module comprises:
a substrate,
a plurality of co-packaged optical (CPO) modules mounted on the substrate, each CPO module includes a photonic integrated circuit and an electronic integrated circuit, the electronic integrated circuit includes at least one of (i) a driver amplifier, or (ii) a transimpedance amplifier (TIA),
a plurality of XSR-to-XSR converters that are disposed near a first edge of the substrate, in which the first edge is positioned near the data processors, the XSR-to-XSR converters are configured to regenerate signals transmitted between the CPO modules to the data processors.

Embodiment 77: The system of any of embodiments 68 to 74 in which the first optical input/output module comprises:
a substrate,
a plurality of co-packaged optical (CPO) modules mounted on the substrate, each CPO module includes a photonic integrated circuit and an electronic integrated circuit, the electronic integrated circuit includes at least one of (i) a driver amplifier, or (ii) a transimpedance amplifier (TIA),
a plurality of XSR-to-LR or XSR-to-MR converters that are disposed near a first edge of the substrate, in which the first edge is positioned near the data processors, and the XSR-to-LR or XSR-to-MR converters are configured to regenerate signals transmitted between the CPO modules and the data processors.

Embodiment 78: The system of embodiment 77 in which each of at least a subset of the co-packaged optical (CPO) modules is surrounded by other CPO modules and does not have any XSR chip between the CPO module and other CPO modules.

Embodiment 79: The system of any of embodiments 68 to 74 in which the first optical input/output module comprises:
a substrate, in which the photonic integrated circuits are mounted on the substrate,
a plurality of XSR-to-LR or XSR-to-MR converters that are disposed near a first edge of the substrate, in which the first edge is positioned near the data processors, and the XSR-to-LR or XSR-to-MR converters are configured to regenerate signals transmitted between the photonic integrated circuits and the data processors.

Embodiment 80: The system of embodiment 79 in which each photonic integrated circuit is driven directly by a corresponding XSR-to-LR or XSR-to-MR converter without a separate driver amplifier or transimpedance amplifier.

Embodiment 81: The system of any of embodiments 68 to 80 in which the interface circuit comprises at least one of a converter or retimer, and the converter or retimer comprises at least one of an XLR-to-XLR retimer, an LR-to-LR retimer, an MR-to-MR retimer, an SR-to-SR retimer, a BoW-to-BoW retimer, an XLR-to-LR converter, an XLR-to-MR converter, an XLR-to-SR converter, an XLR-to-XSR converter, an LR-to-MR converter, an LR-to-SR converter, an LR-to-XSR converter, an MR-to-SR converter, an MR-to-XSR converter, an SR-to-XSR converter, an XLR-to-BoW converter, an LR-to-BoW converter, an MR-to-BoW converter, or an XSR-to-BoW converter.

Embodiment 82: A method comprising:
using a first optical input/output module as a high throughput input to a wafer-scale processing module comprising an array of data processors, including using the first optical input/output module to support at least 50 Tbps data throughput to a first edge the wafer-scale processing module;
wherein the first optical input/output module comprising a plurality of photonic integrated circuits arranged in a two-dimensional pattern comprising at least three photonic integrated circuits,
wherein each of at least some of the photonic integrated circuits receives first optical signals, generates first electrical signals based on the first optical signals, and transmits the first electrical signals to the wafer-scale processing module,
and each of at least some of the photonic integrated circuits receives second electrical signals from the wafer-scale processing module, generates second optical signals based on the second electrical signals, and outputs the second optical signals through one or more optical links.

Embodiment 83: The method of embodiment 82, comprising using the first optical input/output module to support at least 100 Tbps data throughput to the first edge of the wafer-scale processing module.

Embodiment 84: The method of embodiment 82, comprising using a second optical input/output module to support at least 50 Tbps data throughput to a second edge of the wafer-scale processing module.

Embodiment 85: The method of embodiment 84, comprising using a third optical input/output module to support at least 50 Tbps data throughput to a third edge of the wafer-scale processing module.

Embodiment 86: The method of embodiment 85, comprising using a fourth optical input/output module to support at least 50 Tbps data throughput to a fourth edge of the wafer-scale processing module, in which the first, second, third, and fourth optical input/output modules are configured to support an aggregate data throughput of at least 200 Tbps to the wafer-scale processing module.

Embodiment 87: A system comprising:
a multi-wafer processing module comprising:
   a first wafer-scale processing module comprising a first array of data processors and a first optical input/output module, in which the first optical input/output module comprises at least three photonic integrated circuits arranged in a two-dimensional pattern;
   a second wafer-scale processing module comprising a second array of data processors and a second optical input/output module, in which the second optical input/output module comprises at least three photonic integrated circuits arranged in a two-dimensional pattern; and
   one or more optical fibers that optically connect the first optical input/output module to the second input/output module, wherein the first optical input/output module, the second optical input/output module, and the one or more optical fibers provide one or more optical communication links between the first array of data processors and the second array of data processors.

Embodiment 88: The system of embodiment 87 in which the first wafer-scale processing module and the second wafer-scale processing module are positioned side-by-side, the first array of data processors and the second array of data processors face a same direction.

Embodiment 89: The system of embodiment 88 in which the first wafer-scale processing module comprises a first substrate, the first array of data processors are coupled to
the first substrate, the second wafer-scale processing module comprises a second substrate, the second array of data processors are coupled to the second substrate, the first and second wafer-scale processing modules are vertically stacked such that the first array of data processors face toward the second array of data processors, wherein the first and second arrays of data processors are positioned between the first and second substrates.

Embodiment 90: The system of embodiment 89 in which the first substrate comprises a first semiconductor wafer, and the second substrate comprises a second semiconductor wafer.

Embodiment 91: The system of embodiment 89 or 90, comprising a first shared power supply positioned between the first wafer-scale processing module and the second wafer-scale processing module, in which the first shared power supply is configured to provide power to the first array of data processors and the second array of data processors.

Embodiment 92: The system of any of embodiments 89 to 91, comprising a first shared cooling device positioned between the first wafer-scale processing module and the second wafer-scale processing module, in which the first shared cooling device is configured to remove heat from the first array of data processors and the second array of data processors.

Embodiment 93: The system of any of embodiments 89 to 92, comprising a third wafer-scale processing module comprising a third array of data processors and a third optical input/output module, in which the third optical input/output module comprises at least three photonic integrated circuits arranged in a two-dimensional pattern,
wherein the first, second, and third wafer-scale processing modules are vertically stacked together.

Embodiment 94: The system of embodiment 93, comprising a second shared power supply positioned between the second wafer-scale processing module and the third wafer-scale processing module, in which the second shared power supply is configured to provide power to the second array of data processors and the third array of data processors.

Embodiment 95: The system of embodiment 93 or 94, comprising a second shared cooling device positioned between the second wafer-scale processing module and the third wafer-scale processing module, in which the second shared cooling device is configured to remove heat from the second array of data processors and the third array of data processors.

Embodiment 96: The system of any of embodiments 93 to 95, comprising a fourth wafer-scale processing module comprising a fourth array of data processors and a fourth optical input/output module, in which the fourth optical input/output module comprises at least three photonic integrated circuits arranged in a two-dimensional pattern, wherein the first, second, third, and fourth wafer-scale processing modules are vertically stacked together.

Embodiment 97: The system of embodiment 96, comprising a third shared power supply positioned between the third wafer-scale processing module and the fourth wafer-scale processing module, in which the third shared power supply is configured to provide power to the third array of data processors and the fourth array of data processors.

Embodiment 98: The system of embodiment 96 or 97, comprising a third shared cooling device positioned between the third wafer-scale processing module and the fourth wafer-scale processing module, in which the third shared cooling device is configured to remove heat from the third array of data processors and the fourth array of data processors.

Embodiment 99: The system of any of embodiments 96 to 98 in which the second wafer-scale processing module comprises a second substrate, the second array of data processors are coupled to the second substrate, the third wafer-scale processing module comprises a third substrate, the third array of data processors are coupled to the third substrate, and a back side of the second substrate faces a back side of the third substrate.

Embodiment 100: The system of embodiment 99 in which the second shared power supply provides power to the second array of data processors through conductive lines that pass through the second substrate, and the second shared power supply provides power to the third array of data processors through conductive lines that pass through the third substrate.

Embodiment 101: The system of embodiment 99 or 100 in which the second shared cooling device removes heat from the second array of data processors through thermally conductive paths that pass through the second substrate, and the second shared cooling device removes heat from the third array of data processors through thermally conductive paths that pass through the third substrate.

Embodiment 102: A system comprising:
a large scale multi-wafer processing module comprising:
   two or more multi-wafer processing modules arranged in a two-dimensional array, in which each multi-wafer processing module comprises two or more wafer-scale processing modules vertically stacked together;
   wherein at least one wafer-scale processing module communicates with another wafer-scale processing modules through optical communication links.

Embodiment 103: The system of embodiment 102 in which each wafer-scale processing module comprises an array of data processors and an optical input/output module, in which a first wafer-scale processing module is optically linked to a second wafer-scale processing module through a first optical input/output module of the first wafer-scale processing module, a second optical input/output module of the second wafer-scale processing module, and an optical fiber cable that connects the first optical input/output module to the second optical input/output module.

Embodiment 104: A system comprising:
a processing module comprising:
   at least one data processor coupled directly or indirectly to a first substrate; and
   a first optical input/output module comprising at least three photonic integrated circuits coupled directly or indirectly to a second substrate, the at least three photonic integrated circuits arranged in a two-dimensional pattern, the at least three photonic integrated circuits comprising three photonic integrated circuits arranged in a pattern forming a triangle;
   wherein each of the at least three photonic integrated circuits comprises at least three vertical couplers arranged in a two-dimensional pattern, the at least three vertical couplers comprising three vertical couplers arranged in a pattern forming a triangle;
   wherein the photonic integrated circuits are configured to convert input optical signals received at the vertical couplers to input electrical signals that are transmitted directly or indirectly to the at least one data processor.

Embodiment 105: The system of embodiment 104 in which the at least one data processor comprise a plurality of data processors arranged in a two dimensional pattern, the plurality of data processors comprising three data processors arranged in a pattern forming a triangle.

Embodiment 106: The system of embodiment 104 or 105 in which the at least three photonic integrated circuits comprise N1 photonic integrated circuits, N1 is an integer that is greater than or equal to 3, each photonic integrated circuit comprises at least N2 vertical couplers configured to receive input optical signals from fiber cores, N1 is an integer that is greater than or equal to 3,
wherein the first optical input/output module provides an interface between the at least one data processor and N1 bundles of fiber cores, each bundle of fiber cores is coupled to the vertical couplers of a corresponding photonic integrated circuit, and each bundle of fiber cores comprise at least N2 fiber cores.

Embodiment 107: The system of any of embodiments 104 to 106 in which the at least three photonic integrated circuits comprise at least 10 photonic integrated circuits, and each photonic integrated circuit comprises at least 10 vertical couplers configured to receive input optical signals from corresponding fiber cores,
wherein the first optical input/output module provides an interface between the at least one data processor and 10 bundles of fiber cores, and each bundle of fiber cores comprise at least 10 fiber cores.

Embodiment 108: The system of any of embodiments 104 to 107 in which the at least one data processor comprises a wafer-scale processor comprising a plurality of data processors,
wherein the processing module comprises an edge processing module positioned near an edge of the wafer-scale processor, and the edge processing module comprises the first optical input/output module.

Embodiment 109: The system of any of embodiments 104 to 108 in which the wafer-scale processor comprises a plurality of data processors that have a footprint of at least 10 cm×10 cm, each data processor comprises at least one million transistors.

Embodiment 110: The system of embodiment 109 in which the plurality of data processors have a footprint of at least 15 cm×15 cm.

Embodiment 111: The system of embodiment 110 in which the plurality of data processors have a footprint of at least 20 cm×20 cm.

Embodiment 112: The system of any of embodiments 109 to 111 in which the edge processing module is configured to support a communication interface of at least 500 Gbps data throughput between the wafer-scale processor and a plurality of optical fibers.

Embodiment 113: The system of embodiment 112 in which the edge processing module is configured to support a communication interface of at least 1 tetra bps data throughput between the wafer-scale processor and a plurality of optical fibers.

Embodiment 114: The system of embodiment 113 in which the edge processing module is configured to support a communication interface of at least 1.5 tetra bps data throughput between the wafer-scale processor and a plurality of optical fibers.

Embodiment 115: A system comprising:
a processing module comprising:
   a wafer-scale processor comprising an array of at least 4 rows and 4 columns of data processors, in which each data processor comprises at least one million transistors, the wafer-scale processor comprises 4 edges, the wafer-scale processor is configured to be capable of a data processing throughput of at least 500 Gbps; and
   four edge processing modules, in which each edge processing module is positioned near a corresponding edge of the wafer scale processor, each edge processing module comprises an array of at least 2 rows and at least 8 columns of photonic integrated circuits, each photonic integrated circuit comprises at least 2 rows and at least 8 columns of vertical couplers that are configured to receive input optical signals from optical fiber cores or transmit output optical signals to optical fiber cores;
   wherein the four edge processing modules provide communication interfaces between the wafer-scale processor and the optical fiber cores.

1. A system comprising:
a first optical input/output module comprising a plurality of photonic integrated circuits arranged in a two-dimensional pattern comprising at least three photonic integrated circuits, in which each of at least some of the photonic integrated circuits is configured to receive first optical signals and generate first electrical signals based on the first optical signals, each of at least some of the photonic integrated circuits is configured to receive second electrical signals and generate second optical signals based on the second electrical signals; and
at least one data processor that is configured to receive, directly or through an interface circuit, the first electrical signals generated by at least some of the photonic integrated circuits, and to transmit, directly or through the interface circuit, the second electrical signals to at least some of the photonic integrated circuits.

2. The system of claim 1 in which the first optical input/output module comprises a plurality of photonic integrated circuits arranged in a two-dimensional array comprising at least two rows and at least two columns of photonic integrated circuits.

3. The system of claim 1 in which the first optical input/output module comprises:
a plurality of optical connectors, in which each optical connector is associated with a photonic integrated circuit, the optical connector is coupled to a first surface of the photonic integrated circuit, and
a plurality of sets of first electronic integrated circuits, in which each set of the first electronic integrated circuit is associated with one of the photonic integrated circuits, each set of the first electronic integrated circuits includes at least two electronic integrated circuits that are coupled to the first surface of the associated photonic integrated circuit.

4. The system of claim 3 in which each set of first electronic integrated circuits comprises two electronic integrated circuits that are positioned on opposite sides of the optical connector along a plane parallel to the first surface of the associated photonic integrated circuit.

5. The system of claim 3 in which each set of first electronic integrated circuits comprises three electronic integrated circuits that surround three sides of the optical connector along a plane parallel to the first surface of the photonic integrated circuit.

6. The system of claim 3 in which each set of first electronic integrated circuits comprises four electronic integrated circuits that surround four sides of the optical connector along a plane parallel to the first surface of the photonic integrated circuit.

7. The system of claim 3 in which each set of first electronic integrated circuits comprises at least one of an electrical drive amplifier or a transimpedance amplifier.

8. The system of claim 1 in which the first optical input/output module comprises:
a substrate, in which the plurality of photonic integrated circuits are mounted on the substrate, and
a plurality of sets of second electronic integrated circuits mounted on the substrate, each set of second electronic integrated circuits is associated with a photonic integrated circuit and electrically coupled to the photonic integrated circuit through one or more signal conductors and/or traces.

9. The system of claim 8 in which each set of second electronic integrated circuits comprises three electronic integrated circuits that surround three sides of the photonic integrated circuit along a plane parallel to a first surface of the substrate.

10. The system of claim 8 in which each set of second electronic integrated circuits comprises four electronic integrated circuits that surround four sides of the photonic integrated circuit along a plane parallel to a first surface of the substrate.

11. The system of claim 8 in which each set of second electronic integrated circuits comprises a serializers/deserializers module.

12. The system of claim 1 in which each of at least some of the photonic integrated circuits comprises an array of grating couplers, a plurality of optical waveguides coupled to the array of grating couplers, and a plurality of photodetectors coupled to the plurality of optical waveguides.

13. The system of claim 1 in which each of the at least one data processor comprises at least one of a network switch, a central processor unit, a graphics processor unit, a tensor processing unit, a neural network processor, an artificial intelligence accelerator, a digital signal processor, a microcontroller, an application specific integrated circuit (ASIC), or a data storage device.

14. The system of claim 1, comprising a wafer-scale processing module comprising a plurality of data processors, in which the first optical input/output module is configured to receive a plurality of first optical signals through at least some of a plurality of optical links, generate a plurality of first electrical signals based on the plurality of first optical signals, and transmit the plurality of first electrical signals to the data processors directly or through the interface circuit.

15. The system of claim 14 in which the plurality of data processors are configured to generate a plurality of second electrical signals that are transmitted to the first optical input/output modules directly or through the interface circuit, the first optical input/output module is configured to generate a plurality of second optical signals based on the plurality of second electrical signals, and output the plurality of optical signals through at least some of the plurality of optical links.

16. The system of claim 14 in which the wafer-scale processing module comprises a wafer and a two-dimensional arrangement of at least three data processors formed on the wafer.

17. The system of claim 16 in which the two-dimensional arrangement of at least three data processors comprises an array of at least two rows and at least two columns of data processors.

18. The system of claim 17 in which the array of data processors comprise at least three rows and at least three columns of data processors.

19-67. (canceled)

68. A system comprising:
a wafer-scale processing module comprising an array of data processors,
a first optical input/output module comprising a plurality of photonic integrated circuits arranged in a two-dimensional pattern comprising at least three photonic integrated circuits, in which each of at least some of the photonic integrated circuits are configured to receive first optical signals and generate first electrical signals based on the first optical signals, each of at least some of the photonic integrated circuits is configured to receive second electrical signals and generate second optical signals based on the second electrical signals; and
wherein at least some of the data processors are configured to receive, directly or through an interface circuit, the first electrical signals generated by at least some of the photonic integrated circuits, and at least some of the data processors are configured to transmit, directly or through the interface circuit, the second electrical signals to at least some of the photonic integrated circuits.

69.-114. (canceled)

115. A system comprising:
a processing module comprising:
a wafer-scale processor comprising an array of at least 4 rows and 4 columns of data processors, in which each data processor comprises at least one million transistors, the wafer-scale processor comprises 4 edges, the wafer-scale processor is configured to be capable of a data processing throughput of at least 500 Gbps; and
four edge processing modules, in which each edge processing module is positioned near a corresponding edge of the wafer scale processor, each edge processing module comprises an array of at least 2 rows and at least 8 columns of photonic integrated circuits, each photonic integrated circuit comprises at least 2 rows and at least 8 columns of vertical couplers that are configured to receive input optical signals from optical fiber cores or transmit output optical signals to optical fiber cores;
wherein the four edge processing modules provide communication interfaces between the wafer-scale processor and the optical fiber cores.
